(19) United States
(12) Patent Application Publication
(10) Pub. No.: US 2025/0228062 A1
(43) Pub. Date: Jul. 10, 2025

(54) LIGHT EMITTING ELEMENT, FUSED POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: SERAN KIM, Yongin-si (KR); HOI-LIM KIM, Yongin-si (KR); SAE ROM PARK, Yongin-si (KR); SEUNGIN BAEK, Yongin-si (KR); Dongsun YOO, Yongin-si (KR)

(21) Appl. No.: 18/970,721

(22) Filed: Dec. 5, 2024

(30) Foreign Application Priority Data
Jan. 4, 2024 (KR) 10-2024-0001563

(51) Int. Cl. H10K 50/11; H10K 59/38; H10K 85/30; H10K 85/40; H10K 85/60

(52) U.S. Cl. CPC H10K 50/11; H10K 59/38; H10K 85/342; H10K 85/346; H10K 85/40; H10K 85/623; H10K 85/633; H10K 85/636; H10K 85/654; H10K 85/6572; H10K 85/6574; H10K 85/6576; H10K 85/658

(57) ABSTRACT

A light emitting element includes a first electrode, a second electrode on the first electrode, and an emission layer between the first electrode and the second electrode and including a first compound represented by Formula 1.

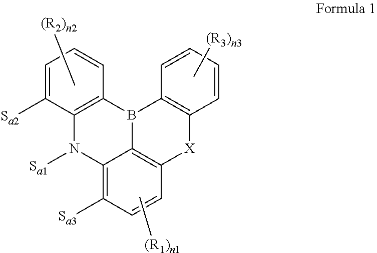

### CROSS-REFERENCE TO RELATED APPLICATION

The present application claims priority to and the benefit of Korean Patent Application No. 10-2024-0001563, filed on Jan. 4, 2024, the entire content of which is incorporated herein by reference.

### BACKGROUND

### 1. Field

One or more embodiments of the present disclosure relate to a light emitting element, a fused polycyclic compound used in the light emitting element, and a display device including the light emitting element.

### 2. Description of the Related Art

As image display devices, organic electroluminescence display devices and/or the like have lately been actively researched and/or developed. Unlike liquid crystal display devices, and/or the like, the organic electroluminescence display devices are self-luminescent display devices in which holes and electrons separately injected from a first electrode and a second electrode combine in an emission layer of the organic electroluminescence display device, and thus a light emitting material including an organic compound in the emission layer emits light to accomplish display of images.

For application of organic electroluminescence elements to display devices, it is desirable for organic electroluminescence elements having a low driving voltage, high luminous efficiency, and a long life, and thus the development of materials, for organic electroluminescence elements, capable of stably attaining such characteristics is being continuously desired or pursued.

In recent years, in order to obtain a highly efficient organic electroluminescence element, technologies pertaining to phosphorescence emission using triplet state energy or fluorescence emission using triplet-triplet annihilation (TTA) in which singlet excitons are generated through collision of triplet excitons are being actively developed or pursued, and thermally activated delayed fluorescence (TADF) materials using a delayed fluorescence phenomenon are under research and development.

### SUMMARY

One or more aspects of embodiments of the present disclosure are directed toward a light emitting element having increased luminous efficiency and longer element service life.

One or more aspects of embodiments of the present disclosure are directed toward a fused polycyclic compound capable of improving luminous efficiency and element service life of a light emitting element including the fused polycyclic compound.

One or more aspects of embodiments of the present disclosure are directed toward a display device having high display quality by including the light emitting element having improved luminous efficiency and lifetime.

Additional aspects will be set forth in part in the description which follows and, in part, will be apparent from the description, or may be learned by practice of the presented embodiments.

According to one or more embodiments of the disclosure, a light emitting element includes a first electrode, a second electrode on the first electrode, and an emission layer between the first electrode and the second electrode and including a first compound represented by Formula 1.

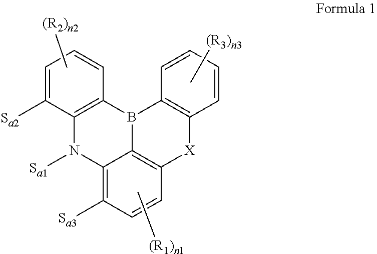

In Formula 1, X may be NR₄, O, S, or Se, Sₐ₂, Sₐ₃, and R₁ to R₄ may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, n1 may be an integer of 0 to 2, n2 may be an integer of 0 to 3, n3 may be an integer of 0 to 4, and any one pair of Sₐ₁ and Sₐ₂ or Sₐ₁ and Sₐ₃ (e.g., any one of the pair of Sₐ₁ and Sₐ₂ or the pair of Sₐ₁ and Sₐ₃) may be positions in which a substituent represented by Formula 2 is connected.

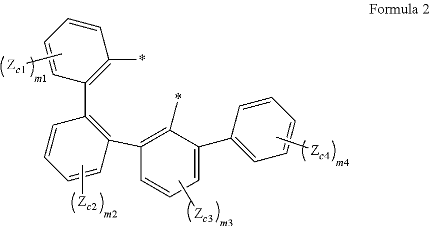

In Formula 2, —* is a position connected to any one pair of Sₐ₁ and Sₐ₂ or Sₐ₁ and Sₐ₃ in Formula 1, Z_{c1} to Z_{c4} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, m1 and m2 may each independently be an integer of 0 to 4, m3 may be an integer of 0 to 3, and m4 may be an integer of 0 to 5.

In one or more embodiments, the first compound represented by Formula 1 may be represented by any one among selected from among Formulas 3-1 to 3-4.

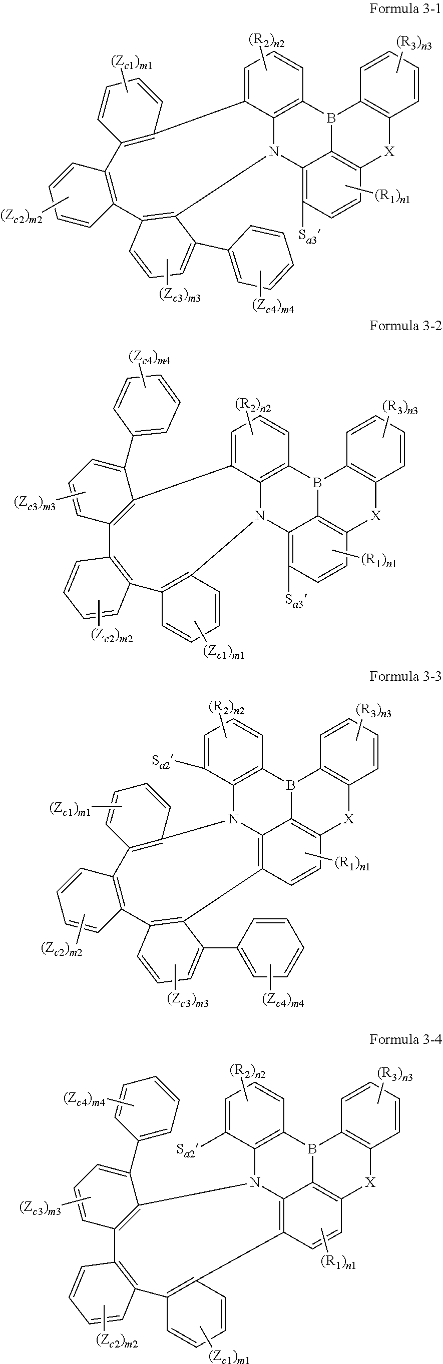

In Formulas 3-1 to 3-4, Sₐ₂′ and Sₐ₃′ may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms.

In Formulas 3-1 to 3-4, X, R₁ to R₃, n1 to n3, Z_{c1} to Z_{c4}, and m1 to m4 may each be the same as defined in Formulas 1 and 2.

In one or more embodiments, the first compound represented by Formula 1 may be represented by Formula 4.

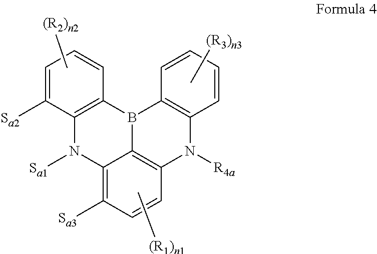

In Formula 4, R₄ₐ may be represented by any one selected from among Formulas S-1 to S-5.

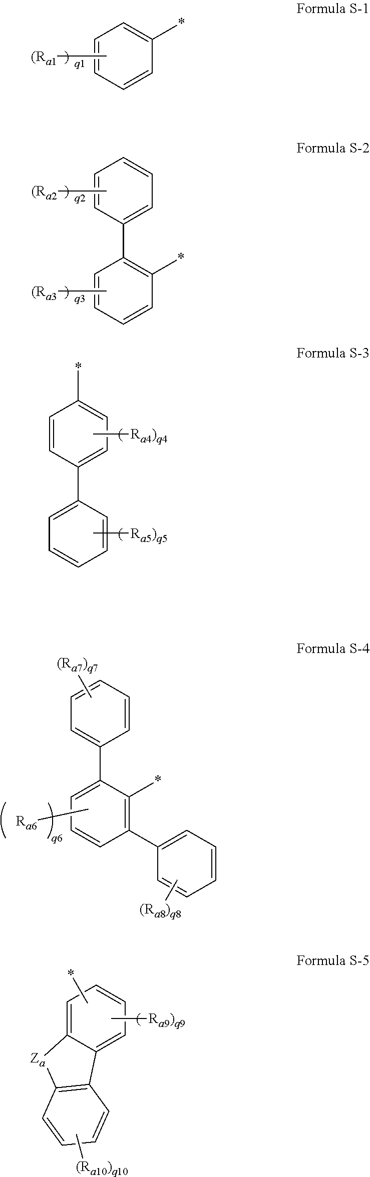

In Formulas S-1 to S-5, Zₐ may be CRₐ₁₁Rₐ₁₂, NRₐ₁₃, O, S, or Se, Rₐ₁ to Rₐ₁₃ may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, q1, q2, q5, q7, and q8 may each independently be an integer of 0 to 5, q3, q4, and q10 may each independently be an integer of 0 to 4, q6 and q9 may each independently be an integer of 0 to 3, and —* may be a position connected to Formula 1.

In Formula 4, R₁ to R₃, n1 to n3, Sₐ₁, Sₐ₂, and Sₐ₃ may each be the same as defined in Formula 1.

In one or more embodiments, the first compound represented by Formula 1 may be represented by Formula 5.

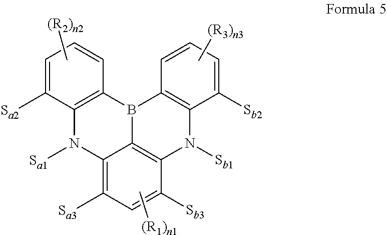

In Formula 5, n1 may be 0 or 1, n3 may be an integer of 0 to 3, S_{b2} and S_{b3} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and any one pair of S_{b1} and S_{b2} or S_{b1} and S_{b3} (e.g., any one of the pair of S_{b1} and S_{b2} or the pair of S_{b1} and S_{b3}) may be positions in which a substituent represented by Formula 6 is connected.

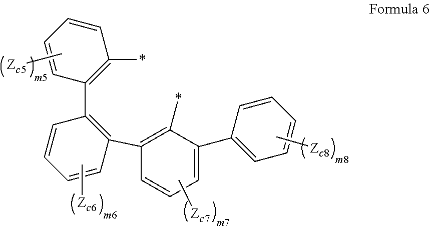

In Formula 6, —* may be a position connected to any one pair of S_{b1} and S_{b2} or S_{b1} and S_{b3} in Formula 5, Z_{c5} to Z_{c8} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, m5 and m6 may each independently be an integer of 0 to 4, m7 may be an integer of 0 to 3, and m8 may be an integer of 0 to 5.

In Formula 5, Sₐ₁, Sₐ₂, Sₐ₃, R₁ to R₃, and n2 may be the same as defined in Formula 1.

In one or more embodiments, the first compound represented by Formula 1 may be represented by any one selected from among Formulas 7-1 to 7-5.

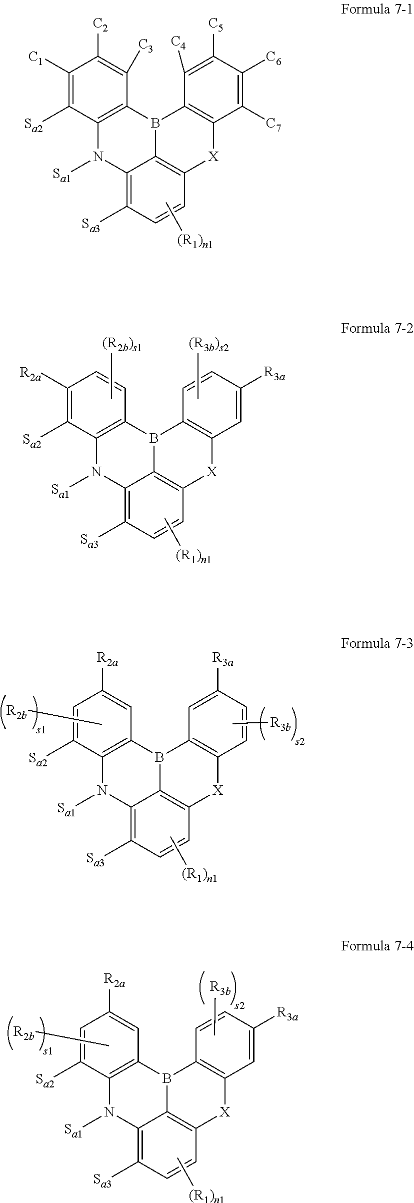

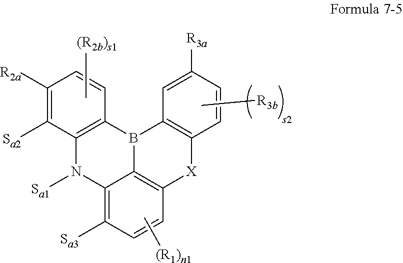

In Formulas 7-1 to 7-5, C₁ to C₇ may each independently be hydrogen or deuterium, R₂ₐ and R₃ₐ may each independently be a cyano group or a substituted or unsubstituted alkyl group having 1 to 10 carbon atoms, or a substituent represented by any one selected from among Formulas A-1 to A-5, R_{2b} and R_{3b} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, s1 may be an integer of 0 to 2, and s2 may be an integer of 0 to 3.

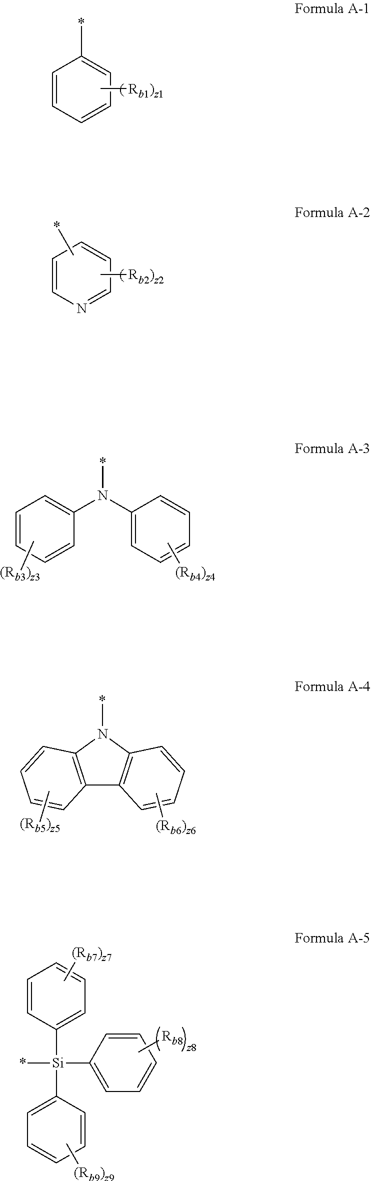

In Formulas A-1 to A-5, R_{b1} to R_{b9} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, z1, z3, z4, and z7 to z9 may each independently be an integer of 0 to 5, z2, z5, and z6 may each independently be an integer of 0 to 4, and —* may be a position connected to Formulas 7-2 to 7-5.

In Formulas 7-1 to 7-5, X, R₁, n1, Sₐ₁, Sₐ₂, and Sₐ₃ may be the same as defined in Formula 1.

In one or more embodiments, in Formula 1, at least one selected from among R₁ to R₃ may be a cyano group, a substituted or unsubstituted isopropyl group, a substituted or unsubstituted t-butyl group, a substituted or unsubstituted phenyl group, a substituted or unsubstituted triphenylsilyl group, a substituted or unsubstituted diphenylamine group, or a substituted or unsubstituted carbazole group.

In one or more embodiments, the first compound represented by Formula 1 may be represented by Formula 8-1 or Formula 8-2.

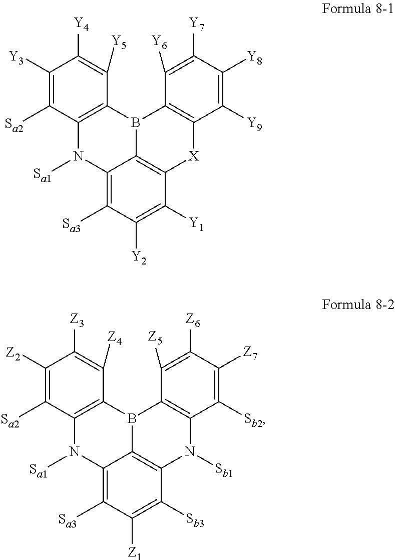

In Formulas 8-1 and 8-2, Y₁ to Y₉ may each independently be selected from among hydrogen, deuterium, and substituents of Substituent Group 1, Z₁ to Z₇ may each independently be selected from among hydrogen, deuterium, and the substituents of Substituent Group 1, S_{b2} and S_{b3} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and any one pair of S_{b1} and S_{b2} or S_{b1} and S_{b3} may be positions in which a substituent represented by Formula 6 is connected.

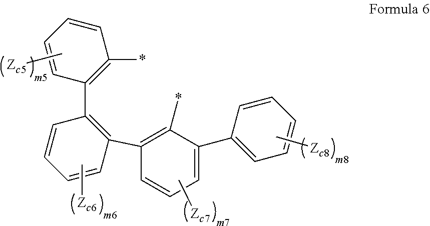

In Formula 6, —* may be a position connected to any one pair of S_{b1} and S_{b2} or S_{b1} and S_{b3} in Formula 8-2, z5 to Z_{c8} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, m5 and m6 may each independently be an integer of 0 to 4, m7 may be an integer of 0 to 3, and m8 may be an integer of 0 to 5.

### Substituent Group 1

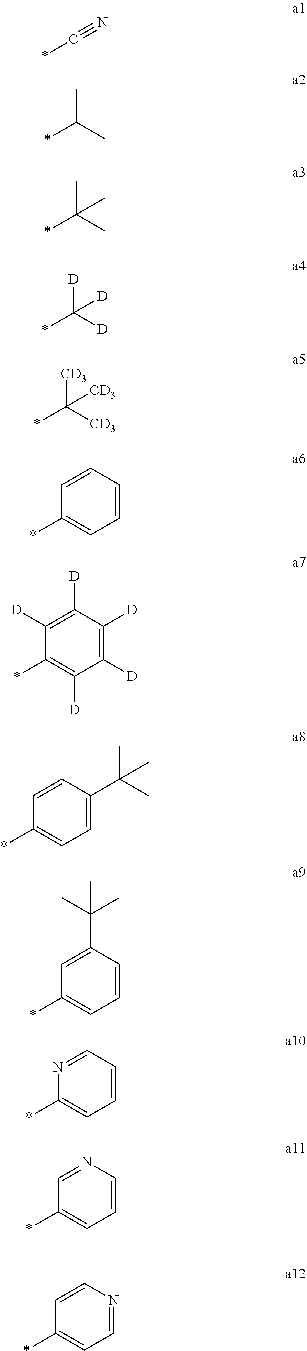

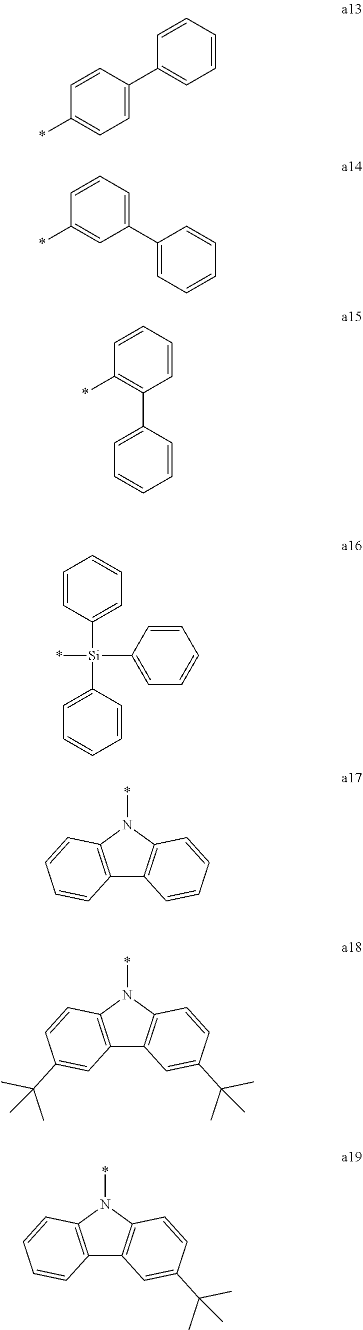

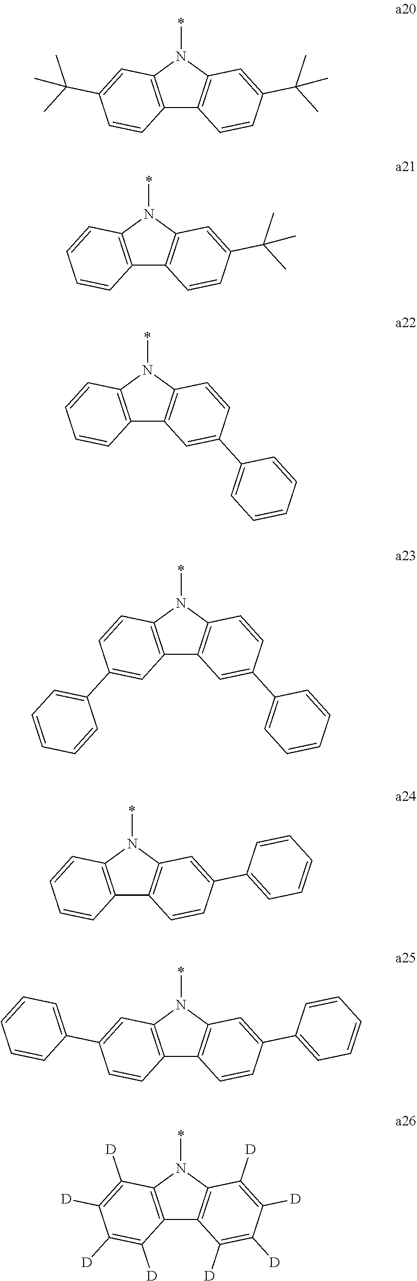

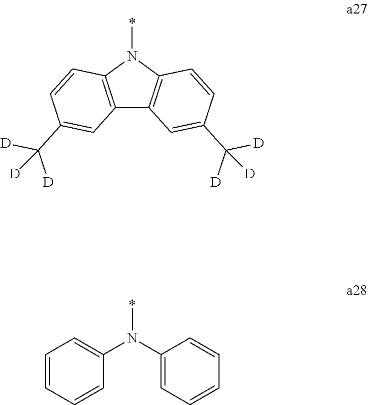 [SMILES: *n1c2ccc(C([2H])([2H])[2H])cc2c2cc(C([2H])([2H])[2H])ccc21 ; *N(c1ccccc1)c1ccccc1]

In Formulas 8-1 and 8-2, X, Sₐ₁, Sₐ₂, and Sₐ₃ may each be the same as defined in Formula 1.

In one or more embodiments, in Formula 2, Z_{c1} to Z_{c4} may each independently be hydrogen, deuterium, a substituted or unsubstituted t-butyl group, a substituted or unsubstituted phenyl group, a substituted or unsubstituted biphenyl group, or a substituted or unsubstituted terphenyl group.

In one or more embodiments, the emission layer may further include at least one of a second compound represented by Formula HT-1, a third compound represented by Formula ET-1, or a fourth compound represented by Formula D-1.

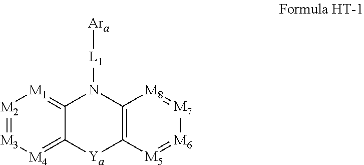

In Formula HT-1, M₁ to M₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Arₐ may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

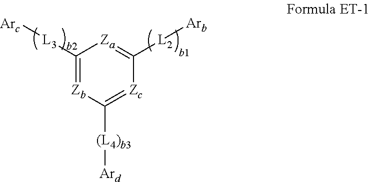

In Formula ET-1, at least one selected from among Zₐ to Z_{c} is N and the others may be CR₅₆, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar_{b} to Ar_{d} may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

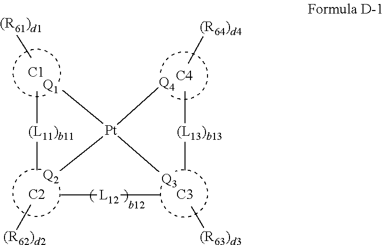

In Formula D-1, Q₁ to Q₄ may each independently be C or N, rings C1 to C4 may each independently be a substituted or unsubstituted hydrocarbon ring having 5 to 30 ring-forming carbon atoms or a substituted or unsubstituted heterocycle having 2 to 30 ring-forming carbon atoms, L₁₁ to L₁₃ may each independently be a direct linkage, *—O+*, *—S—*,

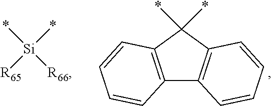

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments of the present disclosure, a display device includes a base layer, a circuit layer on the base layer, and a display element layer on the circuit layer and including a light emitting element, wherein the light emitting element includes a first electrode, a second electrode on the first electrode, and an emission layer between the first electrode and the second electrode and containing a first compound represented by Formula 1.

In one or more embodiments, the light emitting element may further include a capping layer on the second electrode, wherein the capping layer may have a refractive index of about 1.6 or greater in a wavelength range of about 550 nanometers (nm) to about 660 nm.

In one or more embodiments, the display device may further include a light control layer on the display element layer and including quantum dots, wherein the light emitting element may be to emit first color light, and the light control layer may include a first light control portion including a first quantum dot that converts the first color light into second color light having a longer wavelength than the first color light, a second light control portion including a second quantum dot that converts the first color light into third color light having a longer wavelength than the first color light and the second color light, and a third light control portion that transmits the first color light.

In one or more embodiments, the display device may further include a color filter layer on the light control layer, wherein the color filter layer may include a first filter that transmits the second color light, a second filter that transmits the third color light, and a third filter that transmits the first color light.

In one or more embodiments of the present disclosure, a fused polycyclic compound is represented by Formula 1.

### BRIEF DESCRIPTION OF THE DRAWINGS

The accompanying drawings are included to provide a further understanding of the disclosure, and are incorporated in and constitute a part of this disclosure. The drawings illustrate example embodiments of the disclosure and, together with the description, serve to explain principles of the present disclosure. Above and/or other aspects of the disclosure should become apparent and appreciated from the following description of embodiments taken in conjunction with the accompanying drawings. In the drawings:

FIG. 1 is a plan view of a display device according to one or more embodiments of the disclosure;

FIG. 2 is a cross-sectional view of a display device according to one or more embodiments of the disclosure;

FIG. 3 is a cross-sectional view schematically showing a light emitting element according to one or more embodiments of the disclosure;

FIG. 4 is a cross-sectional view schematically showing a light emitting element according to one or more embodiments of the disclosure;

FIG. 5 is a cross-sectional view schematically showing a light emitting element according to one or more embodiments of the disclosure;

FIG. 6 is a cross-sectional view schematically showing a light emitting element according to one or more embodiments of the disclosure;

FIGS. 7 and 8 are each a cross-sectional view of a display device according to one or more embodiments of the disclosure;

FIG. 9 is a cross-sectional view showing a display device according to one or more embodiments of the disclosure;

FIG. 10 is a cross-sectional view showing a display device according to one or more embodiments of the disclosure;

FIG. 11 is a view showing a vehicle in which display devices according to one or more embodiments of the disclosure are arranged;

FIGS. 12A-12C are each a view showing a three-dimensional molecular model of Comparative Example Compound C1;

FIGS. 13A-13C are each a view showing a three-dimensional molecular model of Comparative Example Compound C2;

FIGS. 14A-14C are each a view showing a three-dimensional molecular model of Comparative Example Compound C2;

FIGS. 15A-15C are each a view showing a three-dimensional molecular model of Comparative Example Compound C4;

FIGS. 16A-16C are each a view showing a three-dimensional molecular model of Example Compound 1; and

FIGS. 17A-17C are each a view showing a three-dimensional molecular model of Example Compound 2.

### DETAILED DESCRIPTION

The present disclosure may be modified in one or more suitable manners and have many forms, and thus specific/example embodiments will be exemplified in the drawings and described in more detail in the detailed description of present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are used for referring to like elements. In the accompanying drawings, the dimensions of each structure may be exaggeratingly illustrated for clarity of the present disclosure. It will be understood that, although the terms “first,” “second,” and/or the like, may be used herein to describe one or more suitable components, these components should not be limited by these terms. These terms are only used to distinguish one component from another. For example, a first component could be termed a second component, and, similarly, a second component could be termed a first component, without departing from the scope of example embodiments of the disclosure. As used herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure.”

In the present disclosure, it will be understood that the terms “comprise(s)/comprising,” “include(s)/including,” “have (has)/having,” and/or the like specify the presence of features, numbers, steps, operations, component, parts, and/or one or more (e.g., any suitable) combinations thereof disclosed in the disclosure, but do not exclude the possibility of presence or addition of one or more other features, numbers, steps, operations, component, parts, and/or one or more (e.g., any suitable) combinations thereof. As used herein, the terms “and”, “or”, and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, if (e.g., when) a layer, a film, a region, or a plate is referred to as being “on” or “in an upper portion of” another layer, film, region, or plate, it may be not only “directly on” the layer, film, region, or plate, but one or more intervening layers, films, regions, or plates may also be present. Opposite this, if (e.g., when) a layer, a film, a region, or a plate is referred to as being “below”, “in a lower portion of” another layer, film, region, or plate, it can be not only directly under the layer, film, region, or plate, but one or more intervening layers, films, regions, or plates may also be present. In addition, it will be understood that if (e.g., when) a part is referred to as being “on” another part, it can be arranged above the other part, or arranged under the other part as well. In the present disclosure, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, the term “substituted or unsubstituted” may refer to substituted or unsubstituted with at least one substituent selected from the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon may ring include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic or polycyclic. In addition, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 50, 6 to 40, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

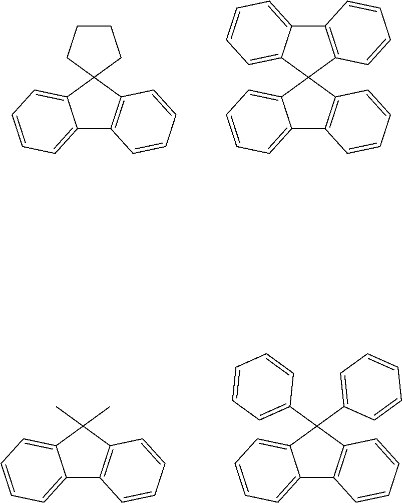

A heterocyclic group as used herein refers to any functional group or substituent derived from a ring containing at least one of B, O, N, P, Si, or Se as a heteroatom. The heterocyclic group includes an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 60, 2 to 50, 2 to 40, 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the present disclosure, the heteroaryl group may contain at least one of B, O, N, P, Si, or S as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 50, 2 to 40, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the present disclosure, a germanium group may include an alkylgermanium group and/or an arylgermanium group. Examples of germanium group may include a trimethylgermanium group, triethylgermanium group, a t-butyldimethylgermanium group, a vinyldimethylgermanium group, a propyldimethylgermanium group, a triphenylgermanium group, a tribiphenylgermanium group, a dipenylgermanium group, a phenyl germanium group, and/or the like, but one or more embodiments of the disclosure is not limited thereto.

In the present disclosure, the number of carbon atoms in a carbonyl group is not specifically limited, but may be 1 to 40, 1 to 30, or 1 to 20. For example, the carbonyl group may have the following structures, but embodiments of the present disclosure are not limited thereto.

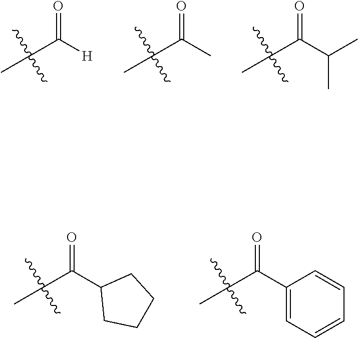

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

A boron group as used herein may refer to that a boron atom is bonded to the alkyl group or the aryl group defined above. The boron group may include an alkyl boron group and/or an aryl boron group. Examples of the boron group may include a dimethylboron group, a trimethylboron group, a t-butyldimethylboron group, a diphenylboron group, a phenylboron group, and/or the like, but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, and an arylamine group may be the same as the examples of the aryl group described above.

In the present disclosure, a direct linkage may refer to a single bond.

In one or more embodiments of the present disclosure,

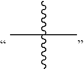

and “—*” refer to a position to be connected.

Hereinafter, embodiments of the disclosure will be described with reference to the accompanying drawings.

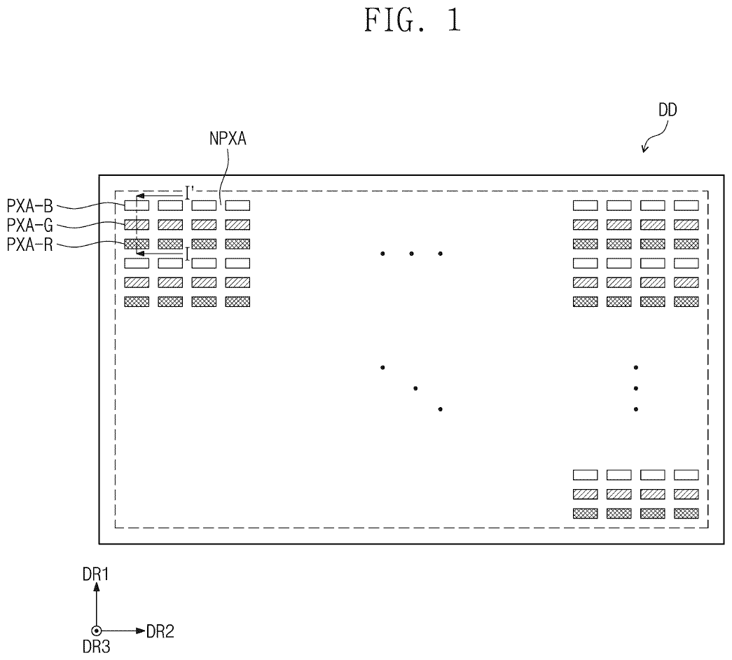

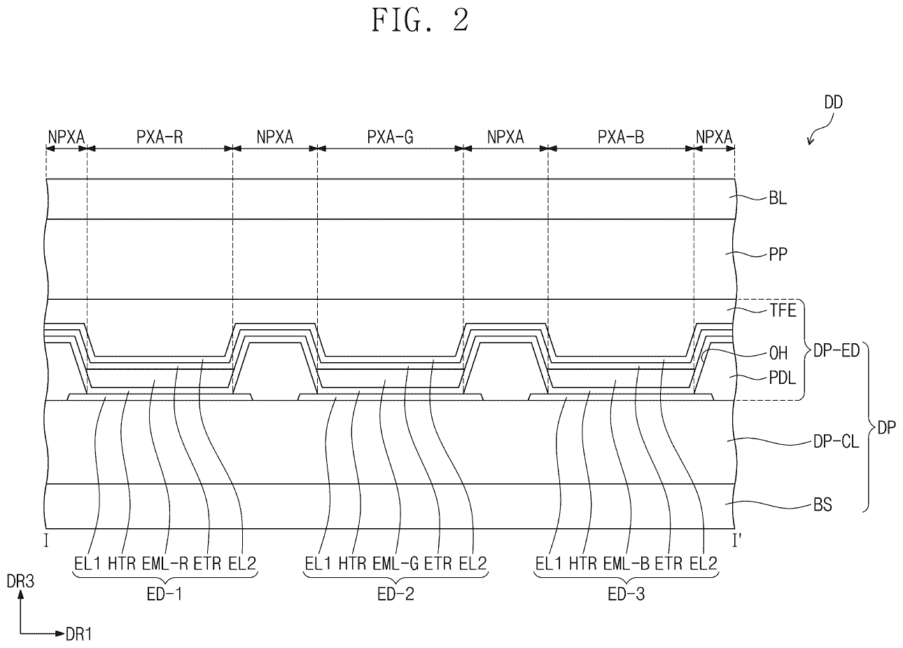

FIG. 1 is a plan view illustrating a display device DD according to one or more embodiments of the present disclosure. FIG. 2 is a cross-sectional view of the display device DD according to one or more embodiments. FIG. 2 is a cross-sectional view illustrating a part taken along the line I-I′ of the display device of FIG. 1.

The display device DD may include a display panel DP and an optical layer PP arranged on the display panel DP. The display panel DP may include light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display device layer DP-ED and the base substrate BL. The filling layer may be an organic material layer. In one or more embodiments, the filling layer may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED may include a pixel defining film PDL, the light emitting elements ED-1, ED-2, and ED-3 arranged between respective portions of the pixel defining film PDL, and an encapsulation layer TFE arranged on the light emitting elements ED-1, ED-2, and ED-3.

The base layer BS may be a member which provides a base surface on which the display device layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors.

Each of the transistors may include a control electrode, an input electrode, and an output electrode. For example, in one or more embodiments, the circuit layer DP-CL may include switching transistor(s) and driving transistor(s) for driving the light emitting elements ED-1, ED-2, and ED-3 of the display device layer DP-ED.

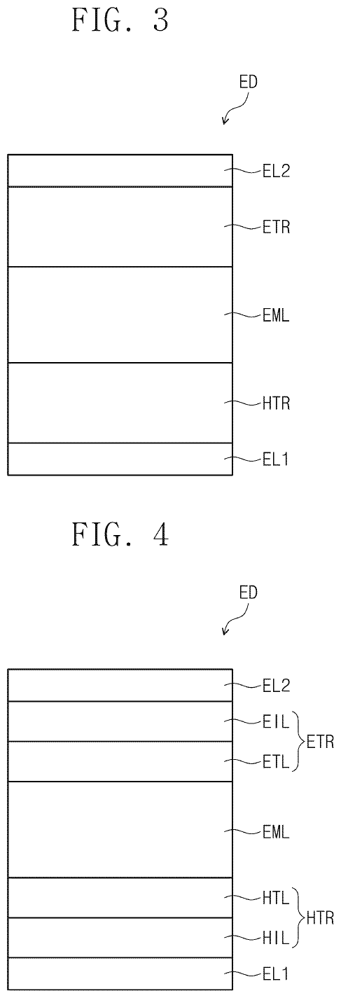

Each of the light emitting elements ED-1, ED-2, and ED-3 may independently have a structure of one of light emitting elements ED of embodiments according to FIGS. 3 to 6, which will be described in more detail later. Each of the light emitting elements ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates one or more embodiments in which the respective emission layers EML-R, EML-G, and EML-B of the light emitting elements ED-1, ED-2, and ED-3 are arranged in openings OH defined in the pixel defining film PDL, and the hole transport region HTR, the electron transport region ETR, and the second electrode EL2 are each provided as a common layer in the entire light emitting elements ED-1, ED-2, and ED-3. However, embodiments of the present disclosure are not limited thereto, for example, in one or more embodiments, the hole transport region HTR and the electron transport region ETR may be provided by being patterned inside the openings OH defined in the pixel defining film PDL. For example, the hole transport region HTR, the respective emission layers EML-R, EML-G, and EML-B, and the electron transport region ETR of the light emitting elements ED-1, ED-2, and ED-3 in one or more embodiments may be provided by being patterned in an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. In some embodiments, the encapsulation-organic film may include a photopolymerizable organic material, but embodiments of the present disclosure are not particularly limited thereto.

The encapsulation layer TFE may be arranged on the second electrode EL2 and may be arranged filling the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from each other on a plane (e.g., in a plan view).

Each of the light emitting regions PXA-R, PXA-G, and PXA-B may be a region divided by the pixel defining film PDL. The non-light emitting areas NPXA may be areas between adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The respective emission layers EML-R, EML-G, and EML-B of the light emitting elements ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include a red light emitting region PXA-R, a green light emitting region PXA-G, and a blue light emitting region PXA-B that are separated from each other.

In the display device DD according to one or more embodiments, the plurality of light emitting elements ED-1, ED-2, and ED-3 may be to emit light beams having wavelengths different from each other. For example, in one or more embodiments, the display device DD may include a first light emitting element ED-1 that emits red light, a second light emitting element ED-2 that emits green light, and a third light emitting element ED-3 that emits blue light. For example, in one or more embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range or at least one light emitting element may be to emit a light beam in a wavelength range different from the others. For example, in some embodiments, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In addition, the red light emitting region PXA-R, the green light emitting region PXA-G, and the blue light emitting region PXA-B may be alternately arranged in this order along a first direction axis DR1.

FIGS. 1 and 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. The areas of the light emitting regions PXA-R, PXA-G, and PXA-B may refer to areas if (e.g., when) viewed on a plane defined by the first direction axis DR1 and the second direction axis DR2 (e.g., the areas in a plan view).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, in one or more embodiments, the arrangement form of the light emitting regions PXA-R, PXA-G, and PXA-B may be a pentile (PENTILE®) arrangement form (for example, an RGBG matrix, an RGBG structure, or an RGBG matrix structure) or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but embodiments of the present disclosure are not limited thereto.

Hereinafter, FIG. 3 to FIG. 6 are each a cross-sectional view schematically showing a light emitting element according to one or more embodiments. The light emitting element ED according to one or more embodiments may include a first electrode EL1, a second electrode EL2 oppositely arranged to the first electrode EL1, and at least one functional layer between the first electrode EL1 and the second electrode EL2. The light emitting element ED of one or more embodiments may include a fused polycyclic compound of one or more embodiments, which will be explained later, in the at least one functional layer.

The light emitting element ED may include a hole transport region HTR, an emission layer EML, an electron transport region ETR, and/or the like, stacked in order (e.g., in the stated order), as the at least one functional layer. Referring to FIG. 3, the light emitting element ED of one or more embodiments may include a first electrode EL1, a hole transport region HTR, an emission layer EML, an electron transport region ETR, and a second electrode EL2, stacked in order (e.g., in the stated order).

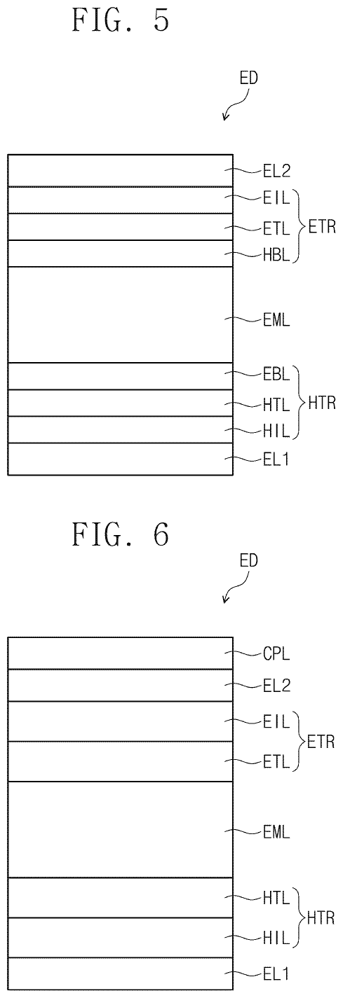

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of one or more embodiments further including a capping layer CPL arranged on a second electrode EL2.

The light emitting element ED of one or more embodiments may include a fused polycyclic compound of one or more embodiments, which will be explained later, in the at least one functional layer. In the light emitting element ED of one or more embodiments, at least one selected from among the hole transport region HTR, the emission layer EML, and the electron transport region ETR may include the fused polycyclic compound of one or more embodiments. For example, in the light emitting element ED of one or more embodiments, the emission layer EML may include the fused polycyclic compound of one or more embodiments.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, the first electrode EL1 may have a three-layer structure of ITO/Ag/ITO, but embodiments of the present disclosure are not limited thereto. In one or more embodiments, the first electrode EL1 may include one of the above-described metal materials, one or more combinations of at least two metal materials of the above-described metal materials, one or more oxides of the above-described metal materials, and/or the like. A thickness of the first electrode EL1 may be from about 700 ångström (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials. For example, in one or more embodiments, the hole transport region HTR

may have a single layer structure of a hole injection layer HIL or a hole transport layer HTL, or may have a single layer structure formed of a hole injection material and a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

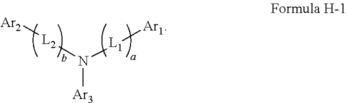

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s or a plurality of L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

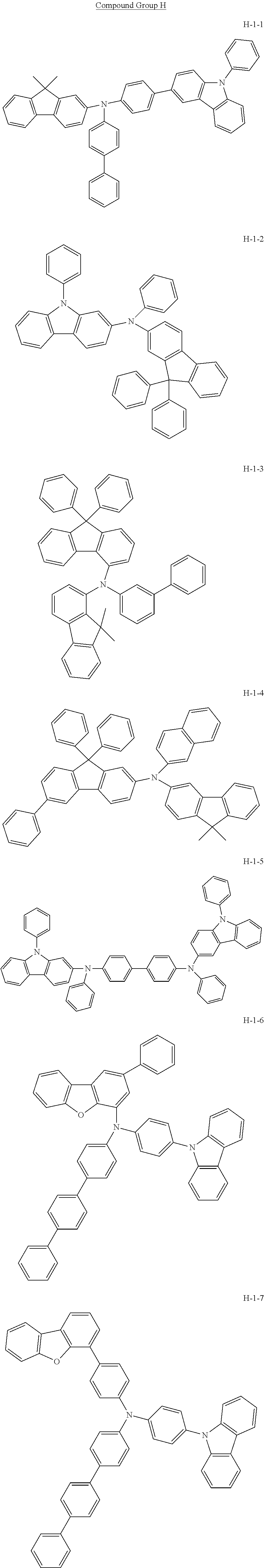

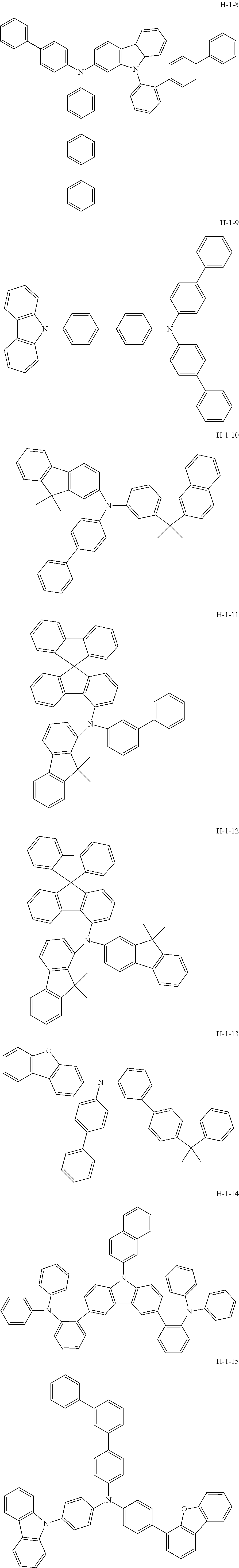

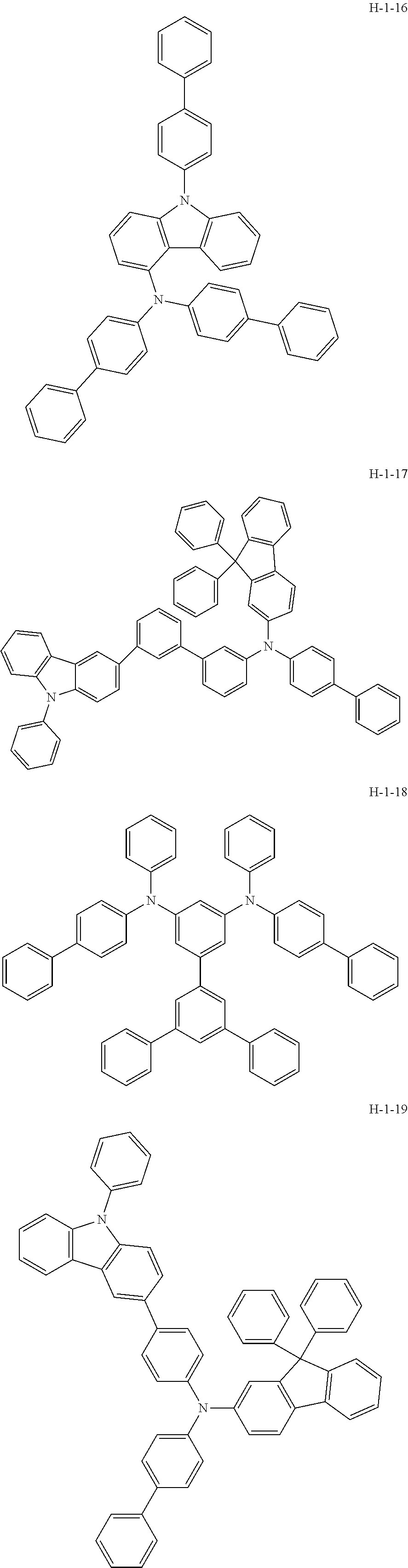

In one or more embodiments, the hole transport region HTR may include at least one selected from among a phthalocyanine compound such as copper phthalocyanine; N¹,N¹′-([1,1′-biphenyl]-4,4′-diyl)bis(N¹-phenyl-N4,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium[tetrakis(pentafluorophenyl) borate], dipyrazino[2,3-f: 2′,3′-h]quinoxaline-2,3,6,7,10,11-hexacarbonitrile (HATCN), and/or the like.

In one or more embodiments, the hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N, N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include at least one selected from 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. When the hole transport region HTR includes a hole injection layer HIL, the hole injection layer HIL may have, for example, a thickness of about 30 Å to about 1,000 Å. When the hole transport region HTR includes a hole transport layer HTL, the hole transport layer HTL may have a thickness of about 250 Å to about 1,000 Å. For example, if (e.g., when) the hole transport region HTR includes an electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

In one or more embodiments, the hole transport region HTR may further include a charge generating material to increase conductivity (e.g., electric conductivity) in addition to the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in one or more embodiments, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F₄-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce the electron injection from the electron transport region ETR to the hole transport region HTR.

The emission layer EML may be provided on the hole transport region HTR. The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

The light emitting element ED of one or more embodiments may include a fused polycyclic compound represented by Formula 1 in at least one functional layer arranged between the first electrode EL1 and the second electrode EL2. In the light emitting element ED according to one or more embodiments, the emission layer EML may include the fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In the present disclosure, the fused polycyclic compound of one or more embodiments may be referred to as a first compound.

The fused polycyclic compound of one or more embodiments includes a fused polycyclic heterocycle in which five rings are fused and a first boron atom, a first nitrogen atom, and a first hetero atom are included, and a first substituent connected to the fused polycyclic heterocycle. In one or more embodiments, the fused polycyclic heterocycle included in the fused polycyclic compound may be formed of five rings in which three substituted or unsubstituted benzene rings are connected through the first boron atom, the first nitrogen atom, and the first hetero atom. For example, for the three benzene rings included in the fused polycyclic heterocycle, the three benzene rings may be connected via the first boron atom, among the three benzene rings, the first benzene ring and the second benzene ring may be connected through the first nitrogen atom, and the remaining third benzene ring may be connected to the first benzene ring through the first hetero atom. The first boron atom, the first nitrogen atom, and the first hetero atom may all be connected to the first benzene ring. In one or more embodiments, the first hetero atom may be a nitrogen (N) atom, an oxygen (O) atom, a sulfur(S) atom, or a selenium (Se) atom. In one or more embodiments, if (e.g., when) the first hetero atom is a nitrogen atom, the nitrogen atom may be referred to as a second nitrogen atom.

The fused polycyclic compound of one or more embodiments may include the first substituent connected to the fused polycyclic heterocycle. The first substituent may include a first terphenyl moiety including three benzene rings, and a first aryl group connected to the first terphenyl moiety. For example, the first substituent may have a structure in which a fifth benzene ring and a sixth benzene ring are connected to a fourth benzene ring to be positioned ortho, and the first aryl group is substituted on the fifth benzene ring. The first substituent may be connected to the fused polycyclic heterocycle through ortho carbon of each of the fifth benzene ring and the sixth benzene ring. Any one of the fifth benzene ring and the sixth benzene ring may be connected to the first nitrogen atom of the fused polycyclic heterocycle, and the other may be connected to the first benzene ring or the second benzene ring, each of which is connected to the first nitrogen atom. For example, in one or more embodiments, the fifth benzene ring may be connected to the first nitrogen atom, and the sixth benzene ring may be connected to the first benzene ring. In one or more embodiments, the fifth benzene ring may be connected to the first benzene ring, and the sixth benzene ring may be connected to the first nitrogen atom. In one or more embodiments, the fifth benzene ring may be connected to the first nitrogen atom, and the sixth benzene ring may be connected to the second benzene ring. In one or more embodiments, the fifth benzene ring may be connected to the second benzene ring, and the sixth benzene ring may be connected to the first nitrogen atom.

When the first substituent is connected to the fused polycyclic heterocycle, four benzene rings may be connected around the first nitrogen atom to form a tetrabenzo azonine derivative represented by the following structure S₁.

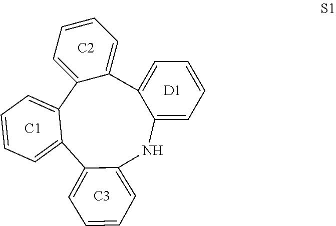

In the structure S₁, a benzene ring represented by C1 may correspond to the fourth benzene ring of the first substituent, a benzene rings represented by C2 and C3 correspond to the fifth benzene ring and the sixth benzene ring, respectively, and D1 may correspond to the first benzene ring or the second benzene ring of the polycyclic heterocycle. Here, for convenience of description, the first aryl group connected to the fifth benzene ring is not provided in the structure S₁.

In one or more embodiments, the first substituent may include the first aryl group connected to the first terphenyl moiety. The first aryl group may be connected to the fifth benzene ring included in the first terphenyl moiety. The first aryl group may be a substituted or unsubstituted phenyl group, but embodiments of the present disclosure are not limited thereto. In one or more embodiments of the fused polycyclic compound, the first aryl group may be connected to the terphenyl moiety to be positioned ortho with respect to the first nitrogen atom, the first benzene ring, or the second benzene ring included in the fused polycyclic heterocycle. For example, if (e.g., when) the fifth benzene ring is connected to the first nitrogen atom and the sixth benzene ring is connected to the first benzene ring, the first aryl group may be connected to be positioned ortho with respect to the first nitrogen atom. In one or more embodiments, if (e.g., when) the fifth benzene ring is connected to the first benzene ring and the sixth benzene ring is connected to the first nitrogen atom, the first aryl group may be connected to be positioned ortho with respect to the first benzene ring. In one or more embodiments, if (e.g., when) the fifth benzene ring is connected to the first nitrogen atom and the sixth benzene ring is connected to the second benzene ring, the first aryl group may be connected to be positioned ortho with respect to the first nitrogen atom. In one or more embodiments, if (e.g., when) the fifth benzene ring is connected to the second benzene ring and the sixth benzene ring is connected to the first nitrogen atom, the first aryl group may be connected to be positioned ortho with respect to the second benzene ring. In one or more embodiments, the first substituent may indicate a substituent represented by Formula 2, which will be described in more detail later.

The fused polycyclic compound of one or more embodiments may be represented by Formula 1.

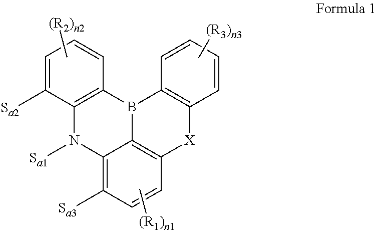

The fused polycyclic compound of one or more embodiments represented by Formula 1 may include a fused polycyclic heterocycle in which five rings are fused around a first boron atom, a first nitrogen atom, and a first hetero atom, and a first substituent connected to the fused polycyclic heterocycle. In the present disclosure, in Formula 1, a benzene ring in which a substituent represented by R₁ is substituted may correspond to the first benzene ring described above, a benzene ring in which a substituent represented by R₂ is substituted may correspond to the second aromatic ring, i.e., second benzene ring, described above, and a benzene ring in which a substituent represented by R₃ is substituted may correspond to the third aromatic ring, i.e., third benzene ring, described above.

In Formula 1, X may be NR₄, O, S, or Se. For example, in one or more embodiments, X may be NR₄.

In Formula 1, Sₐ₂, Sₐ₃, and R₁ to R₄ may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms.

In one or more embodiments, R₁ to R₃ may each independently be hydrogen, deuterium, a cyano group, a substituted or unsubstituted amine group, a substituted or unsubstituted silyl group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R₁ to R₃ may each independently be hydrogen, deuterium, a cyano group, a substituted or unsubstituted methyl group, a substituted or unsubstituted isopropyl group, a substituted or unsubstituted t-butyl group, a substituted or unsubstituted diphenylamine group, a substituted or unsubstituted triphenylsilyl group, a substituted or unsubstituted pyridine group, a substituted or unsubstituted phenyl group, or a substituted or unsubstituted carbazole group.

In one or more embodiments, R₄ may be a substituted or unsubstituted aryl group having 6 to 30 ring-forming carbon atoms or a substituted or unsubstituted heteroaryl group having 2 to 30 ring-forming carbon atoms. For example, in one or more embodiments, R₄ may be a substituted or unsubstituted phenyl group, a substituted or unsubstituted biphenyl group, or a substituted or unsubstituted terphenyl group.

In one or more embodiments, in the fused polycyclic compound represented by Formula 1, at least one selected from among R₁ to R₃ may be a cyano group, a substituted or unsubstituted isopropyl group, a substituted or unsubstituted t-butyl group, a substituted or unsubstituted phenyl group, a substituted or unsubstituted triphenylsilyl group, a substituted or unsubstituted diphenylamine group, or a substituted or unsubstituted carbazole group.

In Formula 1, n1 may an integer of 0 to 2. If (e.g., when) n1 is 0, the fused polycyclic compound of one or more embodiments may not be substituted with R₁. In Formula 1, If (e.g., when) n1 is 2, and R₁'s are each hydrogen, the embodiment may be the same as if (e.g., when) n1 is 0 in Formula 1. When n1 is 2, R₁ provided in plurality may all be the same, or at least one selected from among the plurality of R₁'s may be different.

In Formula 1, n2 may be an integer of 0 to 3. If (e.g., when) n2 is 0, the fused polycyclic compound of one or more embodiments may not be substituted with R₂. In Formula 1, If (e.g., when) n2 is 3, and R₂'s are each hydrogen, the embodiment may be the same as if (e.g., when) n2 is 0 in Formula 1. When n2 is an integer of 2 or greater, R₂ provided in plurality may all be the same, or at least one selected from among the plurality of R₂'s may be different.

In Formula 1, n3 is an integer of 0 to 4. If (e.g., when) n3 is 0, the fused polycyclic compound of one or more embodiments may not be substituted with R₃. In Formula 1, If (e.g., when) n3 is 4, and R₃'s are each hydrogen, the embodiment may be the same as if (e.g., when) n3 is 0 in Formula 1. If (e.g., when) n3 is an integer of 2 or greater, R₃ provided in plurality may all be the same, or at least one selected from among the plurality of R₃'s may be different.

In Formula 1, any one pair of Sₐ₁ and Sₐ₂ or Sₐ₁ and Sₐ₃ (e.g., any one of the pair of Sₐ₁ and Sₐ₂ or the pair of Sₐ₁ and Sₐ₃) may be positions in which a substituent represented by Formula 2 is connected. For example, in one or more embodiments, Sₐ₁ and Sₐ₂ may be positions in which a substituent represented by Formula 2 is connected. In one or more embodiments, Sₐ₁ and Sₐ₃ may be positions in which a substituent represented by Formula 2 is connected.

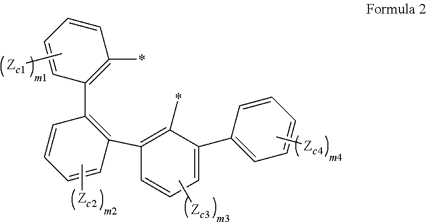

A substituent represented by Formula 2 may correspond to the first substituent described above. In Formula 2, a benzene ring in which a substituent represented by Z_{c2} is substituted may correspond to the fourth benzene ring described above, a benzene ring in which a substituent represented by Z_{c3} is substituted may correspond to the fifth benzene ring described above, and a benzene ring in which a substituent represented by Z_{c1} is substituted may correspond to the sixth benzene ring described above. In Formula 2, a benzene ring in which a substituent represented by Z_{c4} is substituted may correspond to the first aryl group described above.

In Formula 2, —* is a position connected to any one pair of Sₐ₁ and Sₐ₂ or Sₐ₁ and Sₐ₃ in Formula 1.

In Formula 2, Z_{c1} to Z_{c4} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among Z_{c1} to Z_{c4} may independently be bonded to an adjacent group to form a ring. For example, in one or more embodiments, Z_{c1} to Z_{c4} may each independently be hydrogen, deuterium, a substituted or unsubstituted t-butyl group, a substituted or unsubstituted phenyl group, a substituted or unsubstituted biphenyl group, or a substituted or unsubstituted terphenyl group.

In Formula 2, m1 and m2 may each independently be an integer of 0 to 4. If (e.g., when) m1 and m2 are each 0, the fused polycyclic compound of one or more embodiments may not be substituted with each of Z_{c1} and Z_{c2}. If (e.g., when) m1 and m2 are each 4 and each of Z_{c1} and Z_{c2} is all hydrogens, the embodiment may be the same as if (e.g., when) m1 and m2 are each 0. If (e.g., when) m1 and m2 are each an integer of 2 or greater, Z_{c1} and Z_{c2} each provided in plurality may each be the same, or at least one of Z_{c1} Or Z_{c2} each provided in plurality may be different.

In Formula 2, m3 is may be integer of 0 to 3. If (e.g., when) m3 is 0, the fused polycyclic compound of one or more embodiments may not be substituted with Z_{c3}. In Formula 2, if (e.g., when) m3 is 3 and z_{c3}'s are each hydrogen, the embodiment may be the same as if (e.g., when) m3 is 0 in Formula 2. If (e.g., when) m3 is an integer of 2 or greater, Zos provided in plurality may all be the same, or at least one selected from among the plurality of Z_{c3}'s may be different.

In Formula 2, m4 may be an integer of 0 to 5. If (e.g., when) m4 is 0, the fused polycyclic compound of one or more embodiments may not be substituted with Z_{c4}. In Formula 2, if (e.g., when) m4 is 5 and Z_{c4}'s are each hydrogen, the embodiment may be the same as if (e.g., when) m4 is 0 in Formula 2. If (e.g., when) m4 is an integer of 2 or greater, Z_{c4} provided in plurality may all be the same, or at least one selected from among the plurality of z_{c4}'s may be different.

In one or more embodiments, the substituent represented by Formula 2 may be represented by any one selected from among Formulas 2-1 to 2-4.

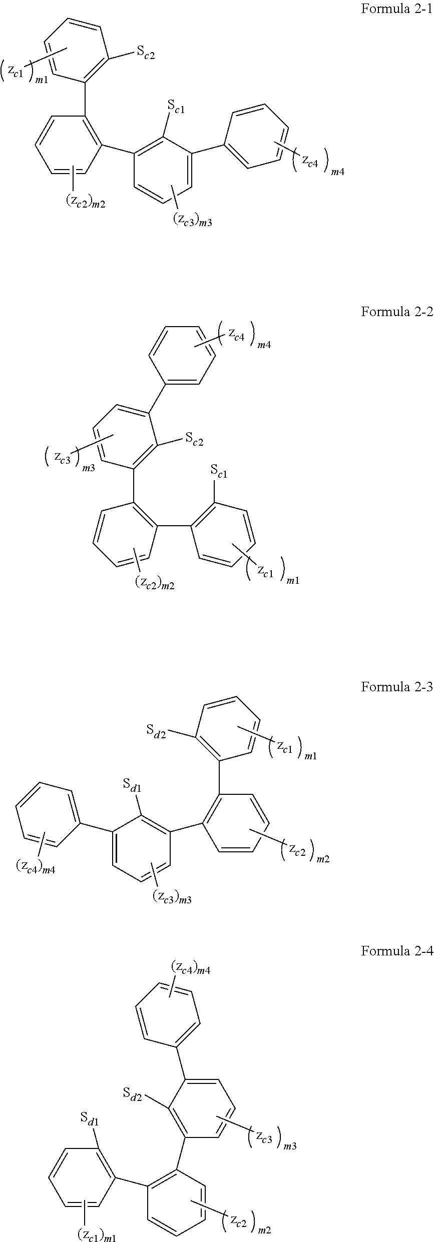

Formulas 2-1 to 2-4 represent embodiments in which a position connected to Formula 1 in the substituent represented by Formula 2 is specified.

In Formulas 2-1 and 2-2, S_{c1} may be a position connected to Sat in Formula 1, and S_{c2} may be a position connected to Sₐ₂ in Formula 1.

In Formulas 2-3 and 2-4, S_{d1} may be a position connected to Sat in Formula 1, and Sₐ₂ may be a position connected to Sₐ₃ in Formula 1.

In Formulas 2-1 to 2-4, the same descriptions as those described in Formula 2 may apply to Z_{c1} to Z_{c4}, and m1 to m4.

In one or more embodiments, the first compound (i.e., the fused polycyclic compound) represented by Formula 1 may be represented by any one selected from among Formulas 3-1 to 3-4.

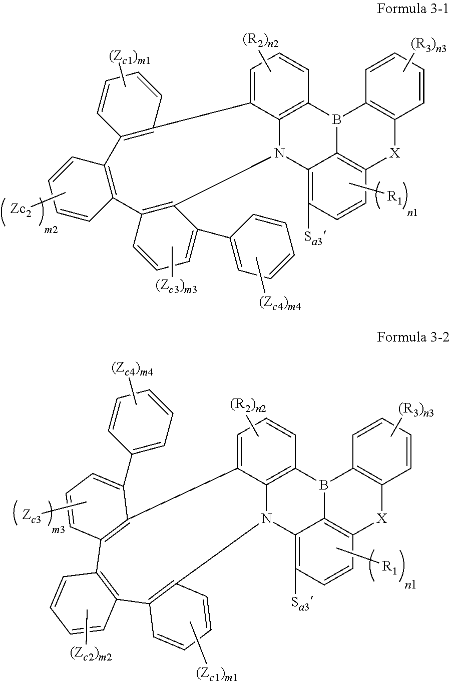

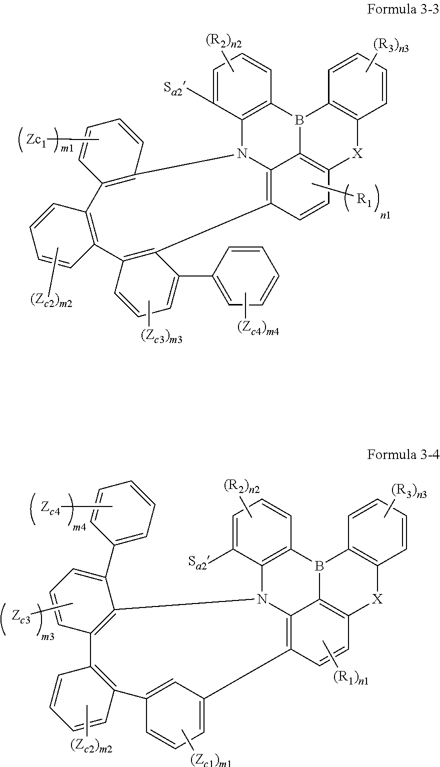

In Formulas 3-1 to 3-4, Sₐ₂′ and Sₐ₃′ may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. For example, in one or more embodiments, Sₐ₂′ and Sₐ₃′ may each be hydrogen.

In Formulas 3-1 to 3-4, the same descriptions as those described in Formulas 1 and 2 may apply to X, R₁ to R₃, n1 to n3, Z_{c1} to Z_{c4}, and m1 to m4.

In one or more embodiments, the first compound represented by Formula 1 may be represented by Formula 4.

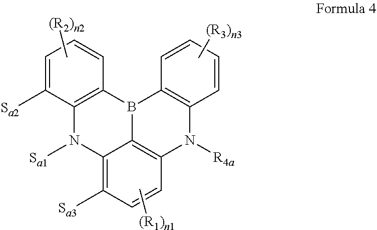

Formula 4 shows an embodiment in which the type or kind of X in Formula 1 is specified.

In Formula 4, R₄ₐ may be represented by any one selected from among Formulas S-1 to S-5.

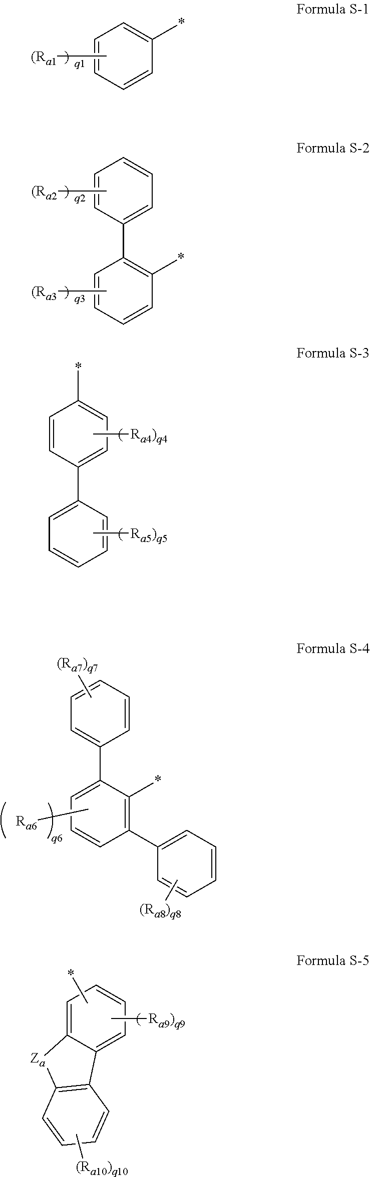

In Formula S-5, Zₐ may be CRₐ₁₁Rₐ₁₂, NRₐ₁₃, O, S, or Se.

In Formulas S-1 to S-5, Rₐ₁ to Rₐ₁₃ may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. For example, in one or more embodiments, Rₐ₁ to Rₐ₁₀ may each independently be hydrogen, deuterium, or a substituted or unsubstituted t-butyl group, and Rₐ₁₁ to Rₐ₁₃ may each independently be a substituted or unsubstituted methyl group or a substituted or unsubstituted phenyl group.

In Formulas S-1 to S-5, q1, q2, q5, q7, and q8 may each independently be an integer of 0 to 5, q3, q4, and q10 may each independently be an integer of 0 to 4, and q6 and q9 may each independently be an integer of 0 to 3. If (e.g., when) q1 to q10 are each 0, the fused polycyclic compound of one or more embodiments may not be substituted with each of Rₐ₁ to Rₐ₁₀. If (e.g., when) each of q1, q2, q5, q7, and q8 is 5, and each of Rₐ₁'s, Rₐ₂'s, Rₐ₅'s, Rₐ₇'s, and Rₐ₈'s is hydrogen, the embodiment may be the same as if (e.g., when) each of q1, q2, q5, q7, and q8 is 0. If (e.g., when) q3, q4, and q10 are each 4 and Rₐ₃'s, Rₐ₄'s, and Rₐ₁₀'s are each hydrogen, the embodiment may be the same as if (e.g., when) q3, q4, and q10 are each 0. If (e.g., when) q6 and q9 are each 3 and Rₐ₆'s and Rₐ₉'s are each hydrogen, the embodiment may be the same as if (e.g., when) q6 and q9 are each 0. If (e.g., when) q1 to q10 are each an integer of 2 or greater, Rₐ₁ to Rₐ₁₀ each provided in plurality may each be the same, or at least one selected from among Rₐ₁ to Rₐ₁₀ each provided in plurality may be different.

In Formulas S-1 to S-5, —* is a position connected to Formula 1.

In Formula 4, the same descriptions as those described in Formula 1 may apply to R₁ to R₃, n1 to n3, Sₐ₁, Sₐ₂, and Sₐ₃.

The fused polycyclic compound of one or more embodiments may include a second substituent connected to a fused polycyclic heterocycle. The second substituent may include a second terphenyl moiety including three benzene rings, and a second aryl group connected to the second terphenyl moiety. For example, the second substituent may have a structure in which an eighth benzene ring and a ninth benzene ring are connected to a seventh benzene ring to be positioned ortho, and the second aryl group is substituted on the eighth benzene ring.

The fused polycyclic compound of one or more embodiments includes the fused polycyclic heterocycle in which five rings are fused and a first boron atom, a first nitrogen atom, and a first hetero atom (e.g., second nitrogen atom) are included. The fused polycyclic compound of one or more embodiments may include the second substituent connected to the fused polycyclic heterocycle. The second substituent may be connected to the fused polycyclic heterocycle through ortho carbon of each of the eighth benzene ring and the ninth benzene ring. Any one of the eighth benzene ring and the ninth benzene ring may be connected to the second nitrogen atom (i.e., first hetero atom) of the fused polycyclic heterocycle, and the other may be connected to the first benzene ring or the third benzene ring, each of which is connected to the second nitrogen atom. For example, in one or more embodiments, the eighth benzene ring may be connected to the second nitrogen atom, and the ninth benzene ring may be connected to the first benzene ring. In one or more embodiments, the eighth benzene ring may be connected to the first benzene ring, and the ninth benzene ring may be connected to the second nitrogen atom. In one or more embodiments, the eighth benzene ring may be connected to the second nitrogen atom, and the ninth benzene ring may be connected to the third benzene ring. In one or more embodiments, the eighth benzene ring may be connected to the third benzene ring, and the ninth benzene ring may be connected to the second nitrogen atom.

When the second substituent is connected to the fused polycyclic heterocycle, four benzene rings may be connected around the second nitrogen atom to form a tetrabenzo azonine derivative represented by the following structure S₂.

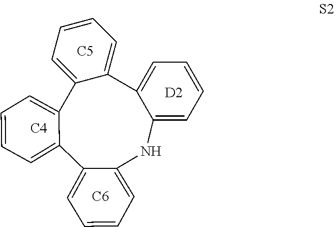

In the structure S₂, a benzene ring represented by C4 may correspond to the seventh benzene ring of the second substituent, a benzene rings represented by C5 and C6 correspond to the eighth benzene ring and the ninth benzene ring, respectively, and a benzene ring represented by D2 may correspond to the first benzene ring or the third benzene ring of the fused polycyclic heterocycle. Meanwhile, for convenience of description, the second aryl group connected to the eighth benzene ring is not provided in the structure S₂.

In one or more embodiments, the second substituent may include the second aryl group connected to the second terphenyl moiety. The second aryl group may be connected to the eighth benzene ring included in the second terphenyl moiety. The second aryl group may be a substituted or unsubstituted phenyl group, but embodiments of the present disclosure are not limited thereto. In one or more embodiments of the fused polycyclic compound, the second aryl group may be connected to the second terphenyl moiety to be positioned ortho with respect to the second nitrogen atom, the first benzene ring, or the third benzene ring included in the fused polycyclic heterocycle. For example, If (e.g., when) the eighth benzene ring is connected to the second nitrogen atom and the ninth benzene ring is connected to the first benzene ring, the second aryl group may be connected to be positioned ortho with respect to the second nitrogen atom. In one or more embodiments, if (e.g., when) the eighth benzene ring is connected to the first benzene ring and the ninth benzene ring is connected to the second nitrogen atom, the second aryl group may be connected to be positioned ortho with respect to the first benzene ring. In one or more embodiments, if (e.g., when) the eighth benzene ring is connected to the second nitrogen atom and the ninth benzene ring is connected to the third benzene ring, the second aryl group may be connected to be positioned ortho with respect to the second nitrogen atom. In one or more embodiments, if (e.g., when) the eighth benzene ring is connected to the third benzene ring and the ninth benzene ring is connected to the second nitrogen atom, the second aryl group may be connected to be positioned ortho with respect to the third benzene ring. In the present disclosure, the second substituent may indicate a substituent represented by Formula 6, which will be described in more detail later.

In one or more embodiments, the first compound represented by Formula 1 may be represented by Formula 5.

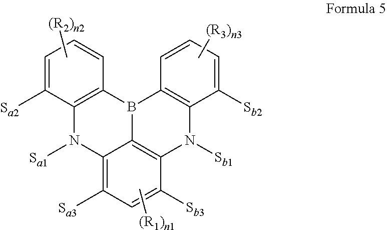

In Formula 5, n1 may be 0 or 1, n3 may be an integer of 0 to 3, S_{b2} and S_{b3} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms.

In Formula 5, any one pair of S_{b1} and S_{b2} or S_{b1} and S_{b3} (e.g., any one of the pair of S_{b1} and S_{b2} or the pair of S_{b1} and S_{b3}) may be positions in which a substituent represented by Formula 6 is connected. In one or more embodiments, in the fused polycyclic compound represented by Formula 5, the substituent represented by Formula 6 may be connected to the positions of S_{b1} and S_{b2}. In one or more embodiments, in the fused polycyclic compound represented by Formula 5, the substituent represented by Formula 6 may be connected to the positions of S_{b1} and

### S_{b3}.

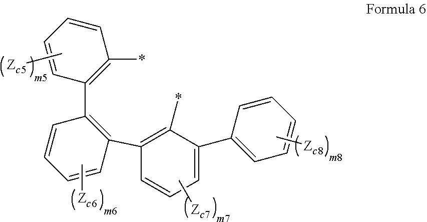

The substituent represented by Formula 6 may correspond to the second substituent described above. In Formula 6, a benzene ring in which a substituent represented by Z_{c6} is substituted may correspond to the seventh benzene ring described above, a benzene ring in which a substituent represented by Z_{c7} is substituted may correspond to the eighth benzene ring described above, and a benzene ring in which a substituent represented by Z_{c5} is substituted may correspond to the ninth benzene ring described above. In Formula 6, a benzene ring in which a substituent represented by Z_{c8} is substituted may correspond to the second aryl group described above.

In Formula 6, —* may be a position connected to any one pair of S_{b1} and S_{b2} or S_{b1} and S_{b3} in Formula 5.

In Formula 6, Z_{c5} to Z_{c8} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among Z_{c5} to Z_{c8} may independently be bonded to an adjacent group to form a ring. For example, in one or more embodiments, Z_{c5} to Z_{c8} may each independently be hydrogen, deuterium, a substituted or unsubstituted t-butyl group, a substituted or unsubstituted phenyl group, a substituted or unsubstituted biphenyl group, or a substituted or unsubstituted terphenyl group.

In Formula 6, m5 and m6 may each independently be an integer of 0 to 4. If (e.g., when) m5 and m6 are each 0, the fused polycyclic compound of one or more embodiments may not be substituted with each of Z_{c5} and Z_{c6}. If (e.g., when) m5 and m6 are each 4 and each of Z_{c5}'s and Z_{c6}'s is hydrogen, the embodiments may be the same as if (e.g., when) m5 and m6 are each 0. If (e.g., when) m5 and m6 are each an integer of 2 or greater, Z_{c5} and Z_{c6} each provided in plurality may each be the same, or at least one of Z_{c5} Or Z_{c6} each provided in plurality may be different.

In Formula 6, m7 is an integer of 0 to 3. If (e.g., when) m7 is 0, the fused polycyclic compound of one or more embodiments may not be substituted with Z_{c7}. In Formula 6, if (e.g., when) m7 is 3 and Z_{c7}'s are each hydrogen, the embodiment may be the same as if (e.g., when) m7 is 0 in Formula 6. If (e.g., when) m7 is an integer of 2 or greater, Z_{c7} provided in plurality may all be the same, or at least one selected from among the plurality of Z_{c7}'s may be different.

In Formula 6, m8 is an integer of 0 to 5. If (e.g., when) m8 is 0, the fused polycyclic compound of one or more embodiments may not be substituted with Z_{c8}. In Formula 6, if (e.g., when) m8 is 5 and Z_{c3}'s are each hydrogen, the embodiment may be the same as if (e.g., when) m8 is 0 in Formula 6. If (e.g., when) m8 is an integer of 2 or greater, Z_{c8} provided in plurality may all be the same, or at least one selected from among the plurality of Z_{c8}'s may be different.

In Formula 5, the same descriptions as those described above in Formula 1 may apply to Sₐ₁, Sₐ₂, Sₐ₃, R₁ to R₃, and n2.

In one or more embodiments, the first compound represented by Formula 1 may be represented by any one selected from among Formulas 7-1 to 7-5.

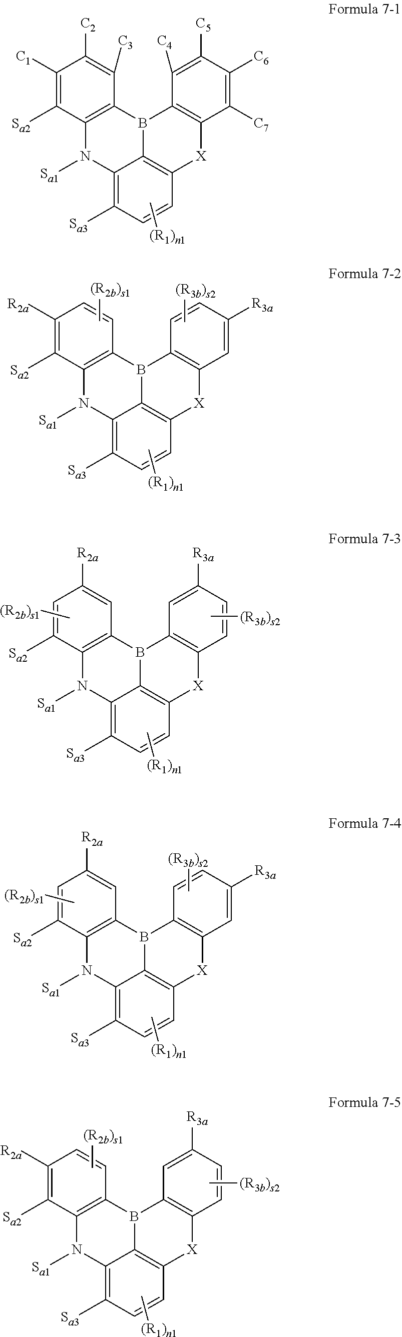

Formulas 7-1 to 7-5 show embodiments in which the types (kinds) of substituents represented by R₂ and R₅ are specified.

In Formula 7-1, C₁ to C₇ may each independently be hydrogen or deuterium.

In Formulas 7-2 to 7-5, R₂ₐ and R₃ₐ may each independently be a cyano group or be a substituted or unsubstituted alkyl group having 1 to 10 carbon atoms, or be a substituent represented by any one selected from among Formulas A-1 to A-5.

In Formulas 7-2 to 7-5, R_{2b} and R_{3b} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. For example, in one or more embodiments, R_{2b} and R_{3b} may each independently be hydrogen or deuterium.

In Formulas 7-2 to 7-5, s1 may be an integer of 0 to 2. If (e.g., when) s1 is 0, the fused polycyclic compound of one or more embodiments may not be substituted with R_{2b}. In Formulas 7-2 to 7-5, if (e.g., when) s1 is 2 and R_{2b}'s are each hydrogen, the embodiment may be the same as if (e.g., when) s1 is 0 in Formulas 7-2 to 7-5. If (e.g., when) s1 is 2, R_{2b} provided in plurality may all be the same, or at least one selected from among the plurality of R_{2b}'s may be different.

In Formulas 7-2 to 7-5, s2 may be an integer of 0 to 3. If (e.g., when) s2 is 0, the fused polycyclic compound of one or more embodiments may not be substituted with R_{3b}. In Formulas 7-2 to 7-5, if (e.g., when) s2 is 3 and Rob's are each hydrogen, the embodiment may be the same as if (e.g., when) s2 is 0 in Formulas 7-2 to 7-5. If (e.g., when) s2 is 2 or 3, R_{3b} provided in plurality may all be the same, or at least one selected from among the plurality of R_{3b}'s may be different.

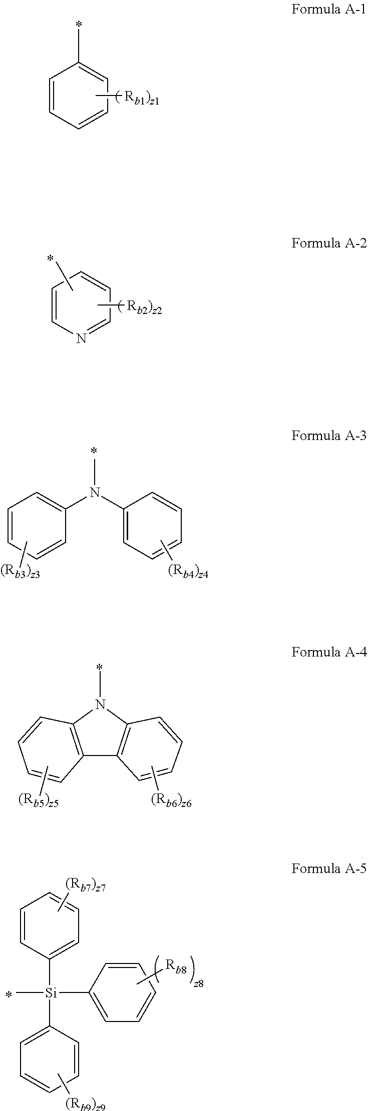

In Formulas A-1 to A-5, R_{b1} to R_{b9} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. For example, in one or more embodiments, R_{b1} to R_{b9} may each independently be hydrogen, deuterium, a substituted or unsubstituted methyl group, or a substituted or unsubstituted t-butyl group.

In Formulas A-1 to A-5, z1, z3, z4, and z7 to z9 may each independently be an integer of 0 to 5, and z2, z5, and z6 may each independently be an integer of 0 to 4. If (e.g., when) z1 to z9 are each 0, the fused polycyclic compound of one or more embodiments may not be substituted with each of R_{b1} to R_{b9}. If (e.g., when) z1, z3, z4, and z7 to z9 are each 5, and R_{b1}'s, R_{b3}'s, R_{b4}'s, and R_{b7}'s to R_{b9}'s are each hydrogen, the embodiment may be the same as if (e.g., when) z1, z3, z4, and z7 to z9 are each 0. If (e.g., when) z2, z5, and z6 are each 4 and R_{b2}'s, R_{b5}'s, and R_{b6}'s are each hydrogen, the embodiment may be the same as if (e.g., when) z2, z5, and z6 are each 0. If (e.g., when) z1 to z9 are each an integer of 2 or greater, R_{b1} to R_{b9} each provided in plurality may each be the same, or at least one selected from among R_{b1} to R_{b9} each provided in plurality may be different.

In Formulas A-1 to A-5, —* is a position connected to Formulas 7-2 to 7-5.

In Formulas 7-1 to 7-5, the same descriptions as those described above in Formula 1 may apply to X, R₁, n1, Sa, Sₐ₂, and Sₐ₃.

In one or more embodiments, the first compound represented by Formula 1 may be represented by Formula 8-1 or Formula 8-2.

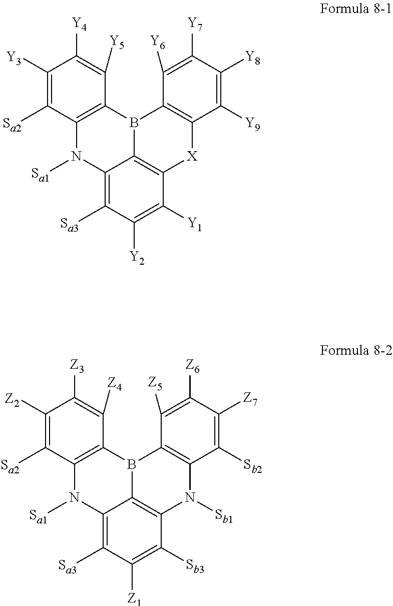

In Formula 8-1, Y₁ to Y₉ may each independently be hydrogen or deuterium, or may be independently selected from among substituents of Substituent Group 1. For example, in one or more embodiments, at least one selected from among Y₁ to Y₉ may be selected from the substituents of Substituent Group 1, and the others may each independently be hydrogen or deuterium. In one or more embodiments, Y₁ to Y₉ may each independently be hydrogen or deuterium.

In Formula 8-2, Z₁ to Z₇ may each independently be hydrogen or deuterium, or may be independently selected from among the substituents of Substituent Group 1. For example, in one or more embodiments, at least one selected from among Z₁ to Z₇ may be selected from the substituents of Substituent Group 1, and the others may each independently be hydrogen or deuterium. In one or more embodiments, Z₁ to Z₇ may each independently be hydrogen or deuterium.

In Formula 8-2, S_{b2} and S_{b3} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms.

In Formula 8-2, any one pair of S_{b1} and S_{b2} or S_{b1} and S_{b3} may be positions in which a substituent represented by Formula 6 is connected. In one or more embodiments, in the fused polycyclic compound represented by Formula 8-2, the substituent represented by Formula 6 may be connected to the positions of S_{b1} and S_{b2}. In one or more embodiments, in the fused polycyclic compound represented by Formula 8-2, the substituent represented by Formula 6 may be connected to the positions of S_{b1} and S_{b3}.

In one or more embodiments, in the fused polycyclic compound represented by Formula 8-2, the substituent represented by Formula 6 may be connected to the positions of S_{b1} and S_{b2}, and S_{b3} may be hydrogen or deuterium. In one or more embodiments, in the fused polycyclic compound represented by Formula 8-2, the substituent represented by Formula 6 may be connected to the positions of S_{b1} and S_{b3}, and S_{b2} may be hydrogen or deuterium.

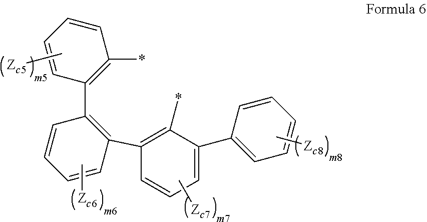

In Formula 6, —* may be a position connected to any one pair of S_{b1} and S_{b2} or S_{b1} and S_{b3} in Formula 8-2.

In Formula 6, Z_{c5} to Z_{c8} may each independently be hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among Z_{c5} to Z_{c8} may independently be bonded to an adjacent group to form a ring. For example, in one or more embodiments, Z_{c5} to Z_{c8} may each independently be hydrogen, deuterium, a substituted or unsubstituted t-butyl group, a substituted or unsubstituted phenyl group, a substituted or unsubstituted biphenyl group, or a substituted or unsubstituted terphenyl group.

In Formula 6, m5 and m6 may each independently be an integer of 0 to 4. If (e.g., when) m5 and m6 are each 0, the fused polycyclic compound of one or more embodiments may not be substituted with each of Z_{c5} and Z_{c6}. If (e.g., when) m5 and m6 are each 4 and each of Z_{c5}'s and Z_{c6}'s is hydrogen, the embodiment may be the same as if (e.g., when) m5 and m6 are each 0. If (e.g., when) m5 and m6 are each an integer of 2 or greater, Z_{c5} and Z_{c6} each provided in plurality may each be the same, or at least one of Z_{c5} or Z_{c6} each provided in plurality may be different.

In Formula 6, m7 may be an integer of 0 to 3. If (e.g., when) m7 is 0, the fused polycyclic compound of one or more embodiments may not be substituted with Z_{c7}. In Formula 6, if (e.g., when) m7 is 3 and Z_{c7}'s are each hydrogen, the embodiment may be the same as if (e.g., when) m7 is 0 in Formula 6. If (e.g., when) m7 is an integer of 2 or greater, Z_{c7} provided in plurality may all be the same, or at least one selected from among the plurality of z_{c7}'s may be different.

In Formula 6, m8 may be an integer of 0 to 5. If (e.g., when) m8 is 0, the fused polycyclic compound of one or more embodiments may not be substituted with Z_{c8}. In Formula 6, if (e.g., when) m8 is 5 and Z_{c5}'s are each hydrogen, the embodiment may be the same as if (e.g., when) m8 is 0 in Formula 6. If (e.g., when) m8 is an integer of 2 or greater, Z_{c8} provided in plurality may all be the same, or at least one selected from among the plurality of Z_{c5}'s may be different.

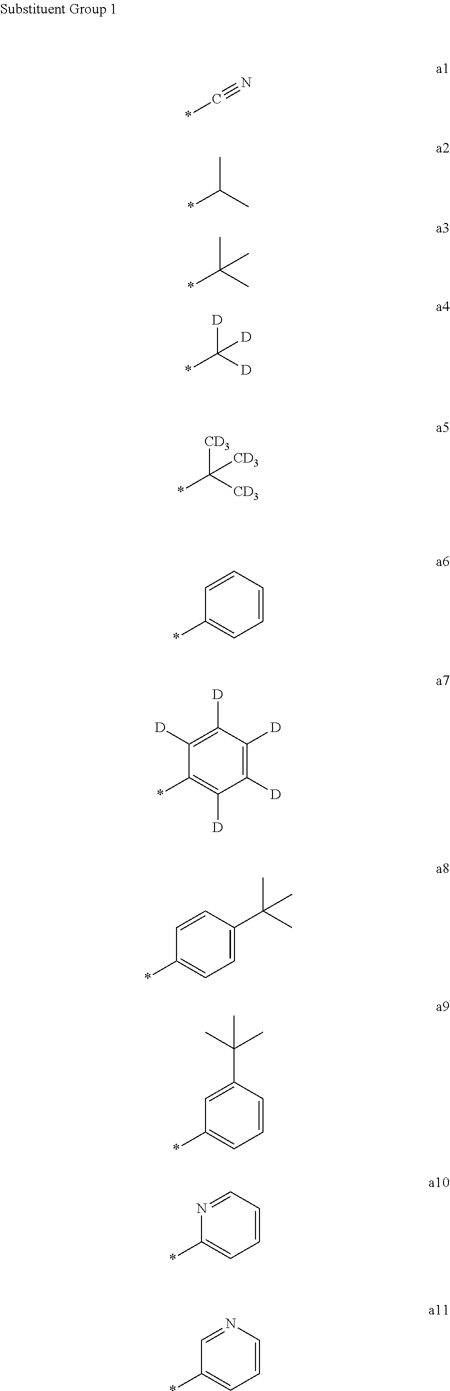

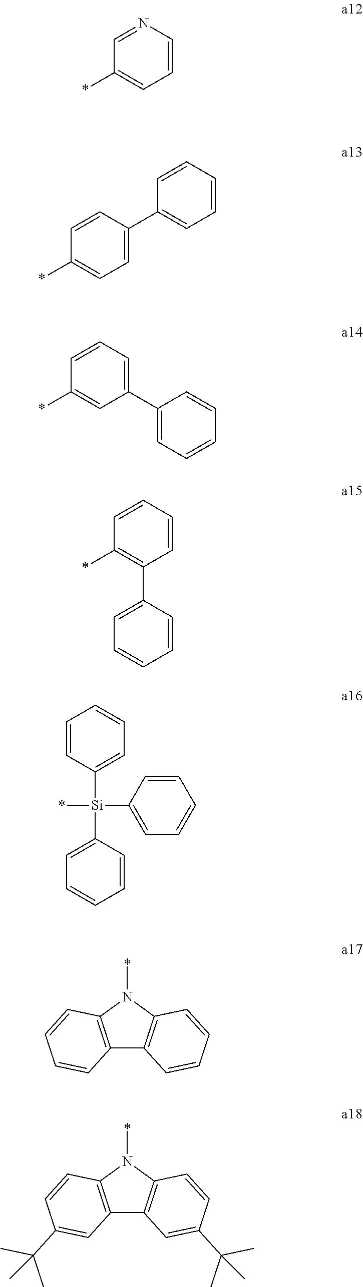

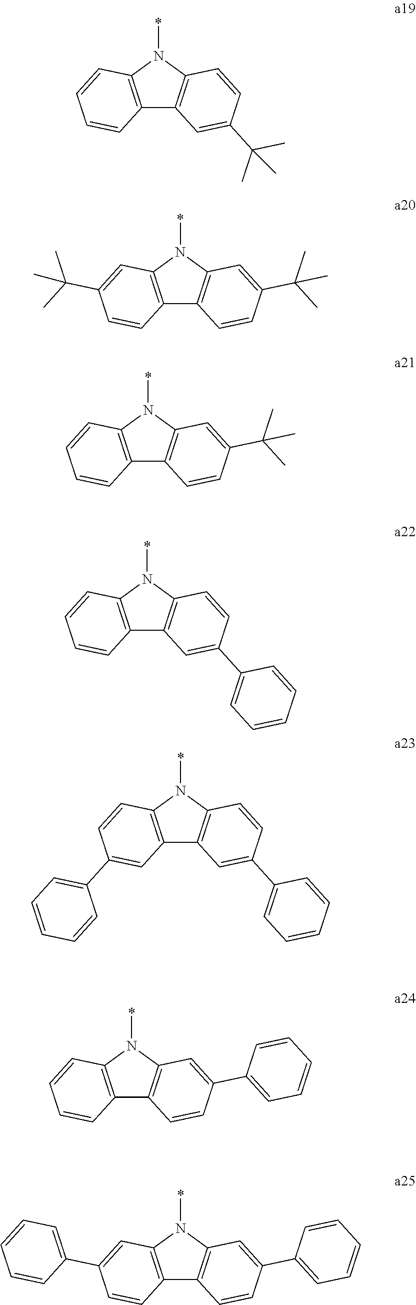

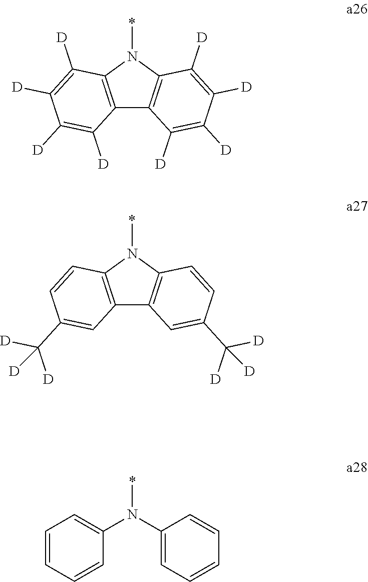 [SMILES: *n1c2c([2H])c([2H])c([2H])c([2H])c2c2c([2H])c([2H])c([2H])c([2H])c21 ; *n1c2ccc(C([2H])([2H])[2H])cc2c2cc(C([2H])([2H])[2H])ccc21 ; *N(c1ccccc1)c1ccccc1]

In Formulas 8-1 and 8-2, the same descriptions as those described in Formula 1 may apply to X, Sₐ₁, Sₐ₂, and Sₐ₃.

In one or more embodiments, the fused polycyclic compound of one or more embodiments represented by Formula 1 may include at least one deuterium as a substituent. The polycyclic compound of one or more embodiments represented by Formula 1 may include a structure in which at least one hydrogen is substituted with deuterium.

The fused polycyclic compound of one or more embodiments may be any one selected from among compounds shown in Compound Group 1. At least one functional layer included in the light emitting element ED of one or more embodiments may include at least one fused polycyclic compound selected from among the compounds shown in Compound Group 1. The light emitting element ED of one or more embodiments may include at least one fused polycyclic compound selected from among the compounds shown in Compound Group 1 in the emission layer EML.

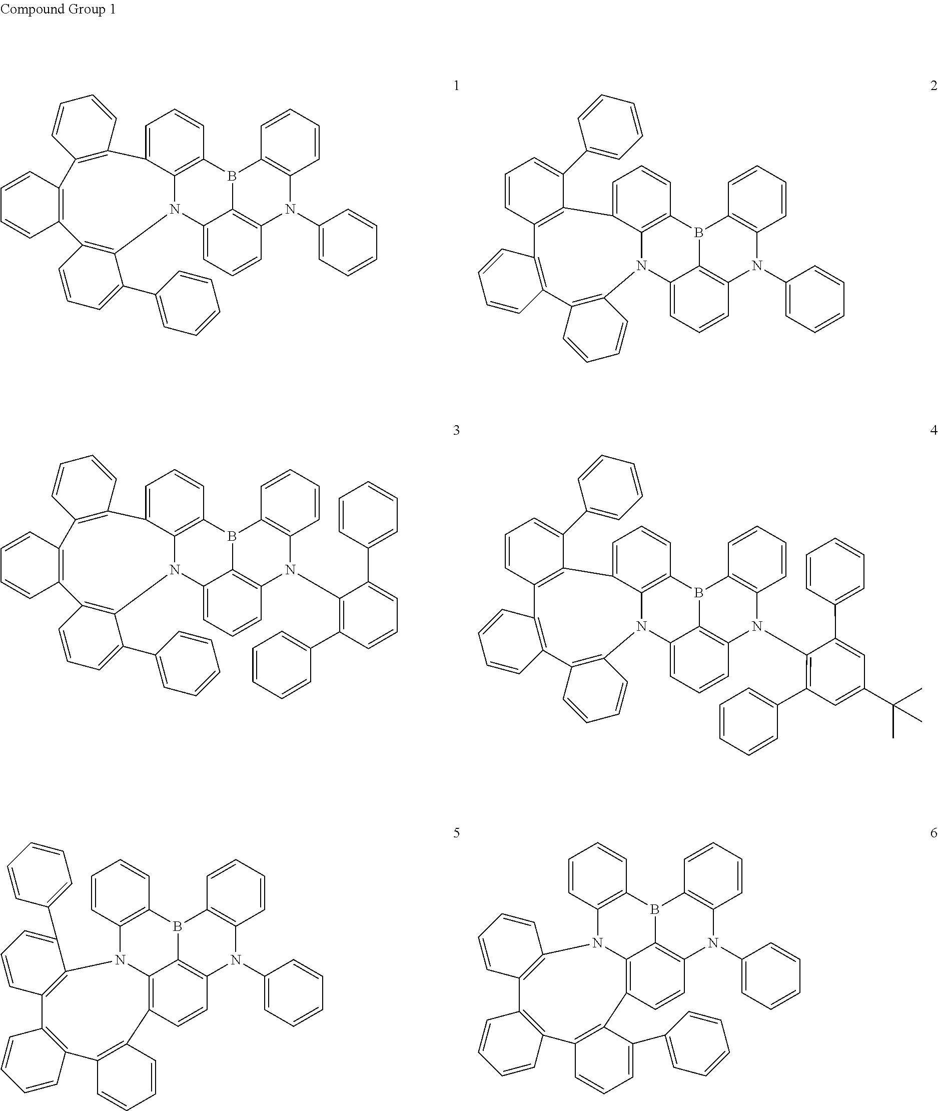

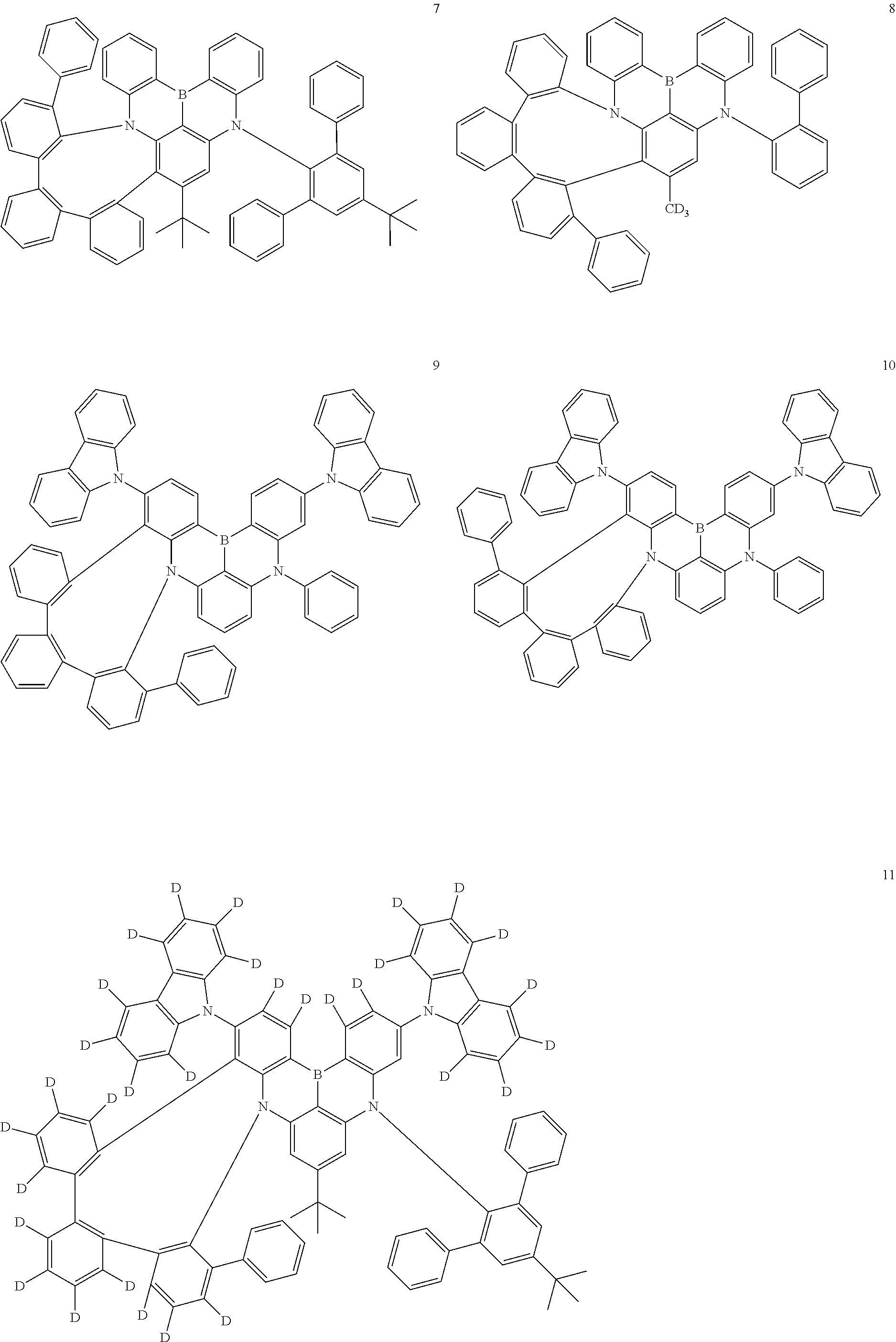

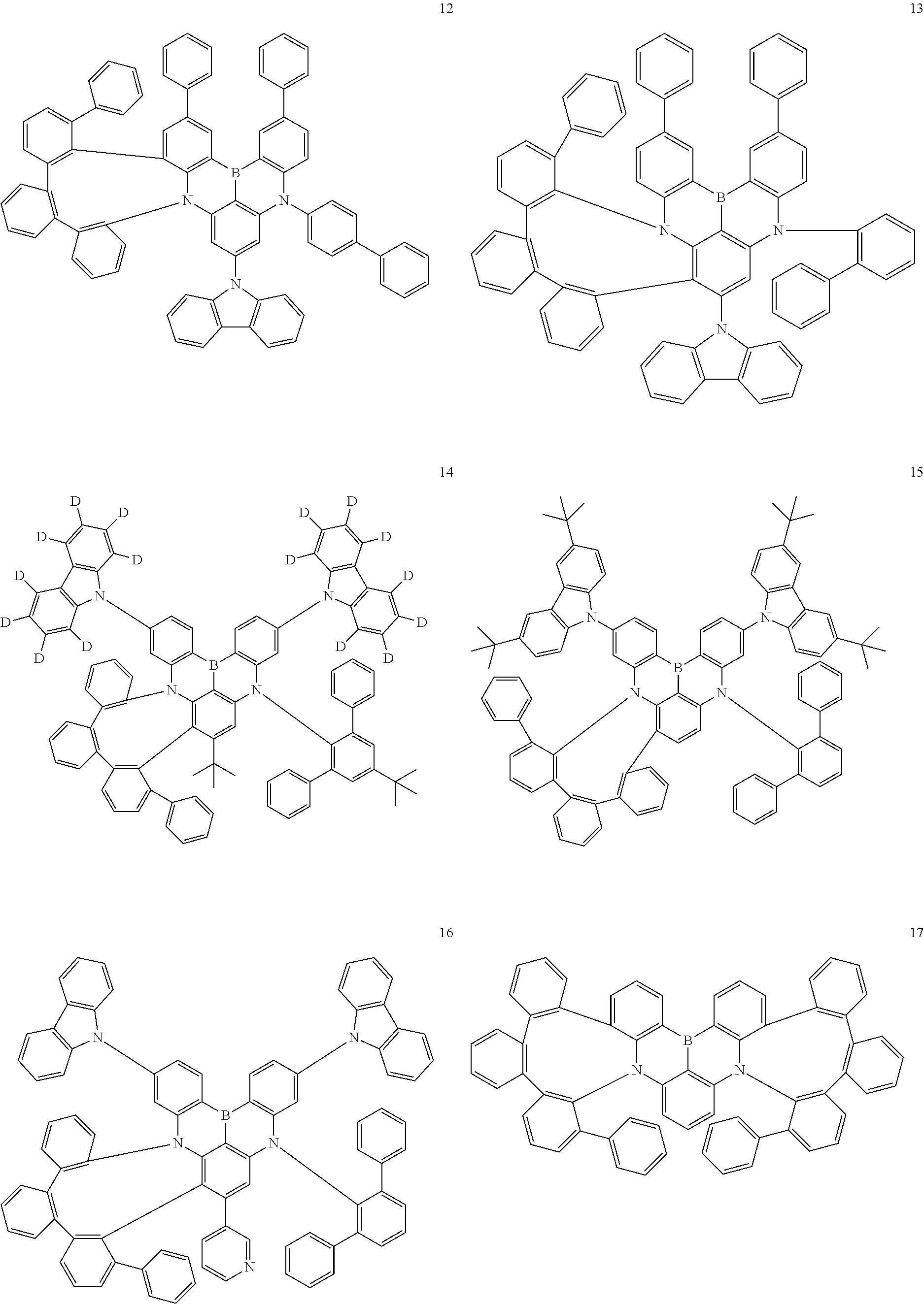

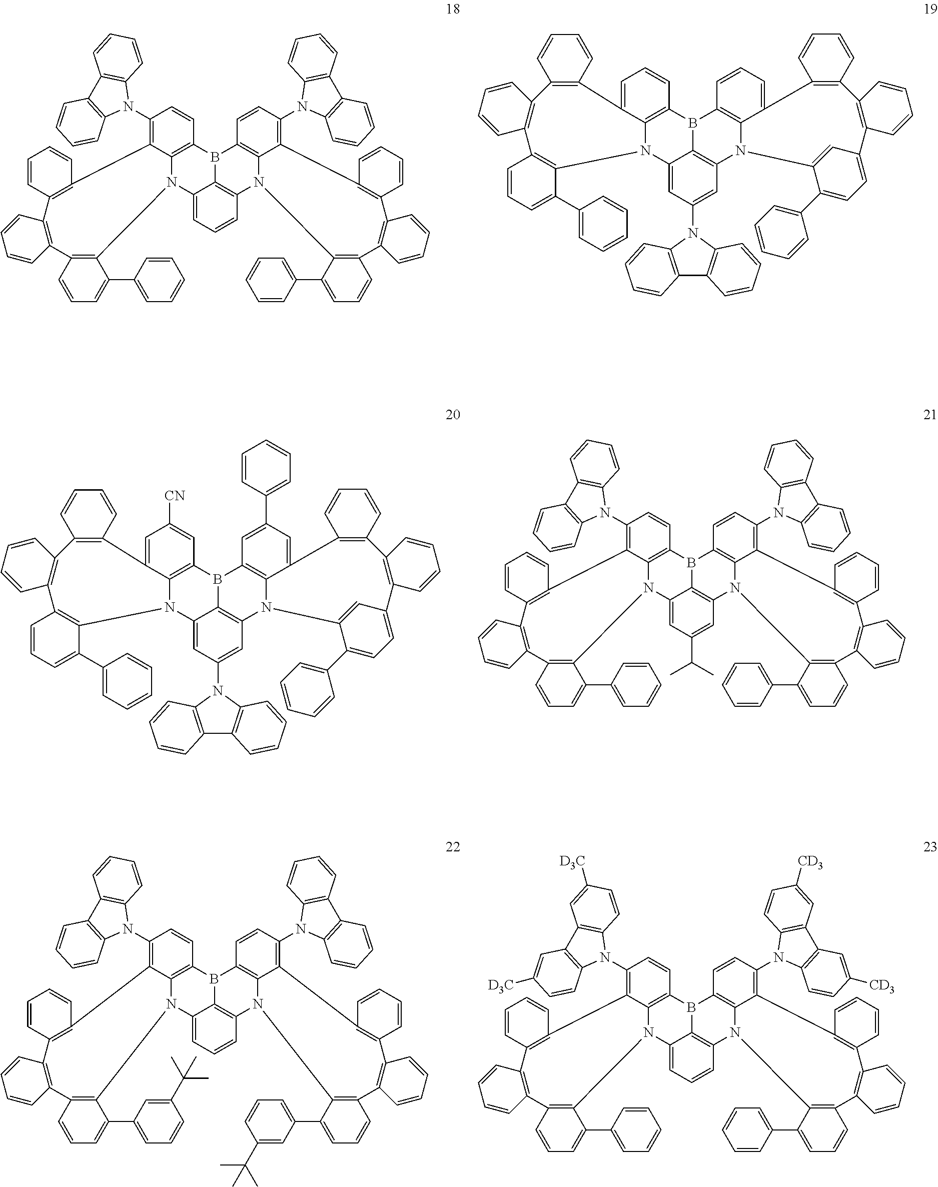

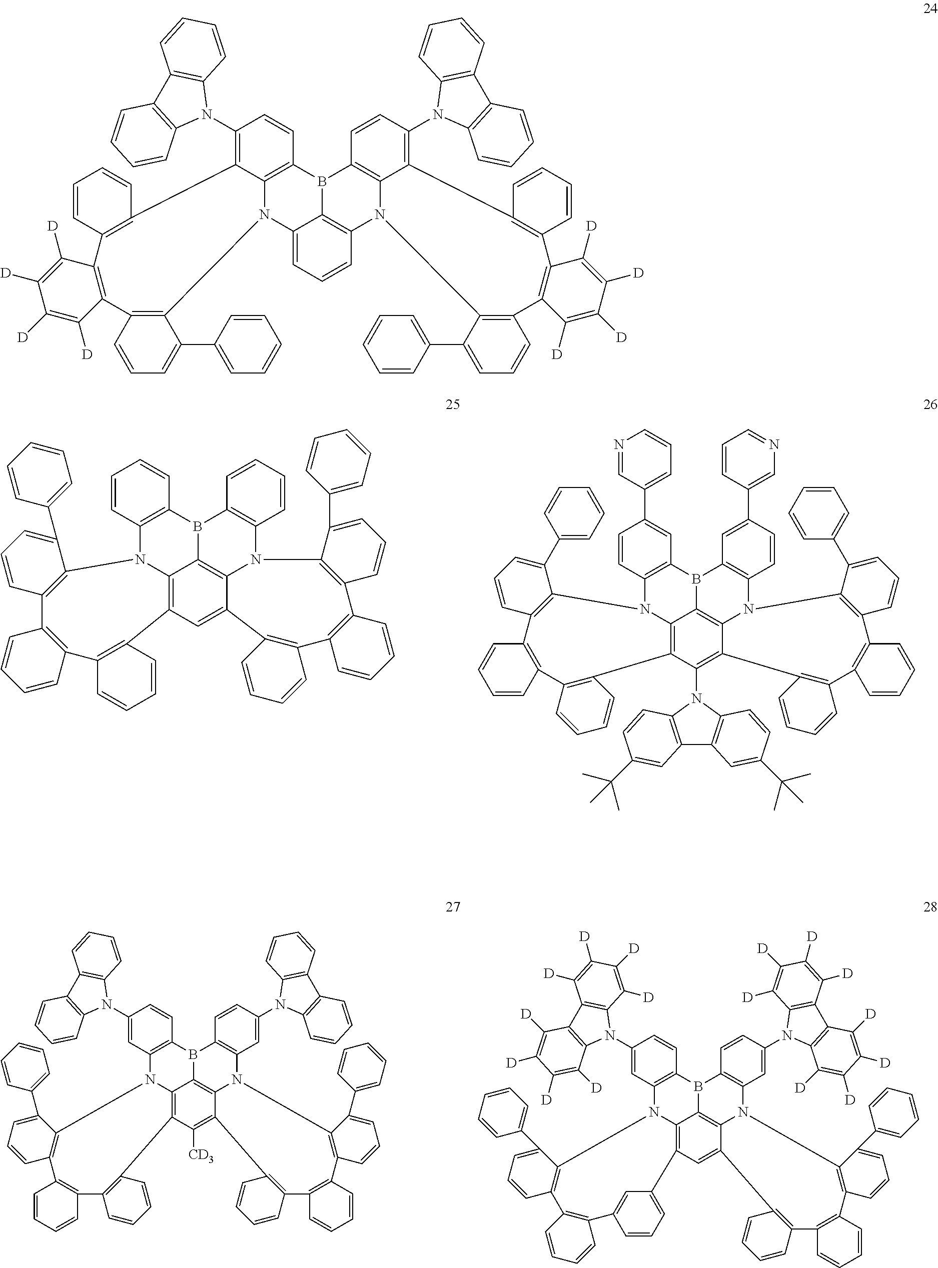

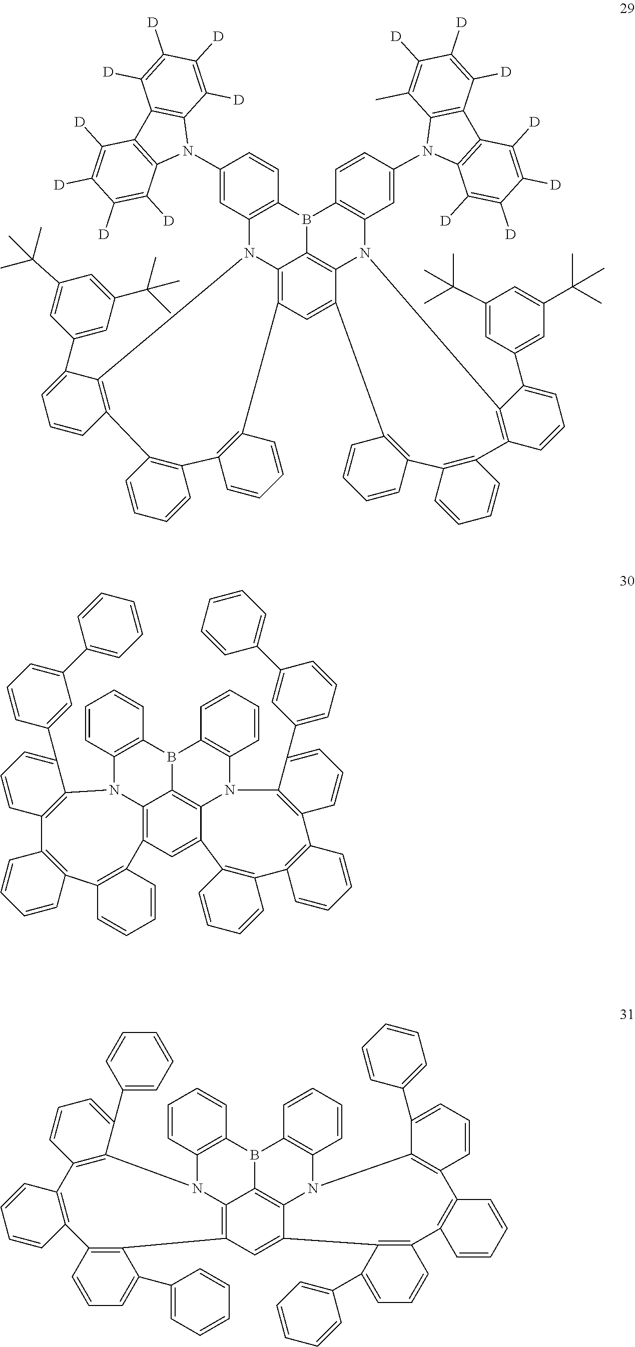

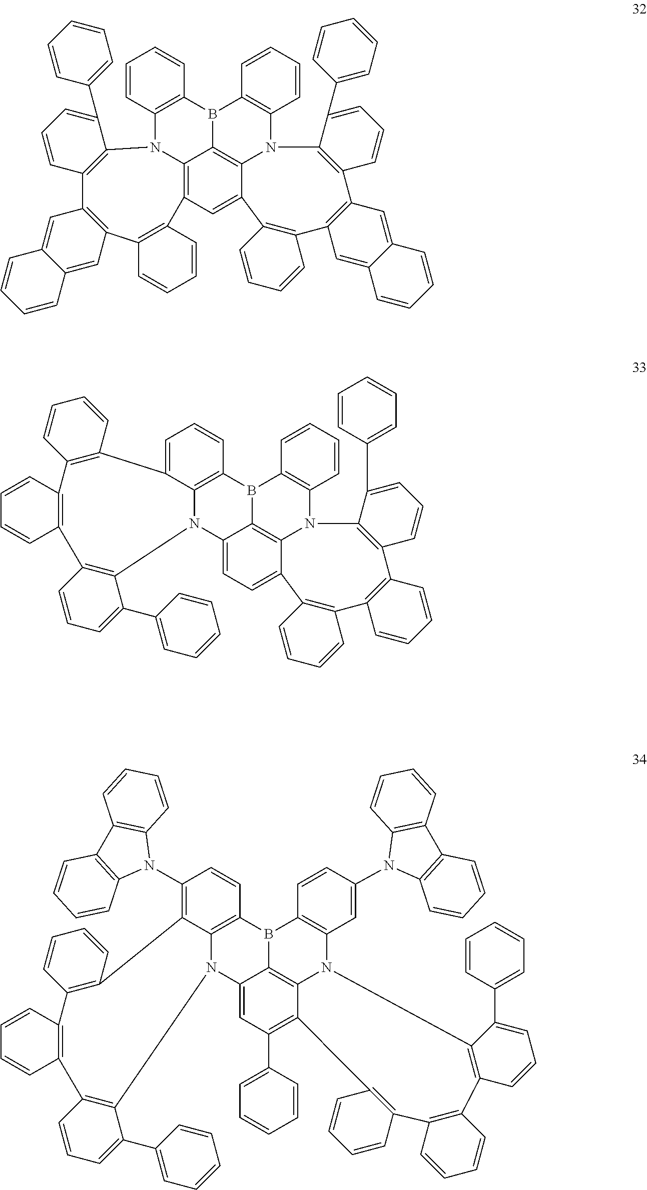 [SMILES: c1ccc(-c2cccc3c4cc5ccccc5cc4c4ccccc4c4cc5c6ccccc6c6cc7ccccc7cc6c6cccc(-c7ccccc7)c6n6c5c5c4n(c23)-c2ccccc2B5c2ccccc2-6)cc1 ; c1ccc(-c2cccc3c4ccccc4c4ccccc4c4cccc5c4n(c23)-c2ccc3c4ccccc4c4ccccc4c4cccc(-c6ccccc6)c4n4c3c2B5c2ccccc2-4)cc1 ; c1ccc(-c2cc3c4c5c2c2ccccc2c2ccccc2c2cccc(-c6ccccc6)c2n5-c2cc(-n5c6ccccc6c6ccccc65)ccc2B4c2ccc(-n4c5ccccc5c5ccccc54)c4c5ccccc5c5ccccc5c5cccc(-c6ccccc6)c5n-3c24)cc1]

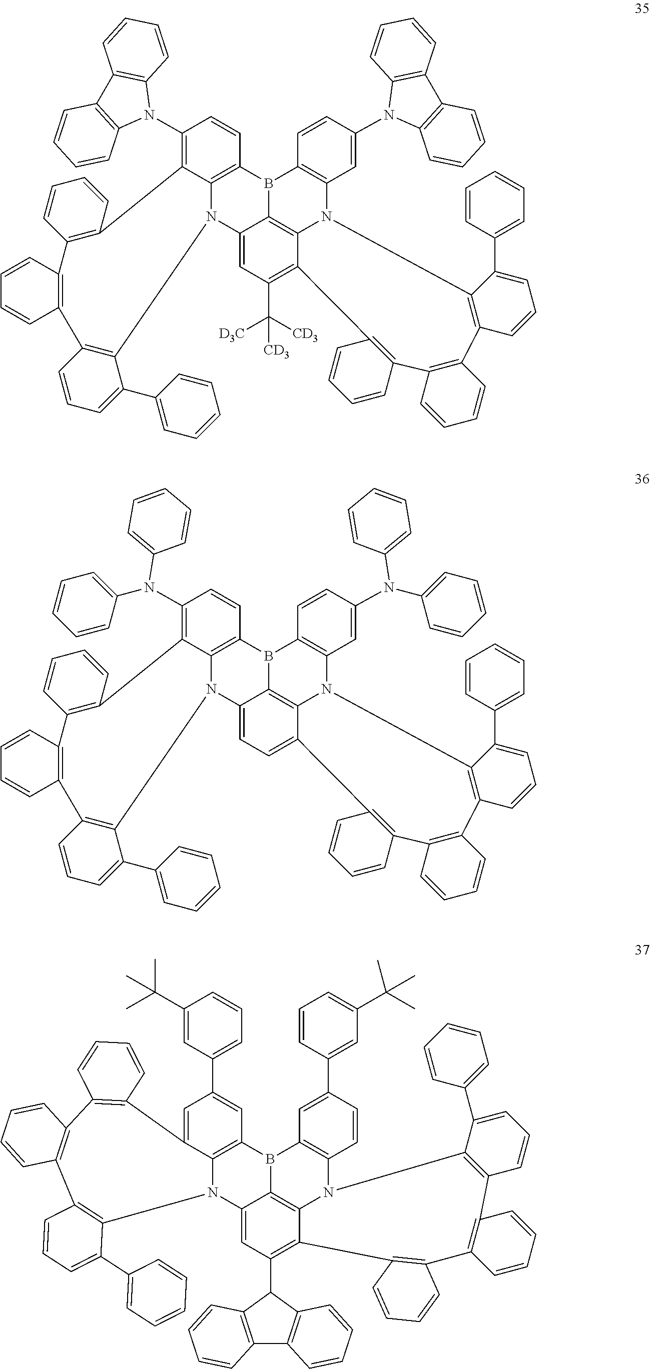

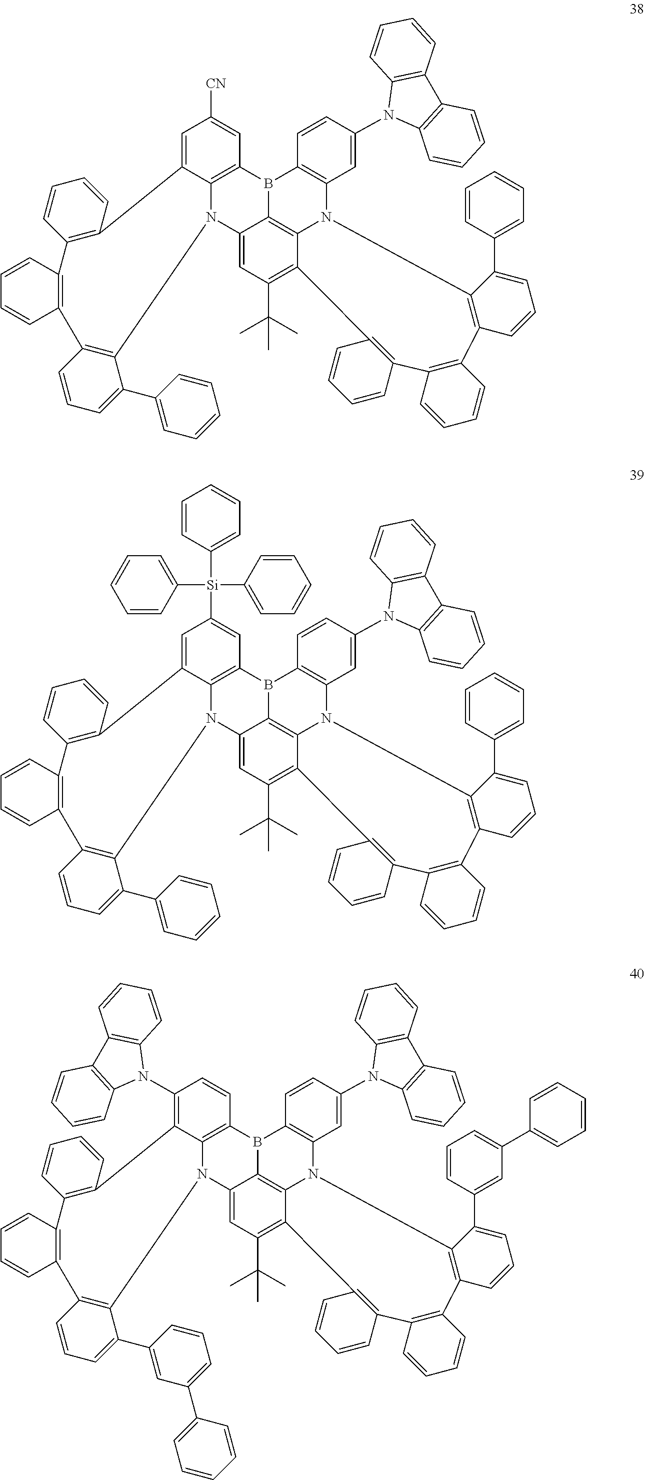 [SMILES: CC(C)(C)c1cc2c3c4c1c1ccccc1c1ccccc1c1cccc(-c5ccccc5)c1n4-c1cc(-n4c5ccccc5c5ccccc54)ccc1B3c1cc(C#N)cc3c4ccccc4c4ccccc4c4cccc(-c5ccccc5)c4n-2c13 ; CC(C)(C)c1cc2c3c4c1c1ccccc1c1ccccc1c1cccc(-c5ccccc5)c1n4-c1cc(-n4c5ccccc5c5ccccc54)ccc1B3c1cc([Si](c3ccccc3)(c3ccccc3)c3ccccc3)cc3c4ccccc4c4ccccc4c4cccc(-c5ccccc5)c4n-2c13 ; CC(C)(C)c1cc2c3c4c1c1ccccc1c1ccccc1c1cccc(-c5cccc(-c6ccccc6)c5)c1n4-c1cc(-n4c5ccccc5c5ccccc54)ccc1B3c1ccc(-n3c4ccccc4c4ccccc43)c3c4ccccc4c4ccccc4c4cccc(-c5cccc(-c6ccccc6)c5)c4n-2c13]

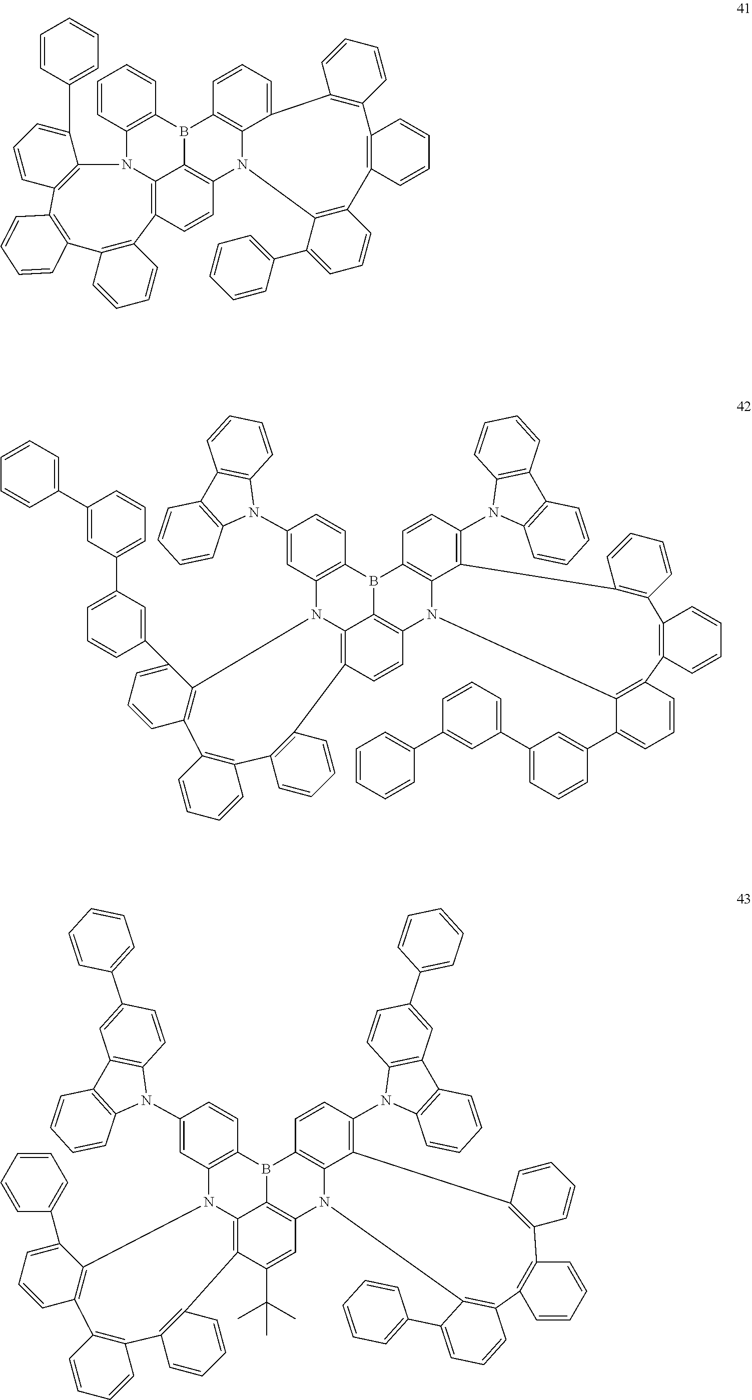 [SMILES: c1ccc(-c2cccc3c4ccccc4c4ccccc4c4cccc5c4n(c23)-c2ccc3c4ccccc4c4ccccc4c4cccc(-c6ccccc6)c4n4c3c2B5c2ccccc2-4)cc1 ; c1ccc(-c2cccc(-c3cccc(-c4cccc5c6ccccc6c6ccccc6c6ccc7c8c6n(c45)-c4cc(-n5c6ccccc6c6ccccc65)ccc4B8c4ccc(-n5c6ccccc6c6ccccc65)c5c6ccccc6c6ccccc6c6cccc(-c8cccc(-c9cccc(-c%10ccccc%10)c9)c8)c6n-7c45)c3)c2)cc1 ; CC(C)(C)c1cc2c3c4c1c1ccccc1c1ccccc1c1cccc(-c5ccccc5)c1n4-c1cc(-n4c5ccccc5c5cc(-c6ccccc6)ccc54)ccc1B3c1ccc(-n3c4ccccc4c4cc(-c5ccccc5)ccc43)c3c4ccccc4c4ccccc4c4cccc(-c5ccccc5)c4n-2c13]

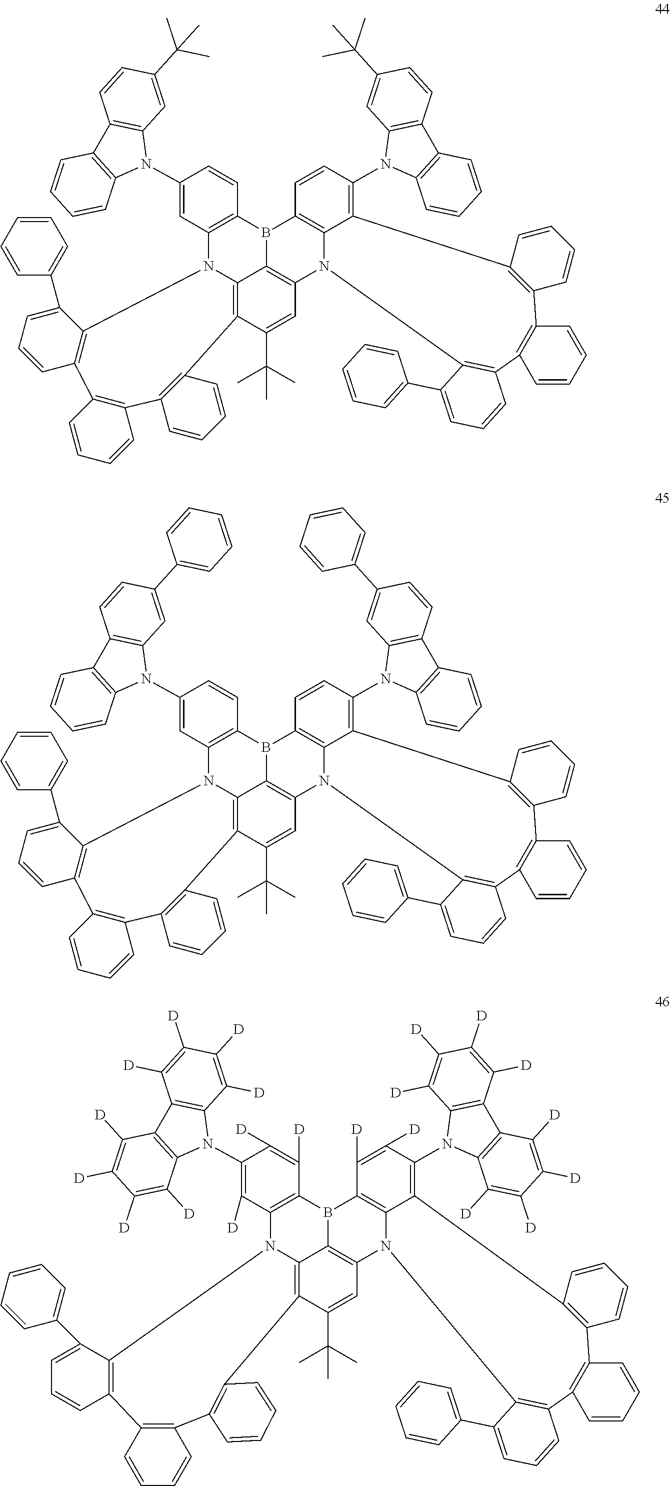

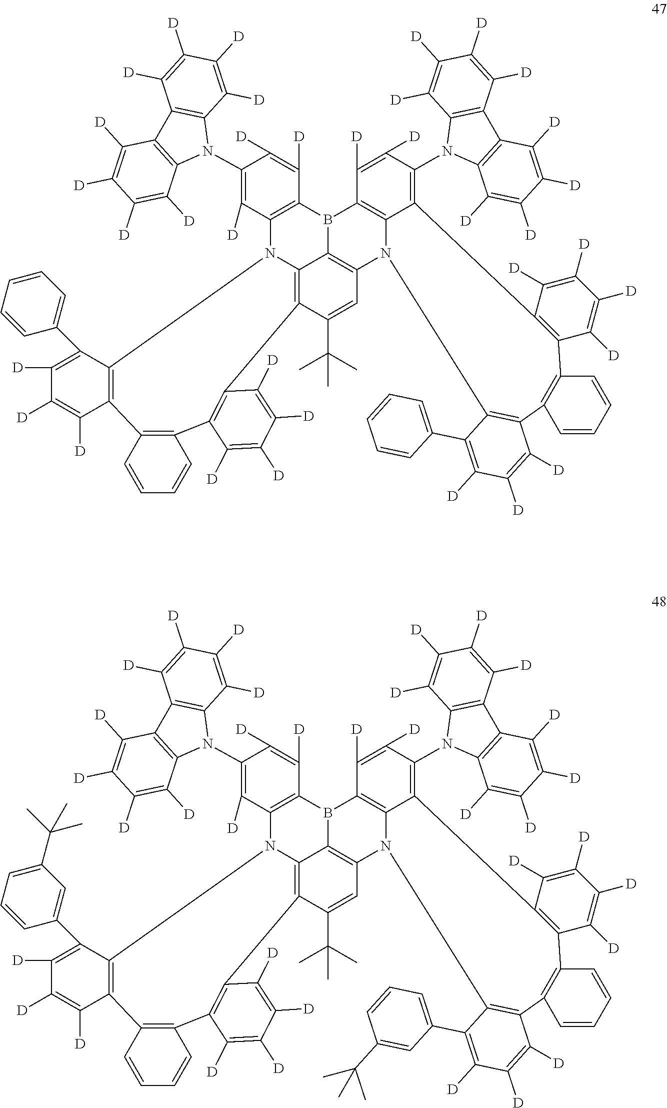

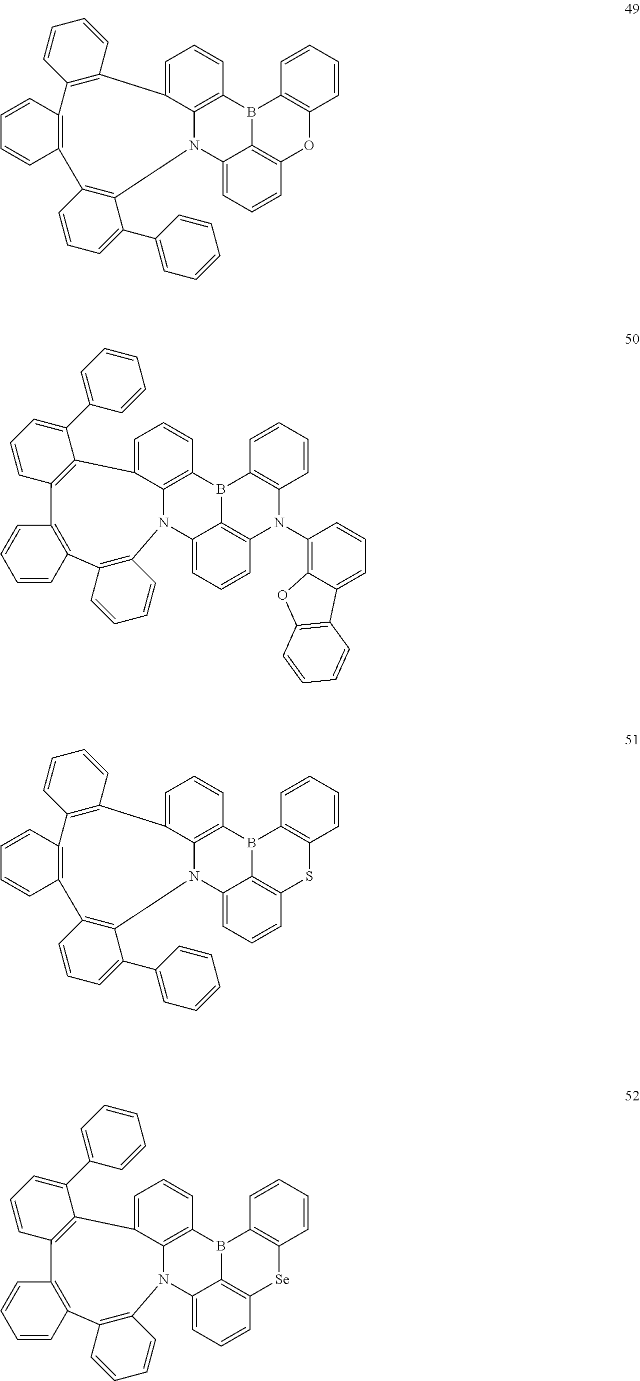 [SMILES: c1ccc(-c2cccc3c4ccccc4c4ccccc4c4cccc5c4n(c23)-c2cccc3c2B5c2ccccc2O3)cc1 ; c1ccc(-c2cccc3c4ccccc4c4ccccc4n4c5c(cccc5c23)B2c3ccccc3N(c3cccc5c3oc3ccccc35)c3cccc-4c32)cc1 ; c1ccc(-c2cccc3c4ccccc4c4ccccc4c4cccc5c4n(c23)-c2cccc3c2B5c2ccccc2S3)cc1 ; c1ccc(-c2cccc3c4ccccc4c4ccccc4n4c5c(cccc5c23)B2c3ccccc3[Se]c3cccc-4c32)cc1]

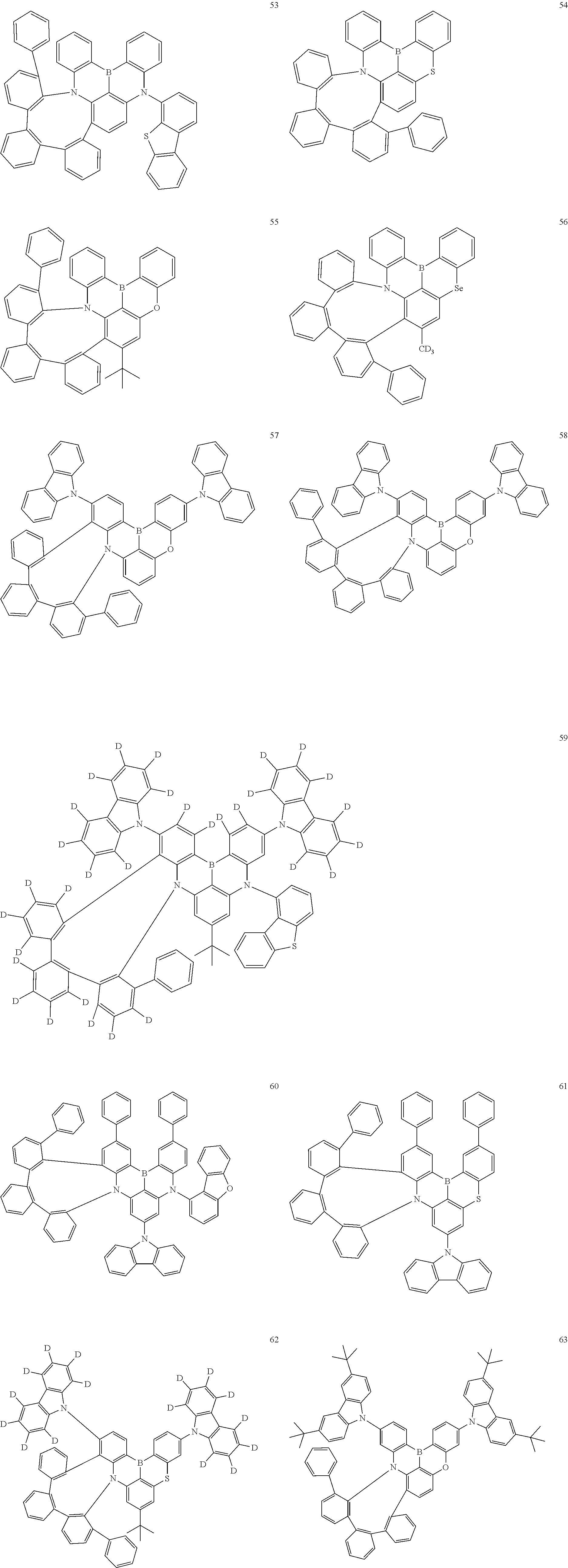

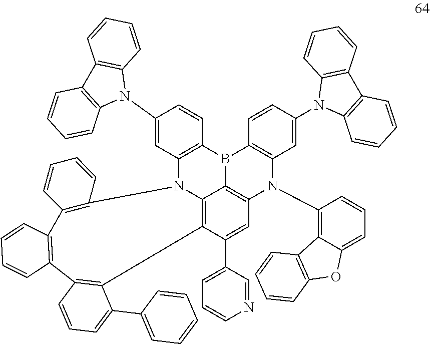 [SMILES: c1ccc(-c2cccc3c4ccccc4c4ccccc4n4c5c6c(cc(-c7cccnc7)c5c23)N(c2cccc3oc5ccccc5c23)c2cc(-n3c5ccccc5c5ccccc53)ccc2B6c2ccc(-n3c5ccccc5c5ccccc53)cc2-4)cc1]

In the example compounds presented in Compound Group 1, “D” indicates deuterium.

The fused polycyclic compound of one or more embodiments represented by Formula 1 has a structure in which the first substituent is connected to a specific position on the fused polycyclic heterocycle, and may thus achieve high efficiency and long lifetime.

The fused polycyclic compound of one or more embodiments includes the fused polycyclic heterocycle in which five rings are fused around the first boron atom, the first nitrogen atom, and the first hetero atom, and the first substituent connected to the fused polycyclic heterocycle. The first substituent may include the first terphenyl moiety including three benzene rings, and the first aryl group connected to the first terphenyl moiety. The first aryl group may be connected to the fifth benzene ring included in the first terphenyl moiety to be positioned ortho with respect to the fused polycyclic heterocycle. In the fused polycyclic compound of one or more embodiments, the first substituent may be connected to the fused polycyclic heterocycle to form a tetrabenzo azonine derivative, and may have improved luminous efficiency and lifetime due to a specific steric structure caused by the first substituent.

The fused polycyclic compound of one or more embodiments may effectively maintain a trigonal planar structure of the boron atom through the steric hindrance effect caused by the first substituent. The boron atom may have electron-deficient properties due to vacant p-orbital, and may thus be bonded to other nucleophiles and be modified into a tetrahedral structure if without a suitable protection, which may result in deterioration of a light emitting element. According to one or more embodiments of the disclosure, in the fused polycyclic compound of one or more embodiments, as the first substituent is introduced into the fused ring core, the vacant p-orbital of the boron atom may be effectively protected, and accordingly, the deterioration caused by the structural deformation may be prevented or reduced.

In addition, in the fused polycyclic compound of one or more embodiments, the steric hindrance effect caused by the first substituent may suppress or reduce intermolecular interactions to control aggregation, excimer formation, or exciplex formation, which may cause greater luminous efficiency. The fused polycyclic compound of one or more embodiments represented by Formula 1 has a bulky structure and thus widens the intermolecular distance to reduce Dexter energy transfer, and accordingly, an increase in the concentration of triplet exciton in the fused polycyclic compound may be prevented or reduced. The triplet exciton at a high concentration remains in an excited state for a long period of time and may thus cause compound decomposition, and may induce hot exciton having high energy generated through triplet-triplet annihilation (TTA) to cause surrounding compound structures to collapse. The triplet-triplet annihilation is a bimolecular reaction that fast-quenches the triplet exciton used for light emission, and may thus cause a decrease in luminous efficiency as a non-radiative transition. In addition, in the fused polycyclic compound of one or more embodiments, the intermolecular distance is increased by the first substituent, and accordingly, the Dexter energy transfer may be suppressed or reduced to prevent or reduce service life deterioration caused by an increase in triplet concentration. Accordingly, when the fused polycyclic compound of one or more embodiments is applied to an emission layer EML of the light emitting element ED, the luminous efficiency may be increased and the element service life may also be improved.

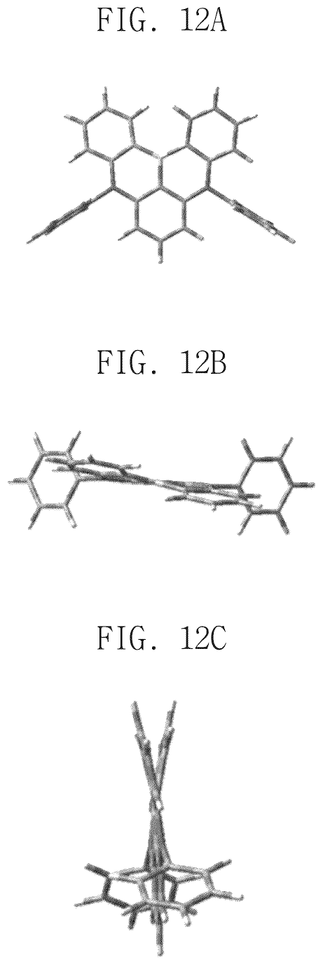

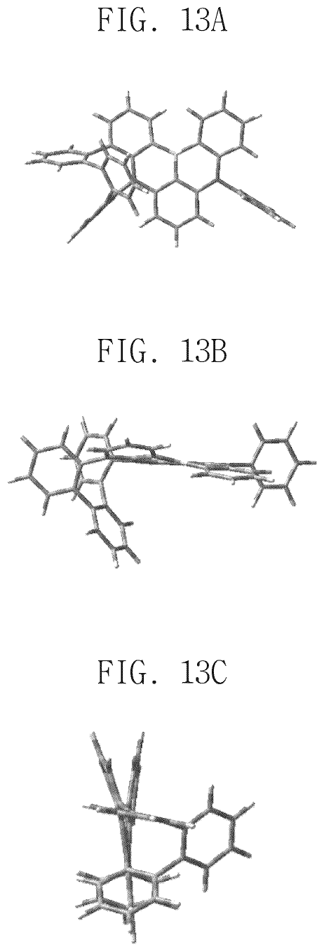

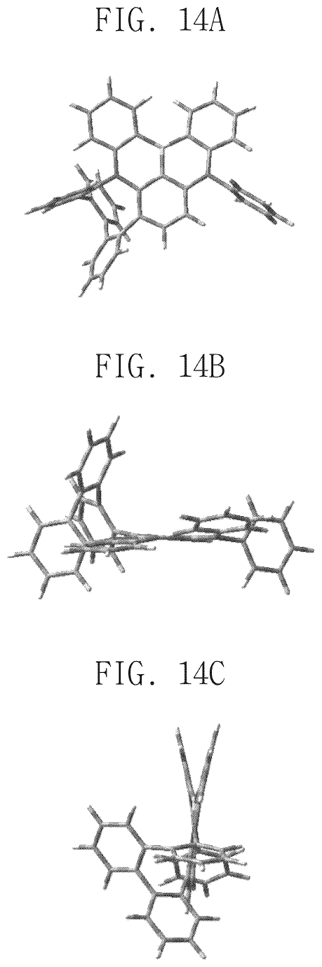

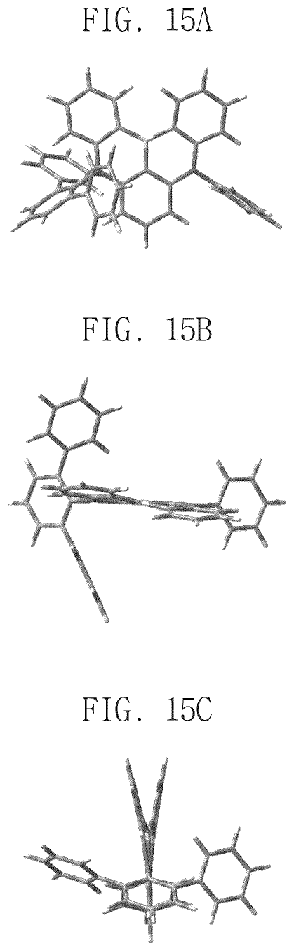

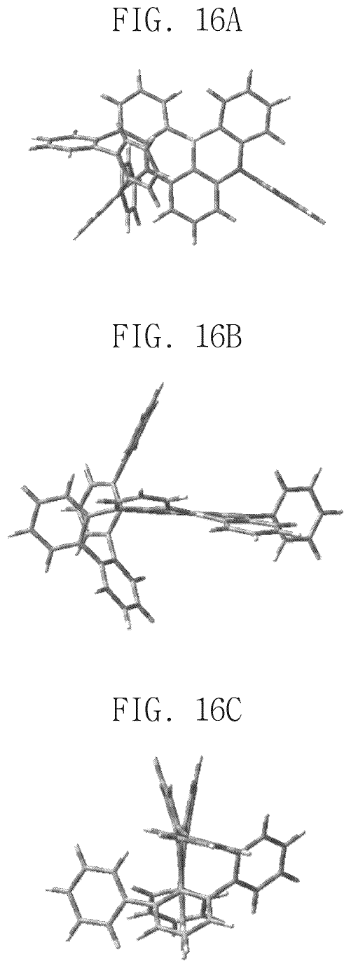

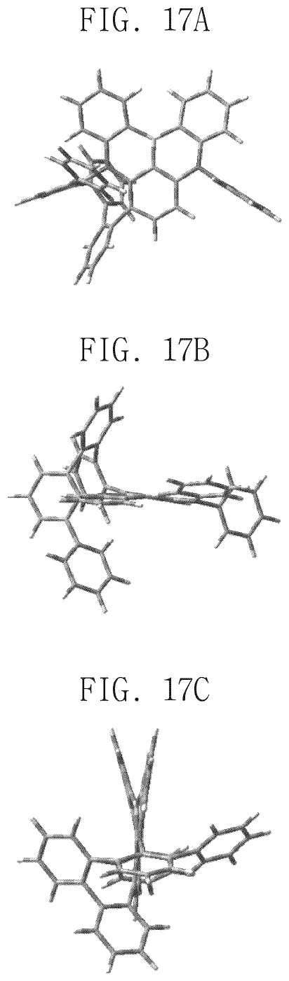

FIGS. 12A to 12C are each a view showing a three-dimensional molecular model of Comparative Example Compound C1. FIGS. 13A to 13C are each a view showing a three-dimensional molecular model of Comparative Example Compound C2. FIGS. 14A to 14C are each a view showing a three-dimensional molecular model of Comparative Example Compound C3. FIGS. 15A to 15C are each a view showing a three-dimensional molecular model of Comparative Example Compound C4. FIGS. 16A to 16C are each a view showing a three-dimensional molecular model of Example Compound 1. FIGS. 17A to 17C are each a view showing a three-dimensional molecular model of Example Compound 2.

FIGS. 12A, 13A, 14A, 15A, 16A, and 17A respectively show three-dimensional molecular models of Comparative Example Compounds and Example Compounds viewed from a front, FIGS. 12B, 13B, 14B, 15B, 16B, and 17B respectively show three-dimensional molecular models of Comparative Example Compounds and Example Compounds viewed from above, and FIGS. 12C, 13C, 14C, 15C, 16C, and 17C respectively show three-dimensional molecular models of Comparative Example Compounds and Example Compounds viewed from a side.

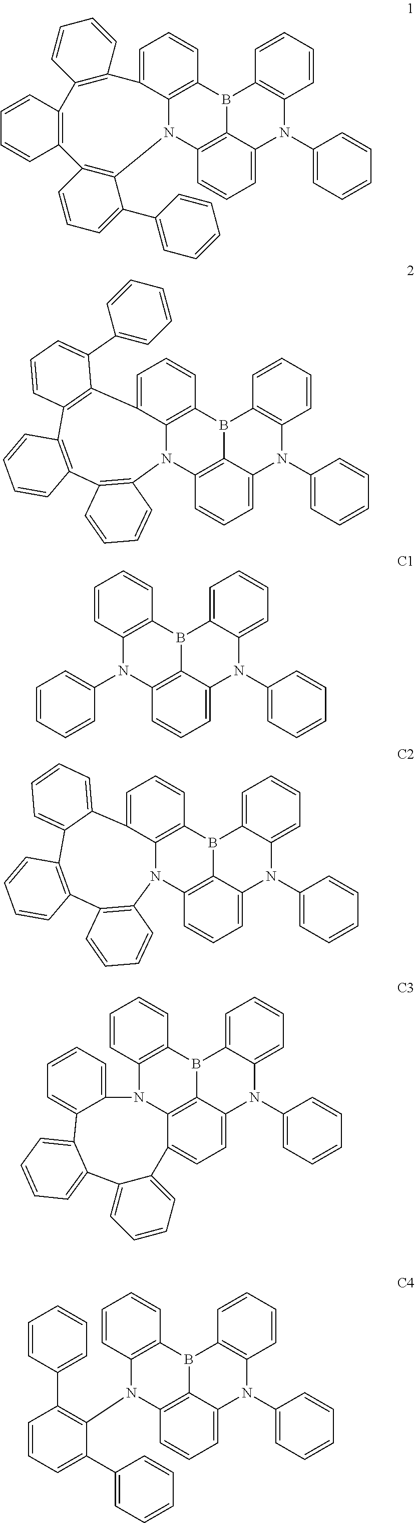

Luminescence transition of a multi-resonance molecule centered on a boron atom takes place in a plate-shaped core, and thus the core portion needs to be protected from external nucleophiles, radicals, and decomposition products in a light emitting element. Accordingly, to physically cover or shield p-orbital of the boron atom, a method of introducing a phenyl group to a nitrogen atom in the core and expanding a substituent connected to the phenyl group may be used. FIGS. 12A to 17C show differences in molecular structure depending on the type or kind of substituent introduced for steric hindrance properties in a fused polycyclic compound.

Comparative Example Compound C1 corresponds to one that has a structure in which an unsubstituted phenyl group is connected to a nitrogen atom in a fused ring core containing a boron atom and the nitrogen atom. Comparative Example Compound C2 and Comparative Example Compound C3 are fused polycyclic compounds containing a tetrabenzo azonine derivative, and are different from Example Compound 1 and Example Compound 2, respectively, in that Comparative Example Compound C2 and Comparative Example Compound C3 have a structure in which a phenyl group connected to the tetrabenzo azonine derivative is not provided. Comparative Example Compound C4 corresponds to one that has a structure in which an unsubstituted terphenyl group is connected to a nitrogen atom in a fused ring core containing a boron atom and the nitrogen atom.

Referring to FIGS. 12A to 12C, in Comparative Example Compound C1, a phenyl group is connected to a nitrogen atom, but the phenyl group itself does not come along a sufficient steric hindrance effect, and thus there may be a degraded boron atom protection effect, certain reduced intermolecular interactions, and certain suppressed or reduced Dexter energy transfer, thereby causing a reduced effect of lowering triplet exciton concentration.

Referring to FIGS. 13A to 13C, 14A to 14C, 16A to 16C, and 17A to 17C, Comparative Example Compound C2 and Comparative Example Compound C3 include a tetrabenzo azonine derivative in the fused polycyclic compound, and may thus have greater steric hindrance properties than Comparative Example Compound C1. The tetrabenzo azonine derivative has a structure in which four benzene rings are bent around a nitrogen-containing nine-membered ring, and this steric hindrance may contribute to control interactions between molecules. However, if (e.g., when) comparing Comparative Example Compounds C2 and C3 with Example Compounds 1 and 2, because the tetrabenzo azonine derivative has stericity in only one direction with respect to the plate-like structure of the fused ring core, the other side of the plate-like structure may be not protected, and thus fails to effectively protect the boron atom from external nucleophiles or radicals, which may approach from the other side, or from decomposition products in a light emitting element. In contrast, the structures of Example Compounds 1 and 2 include a structure in which a tetrabenzo azonine derivative is included and a phenyl group is additionally introduced at a specific position of the tetrabenzo azonine derivative. Accordingly, Example Compounds 1 and 2 may have stericity in both directions (e.g., simultaneously) with respect to the plate-shaped structure of the fused ring core, and may thus effectively protect the boron atom sterically, resulting in further greater lifetime and efficiency than that of Comparative Example Compounds C2 and C3.

In addition, referring to FIGS. 15A to 15C, Comparative Example Compound C4 has a structure in which a terphenyl group is connected to a nitrogen atom, and may thus have stericity in both directions (e.g., simultaneously) with respect to the plate-shaped structure of the fused ring core, thereby having a greater effect of suppressing or reducing interaction with surrounding molecules than Comparative Example Compounds C2 and C3. However, the terphenyl group included in Comparative Example Compound C4 has a terminal phenyl group in which free rotation is allowed, and may thus have an increase in degree of freedom of a terminal substituent adjacent to the boron atom, thereby causing degradation in luminous efficiency and color purity. In contrast, Example Compounds 1 and 2, with the introduction of an additional phenyl group into the tetrabenzo azonine derivative, have stericity in both directions (e.g., simultaneously) with respect to the plate-like structure, and has rigid characteristics due to the 9-membered ring to suppress or reduce intramolecular movement, resulting in a significantly reduced stokes shift, and improved luminous efficiency and lifetime, compared to Comparative Example Compound C4.

An emission spectrum of the fused polycyclic compound represented by Formula 1 has a full width at half maximum of about 10 nm to about 50 nm, for example, about 20 nm to about 40 nm. As the emission spectrum of the polycyclic compound of one or more embodiments represented by Formula 1 has a full width at half maximum in the above range, luminous efficiency may be improved if (e.g., when) the fused polycyclic compound of one or more embodiments is applied to a light emitting element. In addition, element service life may be improved if (e.g., when) the fused polycyclic compound of one or more embodiments is used as a blue light emitting element material for a light emitting element.

In one or more embodiments, the fused polycyclic compound of one or more embodiments represented by Formula 1 may be a thermally activated delayed fluorescence emitting material. In one or more embodiments, the fused polycyclic compound of one or more embodiments represented by Formula 1 may be a thermally activated delayed fluorescence dopant having a difference A Est between a lowest triplet excitation energy level (T1 level) and a lowest singlet excitation energy level (S₁ level) of about 0.6 eV or less. In one or more embodiments, the fused polycyclic compound of one or more embodiments represented by Formula 1 may be a thermally activated delayed fluorescence dopant having a difference A Est between a lowest triplet excitation energy level (T1 level) and a lowest singlet excitation energy level (S₁ level) of about 0.2 eV or less. However, embodiments of the present disclosure are not limited thereto.

In one or more embodiments, the fused polycyclic compound of one or more embodiments represented by Formula 1 may include a first substituent and a second substituent in the compound. By adjusting the number and substitution positions of the first substituent and the second substituent, the singlet energy level and the triplet energy level of the overall compound may be appropriately or suitably adjusted. Accordingly, the fused polycyclic compound according to one or more embodiments of the present disclosure may exhibit improved thermally activated delayed fluorescence properties.

The fused polycyclic compound of one or more embodiments represented by Formula 1 may be a light emitting material having a central emission wavelength in a wavelength range of about 430 nm to about 490 nm. For example, the fused polycyclic compound of one or more embodiments represented by Formula 1 may be a blue thermally activated delayed fluorescence (TADF) dopant. However, embodiments of the present disclosure are not limited thereto, and if (e.g., when) the fused polycyclic compound of one or more embodiments is used as a light emitting material, a first dopant/first compound may be used as a dopant material emitting light in one or more suitable wavelength ranges, such as a red light emitting dopant or a green light emitting dopant.

In the light emitting element ED of one or more embodiments, the emission layer EML may be to emit delayed fluorescence. For example, in one or more embodiments, the emission layer EML may be to emit light of thermally activated delayed fluorescence (TADF).

In one or more embodiments, the emission layer EML of the light emitting element ED may be to emit blue light. For example, the emission layer EML of an organic electroluminescence element ED of one or more embodiments may be to emit blue light in a wavelength range of about 490 nm or less. However, embodiments of the present disclosure are not limited thereto, and the emission layer EML may be to emit green light or red light.

In one or more embodiments, the fused polycyclic compound of one or more embodiments may be included in the emission layer EML. The fused polycyclic compound of one or more embodiments may be included in the emission layer EML as a dopant material. The fused polycyclic compound of one or more embodiments may be a thermally activated delayed fluorescence material. The fused polycyclic compound of one or more embodiments may be used as a thermally activated delayed fluorescence dopant. For example, in the light emitting element ED of one or more embodiments, the emission layer EML may include at least one selected from among the fused polycyclic compounds shown in Compound Group 1 described previously as a thermally activated delayed fluorescence dopant. However, the utilization of the fused polycyclic compound of one or more embodiments is not limited thereto.

In one or more embodiments, the emission layer EML may include multiple compounds. The emission layer EML of one or more embodiments may include the fused polycyclic compound represented by Formula 1, i.e., the first compound, and at least one selected from among a second compound represented by Formula HT-1, a third compound represented by Formula ET-1, and a fourth compound represented by Formula D-1.

In one or more embodiments, the emission layer EML may include the first compound represented by Formula 1 and further include at least one selected from among a second compound represented by Formula HT-1 and a third compound represented by Formula ET-1.

In one or more embodiments, the emission layer EML may include a second compound represented by Formula HT-1. In one or more embodiments, the second compound may be used as a hole transport host material in the emission layer EML.

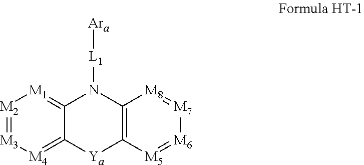

In Formula HT-1, M₁ to M₈ may each independently be N or CR₅₁. For example, in one or more embodiments, all M₁ to M₈ may be CR₅₁. In one or more embodiments, any one selected from among M₁ to M₈ may be N, and the remainder may be CR₅₁.

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that two 6-membered rings (e.g., two benzene rings) connected with the nitrogen atom of Formula HT-1 may be connected via a direct linkage,

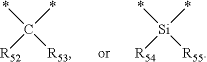

In one or more embodiments, in Formula HT-1, if (e.g., when) Yₐ is a direct linkage, the second compound represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, in one or more embodiments, Arₐ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In one or more embodiments, one or more selected from among R₅₁ to R₅₅ may be independently combined with an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds represented in Compound Group 2. The emission layer EML may include at least one selected from among the compounds represented in Compound Group 2 as a hole transport host material.

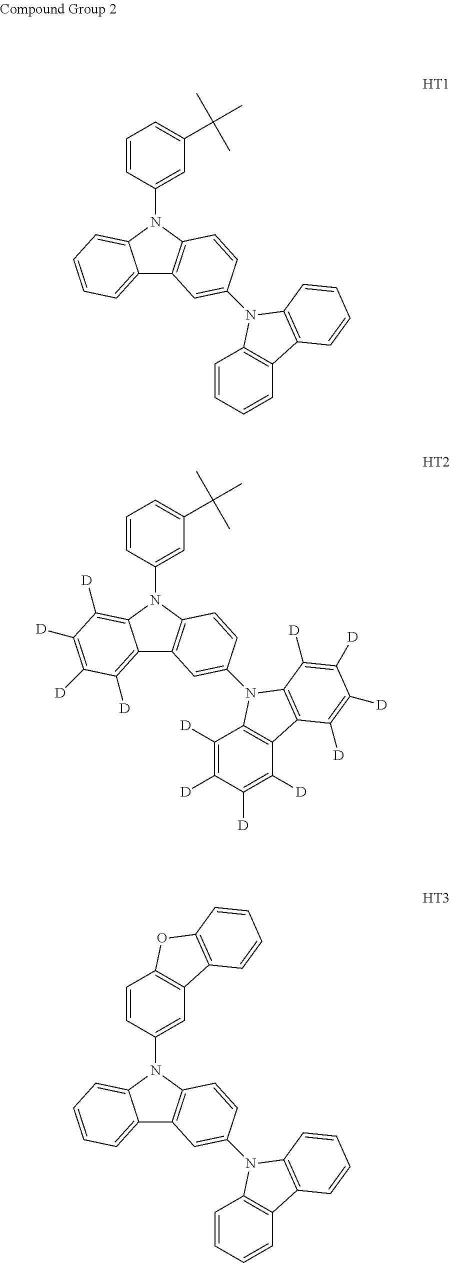 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

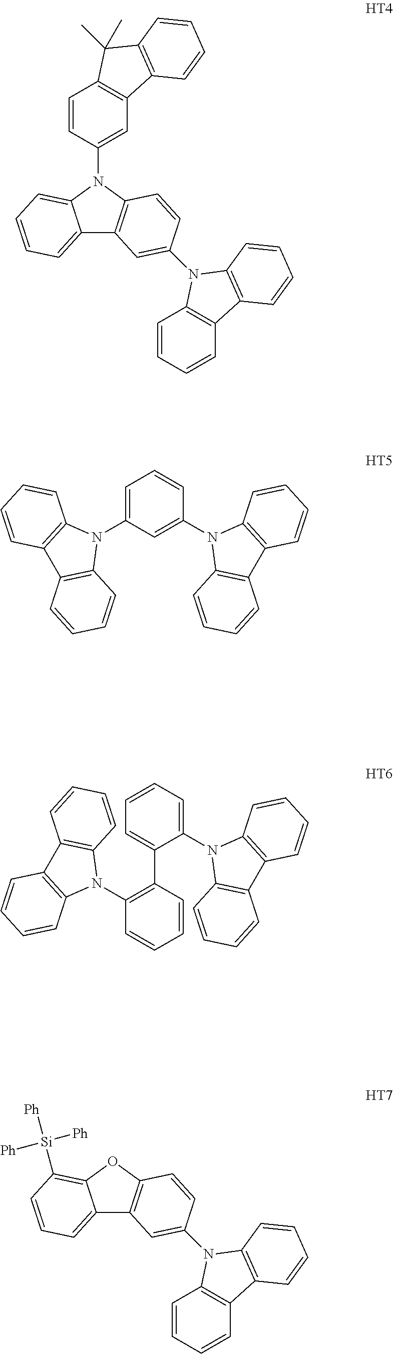 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

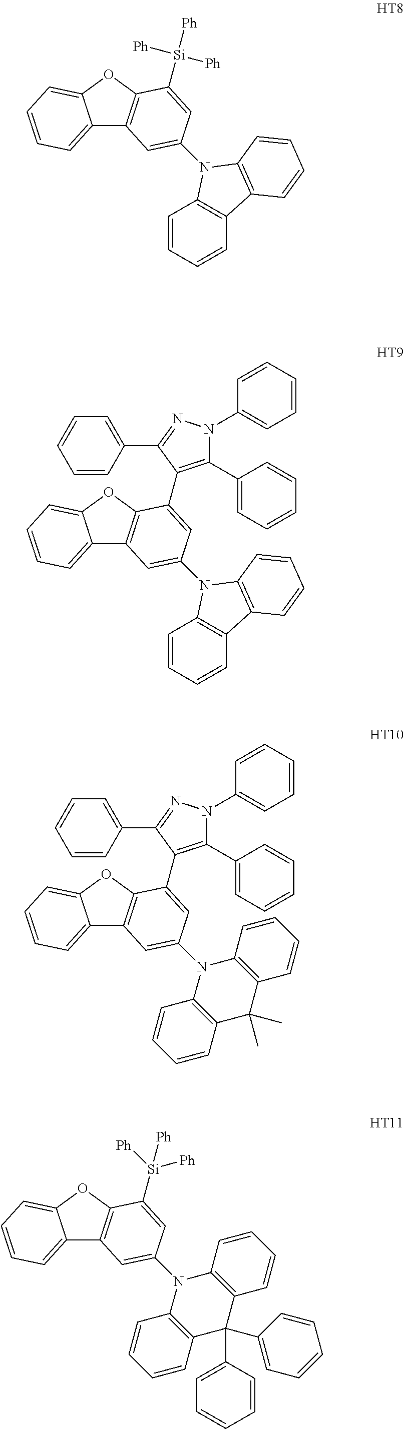 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

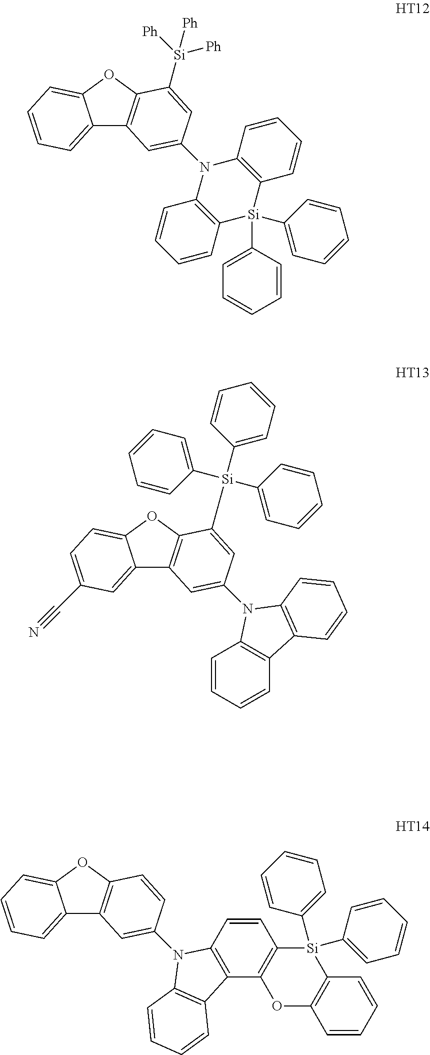 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

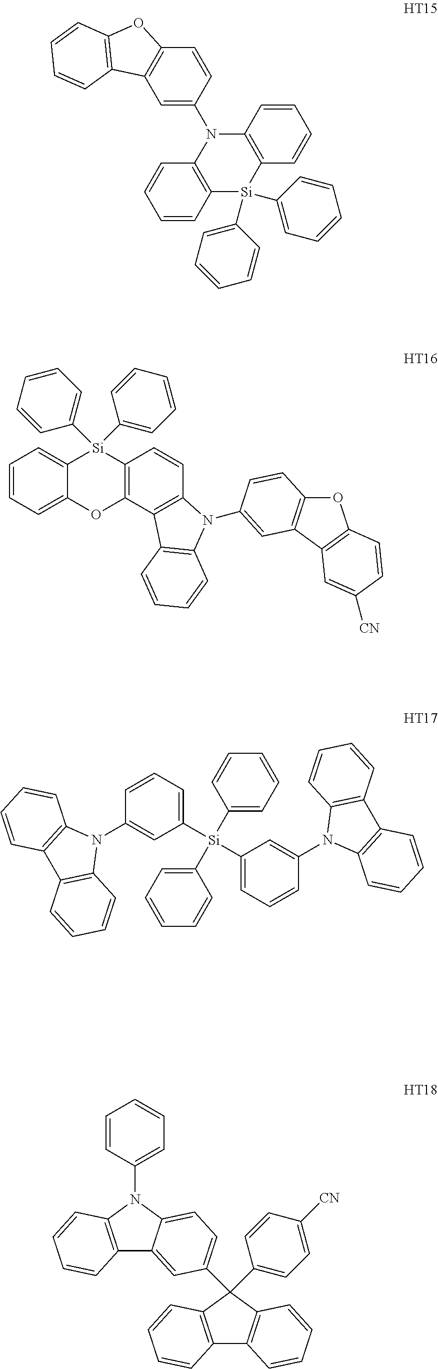 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

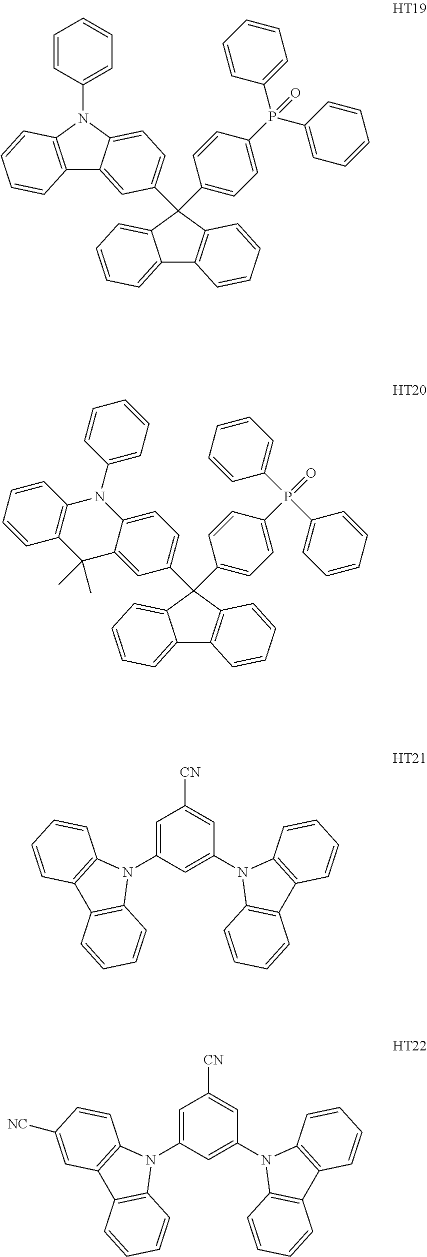 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

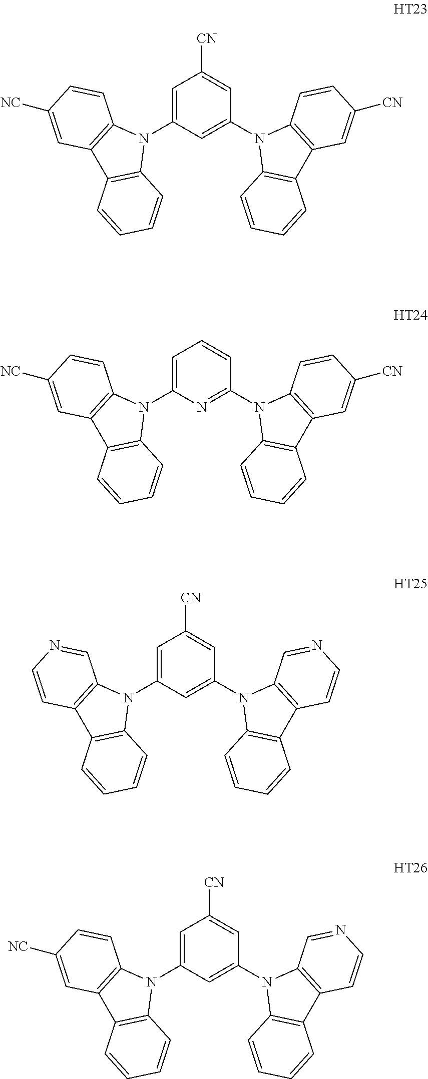 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

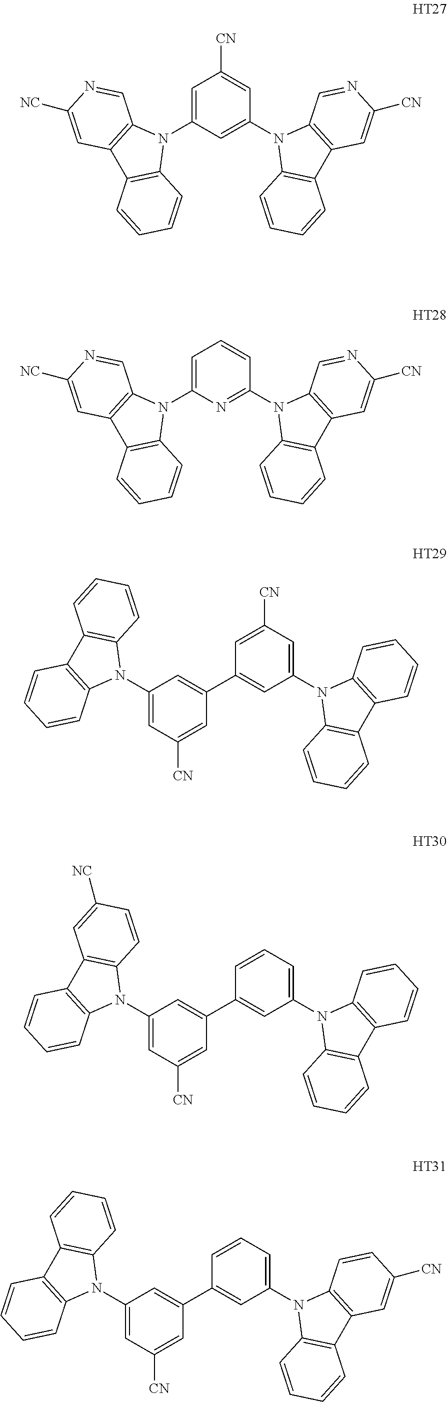 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

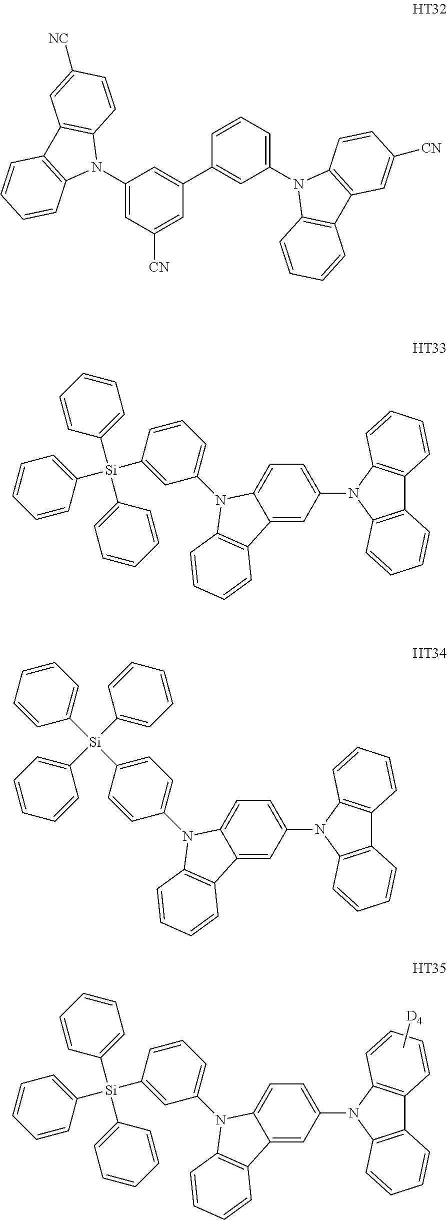

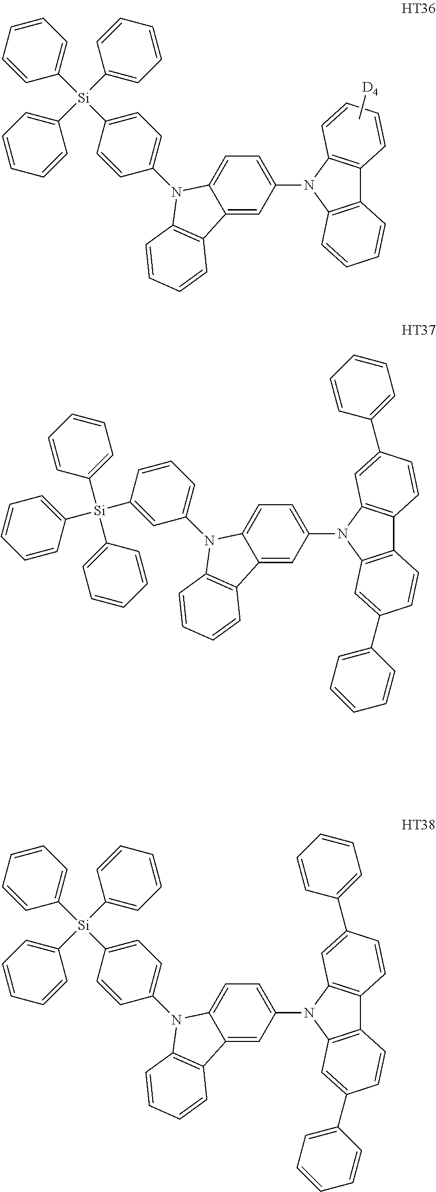

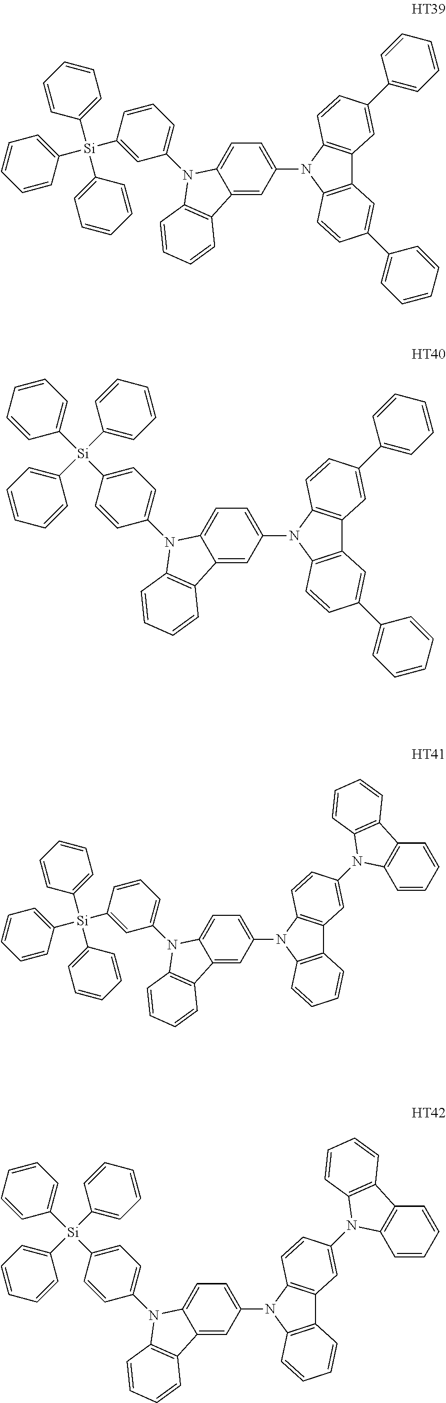 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

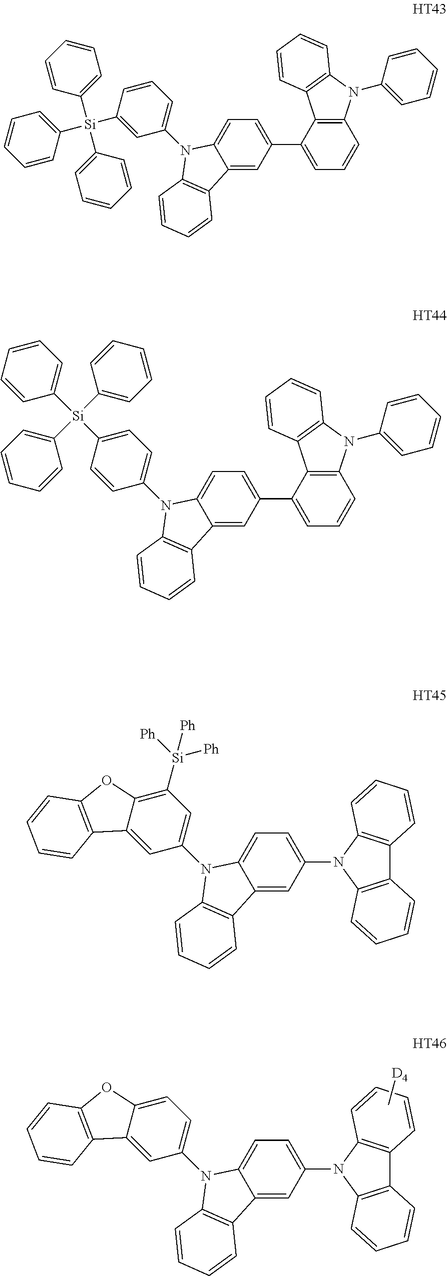

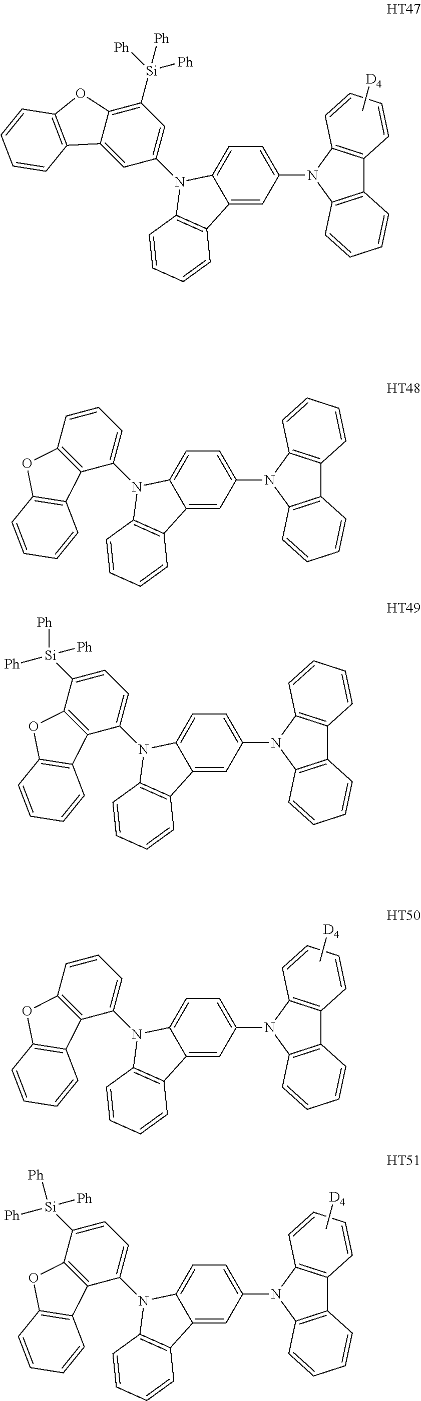

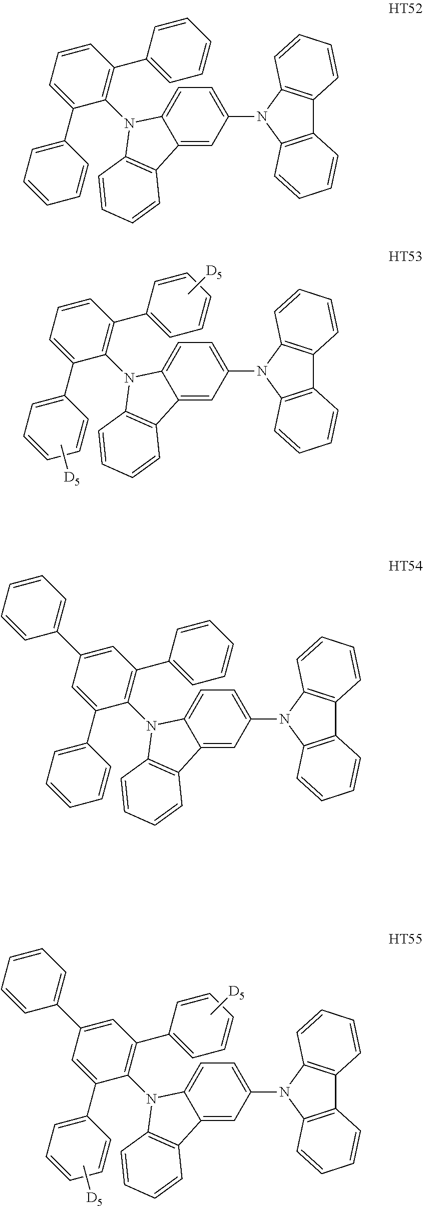

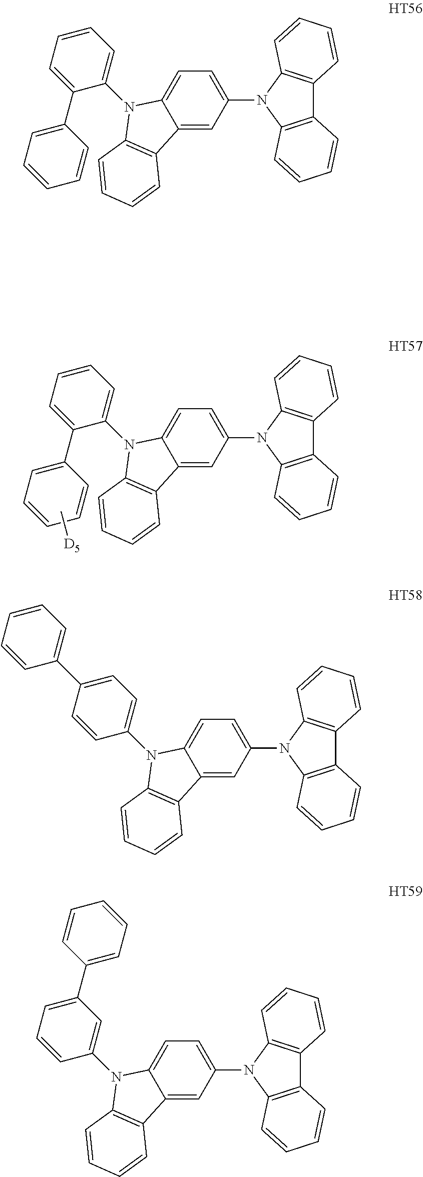

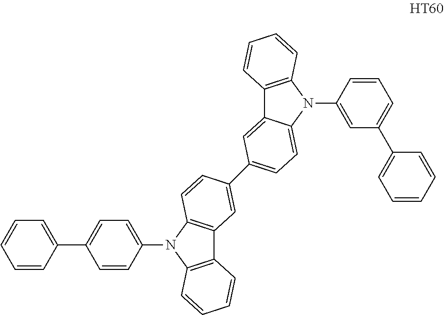 [SMILES: c1ccc(-c2ccc(-n3c4ccccc4c4cc(-c5ccc6c(c5)c5ccccc5n6-c5cccc(-c6ccccc6)c5)ccc43)cc2)cc1]

In the example compounds presented in Compound Group 2, “D” refers to deuterium, and “Ph” may refer to a substituted or unsubstituted phenyl group. For example, in the example compounds presented in Compound Group 2, “Ph” may be an unsubstituted phenyl group.

In one or more embodiments, the emission layer EML may include a third compound represented by Formula ET-1. For example, the third compound may be used as an electron transport host material in the emission layer EML.

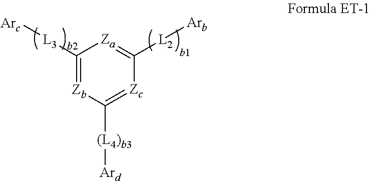

In Formula ET-1, at least one selected from among Zₐ to Z_{c} may be N, and the remainder may be CR₅₆. For example, in one or more embodiments, one selected from among Zₐ to Z_{c} may be N, and the remainder two may each independently be CR₅₆. In those embodiments, the third compound represented by Formula ET-1 may include a pyridine moiety. In one or more embodiments, two selected from among Zₐ to Z_{c} may be N, and the remainder may be CR₅₆. In those embodiments, the third compound represented by Formula ET-1 may include a pyrimidine moiety. In one or more embodiments, Zₐ to Z_{c} may be all N. In those embodiments, the third compound represented by Formula ET-1 may include a triazine moiety.

In Formula ET-1, R₅₆ may be hydrogen, deuterium, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar_{b} to Ar_{d} may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in one or more embodiments, Ar_{b} to Ar_{d} may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if each of b1 to b3 is an integer of 2 or more, L₂'s to L₄'s may each independently be a substituted or unsubstituted arylene group of 6 to 30 ring-forming carbon atoms or a substituted or unsubstituted heteroarylene group of 2 to 30 ring-forming carbon atoms.

In one or more embodiments, the third compound may be any one selected from among compounds in Compound Group 3. The light emitting element ED of one or more embodiments may include at least one selected from among the compounds in Compound Group 3.

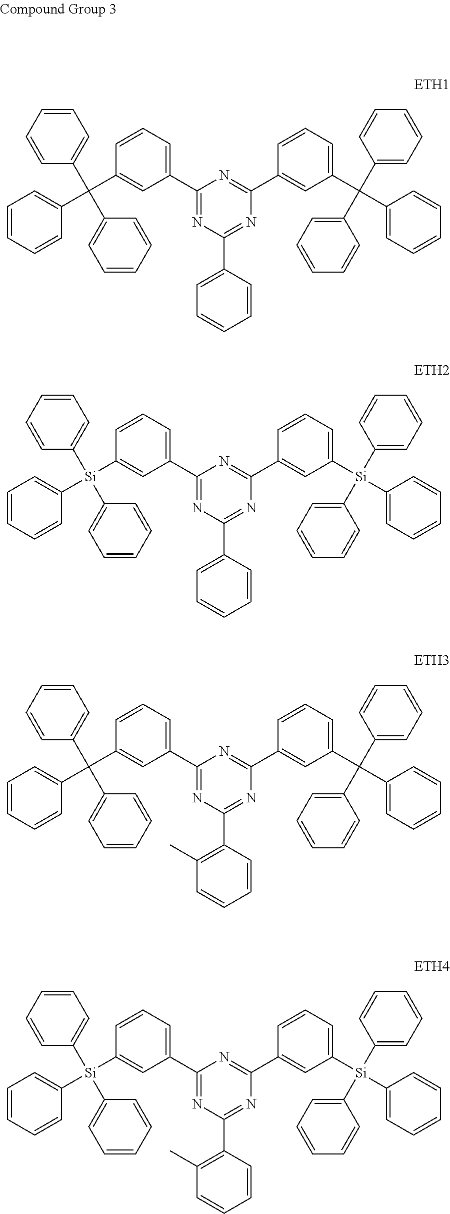 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

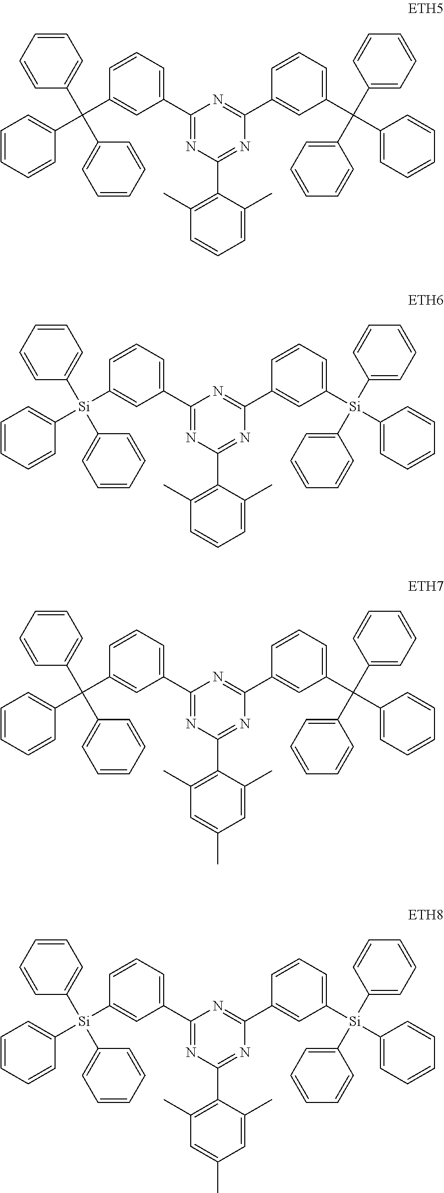 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

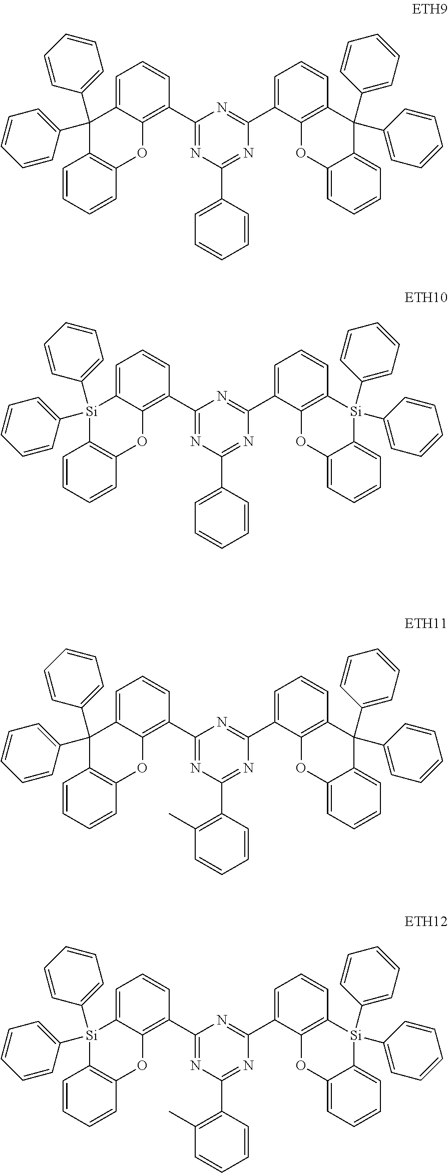 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

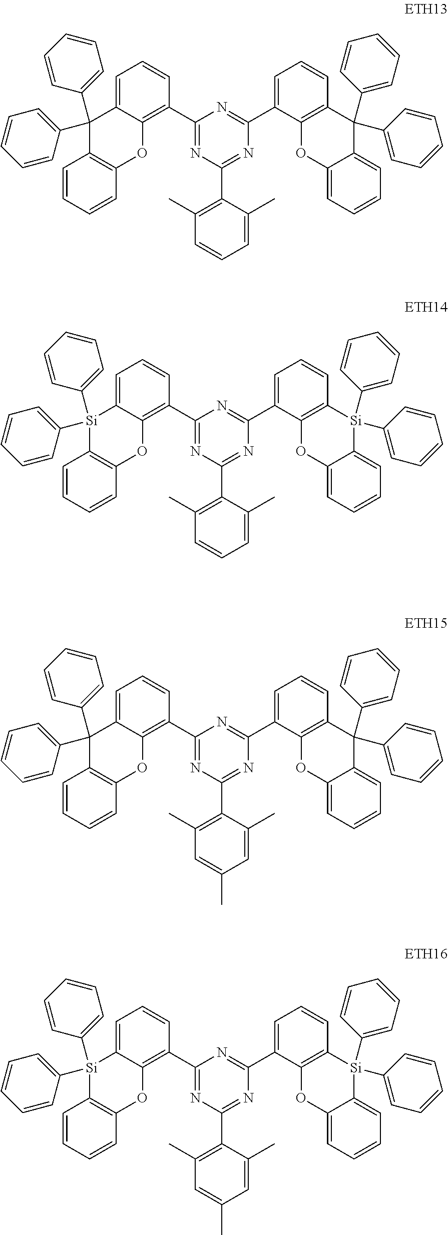 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

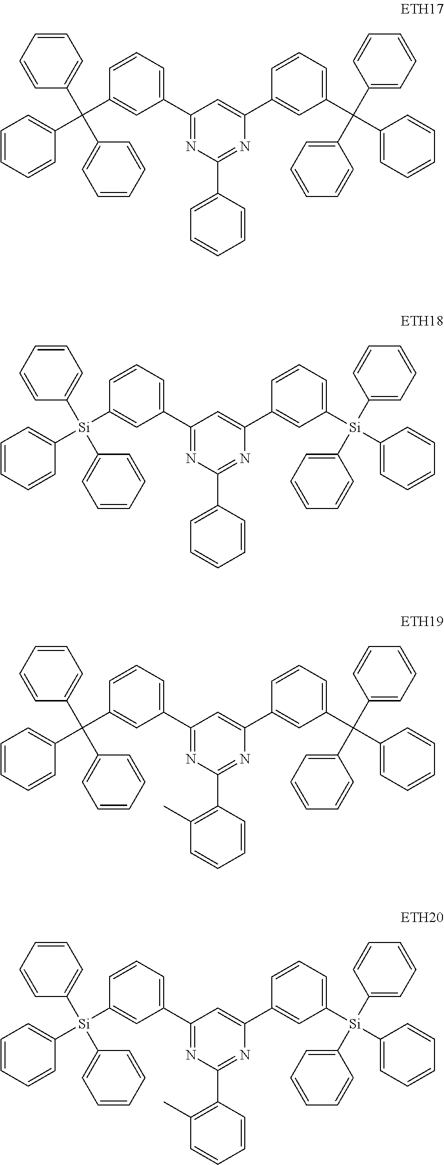 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

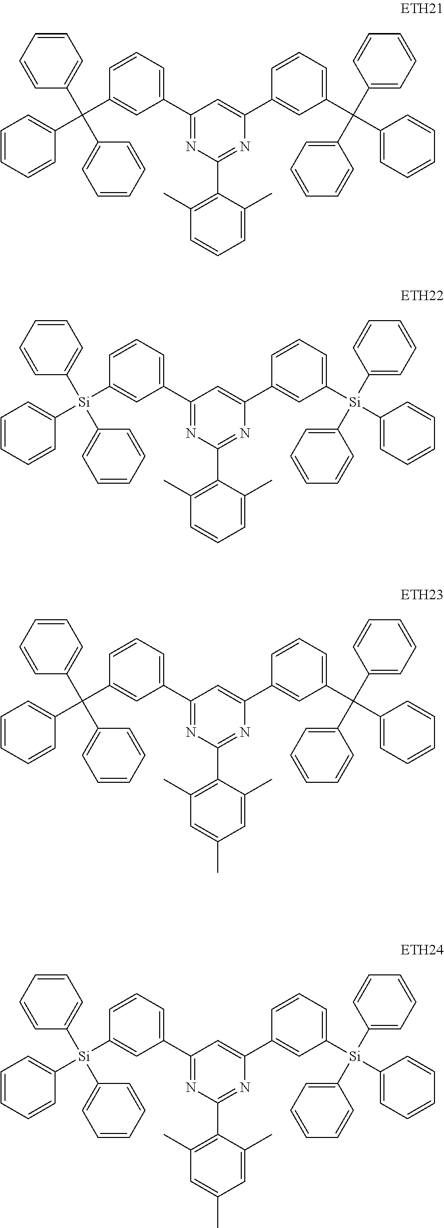 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

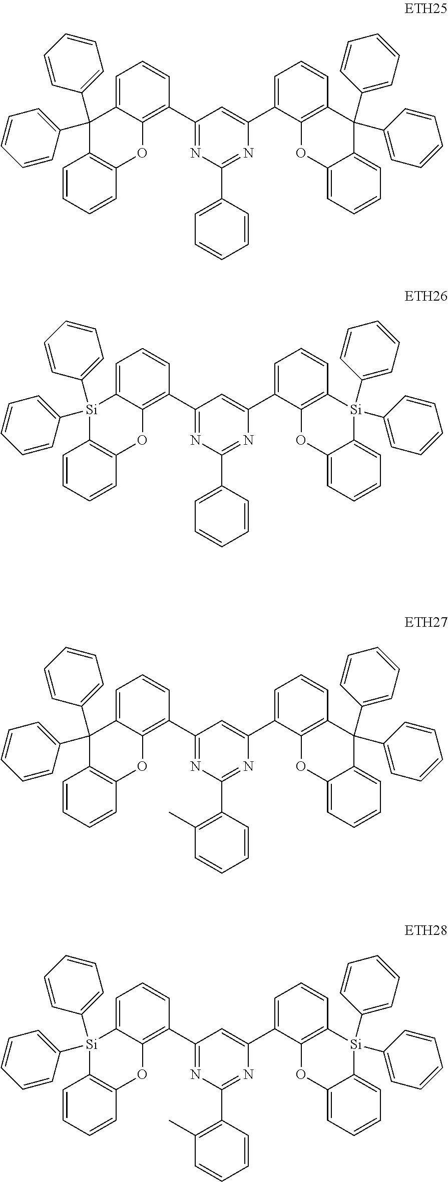 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

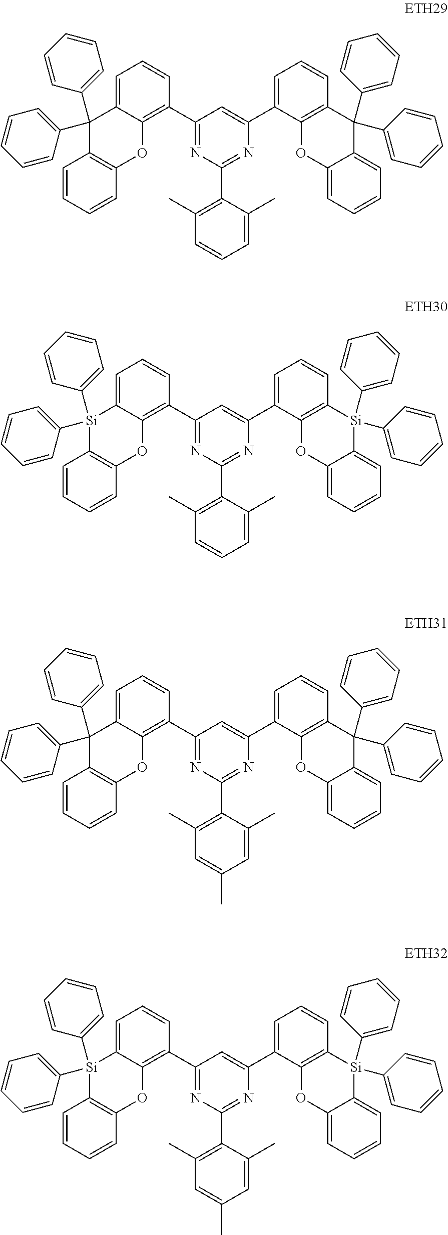 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

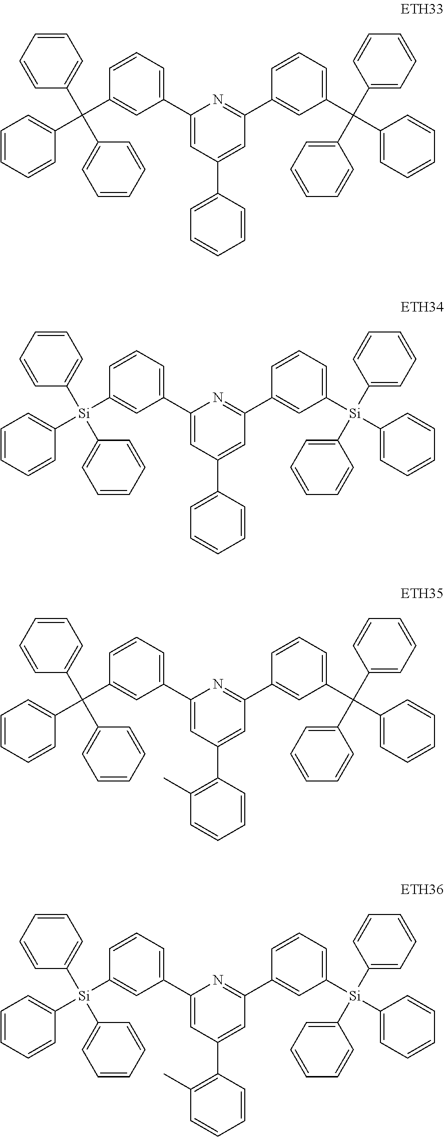 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

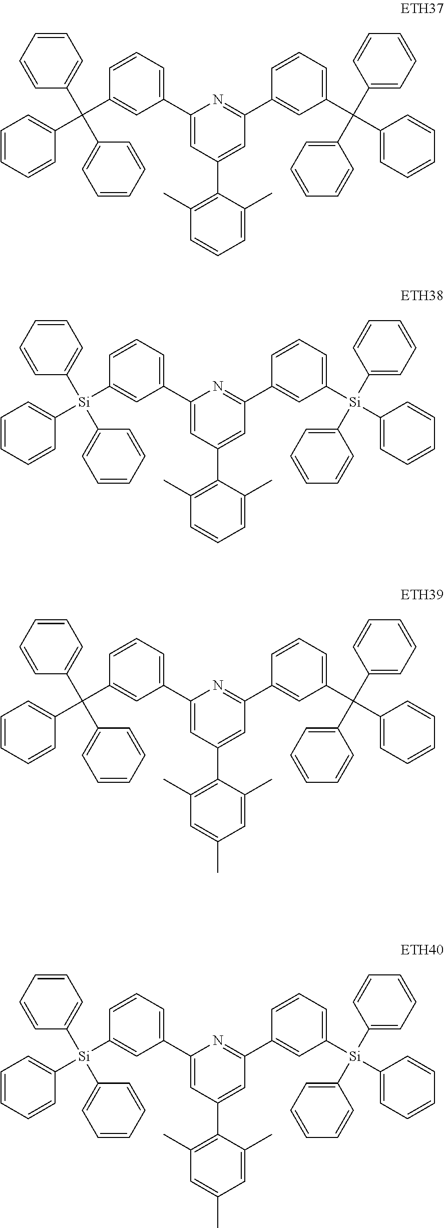 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

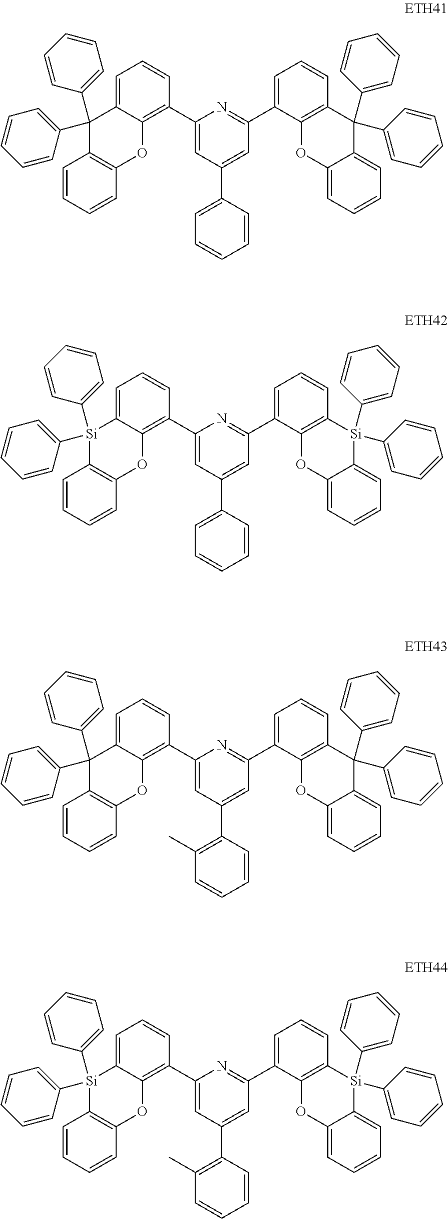 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

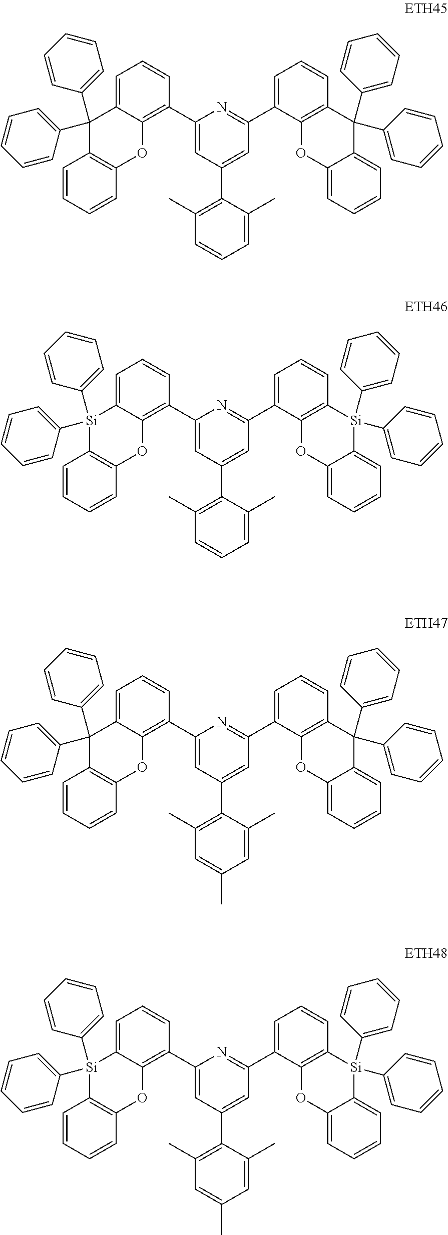 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

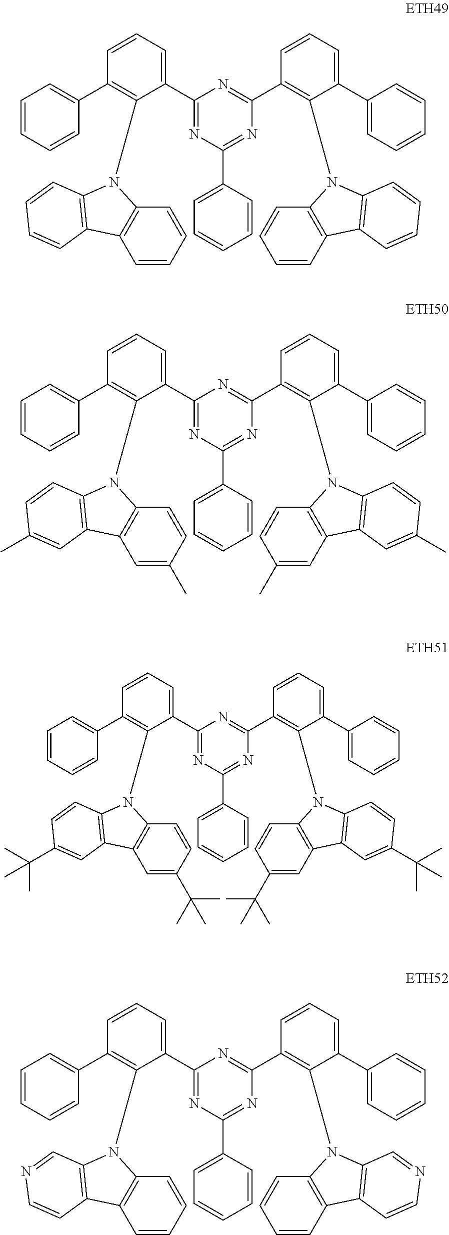

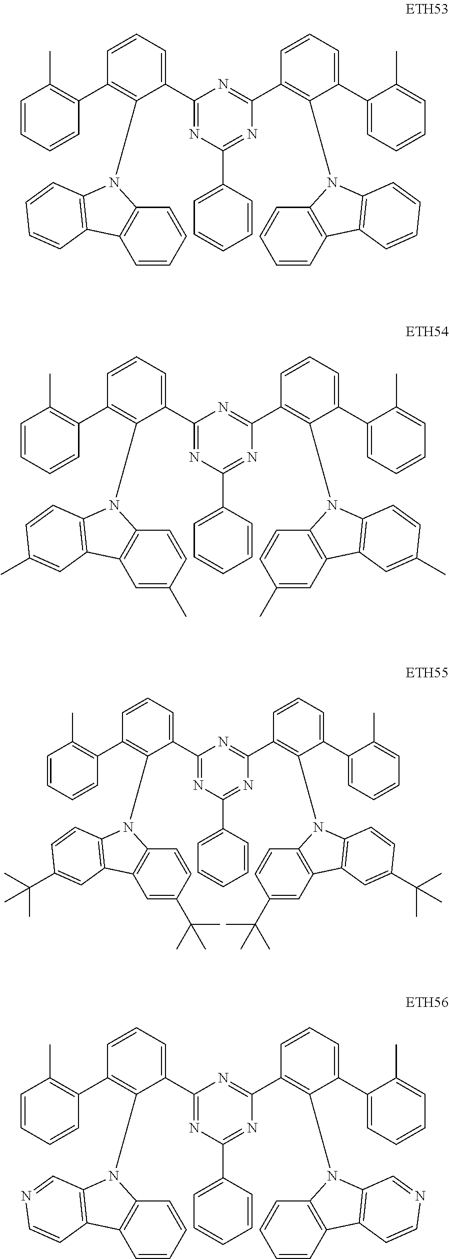

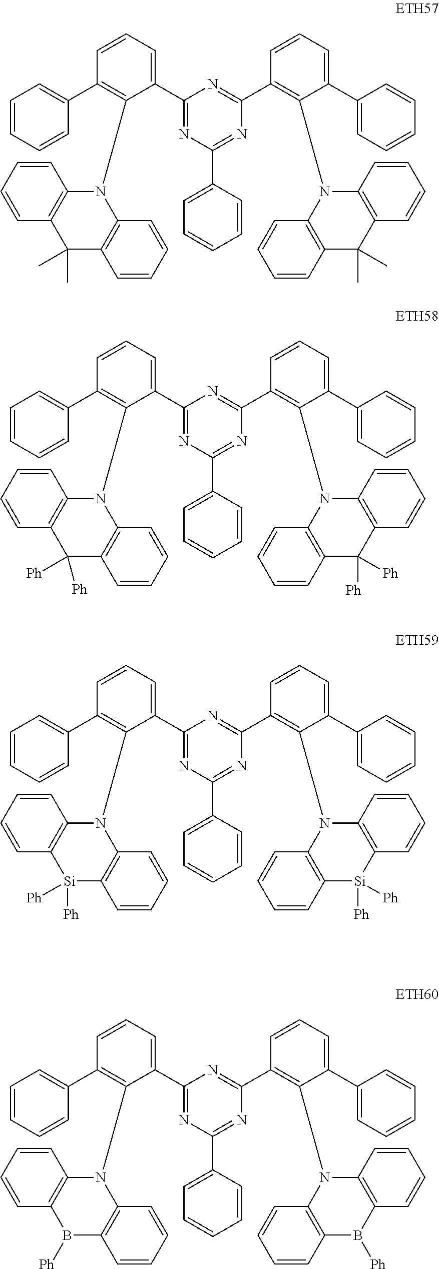

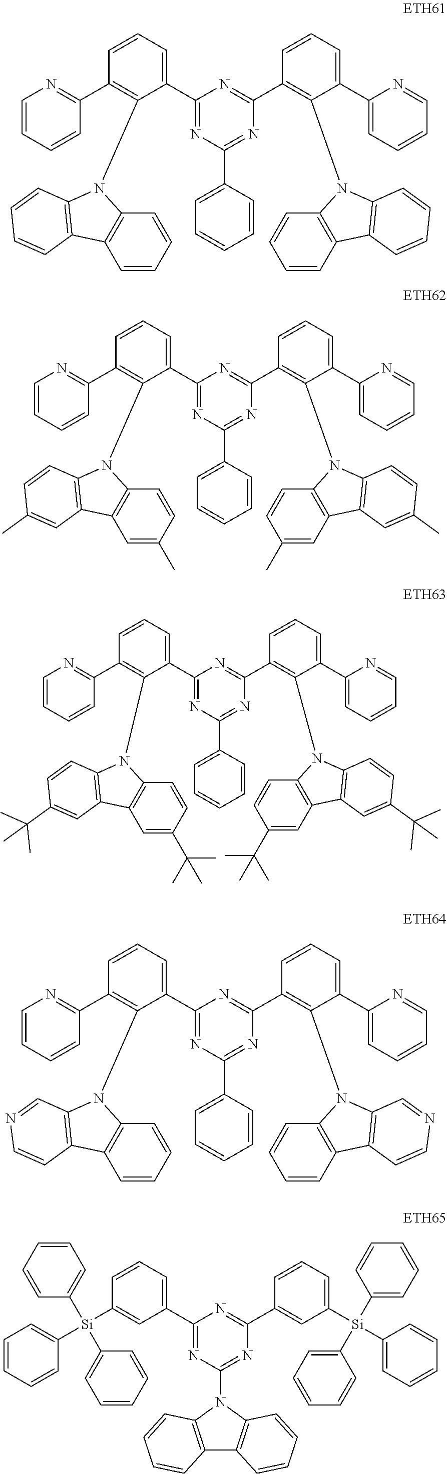

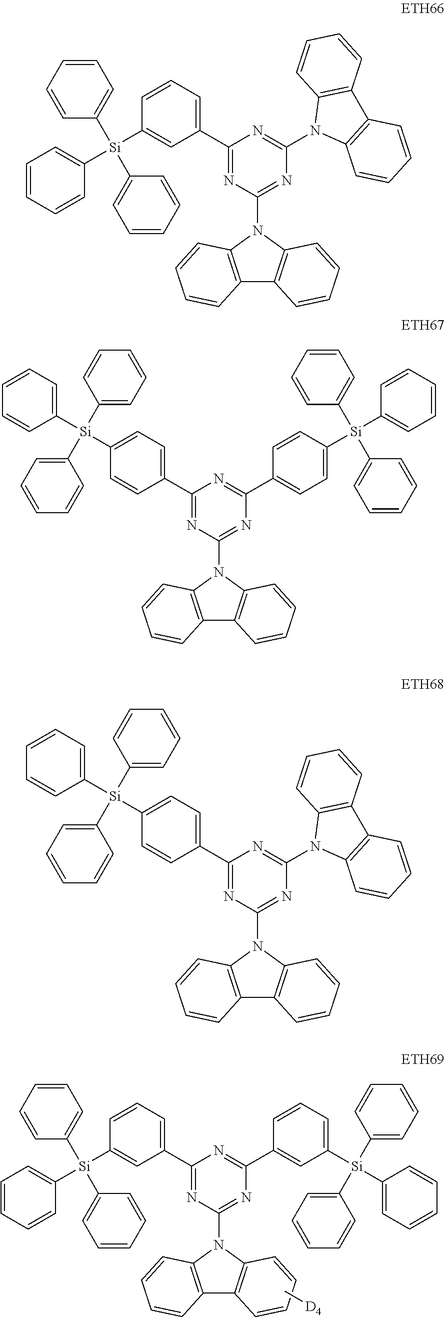

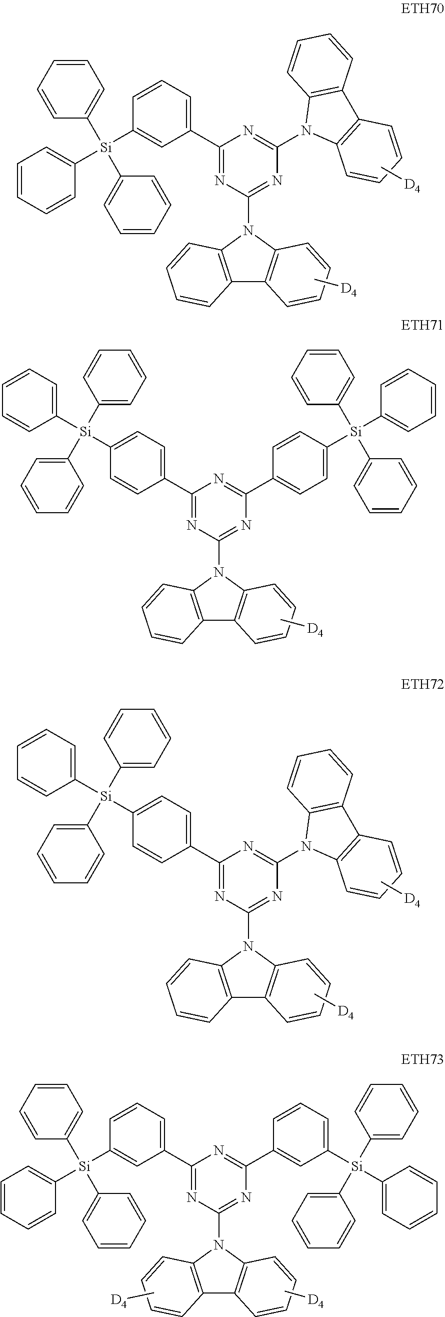

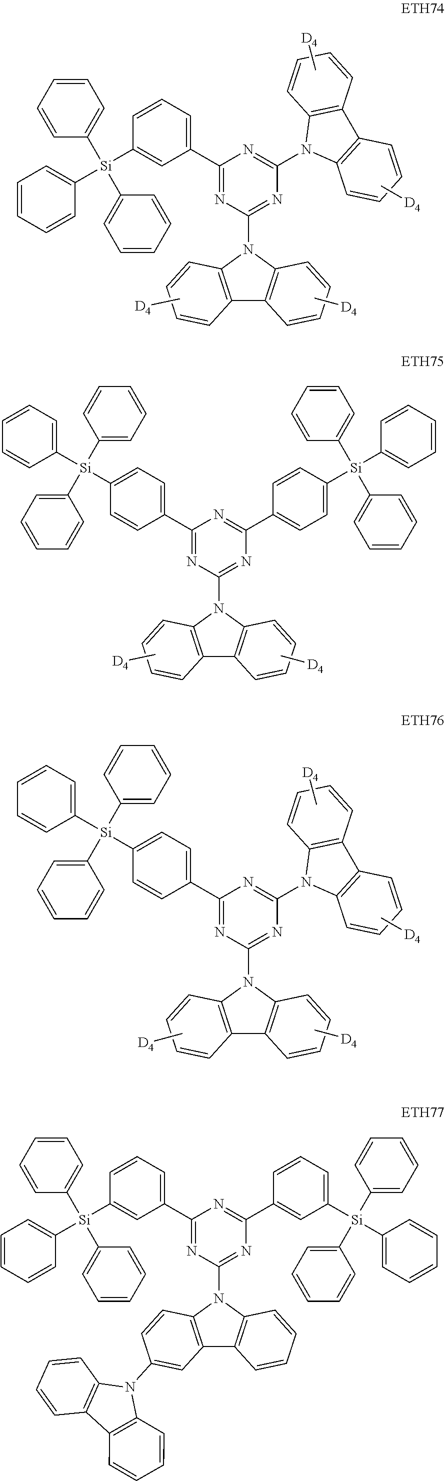

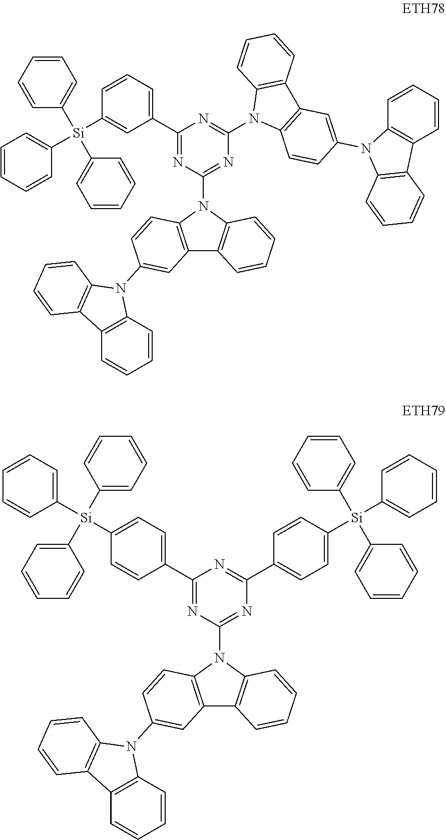 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

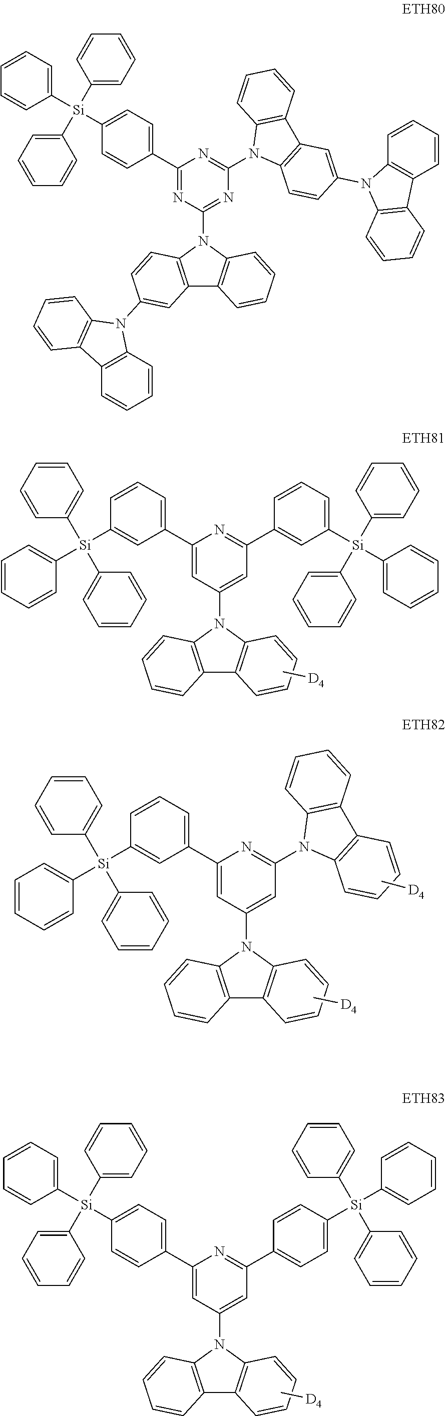

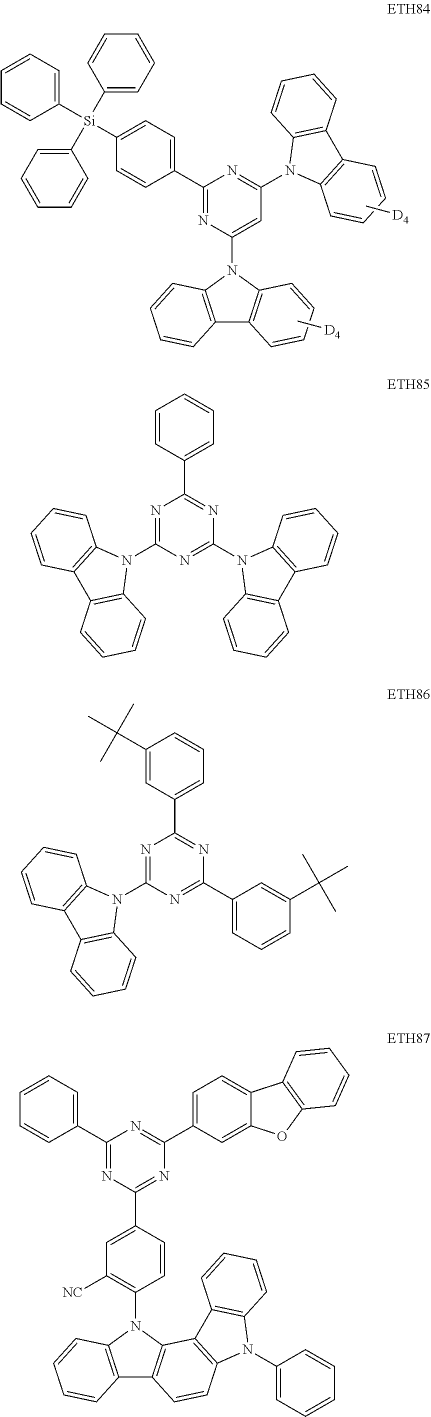

In the example compounds presented in Compound Group 3, “D” refers to deuterium, and “Ph” refers to an unsubstituted phenyl group.

In one or more embodiments, the emission layer EML may include the second compound and the third compound, and the second compound and the third compound may form an exciplex. In the emission layer EML, the exciplex may be formed by the hole transport host and the electron transport host. In these embodiments, a triplet energy of the exciplex formed by the hole transport host and the electron transport host may correspond to a difference between a lowest unoccupied molecular orbital (LUMO) energy level of the electron transport host and a highest occupied molecular orbital (HOMO) energy level of the hole transport host.

For example, in one or more embodiments, an absolute value of the triplet energy level (T1) of the exciplex formed by the hole transport host and the electron transport host may be about 2.4 eV to about 3.0 eV. In addition, the triplet energy of the exciplex may be a smaller value than the energy gap of each host material. The exciplex may have a triplet energy of about 3.0 eV or less, that is an energy gap between the hole transport host and the electron transport host.

In one or more embodiments, the emission layer EML may include a fourth compound in addition to the first compound to the third compound. The fourth compound may be used as a phosphorescence sensitizer of the emission layer EML. Because energy may transfer from the fourth compound to the first compound, light emission may arise.

For example, in one or more embodiments, the emission layer EML may include an organometallic complex including platinum (Pt) as a central metal atom and ligands bonded to the central metal atom, as the fourth compound. In the light emitting element ED of one or more embodiments, the emission layer EML may include a compound represented by Formula D-1 as the fourth compound.

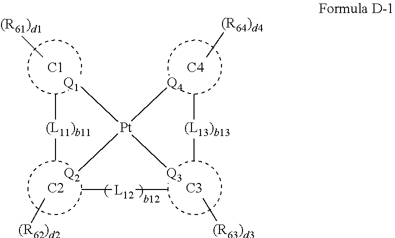

In Formula D-1, Q₁ to Q₄ may each independently be C or N.

In Formula D-1, rings C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, L₁₁ to L₁₃ may each independently be a direct linkage, *—O—*, *—S—*,

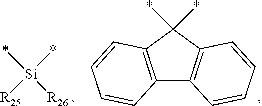

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “—*” refers to a part connected with C1 to C4.

In Formula D-1, b11 to b13 may each independently be 0 or 1. If (e.g., when) b11 is 0, C1 and C2 may be unconnected. If (e.g., when) b12 is 0, C2 and C3 may be unconnected. If (e.g., when) b3 is 0, C3 and C4 may be unconnected.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In one or more embodiments, one or more selected from among R₆₁ to R₆₆ may each be independently combined with an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) d1 to d4 are each 0, the fourth compound may be unsubstituted with R₆₁ to R₆₄, respectively. An embodiment in which d1 to d4 are each 4, and R₆₁'s to R₆₄'s are each hydrogen, may be the same as an embodiment in which d1 to d4 are each 0. If (e.g., when) d1 to d4 are each an integer of 2 or more, each of multiple R₆₁'s to R₆₄'s may be all the same, or at least one selected from among multiple R₆₁'s to R₆₄'s may be different.

In Formula D-1, C₁ to C₄ may each independently be a substituted or unsubstituted hydrocarbon ring or a substituted or unsubstituted heterocycle, represented by any one selected from among C-1 to C-4.

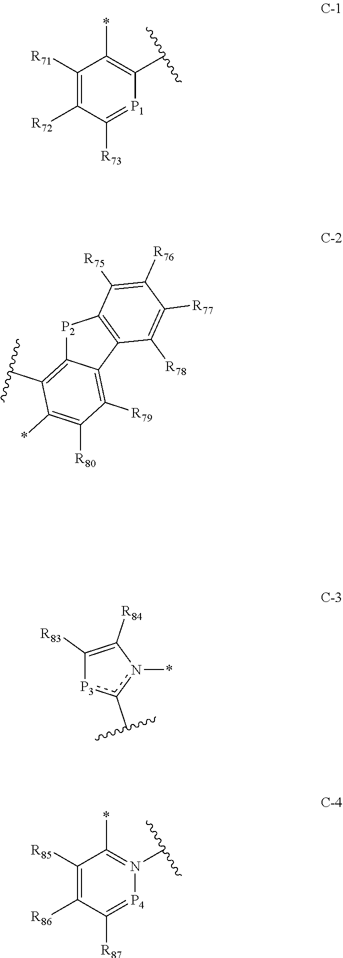

In C-1 to C-4, P₁ may be c—* or CR₇₄, P₂ may be N—* or NR₈₁, P₃ may be N—* or NR₈₂, and P₄ may be c—* or CR₈. R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In addition, in C-1 to C-4,

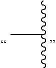

is a part connected with a central metal atom of Pt, and “—*” corresponds to a part connected with an adjacent ring group (C1 to C4) or a linker (L₁₁ to L₁₃).

The emission layer EML of one or more embodiments may include the first compound that is a fused polycyclic compound of the present disclosure, and at least one selected from among the second to fourth compounds. For example, in one or more embodiments, the emission layer EML may include the first compound, the second compound, and the third compound. In the emission layer EML, the second compound and the third compound may form exciplex, and via the exciplex, energy transfer to the first compound may arise, and light emission may arise.

In one or more embodiments, the emission layer EML may include the first compound, the second compound, the third compound, and the fourth compound. In the emission layer EML, the second compound and the third compound may form exciplex, and via the exciplex, energy transfer to the fourth compound and the first compound may arise, and light emission may arise. In one or more embodiments, the fourth compound may be a sensitizer. In the light emitting element ED of one or more embodiments, the fourth compound included in the emission layer EML may act as a sensitizer and may play the role of transferring energy from a host to the first compound that is a light-emitting dopant. For example, in one or more embodiments, the fourth compound that plays the role of an auxiliary dopant may accelerate energy transfer to the first compound that is a light emitting dopant and increase the light emitting ratio of the first compound. Accordingly, the emission efficiency of the emission layer EML of one or more embodiments may be improved. In addition, if (e.g., when) the energy transfer to the first compound increases, excitons formed in the emission layer EML may not be accumulated but rapidly emit light, and the deterioration of the light emitting element may be reduced. Accordingly, the lifetime of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may include at least one selected from among compounds represented in Compound Group 4. The emission layer EML may include at least one selected from among the compounds represented in Compound Group 4 as a sensitizer material.

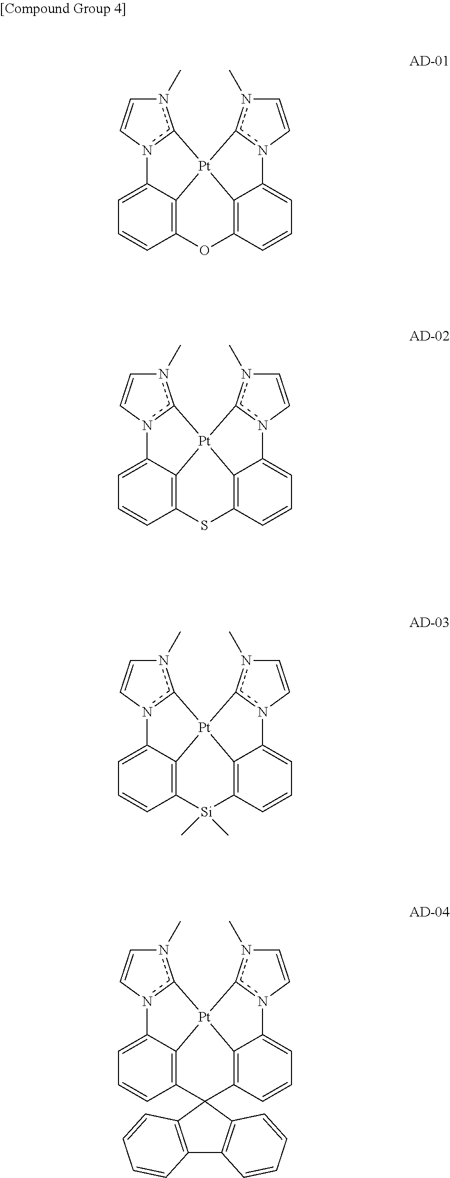

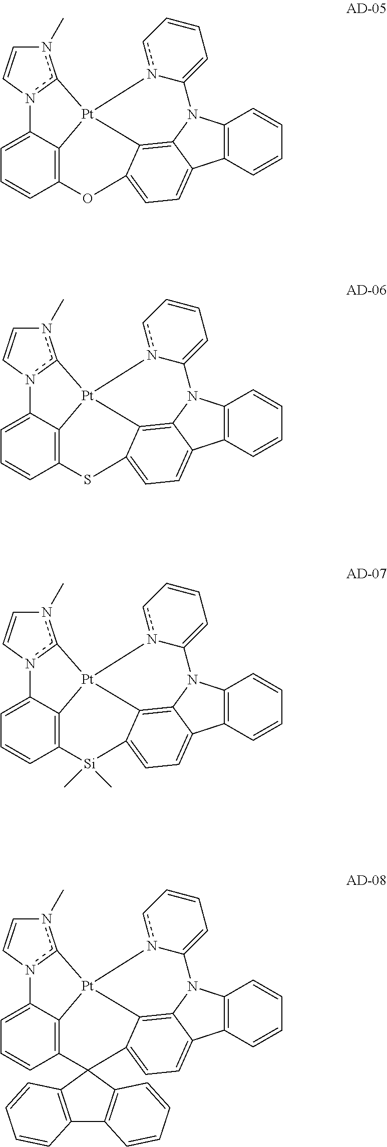

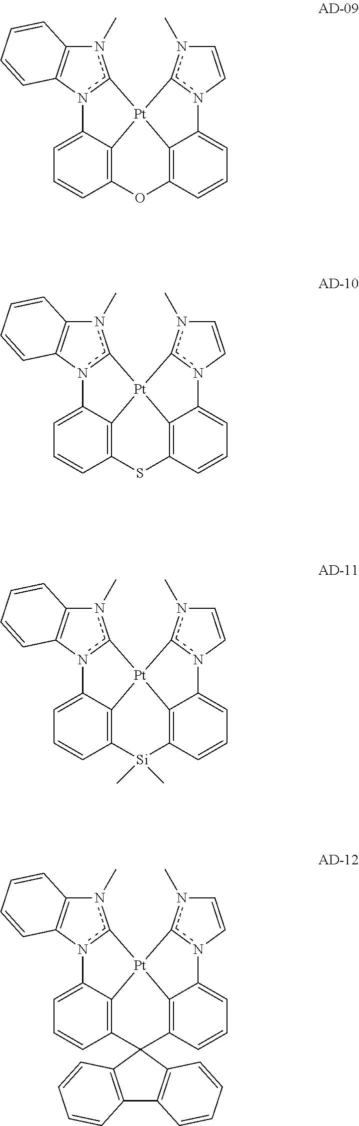

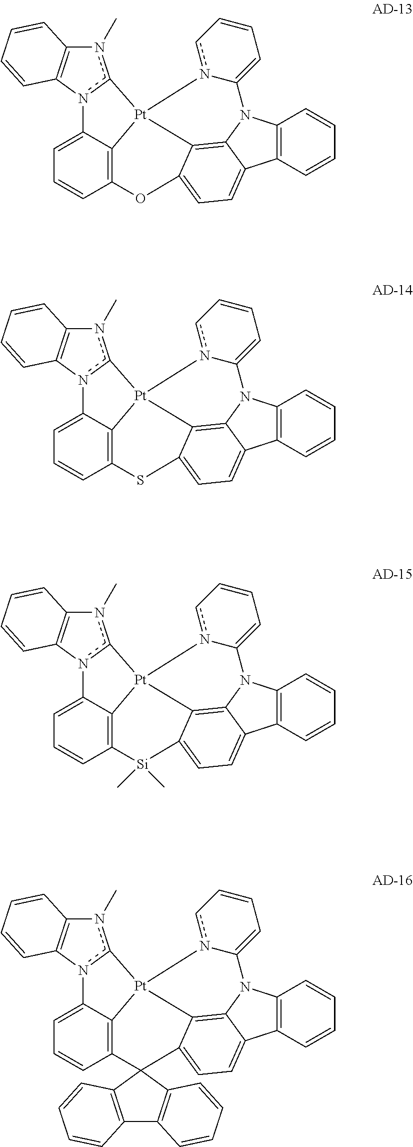

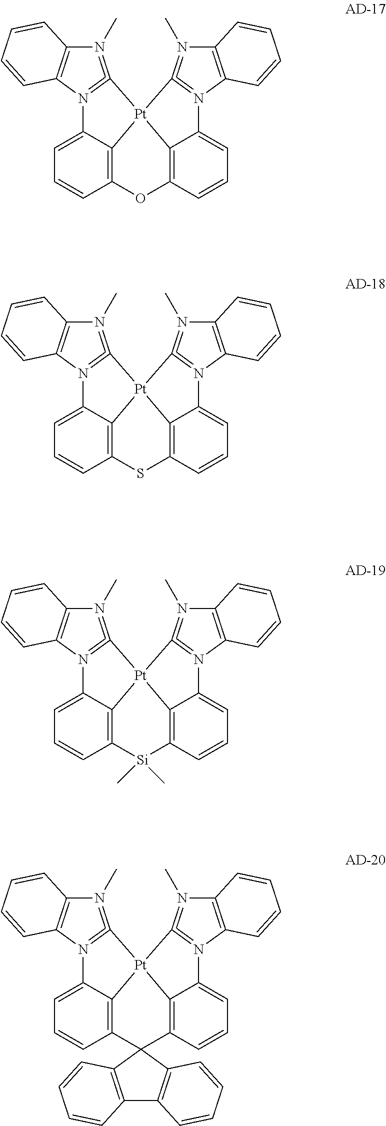

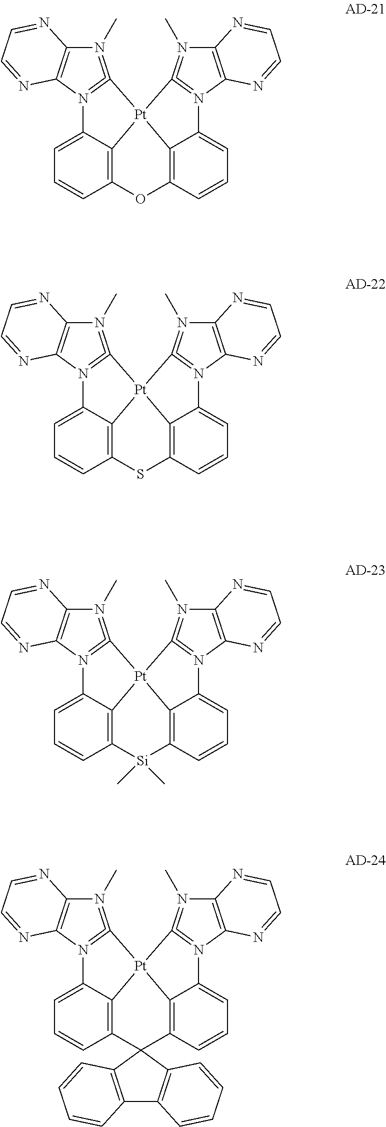

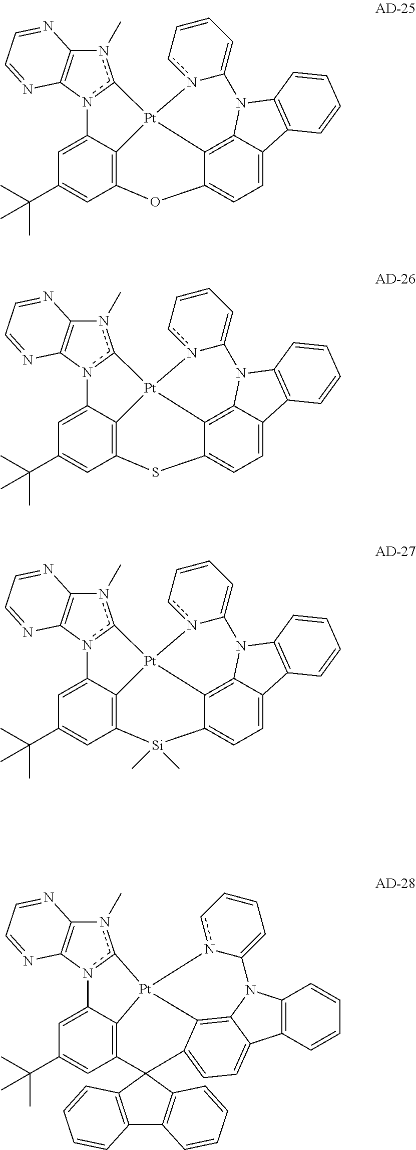

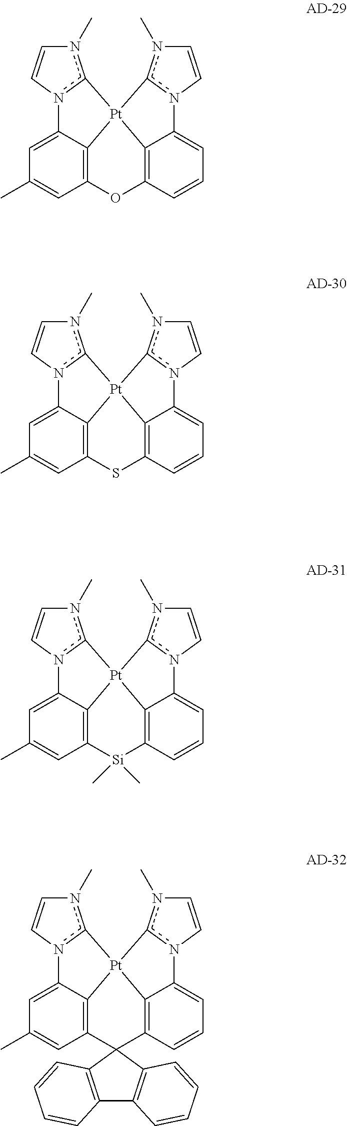

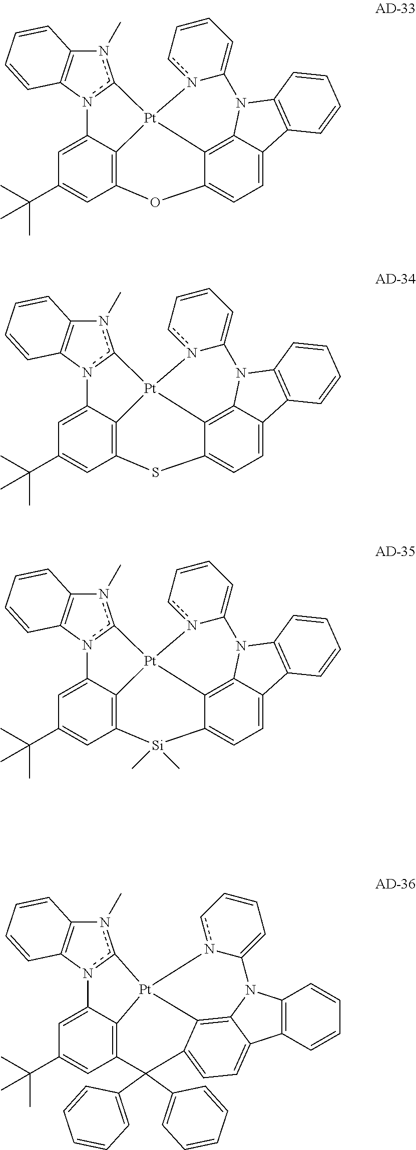

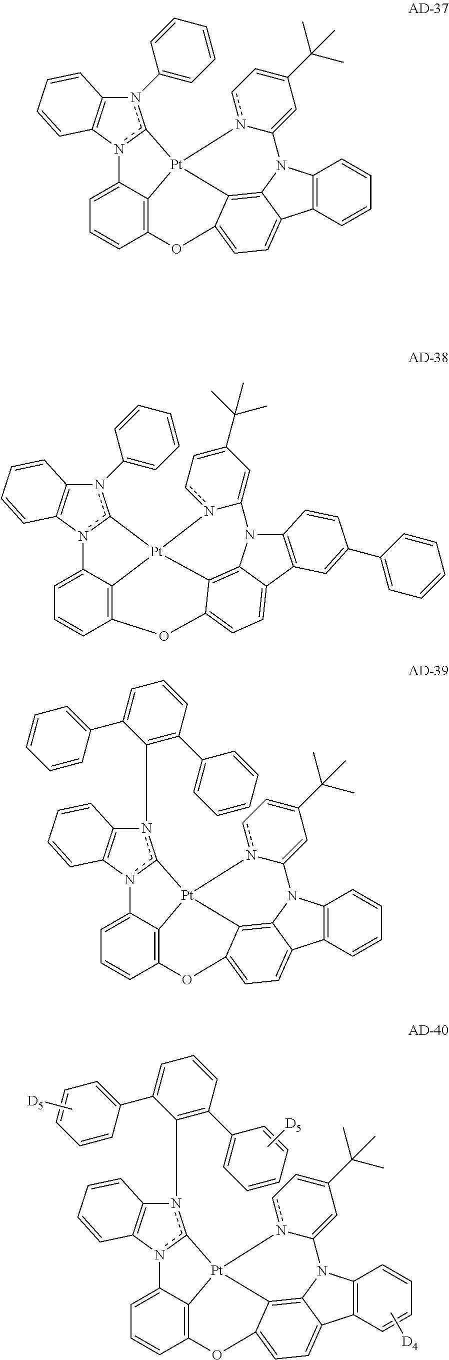

In the example compounds presented in Compound Group 4, “D” refers to deuterium.

In one or more embodiments, the light emitting element ED of one or more embodiments may include multiple emission layers. Multiple emission layers may be stacked in order and provided, and for example, a light emitting element ED including multiple emission layers may be to emit white light (e.g., combined white light). The light emitting element including multiple emission layers may be a light emitting element of a tandem structure. If (e.g., when) the light emitting element ED includes multiple emission layers, at least one emission layer EML may include the first compound represented by Formula 1 of one or more embodiments. In one or more embodiments, if (e.g., when) the light emitting element ED includes multiple emission layers, at least one emission layer EML may include all of the first compound, the second compound, the third compound, and the fourth compound.

In the light emitting element ED of one or more embodiments, if (e.g., when) the emission layer EML includes all of the first compound, the second compound, the third compound, and the fourth compound, an amount of the first compound may be about 0.1 wt % to about 5 wt % based on a total weight of 100 wt % of the first compound, the second compound, the third compound, and the fourth compound. However, embodiments of the present disclosure are not limited thereto. If (e.g., when) the amount of the first compound satisfies the above-described ratio, energy transfer from the second compound and the third compound to the first compound may increase, and accordingly, the emission efficiency and element lifetime may increase.

In the emission layer EML, a total amount of the second compound and the third compound may be the remaining amount excluding an amount of the first compound and the fourth compound. For example, the total amount of the second compound and the third compound may be about 65 wt % to about 95 wt % based on the total weight of 100 wt % of the first compound, the second compound, the third compound, and the fourth compound.

In the total amount of the second compound and the third compound, a weight ratio of the second compound to the third compound may be about 3:7 to about 7:3.

If (e.g., when) the total amount of the second compound and the third compound satisfies the above-described ratio, charge balance properties in the emission layer EML may be improved, and emission efficiency and element lifetime may be improved. If the total amount of the second compound and the third compound deviates from the above-described ratio range, charge balance in the emission layer EML may be broken, emission efficiency may be degraded, and the element may be easily deteriorated.

In one or more embodiments, if (e.g., when) the emission layer EML includes the fourth compound, an amount of the fourth compound may be about 4 wt % to 30 wt % based on the total weight of 100 wt % of the first compound, the second compound, the third compound, and the fourth compound in the emission layer EML. However, embodiments of the present disclosure are not limited thereto. If (e.g., when) the amount of the fourth compound satisfies the above-described amount, energy transfer from a host to the first compound that is a light emitting dopant may increase, and emission ratio may be improved. Accordingly, the emission efficiency of the emission layer EML may be improved. If (e.g., when) the amount ratio of the first compound, the second compound, the third compound, and the fourth compound, included in the emission layer EML satisfies the above-described amount ratio, excellent or suitable emission efficiency and long lifetime of the light emitting element may be achieved.

In the light emitting element ED of one or more embodiments, the emission layer EML may further include one or more selected from among anthracene derivatives, pyrene derivatives, fluoranthene derivatives, chrysene derivatives, dihydrobenzanthracene derivatives, and triphenylene derivatives. For example, in some embodiments, the emission layer EML may include one or more anthracene derivatives or one or more pyrene derivatives.

In the light emitting element ED of embodiments, shown in FIG. 3 to FIG. 6, the emission layer EML may further include one or more suitable hosts and dopants in addition to the above-described host and dopant. For example, in some embodiments, the emission layer EML may include a compound represented by Formula E-1. The compound represented by Formula E-1 may be used as a fluorescence host material.

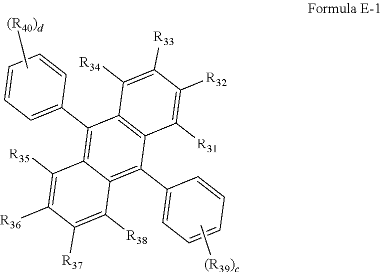

In Formula E-1, R₃₁ to R₄₀ may each independently be hydrogen, deuterium, a halogen, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In one or more embodiments, one or more selected from among R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

The compound represented by Formula E-1 may be any one selected from among Compound E1 to Compound E19.

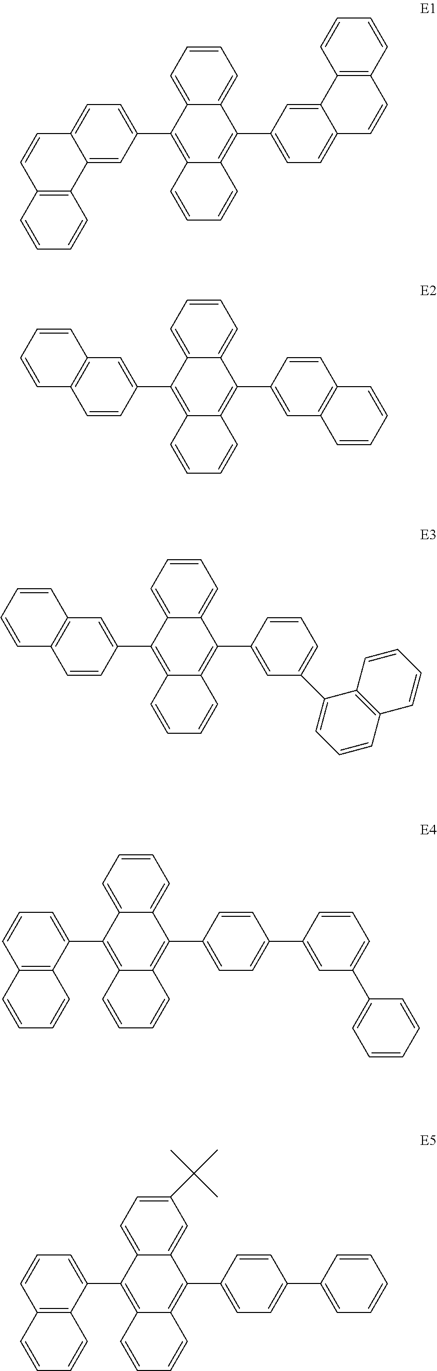

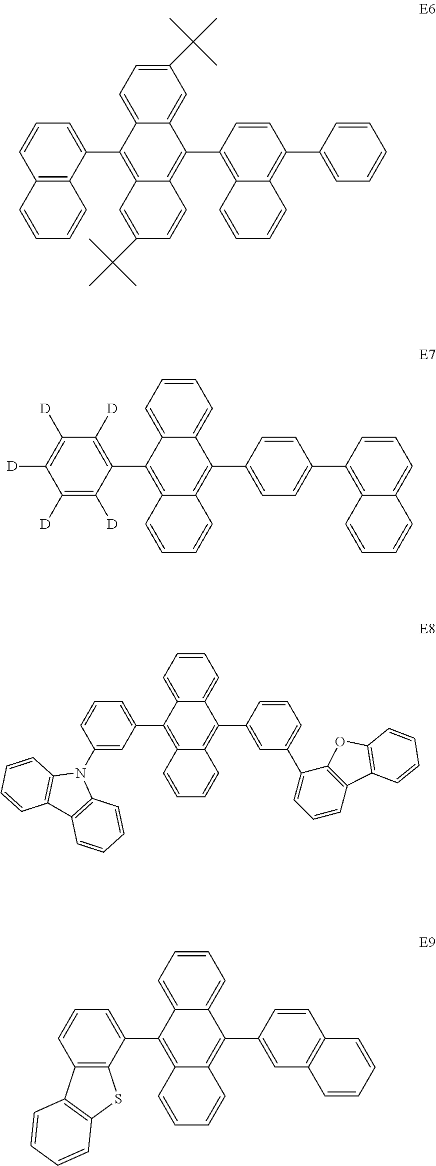

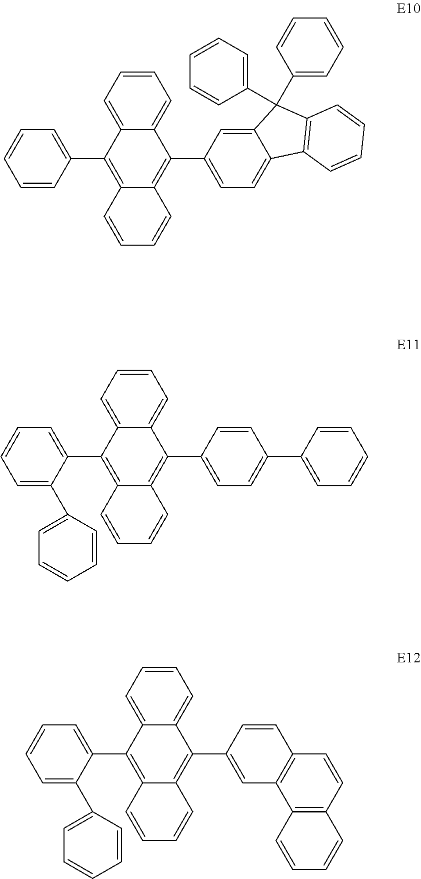

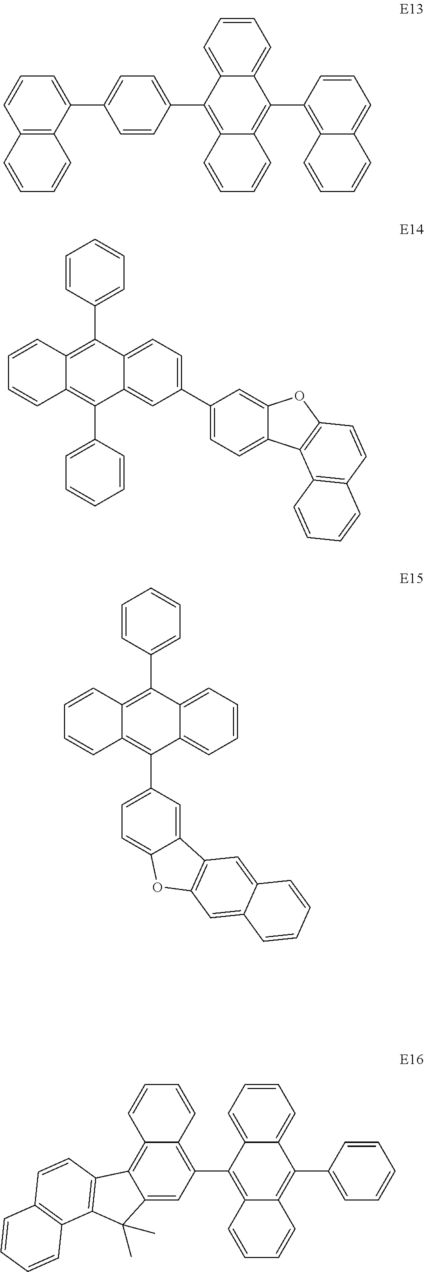

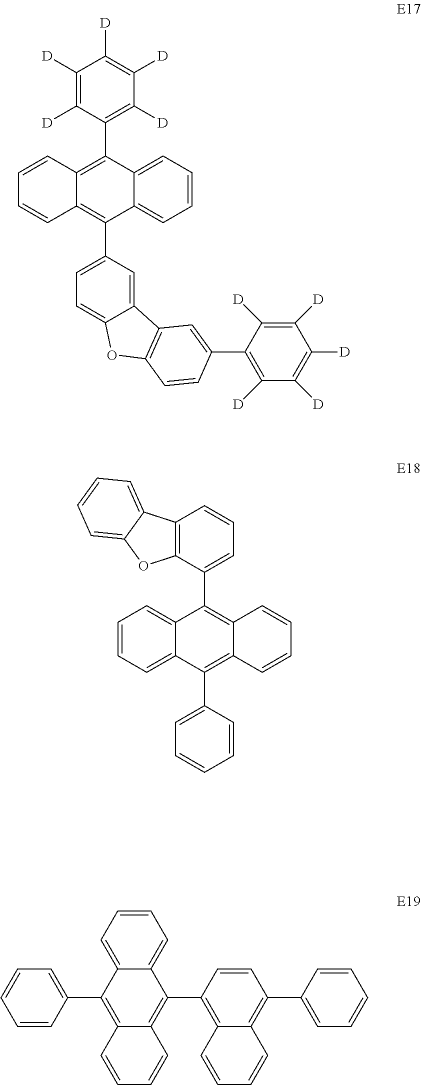

In one or more embodiments, the emission layer EML may include a compound represented by Formula E-2a or Formula E-2b. The compound represented by Formula E-2a or Formula E-2b may be used as a phosphorescence host material.

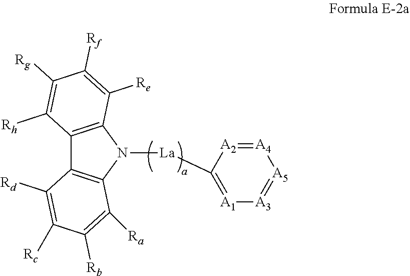

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if (e.g., when) “a” is an integer of 2 or more, multiple La's may each independently be a substituted or unsubstituted arylene group of 6 to 30 ring-forming carbon atoms or a substituted or unsubstituted heteroarylene group of 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In one or more embodiments, one or more selected from among Rₐ to Rᵢ may be combined with an adjacent group to form a hydrocarbon ring or a heterocycle including N, O, S, and/or the like, as a ring-forming atom.

In one or more embodiments, in Formula E-2a, two or three selected from among A₁ to A₅ may be N, and the remainder may be CRᵢ.

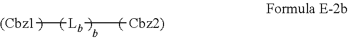

In Formula E-2b, Cbz1 and Cbz2 may each independently be an unsubstituted carbazole group or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” may be an integer of 0 to 10, and if (e.g., when) “b” is an integer of 2 or more, multiple L_{b}'s may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any one selected from among compounds in Compound Group E-2. However, the compounds shown in Compound Group E-2 are only examples, and the compound represented by Formula E-2a or Formula E-2b is not limited to the compounds represented in Compound Group E-2.

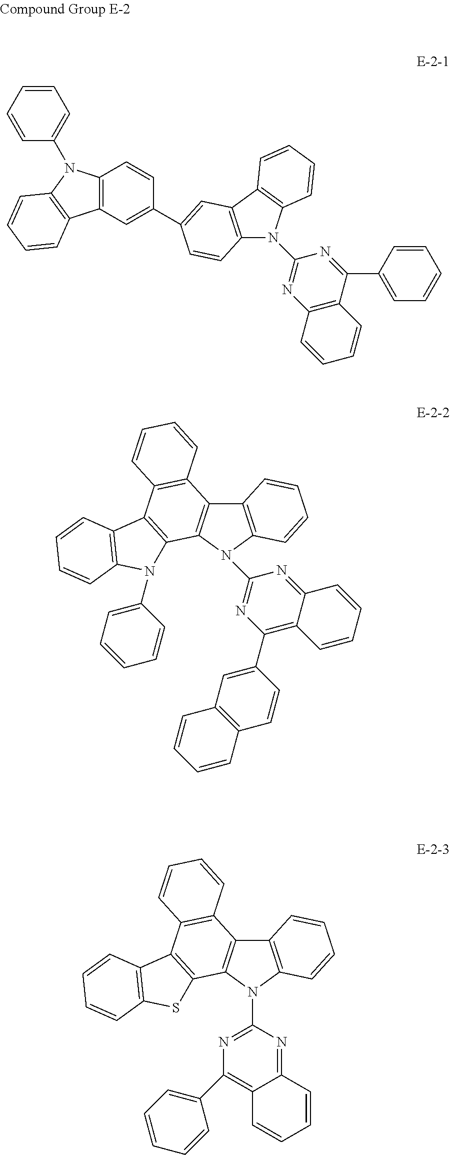 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

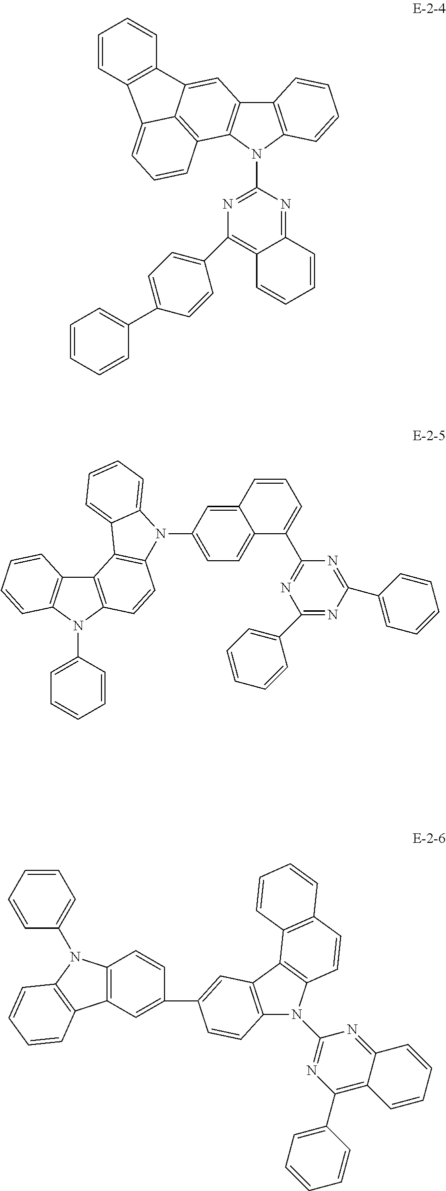 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

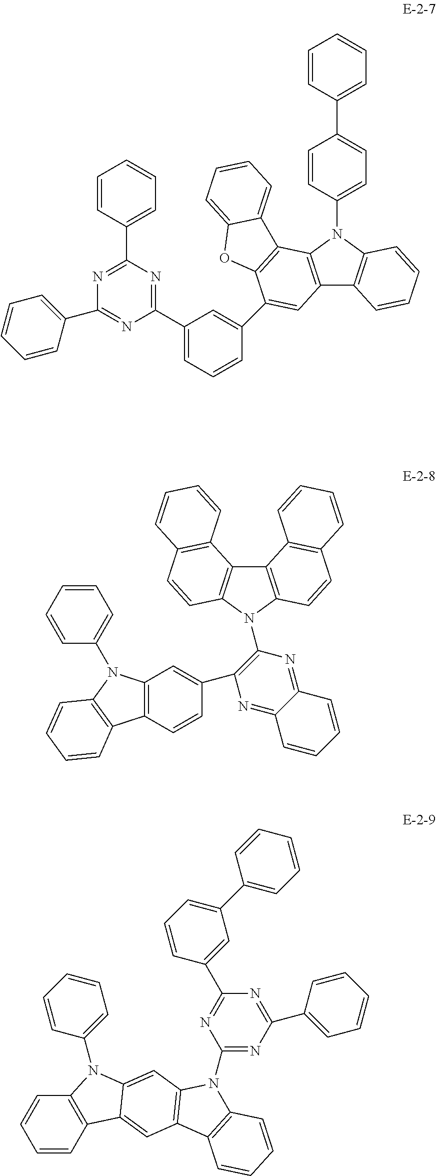 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

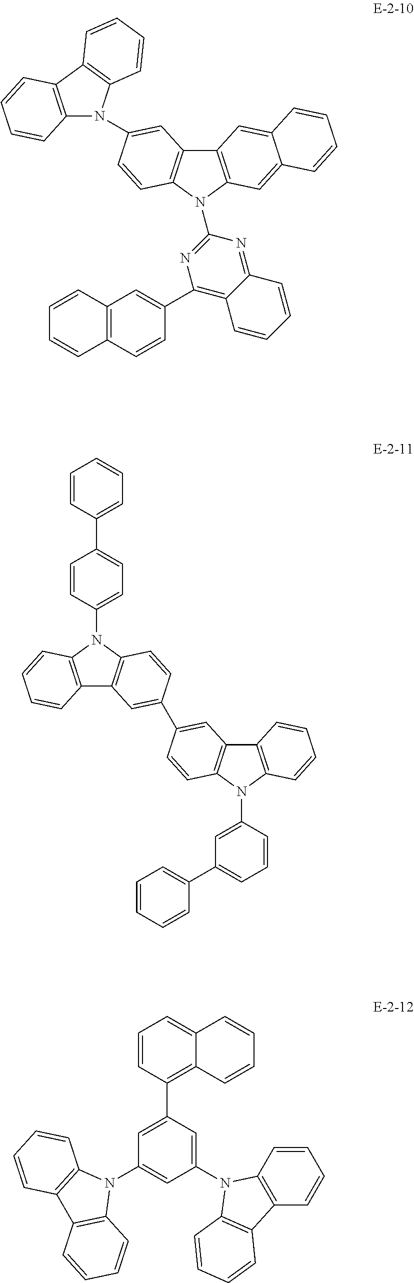 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

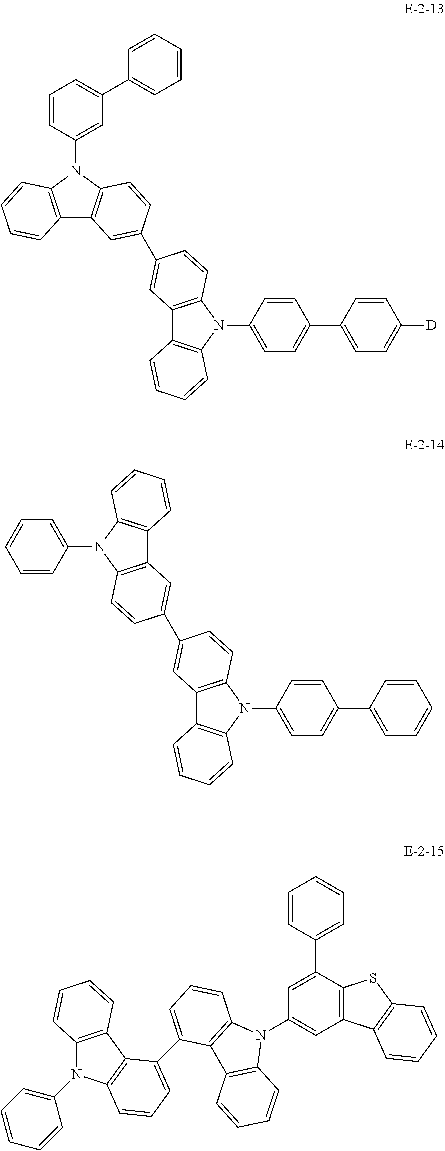 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

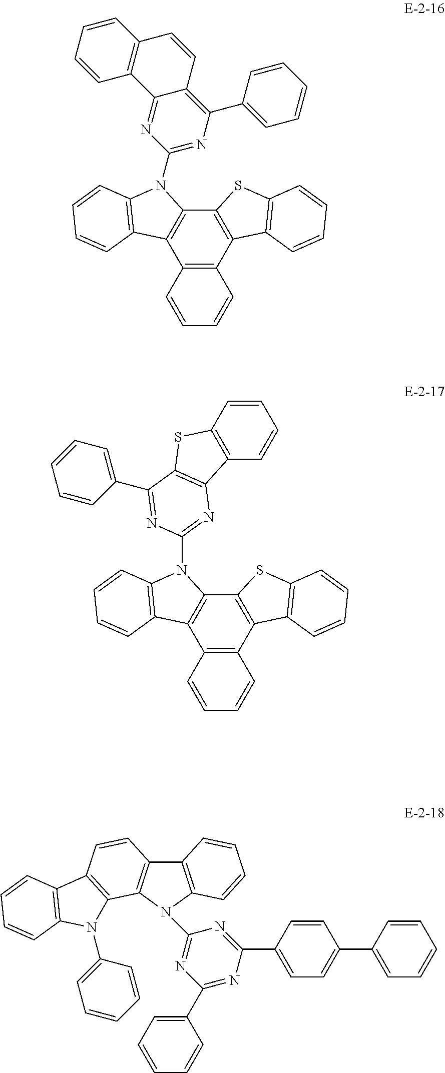 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

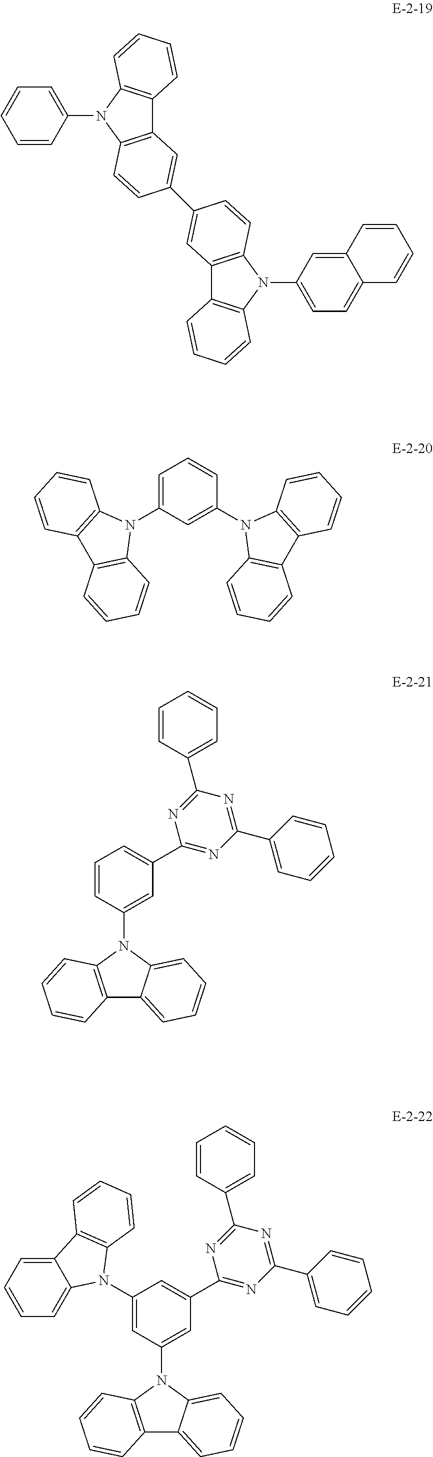 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

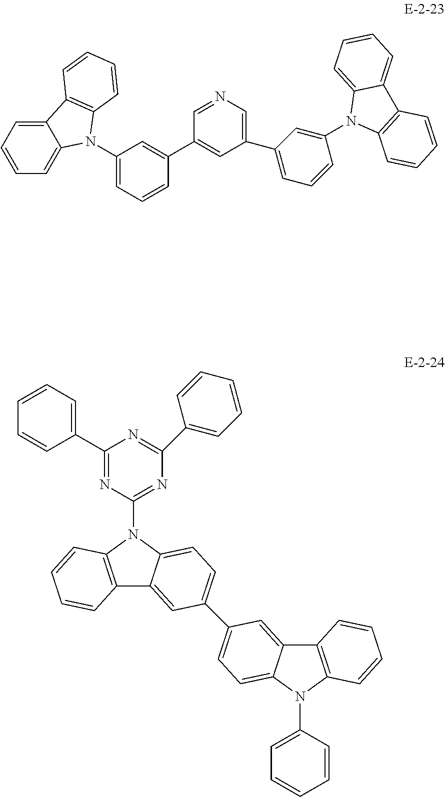 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a material well-suitable in the art as a host material. For example, the emission layer EML may include as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto. For example, tris(8-hydroxyquinolinato)aluminum (Alq₃), 9,10-di(naphthalen-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like. may be used as the host material.

In one or more embodiments, the emission layer EML may include a compound represented by Formula M-a. The compound represented by Formula M-a may be used as a phosphorescence dopant material.

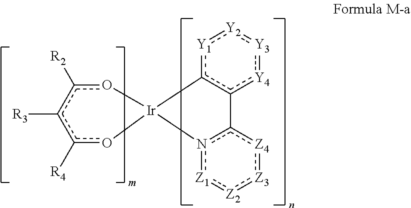

In Formula M-a, Y₁ to Y₄, and Z₁ to Z₄ may each independently be CR₁ or N, and R₁ to R₄ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, if (e.g., when) “m” is 0, “n” is 3, and if (e.g., when) “m” is 1, “n” is 2.

The compound represented by Formula M-a may be used as a phosphorescence dopant.

The compound represented by Formula M-a may be any one selected from among Compounds M-a1 to M-a25. However, Compounds M-a1 to M-a25 are mere examples, and the compound represented by Formula M-a is not limited to the compounds represented by Compounds M-a1 to M-a25.

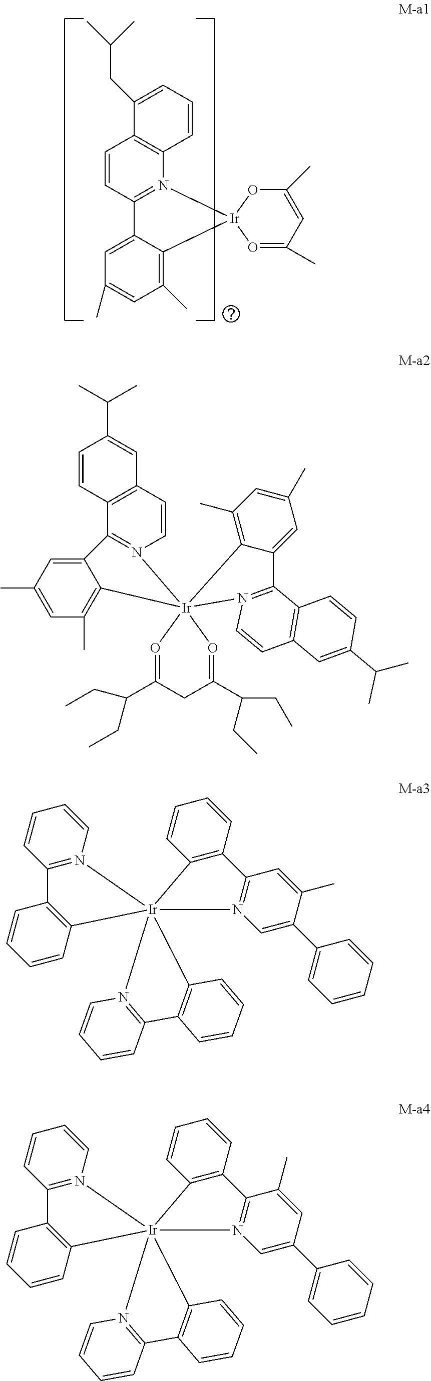

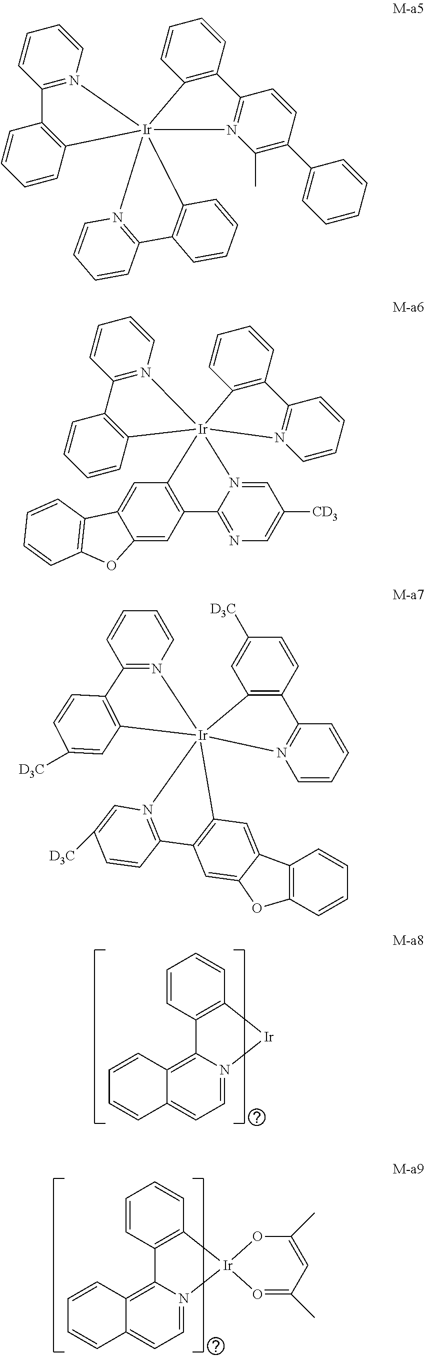

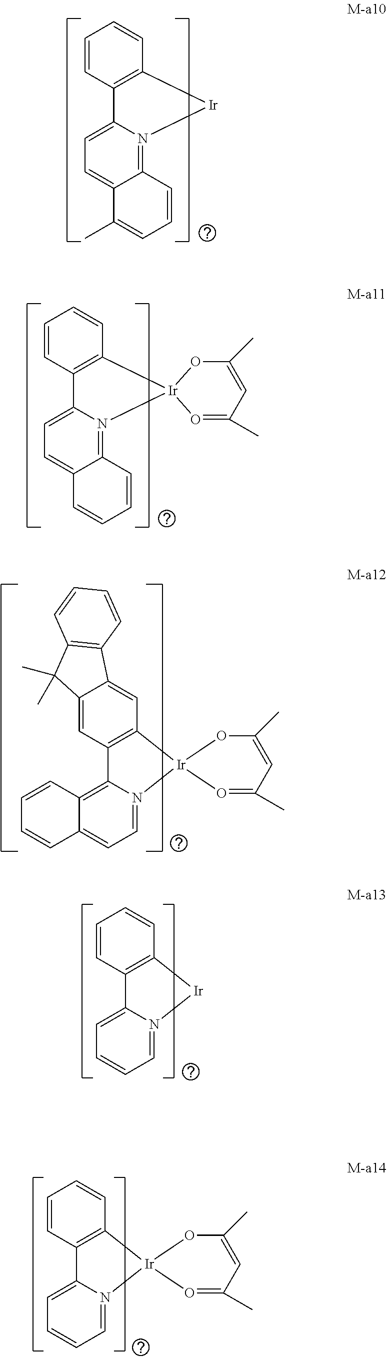

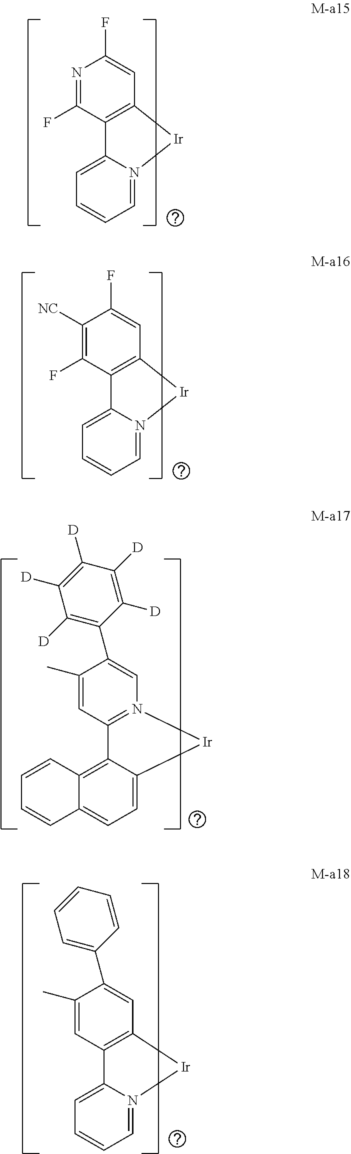

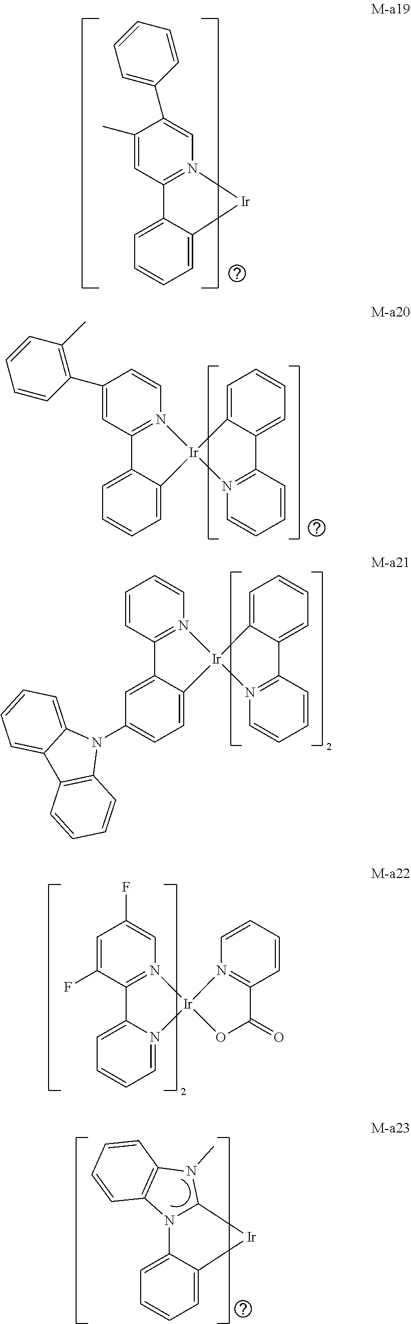

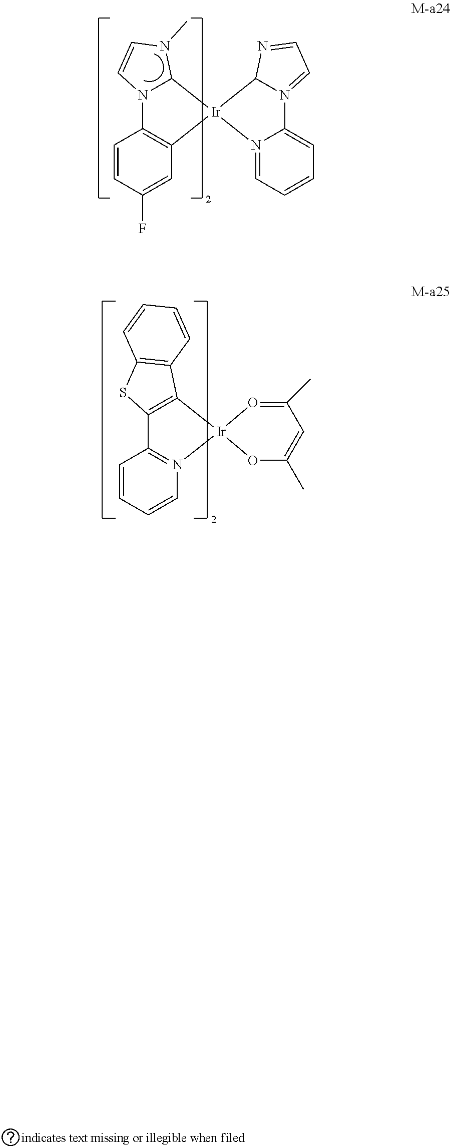

In one or more embodiments, the emission layer EML may further include a compound represented by any one selected from among Formula F-a to Formula F-c. The compounds represented by Formula F-a to Formula F-c may be used as fluorescence dopant materials.

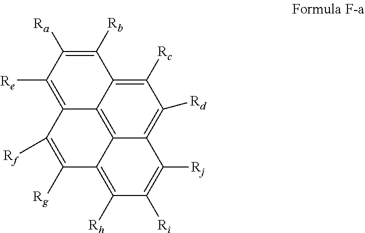

In Formula F-a, two selected from among Rₐ to Rⱼ may each independently be substituted with *—NAr₁Ar₂. The remainder not substituted with *—NAr₁Ar₂ among Rₐ to Rⱼ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, in some embodiments, at least one selected from among Ar₁ and Ar₂ may be a heteroaryl group including O or S as a ring-forming atom.

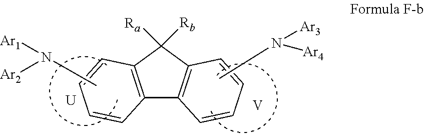

In Formula F-b, Rₐ and R_{b} may each independently be hydrogen, deuterium, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms. In one or more embodiments, at least one selected from among Ar₁ to Ar₄ may be a heteroaryl group including O or S as a ring-forming atom.

In Formula F-b, the number of rings represented by U and V may each independently be 0 or 1. For example, in Formula F-b, if (e.g., when) the number of U or V is 1, one ring forms a fused ring at the designated part by U or V, and if (e.g., when) the number of U or V is 0, a ring is not present at the designated part by U or V. for example, if (e.g., when) the number of U is 0, and the number of V is 1, or if (e.g., when) the number of U is 1, and the number of V is 0, a fused ring having the fluorene core of Formula F-b may be a ring compound with four rings. In one or more embodiments, if (e.g., when) the number of U and the number of V are each 0, the fused ring of Formula F-b may be a ring compound with three rings. In one or more embodiments, if (e.g., when) the number of U and the number of V are each 1, a fused ring having the fluorene core of Formula F-b may be a ring compound with five rings.

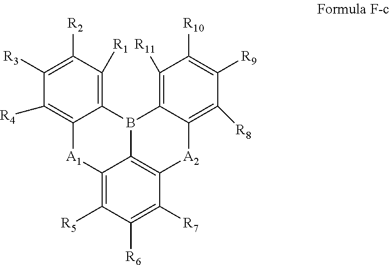

In Formula F-c, A₁ and A₂ may each independently be O, S, Se, or NRₘ, and Rₘ may be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In one or more embodiments, in Formula F-c, A₁ and A₂ may each independently be combined with substituents of an adjacent ring to form a fused ring. For example, if (e.g., when) A₁ and A₂ may each independently be NRₘ, A₁ may be combined with R₄ or R₅ to form a ring. In addition, A₂ may be combined with R₇ or R₈ to form a ring.

In one or more embodiments, the emission layer EML may include as a suitable dopant material, one or more selected from among styryl derivatives (for example, 1,4-bis[2-(3-N-ethylcarbazolyl) vinyl]benzene (BCzVB), 4-(di-p-tolylamino)-4′-[(di-p-tolylamino) styryl]stilbene (DPAVB), N-(4-((E)-2-(6-((E)-4-(diphenylamino) styryl) naphthalen-2-yl) vinyl)phenyl)-N-phenylbenzenamine (N-BDAVBi), and 4,4′-bis[2-(4-(N,N-diphenylamino)phenyl) vinyl]biphenyl(DPAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino) pyrene), and/or the like.

In one or more embodiments, the emission layer EML may include a suitable phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb), or thulium (Tm). For example, iridium (III) bis(4,6-difluorophenylpyridinato-N, C2′) picolinate (Flrpic), bis(2,4-difluorophenylpyridinato)-tetrakis(1-pyrazolyl) borate iridium (III) (Fir6), or platinum octaethyl porphyrin (PtOEP) may be used as the phosphorescence dopant. However, embodiments of the present disclosure are not limited thereto.

In one or more embodiments, the emission layer may include a quantum dot.

In the present disclosure, the quantum dot refers to the crystal of a semiconductor compound. The quantum dot may be to emit light in one or more suitable emission wavelengths according to a size of the crystal. The quantum dot may be to emit light in one or more suitable emission wavelengths by controlling an element ratio in the quantum dot compound.

The diameter of the quantum dot may be, for example, about 1 nm to about 10 nm. In the present disclosure, when quantum dot, quantum dots, or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a chemical bath deposition, a metal organic chemical vapor deposition, a molecular beam epitaxy, or a similar process therewith.

The chemical bath deposition is a method of mixing an organic solvent and a precursor material of a quantum dot and then, growing a quantum dot particle crystal. During growing the crystal, the organic solvent may naturally play the role of a dispersant which is coordinated on the surface of the quantum dot crystal and may control the growth of the crystal. Accordingly, the chemical bath deposition is more advantageous if (e.g., when) compared to a vapor deposition method including a metal organic chemical vapor deposition (MOCVD) and a molecular beam epitaxy (MBE), and the growth of the quantum dot particle may be controlled or selected through a low-cost process.

In one or more embodiments, the emission layer EML may include a quantum dot material. In one or more embodiments, the quantum dot may have a core/shell structure. The core of the quantum dot may be selected from among a Group II-VI compound, a Group III-VI compound, a Group I-III-VI compound, a Group III-V compound, a Group III-II-V compound, a Group IV-VI compound, a Group IV element, a Group IV compound, and/or one or more (e.g., any suitable) combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a (e.g., any suitable) mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a (e.g., any suitable) mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a (e.g., any suitable) mixture thereof. In one or more embodiments, the Group II-VI compound may further include a Group I metal and/or a Group IV element. The Group I-II-VI compound may be selected from among CuSnS and Cu₂ZnS, and the Group II-IV-VI compound may be selected from among ZnSnS and the like. The Group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂, and a (e.g., any suitable) mixture thereof.

The Group III-VI compound may include a binary compound such as In₂S₃, and/or In₂Se₃, a ternary compound such as InGaS₃ and/or InGaSe₃, or any combination thereof.

The Group I-III-VI compound may be selected from among a ternary compound selected from the group consisting of AgInS, AgInS₂, CuInS, CuInS₂, AgGaS₂, CuGaS₂, CuGaO₂, AgGaO₂, AgAIO₂ and mixtures thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a (e.g., any suitable) mixture thereof, a ternary compound selected from the group consisting of SnSeS, SnSeTe, SnSTe, PbSeS, PbSeTe, PbSTe, SnPbS, SnPbSe, SnPbTe, and a (e.g., any suitable) mixture thereof, and a quaternary compound selected from the group consisting of SnPbSSe, SnPbSeTe, SnPbSTe, and a (e.g., any suitable) mixture thereof.

The Group II-IV-V compound may be selected from a ternary compound selected from the group consisting of ZnSnP, ZnSnP₂, ZnSnAs₂, ZnGeP₂, ZnGeAs₂, CdSnP₂, CdGeP₂, and a (e.g., any suitable) mixture thereof.

The Group IV element may be selected from the group consisting of Si, Ge, and a (e.g., any suitable) mixture thereof. The Group IV compound may be a binary compound selected from the group consisting of SiC, SiGe, and a (e.g., any suitable) mixture thereof.

Each element included in the multi-element compound such as the binary compound, ternary compound, and quaternary compound may be present in particles at a substantially uniform concentration or a non-uniform concentration. For example, Formula above indicates the types (kinds) of elements included in a compound, and element ratios in the compound may be different. For example, AgInGaS₂ may indicate AgInₓGa₁₋ₓS₂ (x is a real number between 0 and 1).

In one or more embodiments, the binary compound, the ternary compound, or the quaternary compound may be present at substantially uniform concentration in a particle or may be present at a partially different concentration distribution state in the same particle. For example, a core/shell structure in which one quantum dot wraps another quantum dot may be possible. The interface between the core and the shell may have a concentration gradient in which the concentration of an element present in the shell is decreased toward the center.

In one or more embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties thereof and/or a charging layer for imparting the quantum dot with electrophoretic properties. The shell may have a single layer or a multilayer. Examples of the shell of the quantum dot may include a metal or non-metal oxide, a semiconductor compound, and/or one or more (e.g., any suitable) combinations thereof.

For example, the metal or non-metal oxide for the shell may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

The quantum dot may have a full width at half maximum (FWHM) of emission spectrum of about 45 nm or less, about 40 nm or less, or, about 30 nm or less. Within this range, color purity or color reproducibility of the quantum dot may be improved. In addition, light emitted via such quantum dot is emitted in all directions, and light view angle properties may be improved.

In addition, the shape of the quantum dot may be any suitable shape used in the art, without specific limitation. For example, the shape of spherical nanoparticle, pyramidal nanoparticle, multi-arm nanoparticle, cubic nanoparticle, nanotube, nanowire, nanofiber, nanoplate particle, and/or the like, may be used.

As the size of the quantum dot or the ratio of elements in the quantum dot compound is regulated, the energy band gap of the quantum dot may be accordingly controlled or selected to obtain light of one or more suitable wavelengths from a quantum dot emission layer. Therefore, by using the quantum dots as described above (using quantum dots of different sizes and/or having different element ratios in the quantum dot compound), a light emitting element emitting light of one or more suitable wavelengths may be obtained. For example, the size of the quantum dots or the ratio of elements in the quantum dot compound may be regulated to enable the quantum dots to emit red, green, and/or blue light. In one or more embodiments, the quantum dots may be configured to emit white light by combining light of one or more suitable colors.

In the light emitting element ED of embodiments, as shown in FIG. 3 to FIG. 6, the electron transport region ETR may be provided on the emission layer EML. The electron transport region ETR may include at least one of an electron blocking layer HBL, an electron transport layer ETL, or an electron injection layer EIL. However, embodiments of the present disclosure are not limited thereto.

The electron transport region ETR may have a single layer formed using a single material, a single layer formed using multiple different materials, or a multilayer structure having multiple layers formed using multiple different materials.

For example, in one or more embodiments, the electron transport region ETR may have a single layer structure of an electron injection layer EIL or an electron transport layer ETL, or a single layer structure formed using an electron injection material and an electron transport material. In one or more embodiments, the electron transport region ETR may have a single layer structure formed using multiple different materials, or a structure stacked from the emission layer EML of electron transport layer ETL/electron injection layer EIL, or hole blocking layer HBL/electron transport layer ETL/electron injection layer EIL, without limitation. A thickness of the electron transport region ETR may be, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2.

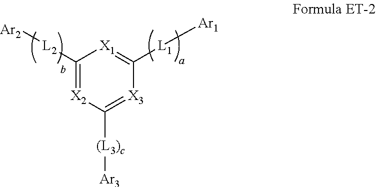

In Formula ET-2, at least one selected from among X₁ to X₃ may be N, and the remainder are CRₐ. Rₐ may be hydrogen, deuterium, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In one or more embodiments, if (e.g., when) “a” to “c” are integers of 2 or more, L₁'s to L₃'s may each independently be a substituted or unsubstituted arylene group of 6 to 30 ring-forming carbon atoms or a substituted or unsubstituted heteroarylene group of 2 to 30 ring-forming carbon atoms.

In one or more embodiments, the electron transport region ETR may include an anthracene-based compound. However, embodiments of the present disclosure are not limited thereto, for example, in some embodiments, the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O₈)-(1,1′-biphenyl-4-olato)aluminum (BAlq), berylliumbis(benzoquinolin-10-olate (Bebq₂), 9,10-di(naphthalen-2-yl) anthracene (ADN), 1,3-bis[3,5-di(pyridin-3-yl)phenyl]benzene (BmPyPhB), CNNPTRZ(4′-(4-(4-(4,6-diphenyl-1,3,5-triazin-2-yl)phenyl) naphthalen-1-yl)-[1,1′-biphenyl]-4-carbonitrile), and mixtures thereof, without limitation.

In one or more embodiments, the electron transport region ETR may include any one selected from among the compounds in Compound Group 3.

In one or more embodiments, the electron transport region ETR may include at least one selected from among Compounds ET1 to ET36.

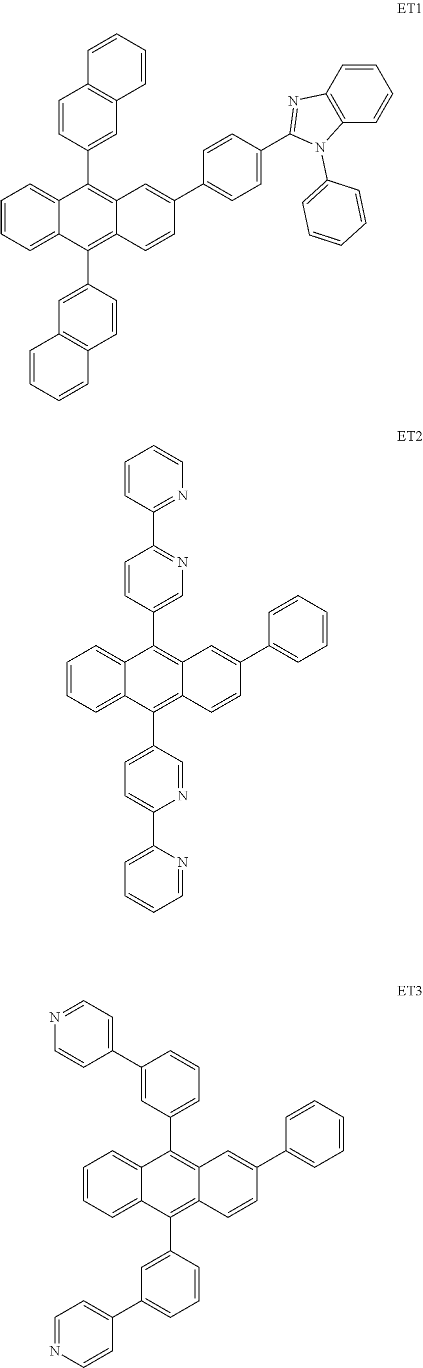 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

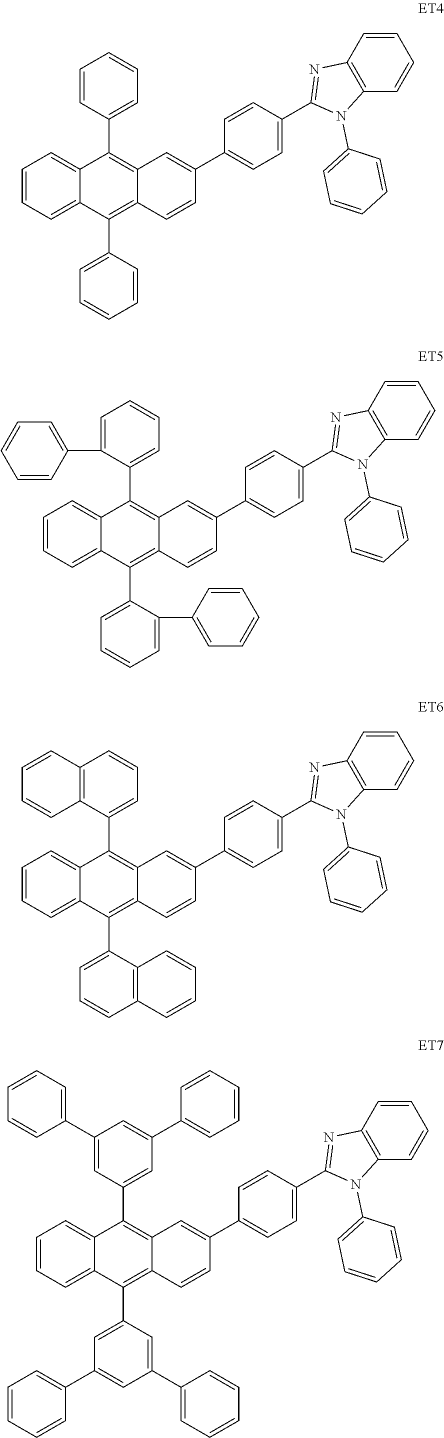 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

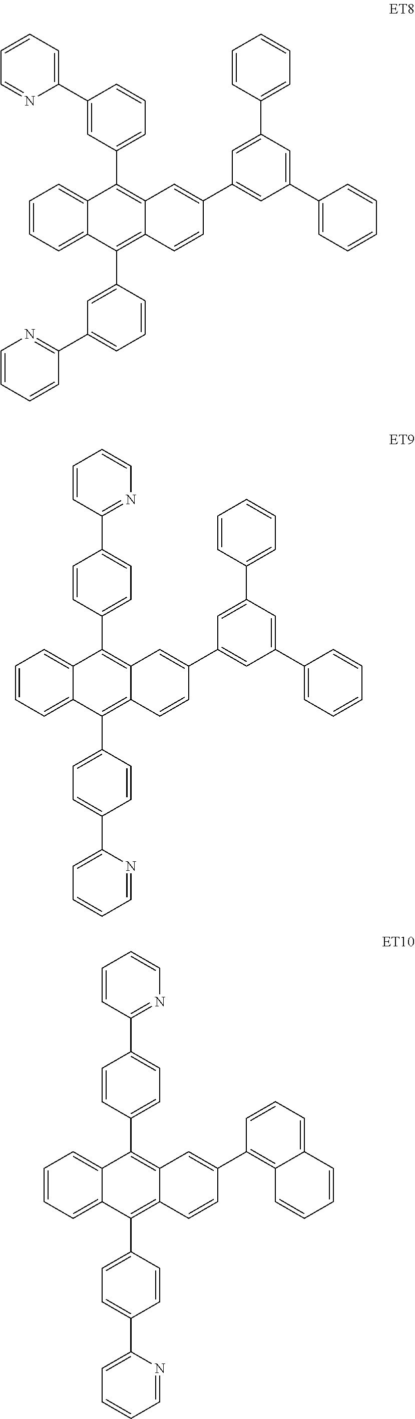

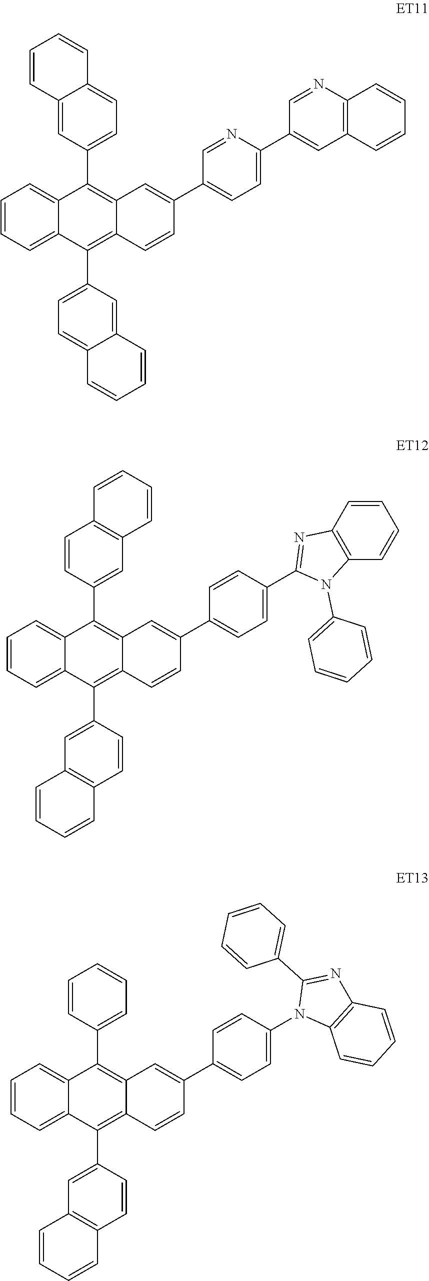 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

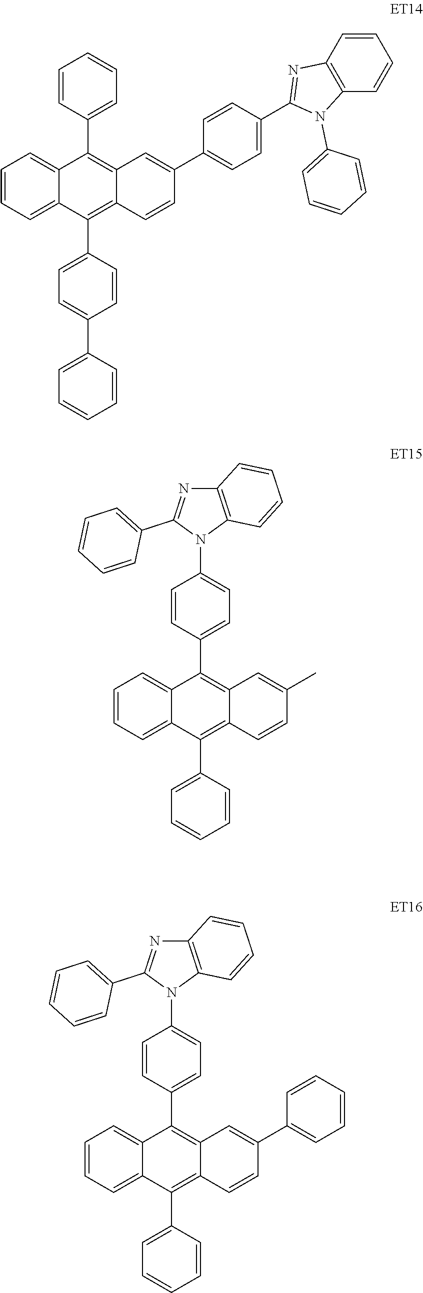 [SMILES: c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

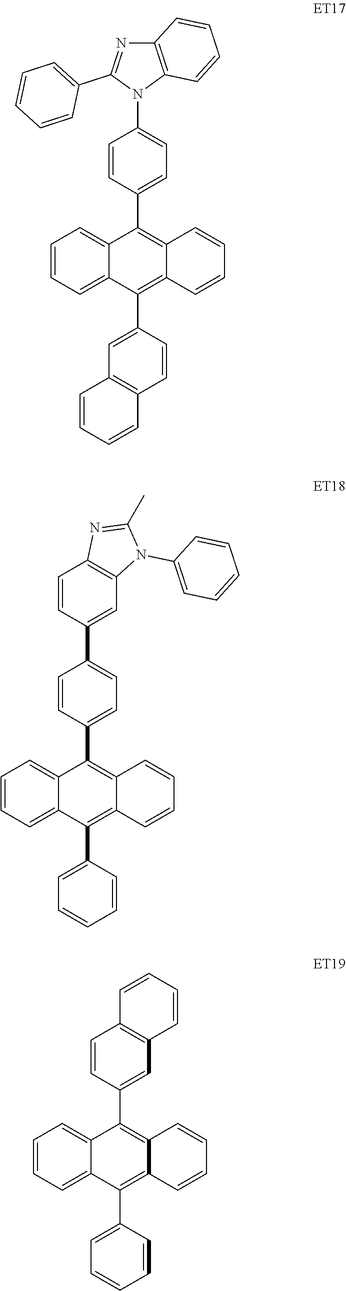

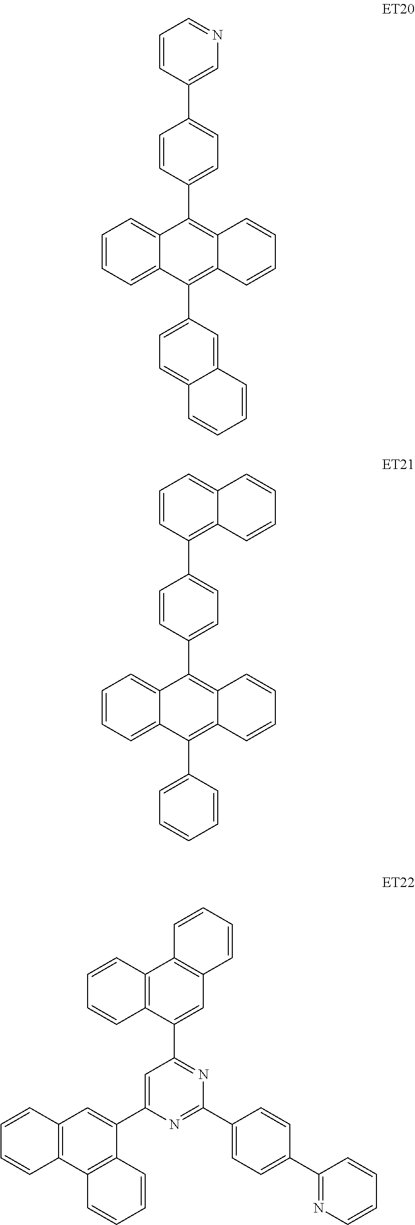

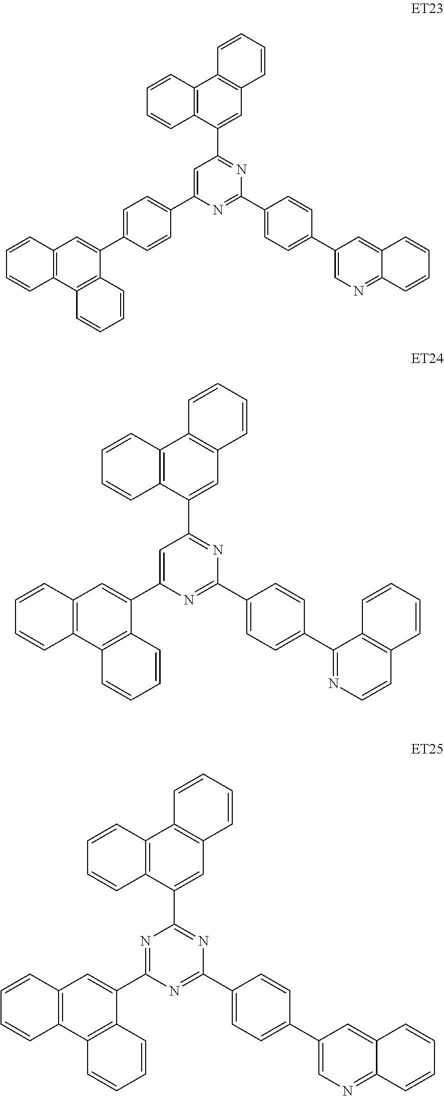 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

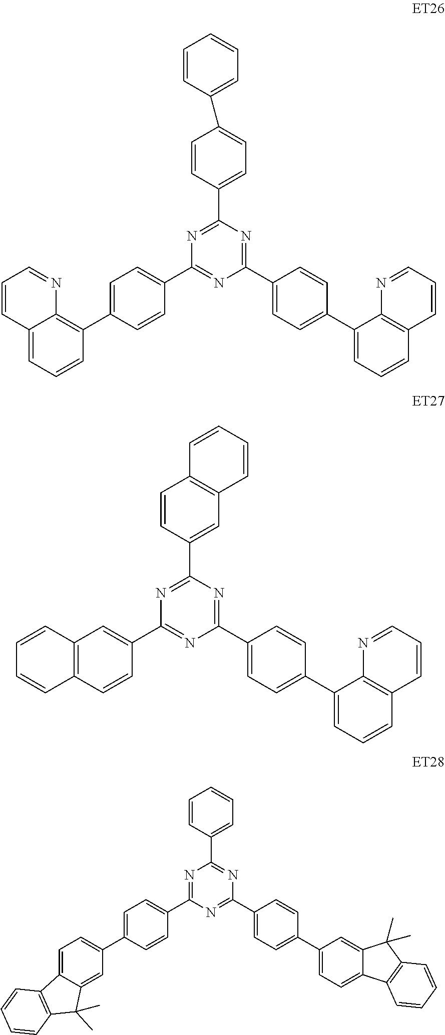 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

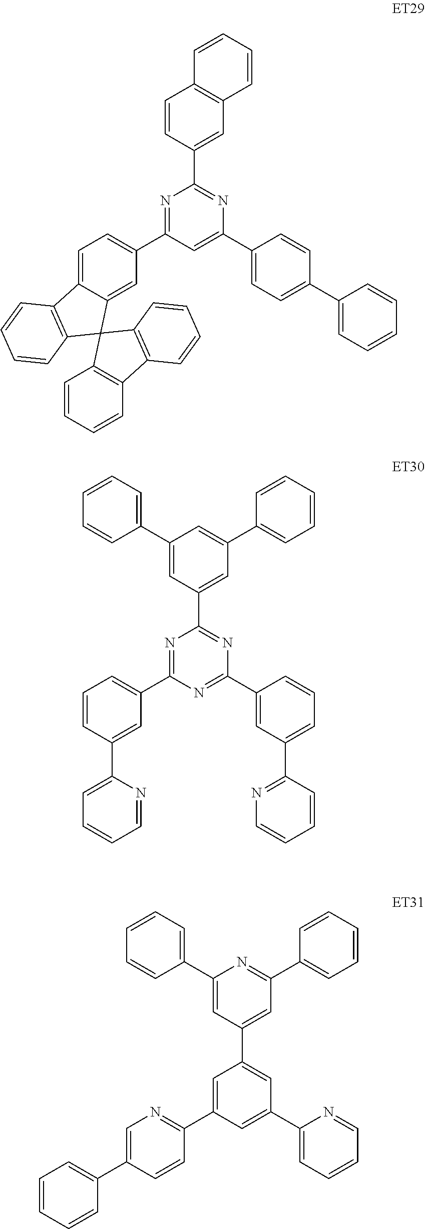 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

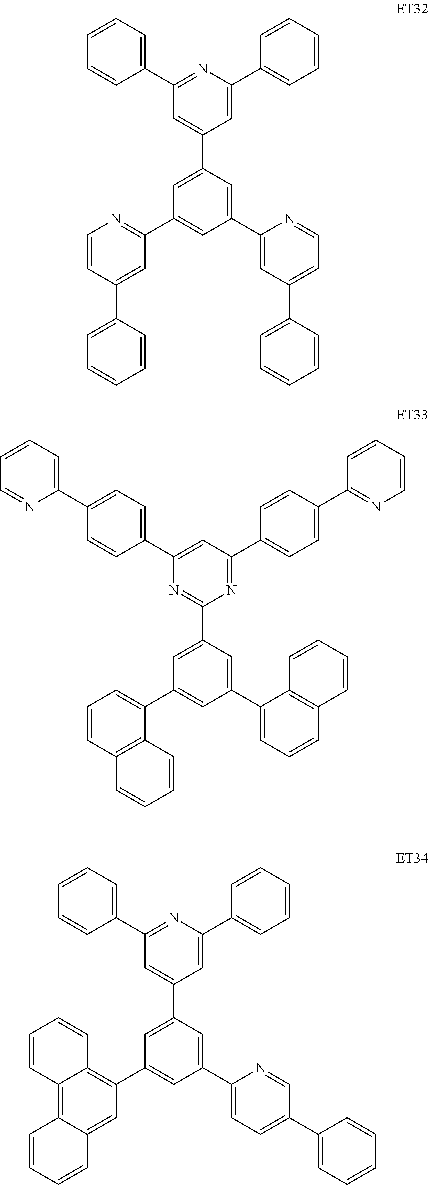 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

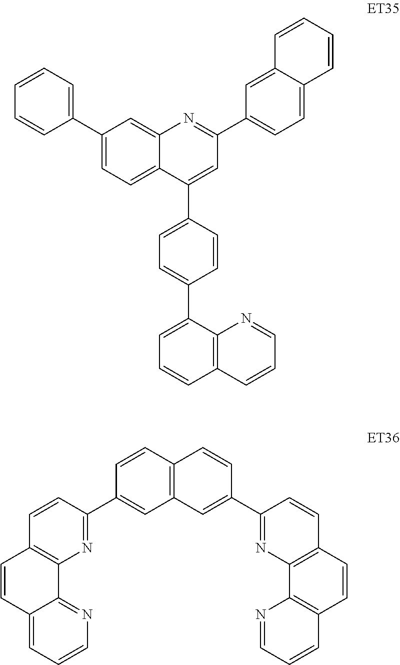 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCl, RbI, CuI, and/or KI, a lanthanide metal such as Yb, or a co-depositing material of the metal halide and the lanthanide metal. For example, the electron transport region ETR may include KI: Yb, RbI: Yb, LiF: Yb, and/or the like, as the co-depositing material. In one or more embodiments, the electron transport region ETR may use a metal oxide such as Li₂O and/or BaO, or 8-hydroxy-lithium quinolate (Liq). However, embodiments of the present disclosure are not limited thereto. In some embodiments, the electron transport region ETR may also be formed using a mixture material of an electron transport material and an insulating organo metal salt. The insulating organo metal salt may be a material having an energy band gap of about 4 eV or more. For example, the insulating organo metal salt may include, for example, one or more of metal acetates, metal benzoates, metal acetoacetates, metal acetylacetonates, or metal stearates.

In one or more embodiments, the electron transport region ETR may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the aforementioned materials. However, embodiments of the present disclosure are not limited thereto.

The electron transport region ETR may include one or more of the compounds of the electron transport region in at least one selected from among an electron injection layer EIL, an electron transport layer ETL, and a hole blocking layer HBL.

If (e.g., when) the electron transport region ETR includes an electron transport layer ETL, the thickness of the electron transport layer ETL may be from about 100 Å to about 1,000 Å, for example, from about 150 Å to about 500 Å. If (e.g., when) the thickness of the electron transport layer ETL satisfies the above-described range, satisfactory electron transport properties may be obtained without substantial increase of a driving voltage. If (e.g., when) the electron transport region ETR includes an electron injection layer EIL, the thickness of the electron injection layer EIL may be from about 1 Å to about 100 Å, and from about 3 Å to about 90 Å. If (e.g., when) the thickness of the electron injection layer EIL satisfies the above described range, satisfactory electron injection properties may be obtained without inducing substantial increase of a driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, if (e.g., when) the first electrode EL1 is an anode, the second cathode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is the transmissive electrode, the second electrode EL2 may include a transparent metal oxide, for example, ITO, IZO, ZnO, ITZO, and/or the like.

If (e.g., when) the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, one or more compounds including thereof, or one or more mixtures thereof (for example, AgMg, AgYb, or MgYb). In one or more embodiments, the second electrode EL2 may have a multilayered structure including a reflective layer or a transflective layer formed using one or more of the above-described materials and a transparent conductive layer formed using ITO, IZO, ZnO, ITZO, and/or the like. For example, the second electrode EL2 may include one of the aforementioned metal materials, a combination of two or more metal materials selected from among the aforementioned metal materials, or one or more oxides of the aforementioned metal materials.

In one or more embodiments, the second electrode EL2 may be connected with an auxiliary electrode. If (e.g., when) the second electrode EL2 is connected with the auxiliary electrode, the resistance of the second electrode EL2 may decrease.

In one or more embodiments, on the second electrode EL2 in the light emitting element ED of one or more embodiments, a capping layer CPL may be further arranged. The capping layer CPL may include a multilayer or a single layer.

In one or more embodiments, the capping layer CPL may be an organic layer or an inorganic layer. For example, if (e.g., when) the capping layer CPL includes an inorganic material, the inorganic material may include an alkali metal compound such as LiF, an alkaline earth metal compound such as MgF₂, SiON, SiNₓ, SiO_{y}, and/or the like.

For example, in some embodiments, if (e.g., when) the capping layer CPL includes an organic material, the organic material may include 2,2′-dimethyl-N, N′-di-[(1-naphthyl)-N, N′-diphenyl]-1,1′-biphenyl-4,4′-diamine (α-NPD), NPB, TPD, m-MTDATA, Alq₃, CuPc, N4,N4, N4′, N4′-tetra(biphenyl-4-yl) biphenyl-4,4′-diamine (TPD15), 4,4′,4″-tris(carbazol sol-9-yl)triphenylamine (TCTA), and/or the like, or includes an epoxy resin, or acrylate such as methacrylate. In one or more embodiments, the capping layer CPL may include at least one selected from among Compounds P1 to P5, but embodiments of the present disclosure are not limited thereto.

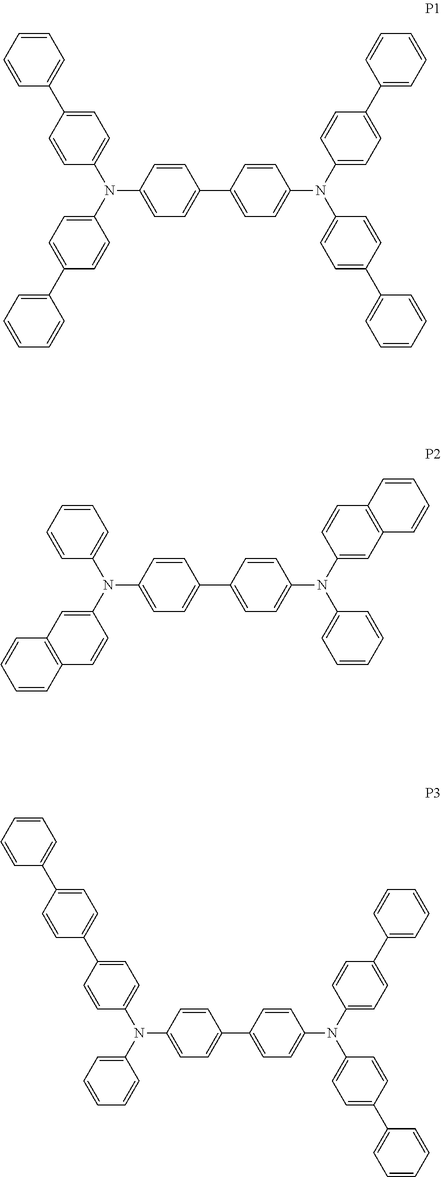 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

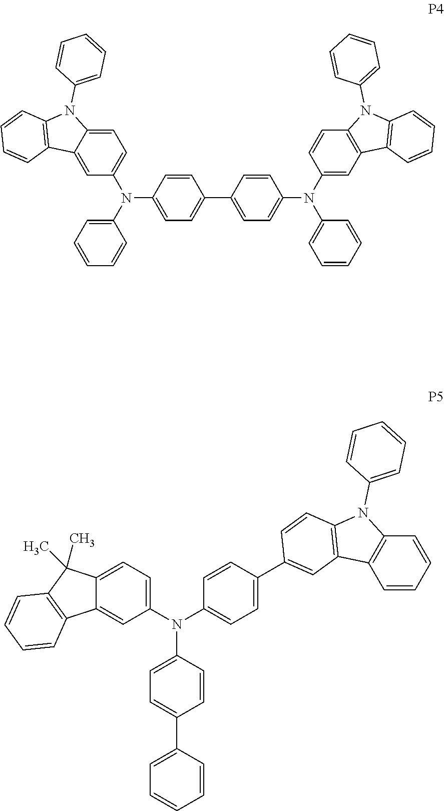 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL with respect to light in a wavelength range of about 550 nm to about 660 nm may be about 1.6 or more.

FIG. 7 to FIG. 10 are each a cross-sectional view of a display device according to one or more embodiments of the present disclosure. In the explanation on the display devices of embodiments referring to FIG. 7 to FIG. 10, the overlapping parts with the explanation on FIG. 1 to FIG. 6 will not be repeated for conciseness, and only different features will be explained chiefly.

Referring to FIG. 7, the display device DD-a according to one or more embodiments may include a display panel DP including a display device layer DP-ED, a light controlling layer CCL arranged on the display panel DP, and a color filter layer CFL. In one or more embodiments shown in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the same structure as any of the light emitting elements of FIG. 3 to FIG. 6 may be applied to the structure of the light emitting element ED shown in FIG. 7.

The emission layer EML of the light emitting element ED included in the display device DD-a according to one or more embodiments may include the fused polycyclic compound of one or more embodiments described above.

Referring to FIG. 7, the emission layer EML may be arranged in an opening part OH defined in a pixel definition layer PDL. For example, the emission layer EML divided by the pixel definition layer PDL and correspondingly provided to each of luminous areas PXA-R, PXA-G, and PXA-B may be to emit light in substantially the same wavelength region. In the display device DD-a of one or more embodiments, the emission layer EML may be to emit blue light. In one or more embodiments, the emission layer EML may be provided as a common layer for all luminous areas PXA-R, PXA-G, and PXA-B.

The light controlling layer CCL may be arranged on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot and/or a layer including a phosphor.

The light controlling layer CCL may include multiple light controlling parts CCP1, CCP2, and CCP3. The light controlling parts CCP1, CCP2, and CCP3 may be separated from one another.

Referring to FIG. 7, a partition pattern BMP may be arranged between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but, in some embodiments, at least a portion of the edges of the light controlling parts CCP1, CCP2, and CCP3 may be overlapped with the partition pattern BMP.

In one or more embodiments, the light controlling layer CCL may include a first light controlling part CCP1 including a first quantum dot QD1 converting first color light provided from the light emitting element ED into second color light, a second light controlling part CCP2 including a second quantum dot QD2 converting first color light into third color light, and a third light controlling part CCP3 transmitting first color light. In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting element ED. For example, in one or more embodiments, the first quantum dot QD1 may be a red quantum dot to emit red light, and the second quantum dot QD2 may be a green quantum dot to emit green light. On the quantum dots QD1 and QD2, the same contents as those described above on quantum dots may be applied.

In one or more embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include a (e.g., may exclude any) quantum dot but include the scatterer SP.

The scatterer SP may be an inorganic particle. For example, the scatterer SP may include at least one selected from among TiO₂, ZnO, Al₂O₃, SiO₂, and hollow silica. In one or more embodiments, the scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light controlling part CCP1, the second light controlling part CCP2, and the third light controlling part CCP3 may respectively include base resins BR1, BR2, and BR3 dispersing the quantum dots QD1 and QD2 and the scatterer SP. In one or more embodiments, the first light controlling part CCP1 may include the first quantum dot QD1 and the scatterer SP dispersed in a first base resin BR1, the second light controlling part CCP2 may include the second quantum dot QD2 and the scatterer SP dispersed in a second base resin BR2, and the third light controlling part CCP3 may include the scatterer particle SP dispersed in a third base resin BR3.

The base resins BR1, BR2, and BR3 are media in which the quantum dots QD1 and QD2 and the scatterer SP are dispersed, and may be composed of one or more suitable resin compositions which may be generally referred to as a binder. For example, the base resins BR1, BR2, and BR3 may each independently be acrylic resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same or different from each other.

In one or more embodiments, the light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may block the exposure of the light controlling parts CCP1, CCP2, and CCP3 to humidity/oxygen. In one or more embodiments, the barrier layer BFL1 may cover the light controlling parts CCP1, CCP2, and CCP3. In one or more embodiments, a color filter layer CFL, which will be explained later, may include a barrier layer BFL2 arranged on the light controlling parts CCP1, CCP2, and CCP3.

The barrier layers BFL1 and BFL2 may include at least one inorganic layer. For example, in some embodiments, the barrier layers BFL1 and BFL2 may each be formed by including an inorganic material. For example, the barrier layers BFL1 and BFL2 may each independently be formed by including one or more selected from among silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, or a metal thin film securing light transmittance. In one or more embodiments, the barrier layers BFL1 and BFL2 may further include an organic layer. The barrier layers BFL1 and BFL2 may be composed of a single layer of multiple layers.

In the display device DD-a of one or more embodiments, the color filter layer CFL may be arranged on the light controlling layer CCL. For example, in one or more embodiments, the color filter layer CFL may be arranged directly on the light controlling layer CCL. In these embodiments, the barrier layer BFL2 may not be provided.

The color filter layer CFL may include filters CF1, CF2, and CF3. The first to third filters CF1, CF2, and CF3 may be arranged corresponding to a red luminous area PXA-R, a green luminous area PXA-G, and a blue luminous area PXA-B, respectively.

In one or more embodiments, the color filter layer CFL may include a first filter CF1 transmitting second color light, a second filter CF2 transmitting third color light, and a third filter CF3 transmitting first color light. For example, in one or more embodiments, the first filter CF1 may be a red filter, the second filter CF2 may be a green filter, and the third filter CF3 may be a blue filter. Each of the filters CF1, CF2, and CF3 may independently include a polymer photosensitive resin and a pigment and/or a dye. In one or more embodiments, the first filter CF1 may include a red pigment and/or a red dye, the second filter CF2 may include a green pigment and/or a green dye, and the third filter CF3 may include a blue pigment and/or a blue dye.

In one or more embodiments, the third filter CF3 may not include a (e.g., may exclude any) pigment and/or dye. The third filter CF3 may include a polymer photosensitive resin and not include a pigment and/or a dye. The third filter CF3 may be transparent. The third filter CF3 may be formed using a transparent photosensitive resin.

In addition, in one or more embodiments, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material and/or an inorganic light blocking material including a black pigment and/or a black dye. The light blocking part may prevent or reduce light leakage phenomenon and divide boundaries among adjacent filters CF1, CF2, and CF3.

In one or more embodiments, on the color filter layer CFL, a base substrate BL may be arranged. The base substrate BL may be a member providing a base surface on which the color filter layer CFL, the light controlling layer CCL, and/or the like, are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In addition, in one or more embodiments, the base substrate BL may not be provided.

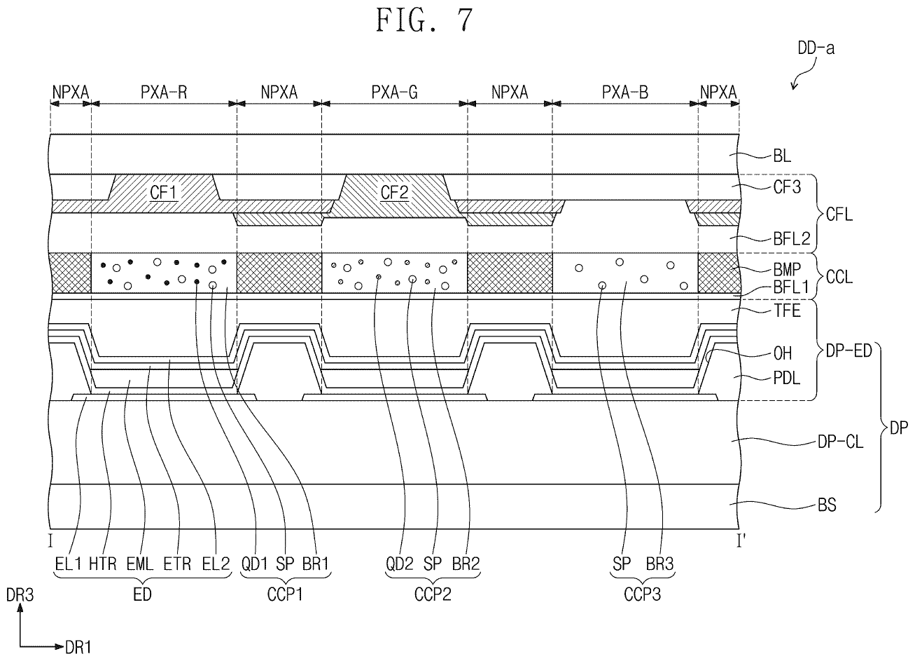

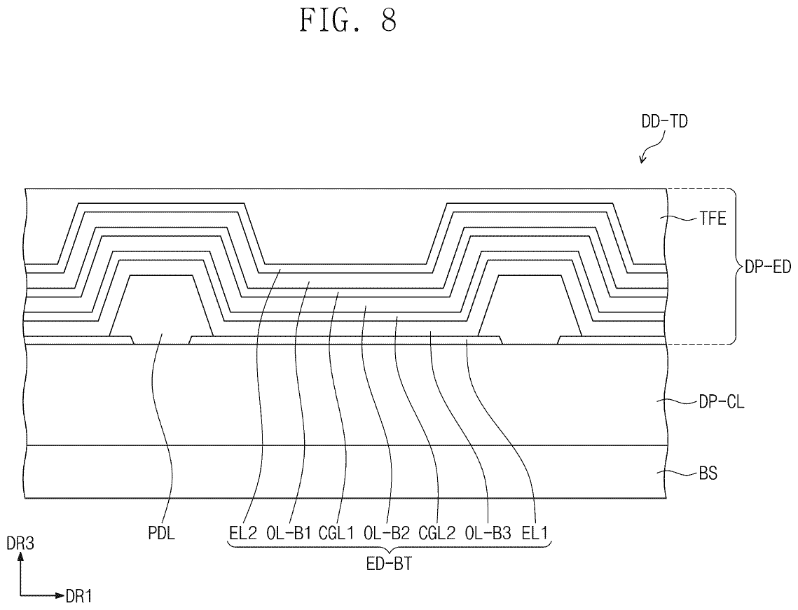

FIG. 8 is a cross-sectional view showing a portion of a display device according to one or more embodiments. In a display device DD-TD of one or more embodiments, the light emitting element ED-BT may include multiple light emitting structures OL-B1, OL-B2, and OL-B3. The light emitting element ED-BT may include oppositely arranged first electrode EL1 and second electrode EL2, and the multiple light emitting structures OL-B1, OL-B2, and OL-B3 stacked in the stated order in a thickness direction and provided between the first electrode EL1 and the second electrode EL2. Each of the light emitting structures OL-B1, OL-B2, and OL-B3 may include an emission layer EML (FIG. 7) and a hole transport region HTR and an electron transport region ETR arranged with the emission layer EML (FIG. 7) therebetween.

For example, the light emitting element ED-BT included in the display device DD-TD of one or more embodiments may be a light emitting element of a tandem structure including multiple emission layers.

In one or more embodiments shown in FIG. 8, light emitted from the light emitting structures OL-B1, OL-B2, and OL-B3 may be all blue light. However, embodiments of the present disclosure are not limited thereto, and the wavelength regions of light emitted from the light emitting structures OL-B1, OL-B2, and OL-B3 may be different from each other. For example, in one or more embodiments, the light emitting element ED-BT including the multiple light emitting structures OL-B1, OL-B2, and OL-B3 emitting light in different wavelength regions may be to emit white light (e.g., combined white light).

Between neighboring light emitting structures OL-B1, OL-B2, and OL-B3, charge generating layers CGL1 and CGL2 may be arranged. The charge generating layers CGL1 and CGL2 may include a p-type or kind charge (e.g., P-charge) generating layer and/or an n-type or kind charge (N-charge) generating layer.

At least one selected from among the light emitting structures OL-B1, OL-B2, and OL-B3 included in the display device DD-TD of one or more embodiments may include the fused polycyclic compound of one or more embodiments described above. For example, in one or more embodiments, at least one selected from the plurality of emission layers included in the light emitting element ED-BT may include the fused polycyclic compound of one or more embodiments.

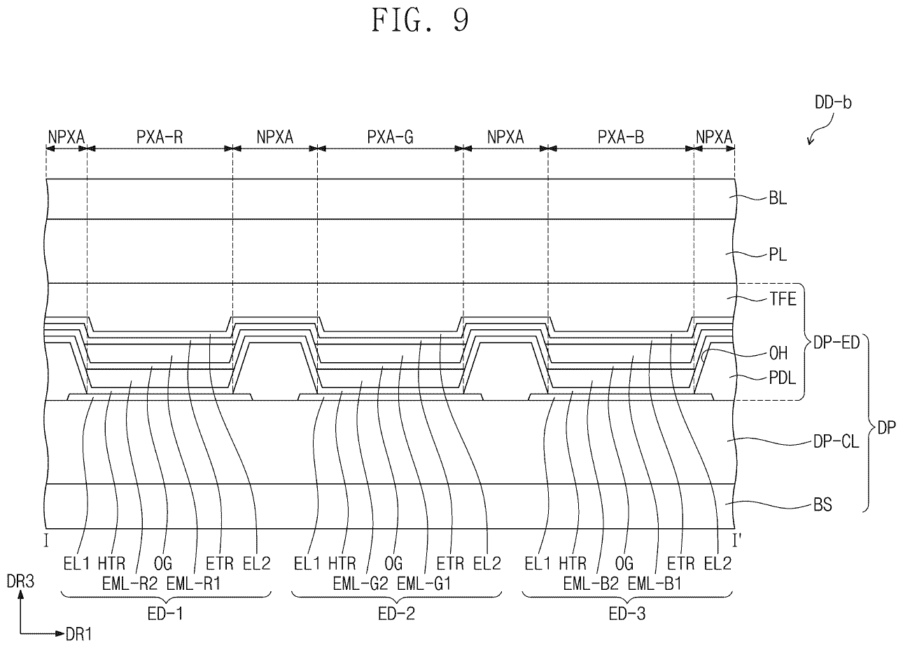

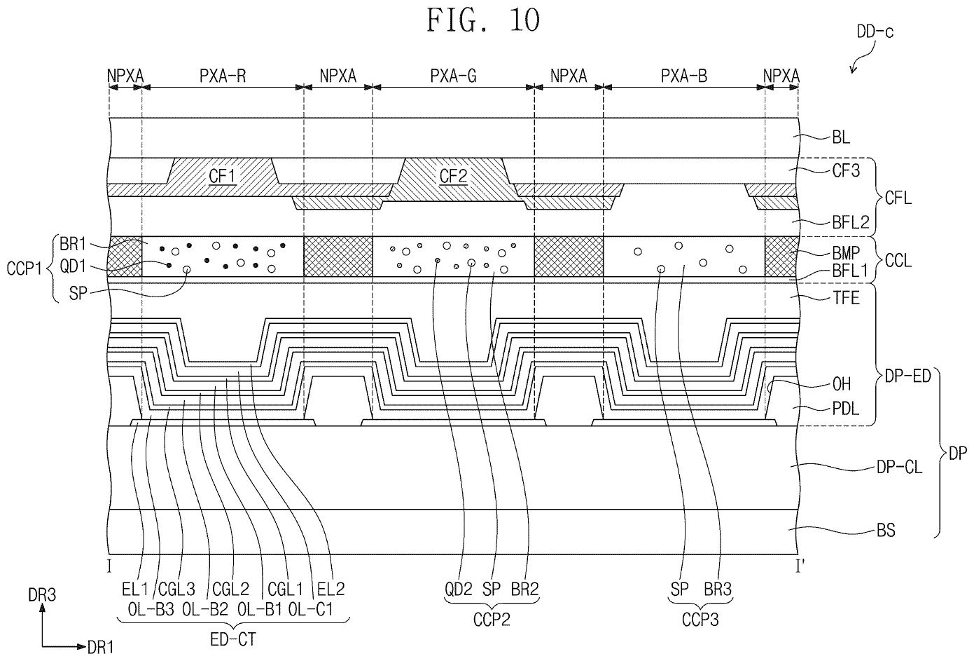

FIG. 9 is a cross-sectional view showing a display device according to one or more embodiments of the present disclosure. FIG. 10 is a cross-sectional view showing a display device according to one or more embodiments of the present disclosure.

Referring to FIG. 9, a display device DD-b according to one or more embodiments may include light emitting elements ED-1, ED-2, and ED-3, formed by stacking two emission layers. Compared to the display device DD of one or more embodiments shown in FIG. 2, the display device DD-b shown in FIG. 9 is different in that first to third light emitting elements ED-1, ED-2, and ED-3 each include two emission layers stacked in a thickness direction. In the first to third light emitting elements ED-1, ED-2, and ED-3, two emission layers may be to emit light in substantially the same wavelength region.

In one or more embodiments, the first light emitting element ED-1 may include a first red emission layer EML-R₁ and a second red emission layer EML-R₂. The second light emitting element ED-2 may include a first green emission layer EML-G1 and a second green emission layer EML-G2. In addition, the third light emitting element ED-3 may include a first blue emission layer EML-B1 and a second blue emission layer EML-B2. Between the first red emission layer EML-R₁ and the second red emission layer EML-R₂, between the first green emission layer EML-G1 and the second green emission layer EML-G2, and between the first blue emission layer EML-B1 and the second blue emission layer EML-B2, an emission auxiliary part OG may be arranged.

The emission auxiliary part OG may include a single layer or a multilayer. The emission auxiliary part OG may include a charge generating layer. For example, the emission auxiliary part OG may include an electron transport region, a charge generating layer, and a hole transport region stacked in the stated order. In one or more embodiments, the emission auxiliary part OG may be provided as a common layer in all of the first to third light emitting elements ED-1, ED-2, and ED-3. However, embodiments of the present disclosure are not limited thereto, and the emission auxiliary part OG may be patterned and provided in an opening part OH defined in a pixel definition layer PDL.

The first red emission layer EML-R₁, the first green emission layer EML-G1, and the first blue emission layer EML-B1 may be arranged between the electron transport region ETR and the emission auxiliary part OG. The second red emission layer EML-R₂, the second green emission layer EML-G2, and the second blue emission layer EML-B2 may be arranged between the emission auxiliary part OG and the hole transport region HTR.

For example, in one or more embodiments, the first light emitting element ED-1 may include a first electrode EL1, a hole transport region HTR, a second red emission layer EML-R₂, an emission auxiliary part OG, a first red emission layer EML-R₁, an electron transport region ETR, and a second electrode EL2, stacked in the stated order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in the stated order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in the stated order.

In one or more embodiments, an optical auxiliary layer PL may be arranged on the display device layer DP-ED. The optical auxiliary layer PL may include a polarization layer. The optical auxiliary layer PL may be arranged on the display panel DP and may control reflected light at the display panel DP by external light. In one or more embodiments, the optical auxiliary layer PL may not be provided in the display device.

At least one emission layer included in a display device DD-b of one or more embodiments shown in FIG. 9 may include the fused polycyclic compound of one or more embodiments described above. For example, at least one of the first blue emission layer EML-B1 or the second blue emission layer EML-B2 may include the fused polycyclic compound of one or more embodiments.

Different from FIG. 8 and FIG. 9, a display device DD-c in FIG. 10 is shown to include four light emitting structures OL-B1, OL-B2, OL-B3, and OL-C1. According to one or more embodiments, a light emitting element ED-CT may include oppositely arranged first electrode EL1 and second electrode EL2, and first to fourth light emitting structures OL-B1, OL-B2, OL-B3, and OL-C1 stacked in a thickness direction between the first electrode EL1 and the second electrode EL2. In one or more embodiments, the third light emitting structures OL-B3, the second light emitting structures OL-B2, the first light emitting structures OL-B1, and the fourth light emitting structures OL-C1 are stacked in the stated order in a thickness direction. Between the first to fourth light emitting structures OL-B1, OL-B2, OL-B3, and OL-C1, charge generating layers CGL1, CGL2 and CGL3 may each be separately arranged. For example, A first charge generating layer CGL1 is arranged between the first light emitting structures OL-B1 and the fourth light emitting structures OL-C1. A second charge generating layer CGL2 is arranged between the first light emitting structures OL-B1 and the second light emitting structures OL-B2. A third charge generating layer CGL3 is arranged between the second light emitting structures OL-B2 and the third light emitting structures OL-B3.

In one or more embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, for example, the first to fourth light emitting structures OL-B1, OL-B2, OL-B3, and OL-C1 may be to emit different wavelengths of light.

At least one selected from among the light emitting structures OL-B1, OL-B2, OL-B3, and OL-C1 included in the display device DD-c according to one or more embodiments may include the fused polycyclic compound of one or more embodiments described above. For example, in one or more embodiments, at least one selected from among the first to third light emitting structures OL-B1, OL-B2, and OL-B3 may include the fused polycyclic compound of one or more embodiments described above.

The light emitting element ED described above according to one or more embodiments of the disclosure may include the fused polycyclic compound of one or more embodiments in at least one functional layer arranged between the first electrode EL1 and the second electrode EL2, and may thus exhibit excellent or suitable light emitting efficiency and improved lifespan. For example, the fused polycyclic compound according to one or more embodiments may be included in the emission layer EML of the light emitting element ED of one or more embodiments, and the light emitting element of one or more embodiments may exhibit long lifespan.

In one or more embodiments, an electronic apparatus may include a display device including multiple light emitting elements and a control part controlling the display device. The electronic apparatus of one or more embodiments may be an apparatus activated according to electrical signals. The electronic apparatus may include display devices of one or more suitable embodiments. For example, the electronic apparatus may include one or more selected from among televisions, monitors, large-size display devices such as outside billboards, personal computers, laptop computers, personal digital terminals, display devices for automobiles, game consoles, portable electronic devices, medium- and small-size display devices such as cameras.

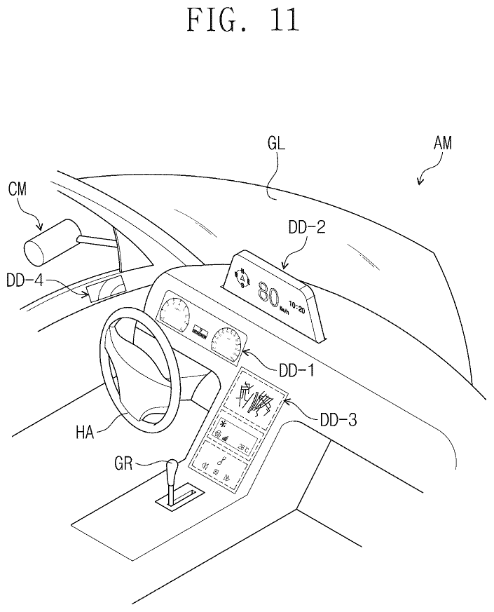

FIG. 11 is a diagram showing an automobile AM in which first to fourth display devices DD-1, DD-2, DD-3, and DD-4 are arranged. At least one selected from among the first to fourth display devices DD-1, DD-2, DD-3, and DD-4 may include substantially the same configuration as the display devices DD, DD-TD, DD-a, DD-b, and/or DD-c of embodiments, explained referring to FIGS. 1, 2, and 7 to 10.

In FIG. 11, a vehicle is shown as an automobile AM, but this is an example, and the first to fourth display devices DD-1, DD-2, DD-3, and DD-4 may be arranged on other transport apparatuses such as bicycles, motorcycles, trains, ships, and/or airplanes. In addition, at least one selected from among the first to fourth display devices DD-1, DD-2, DD-3, and DD-4 including substantially the same configurations as the display devices DD, DD-TD, DD-a, DD-b, and/or DD-c may be introduced in personal computers, laptop computers, personal digital terminals, game consoles, portable electronic devices, televisions, monitors, external billboards, and/or the like. These are suggested as mere examples, and thus the display device may be introduced in other electronic devices as long as not deviated from the disclosure.

In one or more embodiments, at least one selected from among the first to fourth display devices DD-1, DD-2, DD-3, and DD-4 may include the light emitting element ED of one or more embodiments described with reference to FIGS. 3 to 6. The light emitting element ED of one or more embodiments may include the fused polycyclic compound of one or more embodiments. At least one selected from among the first to fourth display devices DD-1, DD-2, DD-3, and DD-4 may include the light emitting element ED including the fused polycyclic compound of one or more embodiments, thereby improving a display service life.

Referring to FIG. 11, an automobile AM may include a steering wheel HA for the operation of the automobile AM and a gear GR. In addition, the automobile AM may include a front window GL arranged to face a driver.

A first display device DD-1 may be arranged in a first region overlapping with the steering wheel HA. For example, the first display device DD-1 may be a digital cluster displaying first information of the automobile AM. The first information may include a first graduation showing the running speed of the automobile AM, a second graduation showing the number of revolution of an engine (i.e., revolutions per minute (RPM)), and images showing a fuel state. The first graduation and the second graduation may each be represented by digital images.

A second display device DD-2 may be arranged in a second region facing (e.g., opposite to) a driver seat and overlapping with the front window GL. The driver seat may be a seat where the steering wheel HA faces. For example, the second display device DD-2 may be a head up display (HUD) showing second information of the automobile AM. The second display device DD-2 may be optically clear. The second information may include digital numbers showing the running speed of the automobile AM and may further include information including the current time. In one or more embodiments, the second information of the second display device DD-2 may be projected and displayed on the front window GL.

A third display device DD-3 may be arranged in a third region adjacent to the gear GR. For example, the third display device DD-3 may be a center information display (CID) for the automobile, arranged between the driver seat and a passenger seat and showing third information. The passenger seat may be a seat separated from the driver seat with the gear GR therebetween. The third information may include information on road conditions (for example, navigation information), on playing music or radio, on playing a dynamic image (or image), on the temperature in the automobile AM, and/or the like.

A fourth display device DD-4 may be arranged in a fourth region separated from the steering wheel HA and the gear GR and adjacent to a side of the automobile AM. For example, the fourth display device DD-4 may be a digital wing mirror displaying fourth information. The fourth display device DD-4 may display the external image of the automobile AM, taken by a camera module CM arranged at the outside of the automobile AM. The fourth information may include external images of the automobile AM.

The above-described first to fourth information may be examples, and the first to fourth display devices DD-1, DD-2, DD-3, and DD-4 may further display information on the inside and outside of the automobile. The first to fourth information may include different information from each other. However, embodiments of the present disclosure are not limited thereto, for example, a portion of the first to fourth information may include the same information.

Hereinafter, with reference to Examples and Comparative Examples, a fused polycyclic compound and a light emitting element of one or more embodiments of the disclosure will be specifically described. In addition, Examples are shown only for the understanding of the present disclosure, and the scope of the disclosure is not limited thereto.

### EXAMPLES

### 1. Synthesis of Fused Polycyclic Compounds

First, processes of synthesizing fused polycyclic compounds according to one or more embodiments of the present disclosure will be described in more detail by presenting processes of synthesizing Compounds 1, 2, 5, 6, 12, 29, 43, 50, and 57 as examples. In addition, the processes of synthesizing fused polycyclic compounds, which will be described hereinafter, are provided as mere examples, and thus the processes of synthesizing fused polycyclic compounds according to one or more embodiments of the present disclosure are not limited to Examples.

### (1) Synthesis of Compound 1

Fused polycyclic compound 1 according to one or more embodiments may be synthesized by, for example, a synthesis scheme described herein.

### Synthesis of Intermediate 1-1

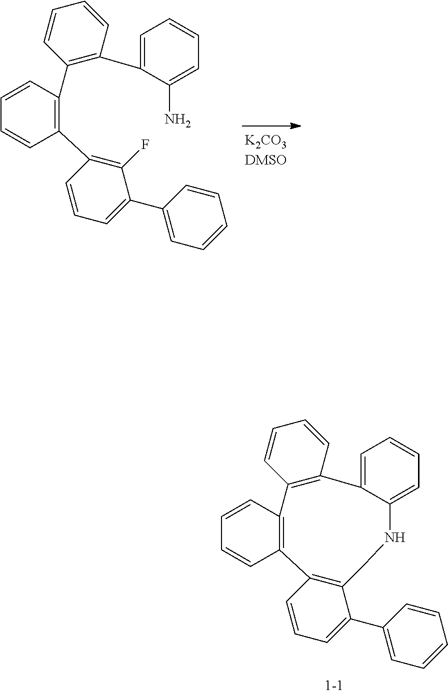 [SMILES: Nc1ccccc1-c1ccccc1-c1ccccc1-c1cccc(-c2ccccc2)c1F ; c1ccc(-c2cccc3c2CNc2ccccc2-c2ccccc2-c2ccccc2-3)cc1]

2′″-fluoro-[1,1′: 2′,1″: 2″,1′: 3″,1″-quinquephenyl]-2-amine (1 eq) and potassium carbonate (K₂CO₃, 3 eq) were dissolved in dimethyl sulfoxide (DMSO) and stirred at 160° C. for 24 hours in a nitrogen atmosphere. The mixture was cooled, and then dried under reduced pressure to remove dimethyl sulfoxide. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 1-1. (Yield: 62%)

### Synthesis of Intermediate 1-2

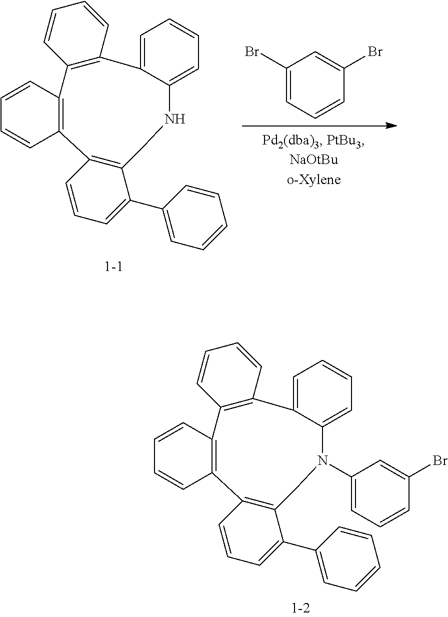 [SMILES: c1ccc(-c2cccc3c2CNc2ccccc2-c2ccccc2-c2ccccc2-3)cc1 ; Brc1cccc(Br)c1 ; Brc1cccc(N2Cc3c(-c4ccccc4)cccc3-c3ccccc3-c3ccccc3-c3ccccc32)c1]

Intermediate 1-1 (1 eq), 1,3-dibromobenzene (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 80° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 1-2. (Yield: 60%)

### Synthesis of Intermediate 1-3

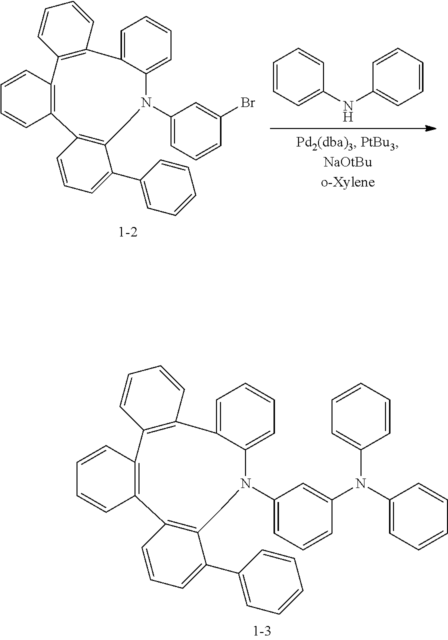

Intermediate 1-2 (1 eq), diphenylamine (1 eq), tris(dibenzylideneacetone)dipalladium(0) (Pd₂(dba)₃, 0.05 eq), tri-tert-butylphosphine (PtBus, 0.10 eq), and sodium tert-butoxide (NaOtBu, 1.5 eq) were dissolved in o-Xylene and stirred at 90° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, and then the organic layer was dried over MgSO₄ and then dried under reduced pressure. The resulting product was purified through column chromatography and recrystallized (solvent:dichloromethane:n-hexane) to obtain Intermediate 1-3. (Yield: 58%)

### Synthesis of Compound 1

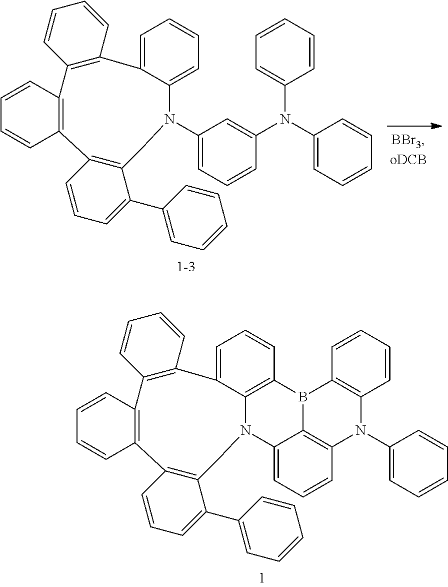 [SMILES: c1ccc(-c2cccc3c2CN(c2cccc(N(c4ccccc4)c4ccccc4)c2)c2ccccc2-c2ccccc2-c2ccccc2-3)cc1 ; c1ccc(-c2cccc3c2CN2c4cccc5c4B(c4ccccc4N5c4ccccc4)c4cccc(c42)-c2ccccc2-c2ccccc2-3)cc1]

Intermediate 1-3 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Compound 1. (Yield: 13%)

### (2) Synthesis of Compound 2

Fused polycyclic Compound 2 according to one or more embodiments may be synthesized by, for example, a synthesis scheme described herein.

### Synthesis of Intermediate 2-1

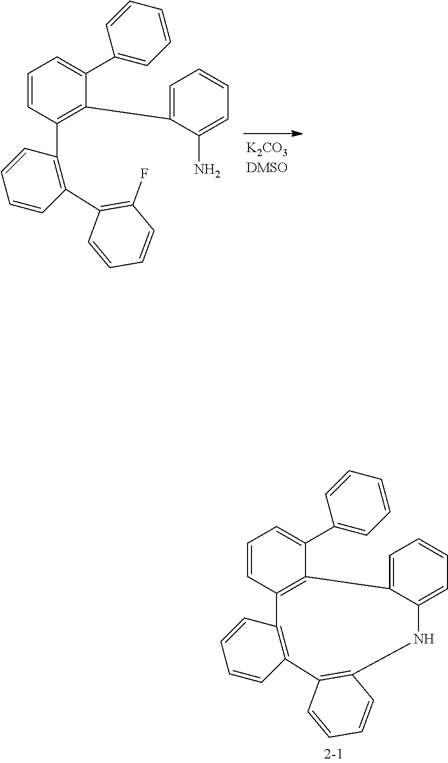 [SMILES: Nc1ccccc1-c1c(-c2ccccc2)cccc1-c1ccccc1-c1ccccc1F ; c1ccc(-c2cccc3c4ccccc4c4ccccc4[nH]c4ccccc4c23)cc1]

2″-fluoro-6′-phenyl-[1,1′: 2′,1″: 2″,1′″-quaterphenyl]-2-amine (1 eq) and potassium carbonate (K₂CO₃, 3 eq) were dissolved in dimethyl sulfoxide (DMSO) and then stirred at 160° C. for 24 hours in a nitrogen atmosphere. The mixture was cooled, and then dried under reduced pressure to remove dimethyl sulfoxide. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 2-1. (Yield: 65%)

### Synthesis of Intermediate 2-2

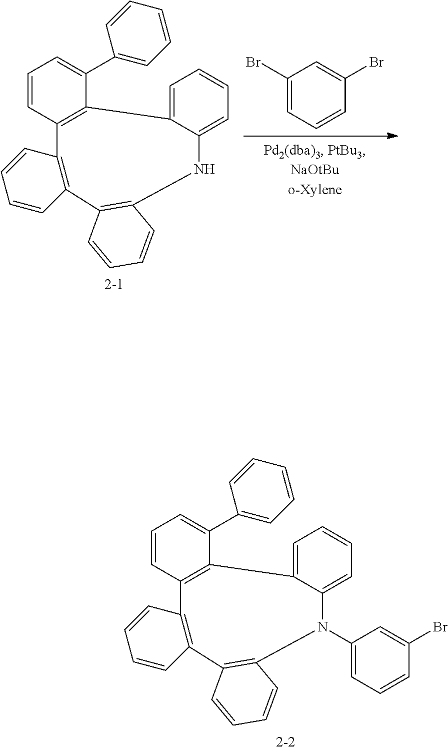

Intermediate 2-1 (1 eq), 1,3-dibromobenzene (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 80° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 2-2. (Yield: 62%)

### Synthesis of Intermediate 2-3

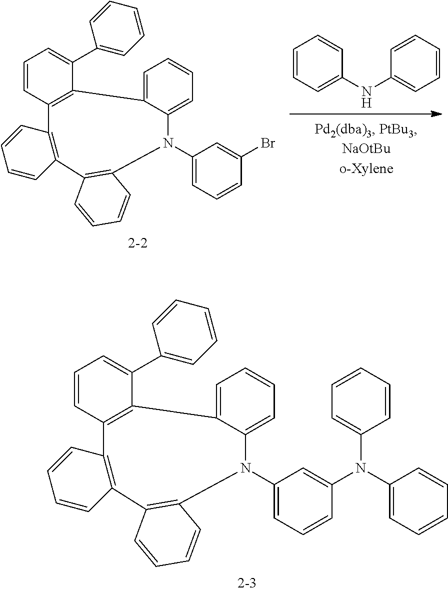 [SMILES: Brc1cccc(-n2c3ccccc3c3ccccc3c3cccc(-c4ccccc4)c3c3ccccc32)c1 ; c1ccc(Nc2ccccc2)cc1 ; c1ccc(-c2cccc3c4ccccc4c4ccccc4n(-c4cccc(N(c5ccccc5)c5ccccc5)c4)c4ccccc4c23)cc1]

Intermediate 2-2 (1 eq), diphenylamine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over MgSO₄ and then dried under reduced pressure. The resulting product was purified through column chromatography and recrystallized (solvent:dichloromethane:n-hexane) to obtain Intermediate 2-3. (Yield: 59%)

### Synthesis of Compound 2

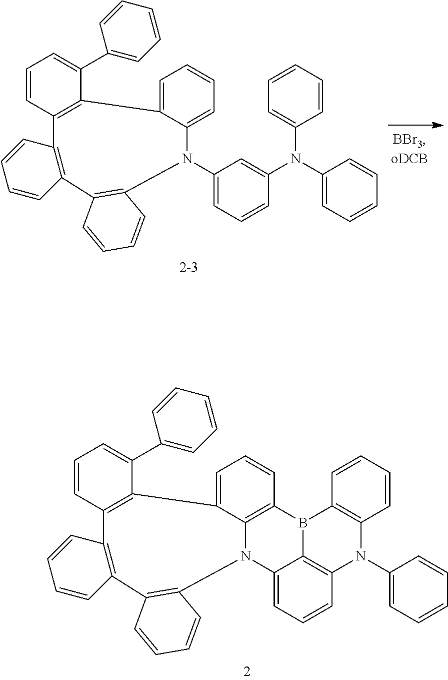 [SMILES: c1ccc(-c2cccc3c4ccccc4c4ccccc4n(-c4cccc(N(c5ccccc5)c5ccccc5)c4)c4ccccc4c23)cc1 ; c1ccc(-c2cccc3c4ccccc4c4ccccc4n4c5c(cccc5c23)B2c3ccccc3N(c3ccccc3)c3cccc-4c32)cc1]

Intermediate 2-3 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Compound 2. (Yield: 15%)

### (3) Synthesis of Compound 5

Fused polycyclic Compound 5 according to one or more embodiments may be synthesized by, for example, a synthesis scheme described herein.

### Synthesis of Intermediate 5-1

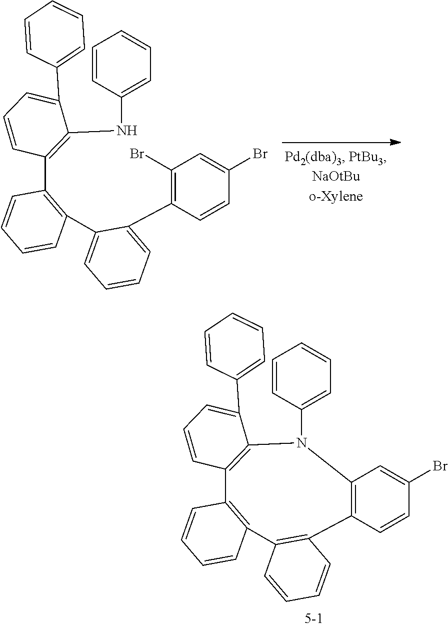 [SMILES: Brc1ccc(-c2ccccc2-c2ccccc2-c2cccc(-c3ccccc3)c2Nc2ccccc2)c(Br)c1 ; Brc1ccc2c3ccccc3c3ccccc3c3cccc(-c4ccccc4)c3n(-c3ccccc3)c2c1]

2,4-dibromo-N-phenyl-[1,1′: 2′,1″: 2″,1″: 3″,1″-quinquephenyl]-2′″-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 80° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 5-1. (Yield: 63%)

### Synthesis of Intermediate 5-2

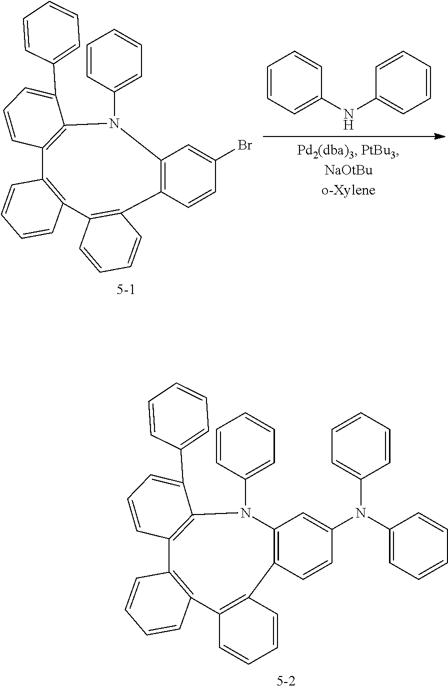 [SMILES: Brc1ccc2c3ccccc3c3ccccc3c3cccc(-c4ccccc4)c3n(-c3ccccc3)c2c1 ; c1ccc(Nc2ccccc2)cc1 ; c1ccc(-c2cccc3c4ccccc4c4ccccc4c4ccc(N(c5ccccc5)c5ccccc5)cc4n(-c4ccccc4)c23)cc1]

Intermediate 5-1 (1 eq), diphenylamine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. The mixture was cooled, and then dried under reduced pressure to remove to remove o-Xylene.

Thereafter, the resulting product was diluted with ethyl acetate and washed three times with water to obtain an organic layer, which was then dried over MgSO₄ and then dried under reduced pressure. The resulting product was purified through column chromatography and recrystallized (solvent:dichloromethane:n-hexane) to obtain Intermediate 5-2. (Yield: 60%)

### Synthesis of Compound 5

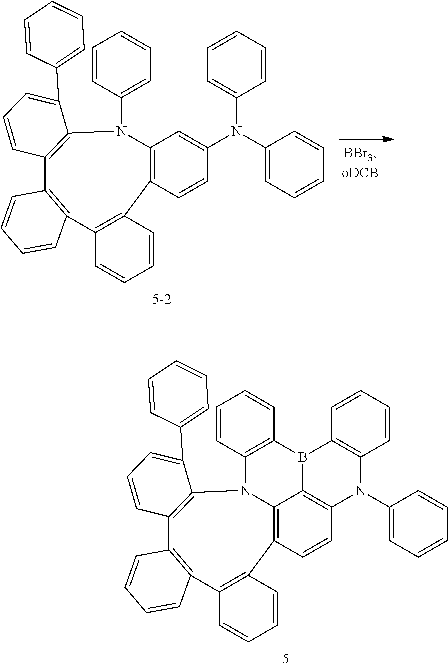 [SMILES: c1ccc(-c2cccc3c4ccccc4c4ccccc4c4ccc(N(c5ccccc5)c5ccccc5)cc4n(-c4ccccc4)c23)cc1 ; c1ccc(-c2cccc3c4ccccc4c4ccccc4c4ccc5c6c4n(c23)-c2ccccc2B6c2ccccc2N5c2ccccc2)cc1]

Intermediate 5-2 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Compound 5. (Yield: 15%)

### (4) Synthesis of Compound 6

Fused polycyclic compound 6 according to one or more embodiments may be synthesized by, for example, a synthesis scheme described herein.

### Synthesis of Intermediate 6-1

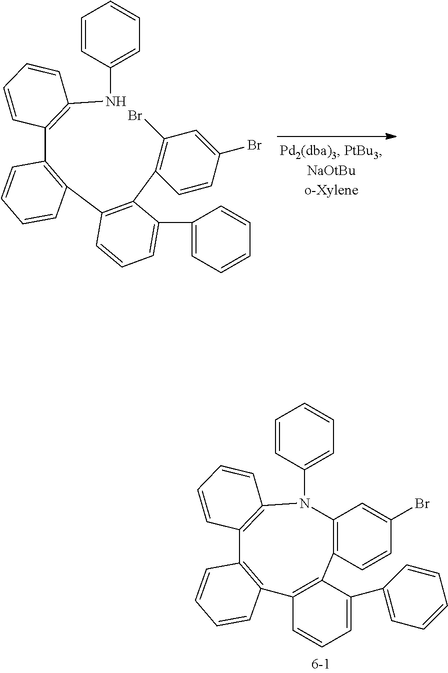 [SMILES: Brc1ccc(-c2c(-c3ccccc3)cccc2-c2ccccc2-c2ccccc2Nc2ccccc2)c(Br)c1 ; Brc1ccc2c3c(-c4ccccc4)cccc3c3ccccc3c3ccccc3n(-c3ccccc3)c2c1]

2″,4′″-dibromo-N,3″-diphenyl-[1,1′: 2′,1″: 2″,1′″-quaterphenyl]-2-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 80° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 6-1. (Yield: 64%)

### Synthesis of Intermediate 6-2

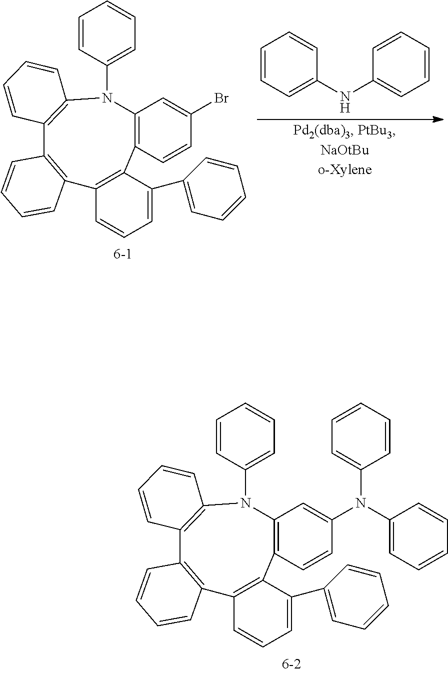

Intermediate 6-1 (1 eq), diphenylamine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over MgSO₄ and then dried under reduced pressure. The resulting product was purified through column chromatography and recrystallized (solvent:dichloromethane:n-hexane) to obtain Intermediate 6-2. (Yield: 60%)

### Synthesis of Compound 6

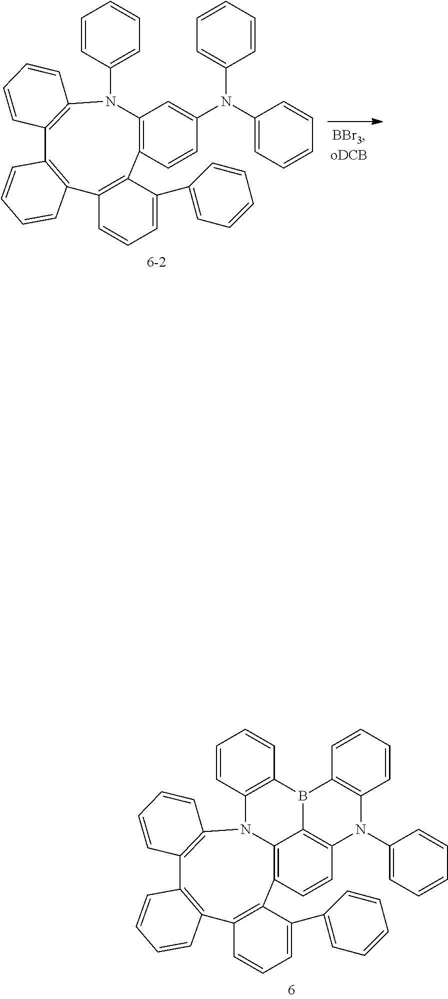 [SMILES: c1ccc(-c2cccc3c4ccccc4c4ccccc4n(-c4ccccc4)c4cc(N(c5ccccc5)c5ccccc5)ccc4c23)cc1 ; c1ccc(-c2cccc3c4ccccc4c4ccccc4n4c5c6c(ccc5c23)N(c2ccccc2)c2ccccc2B6c2ccccc2-4)cc1]

Intermediate 6-2 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Compound 6. (Yield: 15%)

### (5) Synthesis of Compound 12

Fused polycyclic Compound 12 according to one or more embodiments may be synthesized by, for example, a synthesis scheme described herein.

### Synthesis of Intermediate 12-1

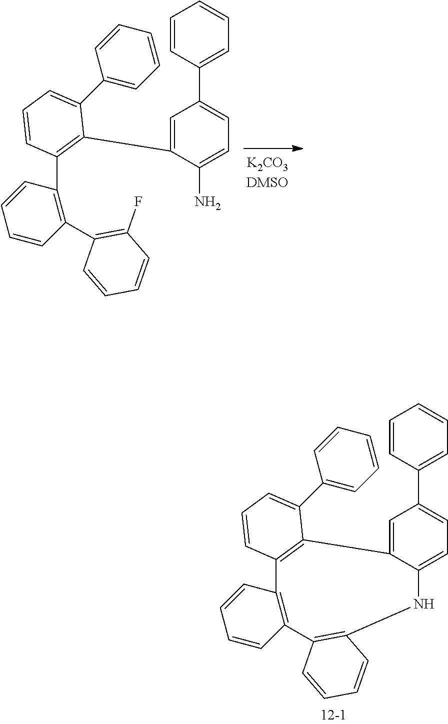 [SMILES: Nc1ccc(-c2ccccc2)cc1-c1c(-c2ccccc2)cccc1-c1ccccc1-c1ccccc1F ; c1ccc(-c2ccc3[nH]c4ccccc4c4ccccc4c4cccc(-c5ccccc5)c4c3c2)cc1]

2-fluoro-3″-phenyl-[1,1′: 2′, 1 “: 2”, 1″: 3″,1′″-quinquephenyl]-6″-amine (1 eq) and potassium carbonate (K₂CO₃, 3 eq) were dissolved in dimethyl sulfoxide (DMSO) and stirred at 160° C. for 24 hours in a nitrogen atmosphere. The mixture was cooled, and then dried under reduced pressure to remove dimethyl sulfoxide. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 12-1. (Yield: 60%)

### Synthesis of Intermediate 12-2

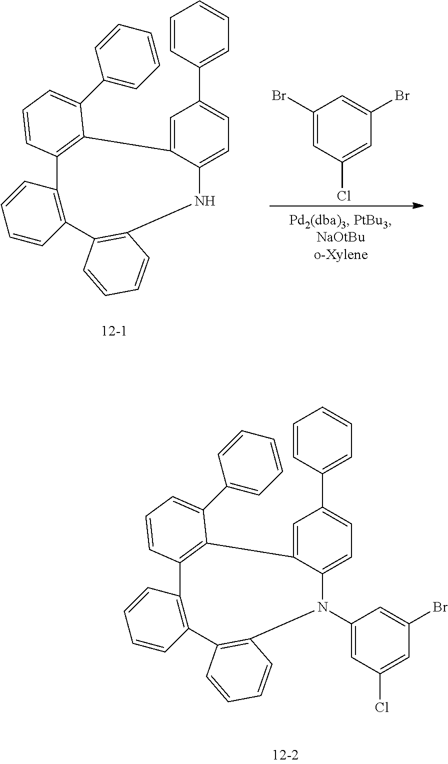 [SMILES: c1ccc(-c2ccc3[nH]c4ccccc4c4ccccc4c4cccc(-c5ccccc5)c4c3c2)cc1 ; Clc1cc(Br)cc(Br)c1 ; Clc1cc(Br)cc(-n2c3ccccc3c3ccccc3c3cccc(-c4ccccc4)c3c3cc(-c4ccccc4)ccc32)c1]

Intermediate 12-1 (1 eq), 1,3-dibromo-5-chlorobenzene (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 80° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 12-2. (Yield: 58%)

### Synthesis of Intermediate 12-3

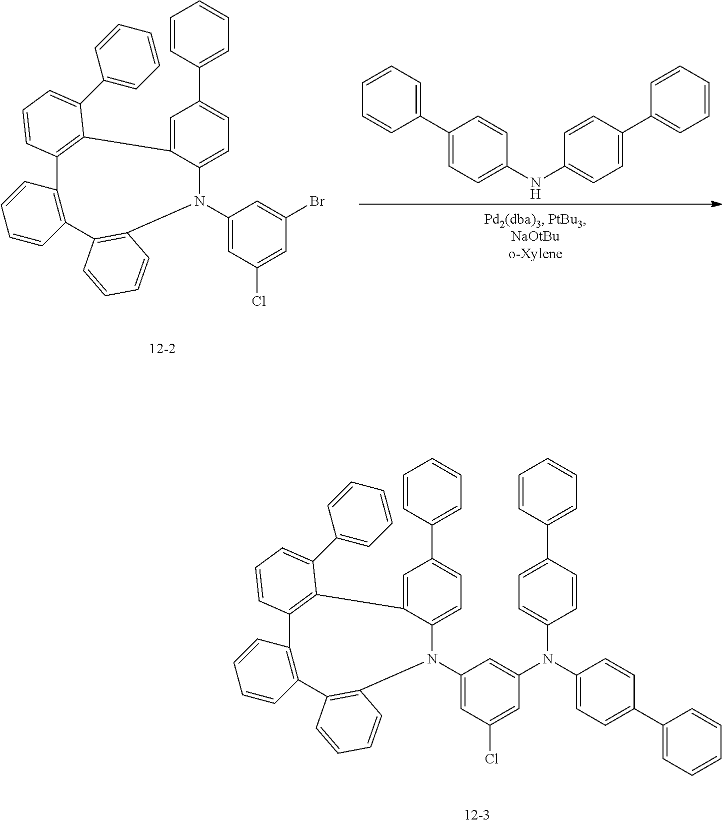 [SMILES: Clc1cc(Br)cc(-n2c3ccccc3c3ccccc3c3cccc(-c4ccccc4)c3c3cc(-c4ccccc4)ccc32)c1 ; c1ccc(-c2ccc(Nc3ccc(-c4ccccc4)cc3)cc2)cc1 ; Clc1cc(N(c2ccc(-c3ccccc3)cc2)c2ccc(-c3ccccc3)cc2)cc(-n2c3ccccc3c3ccccc3c3cccc(-c4ccccc4)c3c3cc(-c4ccccc4)ccc32)c1]

Intermediate 12-2 (1 eq), di([1,1′-biphenyl]-4-yl)amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over MgSO₄ and then dried under reduced pressure. The resulting product was purified through column chromatography and recrystallized (solvent:dichloromethane:n-hexane) to obtain Intermediate 12-3. (Yield: 56%)

### Synthesis of Intermediate 12-4

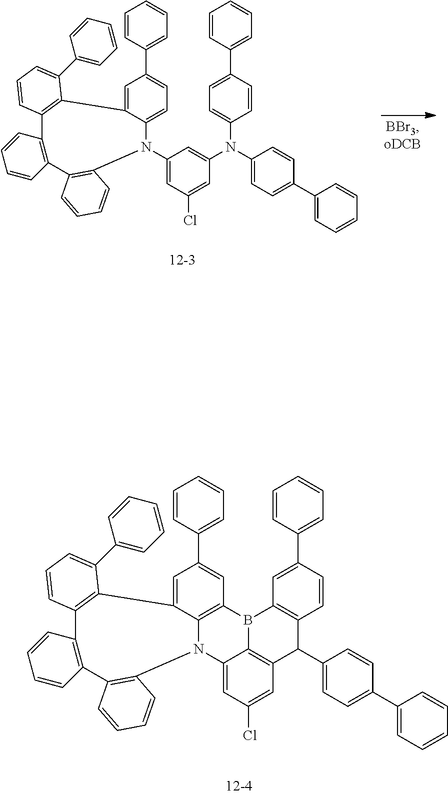 [SMILES: Clc1cc(N(c2ccc(-c3ccccc3)cc2)c2ccc(-c3ccccc3)cc2)cc(-n2c3ccccc3c3ccccc3c3cccc(-c4ccccc4)c3c3cc(-c4ccccc4)ccc32)c1 ; Clc1cc2c3c(c1)-n1c4ccccc4c4ccccc4c4cccc(-c5ccccc5)c4c4cc(-c5ccccc5)cc(c41)B3c1cc(-c3ccccc3)ccc1C2c1ccc(-c2ccccc2)cc1]

Intermediate 12-3 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization, thereby obtaining Intermediate 12-4. (Yield: 46%)

### Synthesis of Compound 12

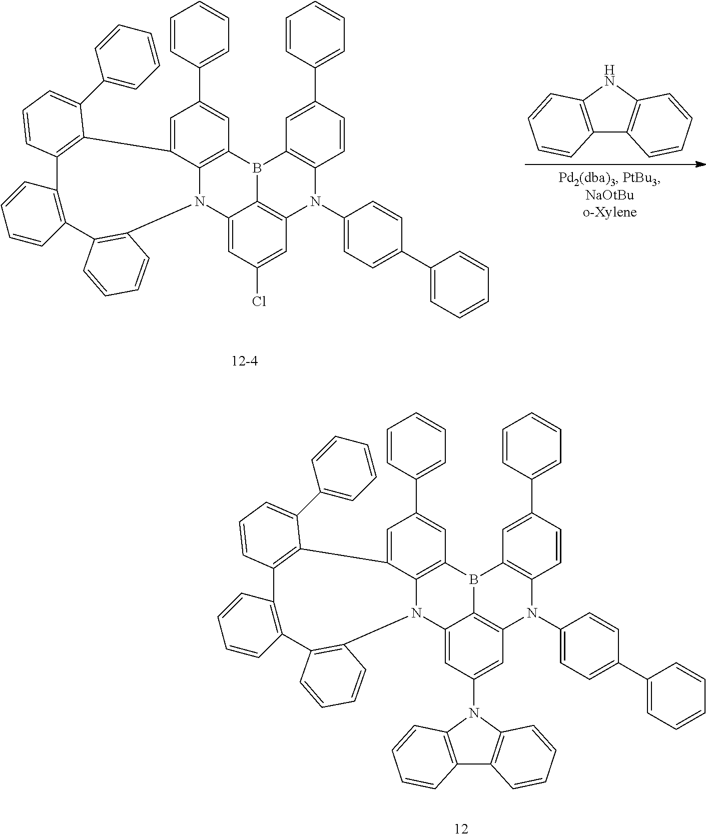 [SMILES: Clc1cc2c3c(c1)-n1c4ccccc4c4ccccc4c4cccc(-c5ccccc5)c4c4cc(-c5ccccc5)cc(c41)B3c1cc(-c3ccccc3)ccc1N2c1ccc(-c2ccccc2)cc1 ; c1ccc2c(c1)[nH]c1ccccc12 ; c1ccc(-c2ccc(N3c4ccc(-c5ccccc5)cc4B4c5c3cc(-n3c6ccccc6c6ccccc63)cc5-n3c5ccccc5c5ccccc5c5cccc(-c6ccccc6)c5c5cc(-c6ccccc6)cc4c53)cc2)cc1]

Intermediate 12-4 (1 eq), 9H-carbazole (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over magnesium sulfate (MgSO₄) and then dried under reduced pressure. The resulting product was purified through column chromatography and recrystallized (solvent:dichloromethane:n-hexane) to obtain Compound 12. (Yield: 12%)

### (6) Synthesis of Compound 29

Fused polycyclic Compound 29 according to one or more embodiments may be synthesized by, for example, a synthesis scheme described herein.

### Synthesis of Intermediate 29-1

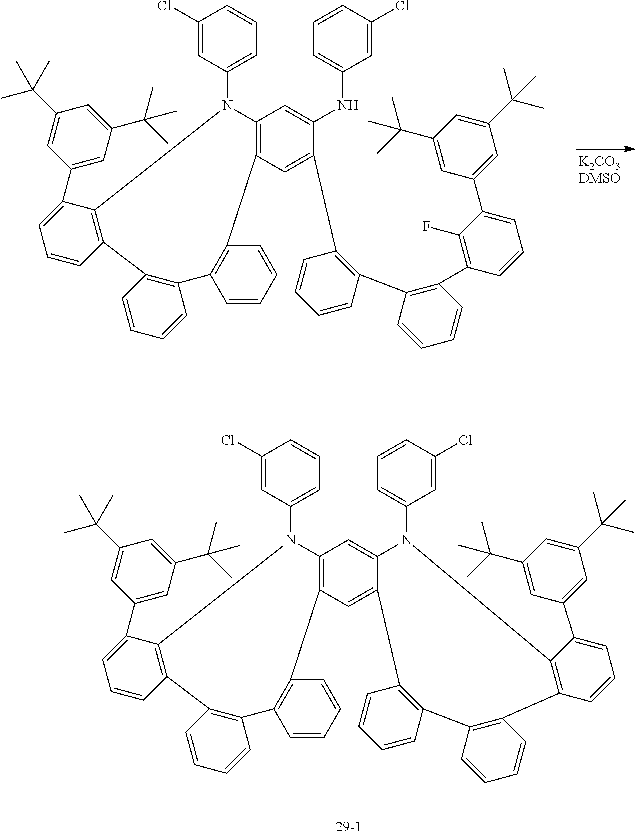

N,9-bis(3-chlorophenyl)-6-(3′″,5′″-di-tert-butyl-2″-fluoro-[1,1′: 2′,1″: 3″,1′″-quaterphenyl]-2-yl)-10-(3,5-di-tert-butylphenyl)-9H-tetrabenzo[b,d,f,h]azonin-7-amine (1 eq) and potassium carbonate (K₂CO₃, 3 eq) were dissolved in dimethyl sulfoxide (DMSO) and stirred at 160° C. for 24 hours in a nitrogen atmosphere. The mixture was cooled, and then dried under reduced pressure to remove dimethyl sulfoxide. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 29-1. (Yield: 55%)

### Synthesis of Intermediate 29-2

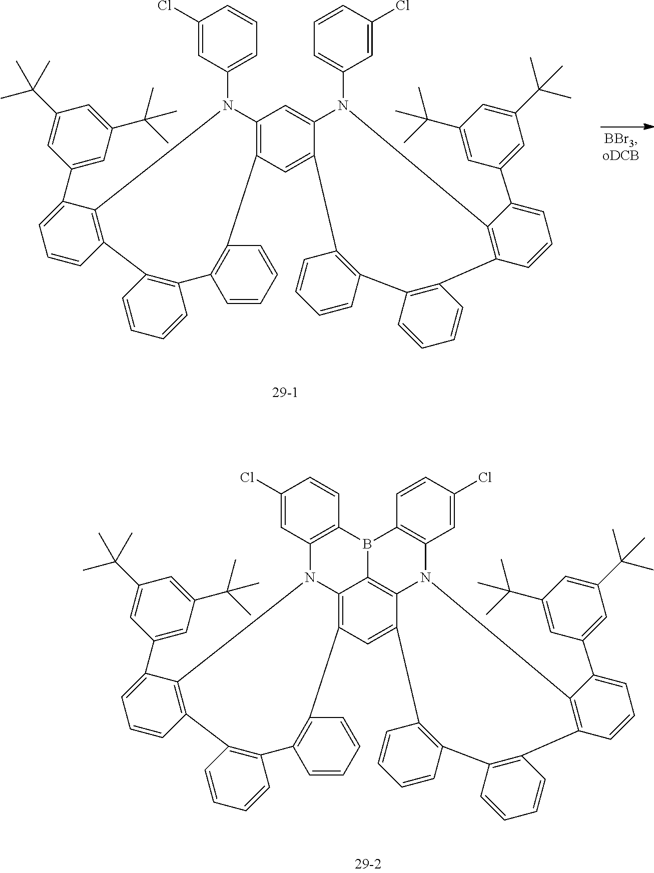

Intermediate 29-1 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Intermediate 29-2. (Yield: 41%)

### Synthesis of Compound 29

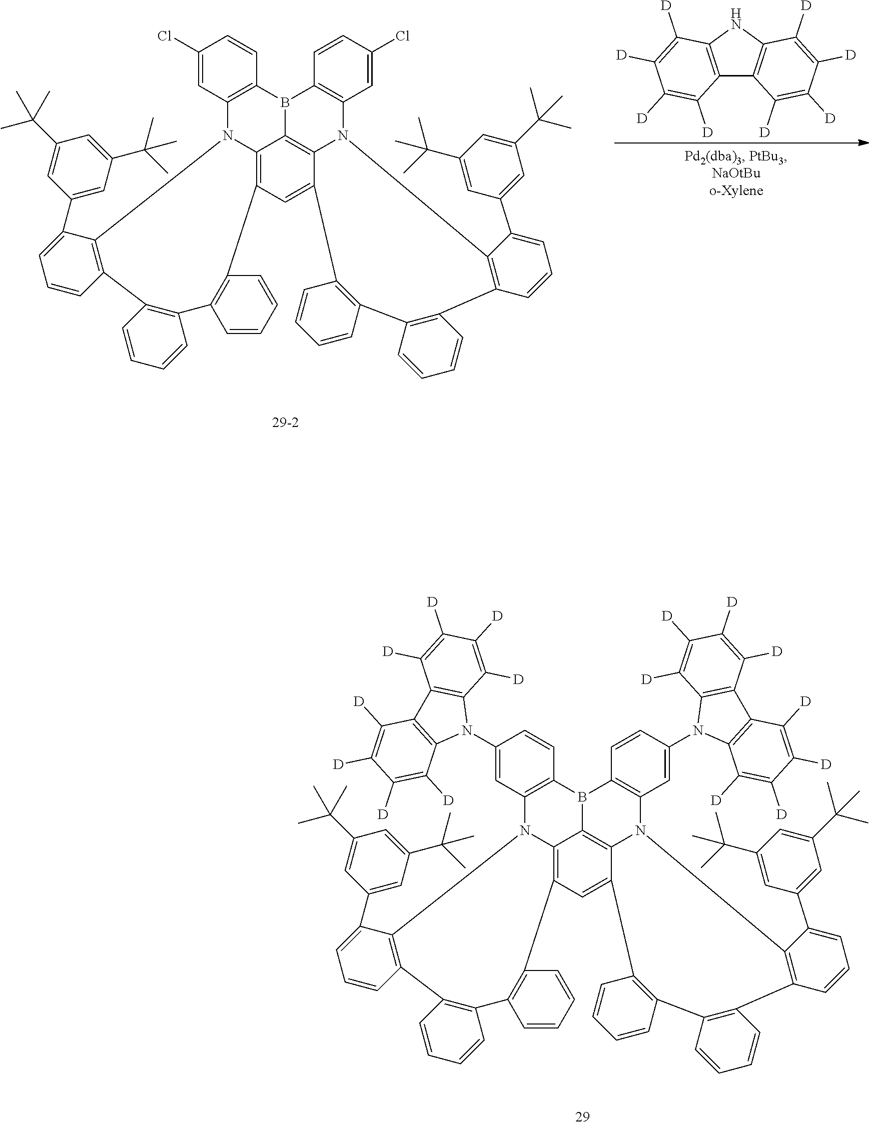

Intermediate 29-2 (1 eq), 9H-carbazole-1,2,3,4,5,6,7,8-d8 (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over magnesium sulfate (MgSO₄) and then dried under reduced pressure. The resulting product was purified through column chromatography and recrystallized (solvent:dichloromethane:n-hexane) to obtain Compound 29. (Yield: 9%)

### (7) Synthesis of Compound 43

Fused polycyclic compound 43 according to one or more embodiments may be synthesized by, for example, a synthesis schedule described herein.

### Synthesis of Intermediate 43-1

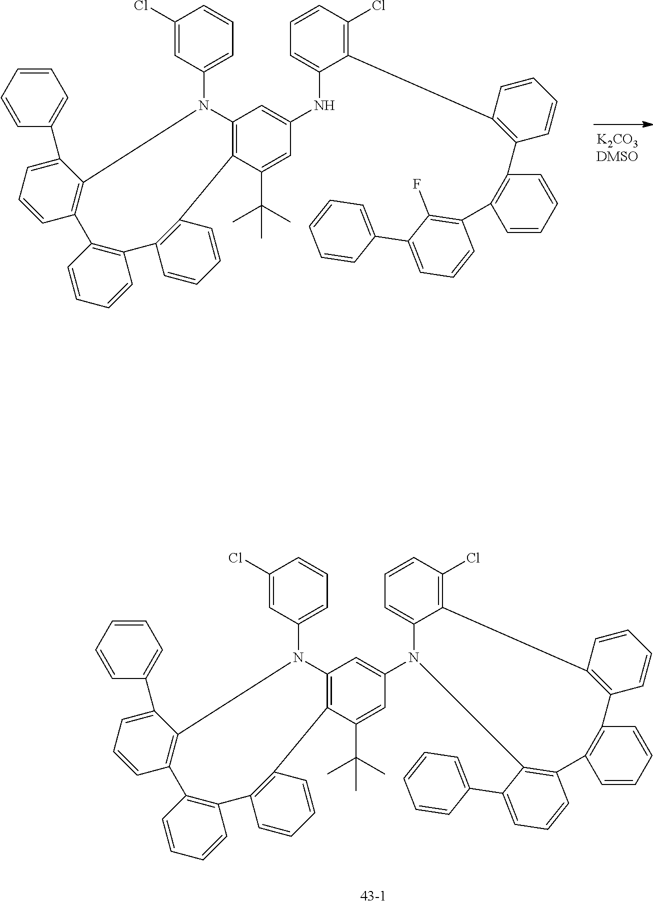 [SMILES: CC(C)(C)c1cc(Nc2cccc(Cl)c2-c2ccccc2-c2ccccc2-c2cccc(-c3ccccc3)c2F)cc2c1c1ccccc1c1ccccc1c1cccc(-c3ccccc3)c1n2-c1cccc(Cl)c1 ; CC(C)(C)c1cc(-n2c3cccc(Cl)c3c3ccccc3c3ccccc3c3cccc(-c4ccccc4)c32)cc2c1c1ccccc1c1ccccc1c1cccc(-c3ccccc3)c1n2-c1cccc(Cl)c1]

5-(tert-butyl)-N-(6-chloro-2″′-fluoro-[1,1′: 2′,1″: 2″,1″: 3′,1″-quinquephenyl]-2-yl)-9-(3-chlorophenyl)-10-phenyl-9H-tetrabenzo[b,d,f,h]azonin-7-amine (1 eq) and potassium carbonate (K₂CO₃, 3 eq) were dissolved in dimethyl sulfoxide (DMSO) and stirred at 160° C. for 24 hours in a nitrogen atmosphere. The mixture was cooled, and then dried under reduced pressure to remove dimethyl sulfoxide. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 43-1. (Yield: 57%)

### Synthesis of Intermediate 43-2

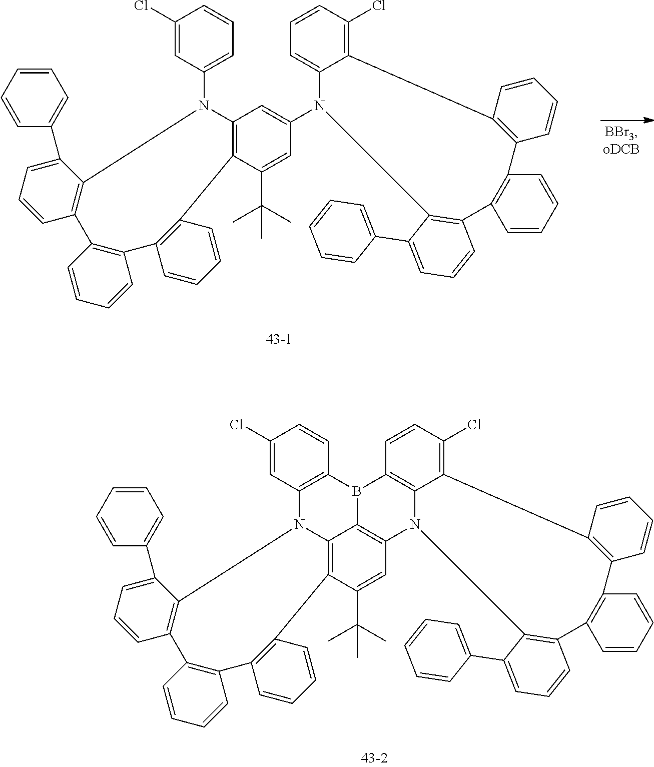 [SMILES: CC(C)(C)c1cc(-n2c3cccc(Cl)c3c3ccccc3c3ccccc3c3cccc(-c4ccccc4)c32)cc2c1c1ccccc1c1ccccc1c1cccc(-c3ccccc3)c1n2-c1cccc(Cl)c1 ; CC(C)(C)c1cc2c3c4c1c1ccccc1c1ccccc1c1cccc(-c5ccccc5)c1n4-c1cc(Cl)ccc1B3c1ccc(Cl)c3c4ccccc4c4ccccc4c4cccc(-c5ccccc5)c4n-2c13]

Intermediate 43-1 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Intermediate 43-2. (Yield: 42%)

### Synthesis of Compound 43

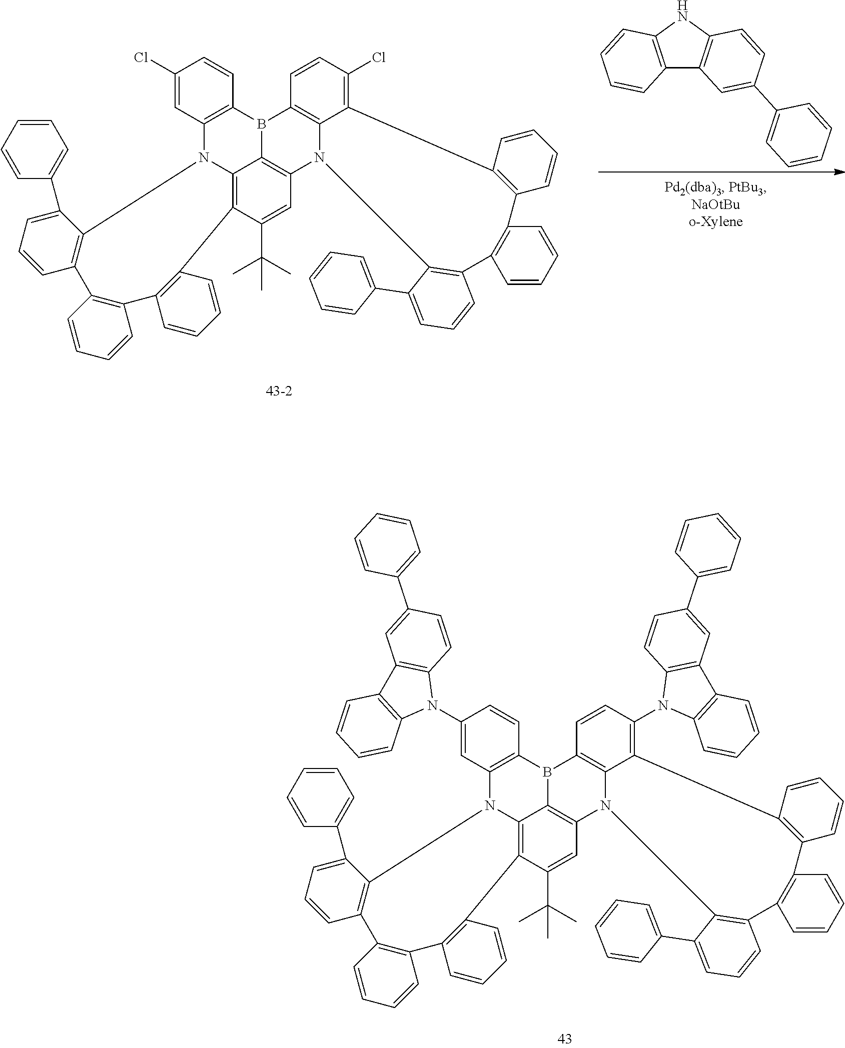 [SMILES: CC(C)(C)c1cc2c3c4c1c1ccccc1c1ccccc1c1cccc(-c5ccccc5)c1n4-c1cc(Cl)ccc1B3c1ccc(Cl)c3c4ccccc4c4ccccc4c4cccc(-c5ccccc5)c4n-2c13 ; c1ccc(-c2ccc3[nH]c4ccccc4c3c2)cc1 ; CC(C)(C)c1cc2c3c4c1c1ccccc1c1ccccc1c1cccc(-c5ccccc5)c1n4-c1cc(-n4c5ccccc5c5cc(-c6ccccc6)ccc54)ccc1B3c1ccc(-n3c4ccccc4c4cc(-c5ccccc5)ccc43)c3c4ccccc4c4ccccc4c4cccc(-c5ccccc5)c4n-2c13]

Intermediate 43-2 (1 eq), 3-phenyl-9H-carbazole (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over magnesium sulfate (MgSO₄) and then dried under reduced pressure. The resulting product was purified through column chromatography and recrystallized (solvent:dichloromethane:n-Hexane) to obtain Compound 43. (Yield: 10%)

### (8) Synthesis of Compound 50

Fused polycyclic compound 50 according to one or more embodiments may be synthesized by, for example, a synthesis scheme described herein.

### Synthesis of Intermediate 50-1

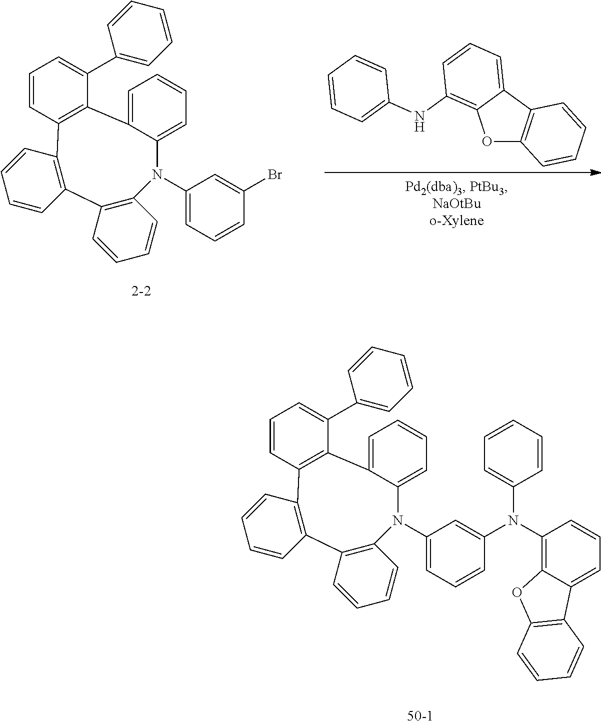 [SMILES: Brc1cccc(-n2c3ccccc3c3ccccc3c3cccc(-c4ccccc4)c3c3ccccc32)c1 ; c1ccc(Nc2cccc3c2oc2ccccc23)cc1 ; c1ccc(-c2cccc3c4ccccc4c4ccccc4n(-c4cccc(N(c5ccccc5)c5cccc6c5oc5ccccc56)c4)c4ccccc4c23)cc1]

Intermediate 2-2 (1 eq), N-phenyl-dibenzo[b,d]furan-4-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over MgSO₄ and then dried under reduced pressure. The resulting product was purified through column chromatography and recrystallized (solvent:dichloromethane:n-hexane) to obtain Intermediate 50-1. (Yield: 57%)

### Synthesis of Compound 50

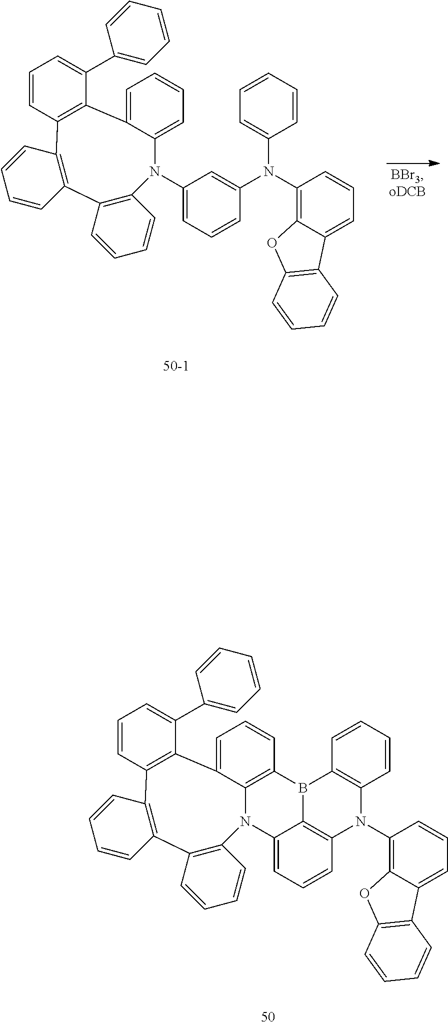 [SMILES: c1ccc(-c2cccc3c4ccccc4c4ccccc4n(-c4cccc(N(c5ccccc5)c5cccc6c5oc5ccccc56)c4)c4ccccc4c23)cc1 ; c1ccc(-c2cccc3c4ccccc4c4ccccc4n4c5c(cccc5c23)B2c3ccccc3N(c3cccc5c3oc3ccccc35)c3cccc-4c32)cc1]

Intermediate 50-1 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Compound 50. (Yield: 13%)

### (9) Synthesis of Compound 57

Fused polycyclic compound 57 according to one or more embodiments may be synthesized by, for example, a synthesis scheme described herein.

### Synthesis of Intermediate 57-1

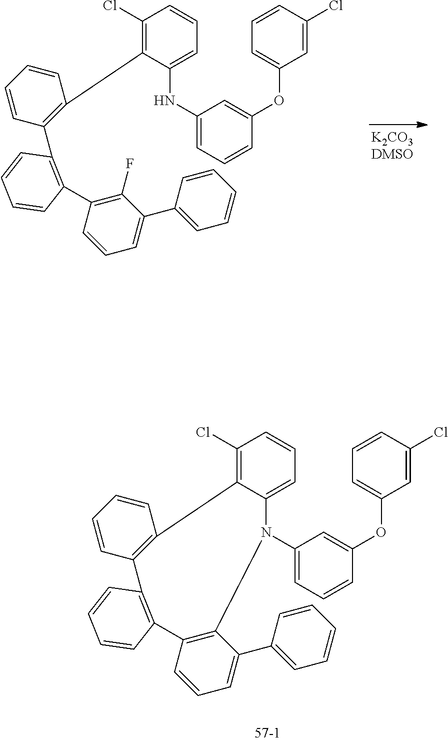 [SMILES: Fc1c(-c2ccccc2)cccc1-c1ccccc1-c1ccccc1-c1c(Cl)cccc1Nc1cccc(Oc2cccc(Cl)c2)c1 ; Clc1cccc(Oc2cccc(-n3c4cccc(Cl)c4c4ccccc4c4ccccc4c4cccc(-c5ccccc5)c43)c2)c1]

6-chloro-N-(3-(3-chlorophenoxy)phenyl)-2″-fluoro-[1, 1′: 2′,1″: 2″,1′″: 3′″, 1″″-quinquephenyl]-2-amine (1 eq) and potassium carbonate (K₂CO₃, 3 eq) were dissolved in dimethyl sulfoxide (DMSO) and stirred at 160° C. for 24 hours in a nitrogen atmosphere. The mixture was cooled, and then dried under reduced pressure to remove dimethyl sulfoxide. Thereafter, the resulting product was diluted with ethyl acetate and washed three times with water to obtain an organic layer, and then the organic layer was dried over magnesium sulfate (MgSO₄) and then dried under reduced pressure. The resulting product was purified through column chromatography and recrystallized (solvent:dichloromethane:n-hexane) to obtain Intermediate 57-1. (Yield: 56%)

### Synthesis of Intermediate 57-2

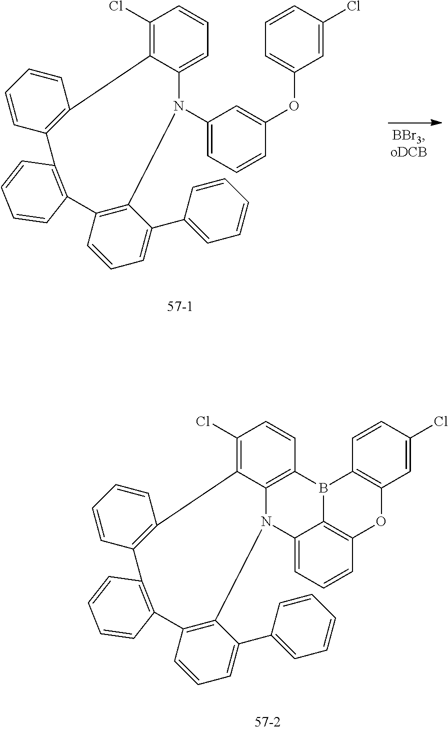 [SMILES: Clc1cccc(Oc2cccc(-n3c4cccc(Cl)c4c4ccccc4c4ccccc4c4cccc(-c5ccccc5)c43)c2)c1 ; Clc1ccc2c(c1)Oc1cccc3c1B2c1ccc(Cl)c2c4ccccc4c4ccccc4c4cccc(-c5ccccc5)c4n-3c12]

Intermediate 57-1 (1 eq) was dissolved in ortho dichlorobenzene (oDCB) in a flask, and the flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resultant product to 0° C., triethylamine was slowly dropped into the flask until exotherm stopped to complete the reaction. Thereafter, n-hexane and methanol were added to precipitate and filtrate the mixture to obtain a solid content. The obtained solid content was purified through silica filtration and then purified through MC/Hex (methylenechloride/hexane) recrystallization to obtain Intermediate 57-2. (Yield: 42%)

### Synthesis of Compound 57

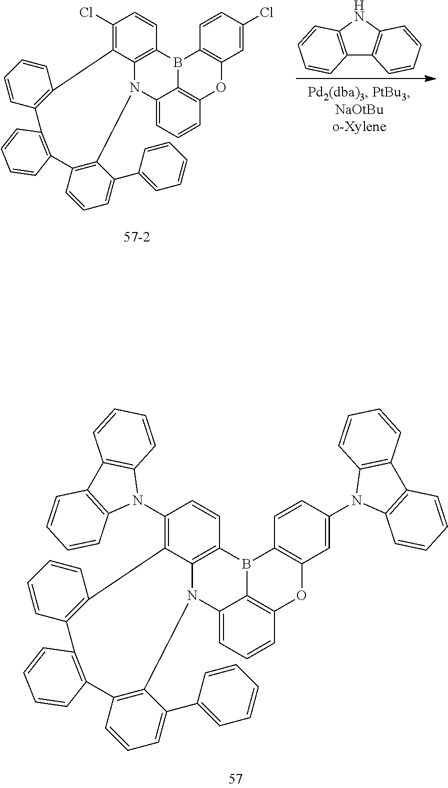 [SMILES: Clc1ccc2c(c1)Oc1cccc3c1B2c1ccc(Cl)c2c4ccccc4c4ccccc4c4cccc(-c5ccccc5)c4n-3c12 ; c1ccc2c(c1)[nH]c1ccccc12 ; c1ccc(-c2cccc3c4ccccc4c4ccccc4c4c(-n5c6ccccc6c6ccccc65)ccc5c4n(c23)-c2cccc3c2B5c2ccc(-n4c5ccccc5c5ccccc54)cc2O3)cc1]

Intermediate 57-2 (1 eq), 9H-carbazole (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. The mixture was cooled, and then dried under reduced pressure to remove to remove o-Xylene. Thereafter, the resulting product was diluted with ethyl acetate and washed three times with water to obtain an organic layer, which was then dried over magnesium sulfate (MgSO₄) and then dried under reduced pressure. The resulting product was purified through column chromatography and recrystallized (solvent:dichloromethane:n-Hexane) to obtain Compound 57. (Yield: 10%)

### 2. Preparation and Evaluation of Light Emitting Element

Light emitting elements of one or more embodiments including a fused polycyclic compound of one or more embodiments in an emission layer were each prepared using a method described herein. Light emitting elements of Examples 1 to 9 were each prepared respectively using fused polycyclic compounds of Compounds 1, 2, 5, 6, 12, 29, 43, 50, and 57, which are Example Compounds described above, as a dopant material of an emission layer. Comparative Examples 1 to 7 correspond to light emitting elements prepared respectively using Comparative Example Compound C1 to C7 as a dopant material of an emission layer.

### Example Compound

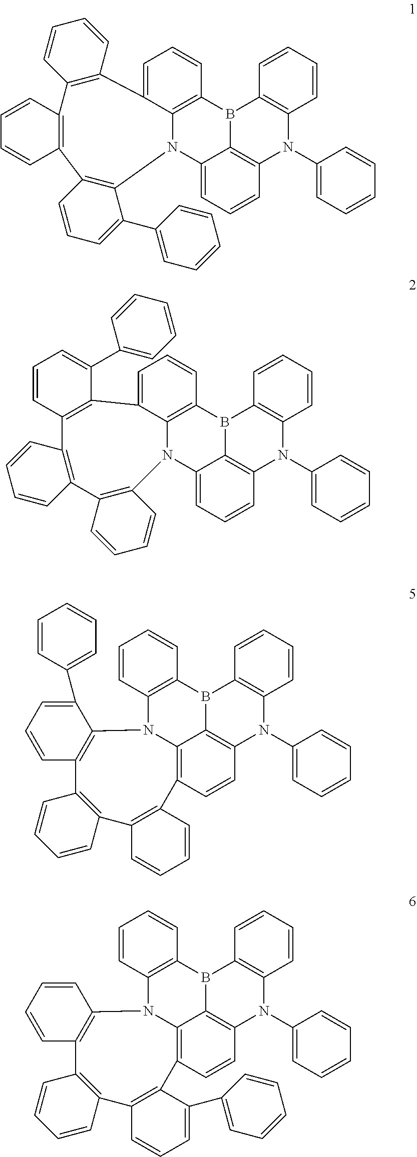

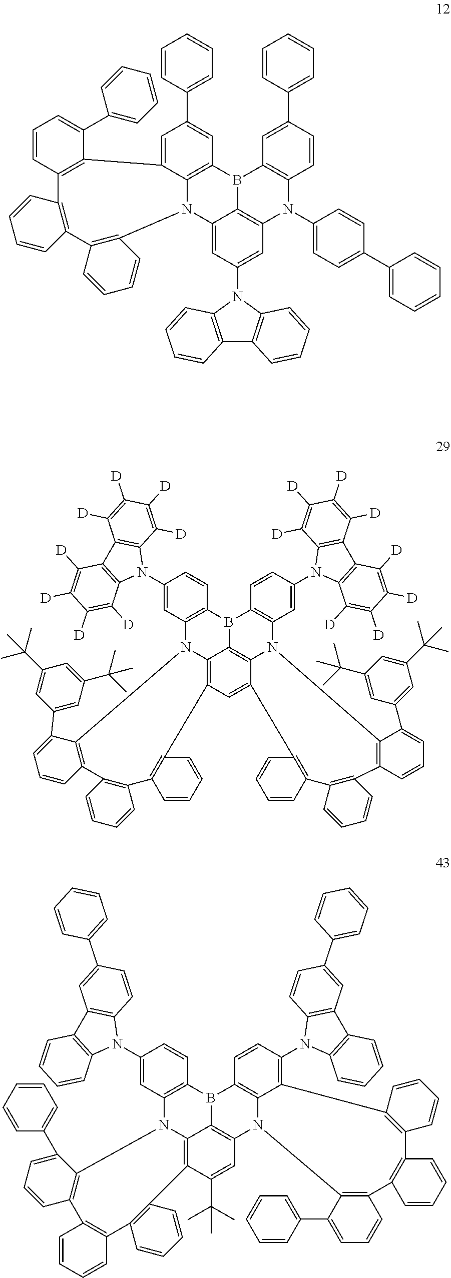

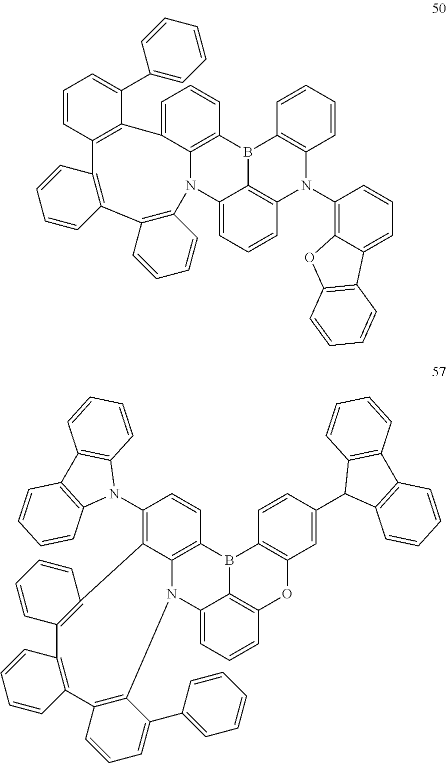 [SMILES: c1ccc(-c2cccc3c4ccccc4c4ccccc4n4c5c(cccc5c23)B2c3ccccc3N(c3cccc5c3oc3ccccc35)c3cccc-4c32)cc1 ; c1ccc(-c2cccc3c4ccccc4c4ccccc4c4c(-n5c6ccccc6c6ccccc65)ccc5c4n(c23)-c2cccc3c2B5c2ccc(C4c5ccccc5-c5ccccc54)cc2O3)cc1]

### Comparative Example Compound

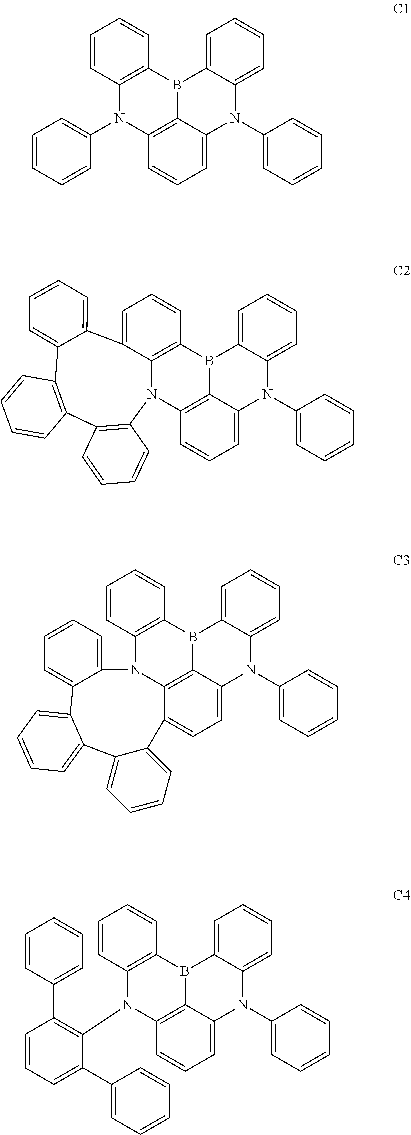 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4ccccc4c4ccccc4c4cccc3c42)cc1 ; c1ccc(N2c3ccccc3B3c4ccccc4-n4c5ccccc5c5ccccc5c5ccccc5c5ccc2c3c54)cc1 ; c1ccc(-c2cccc(-c3ccccc3)c2N2c3ccccc3B3c4ccccc4N(c4ccccc4)c4cccc2c43)cc1]

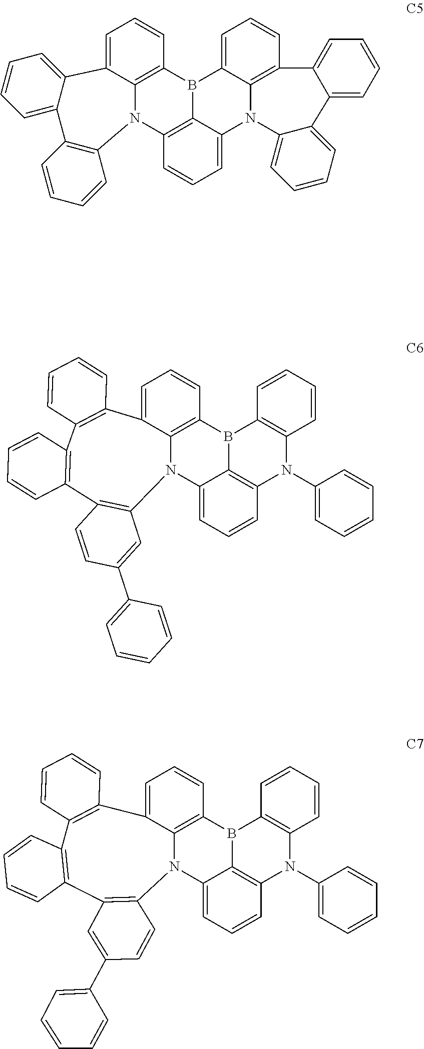 [SMILES: c1ccc2c(c1)-c1ccccc1N1c3cccc4c3B(c3cccc-2c31)c1cccc2c1N4c1ccccc1-c1ccccc1-2 ; c1ccc(-c2ccc3c4ccccc4c4ccccc4c4cccc5c4n(c3c2)-c2cccc3c2B5c2ccccc2N3c2ccccc2)cc1 ; c1ccc(-c2ccc3c(c2)c2ccccc2c2ccccc2c2cccc4c2n3-c2cccc3c2B4c2ccccc2N3c2ccccc2)cc1]

### Manufacture of Light Emitting Elements

As for each of light emitting elements of Examples and Comparative Examples, as an anode, a glass substrate having an ITO electrode (Corning, 15Ω/cm², 1200 Å) formed thereon was cut to a size of about 50 mm×50 mm×0.7 mm, subjected to ultrasonic cleaning with isopropyl alcohol and then pure water for 5 minutes each and ultraviolet irradiation for 30 minutes, and then exposed to ozone for cleaning to be then mounted on a vacuum deposition apparatus.

On the anode, a hole injection layer having a thickness of 300 Å was formed through the deposition of NPB, and on the hole injection layer, a hole transport layer having a thickness of 200 Å was formed through the deposition of H-1-1, and then on the hole transport layer, an electron blocking layer having a thickness of 100 Å was formed through the deposition of CzSi.

Thereafter, an emission layer having a thickness of 200 Å was formed through the co-deposition of a host mixture in which a second compound and a third compound according to one or more embodiments were mixed in a weight ratio of 1:1, a fourth compound, and Example Compound or Comparative Example Compound in a weight ratio of 82:15:3, and on the emission layer, a hole blocking layer having a thickness of 200 Å was formed through the deposition of TSPO1. Then, on the hole blocking layer, an electron transport layer having a thickness of 300 Å was formed through the deposition of TPBi, and then on the electron transport layer, an electron injection layer having a thickness of 10 Å was formed through the deposition of LiF. Thereafter, a second electrode EL2 was formed to have a thickness of 3000 Å using Al to form a LiF/Al electrode. Thereafter, a capping layer having a thickness of 700 Å was formed using P4 on an upper portion of the second electrode.

Each layer was formed through vacuum evaporation. Meanwhile, HT1 selected from among the compounds of Compound Group 2 described above was used as the second compound, ETH85 selected from among the compounds of Compound Group 3 described above was used as the third compound, and AD-37 among selected from among the compounds of Compound Group 4 described above was used as the fourth compound.

The compounds used in the preparation of the light emitting elements of Examples and Comparative Examples are disclosed herein. The following materials were used for the preparation of the light emitting elements after sublimation-purifying commercially available products.

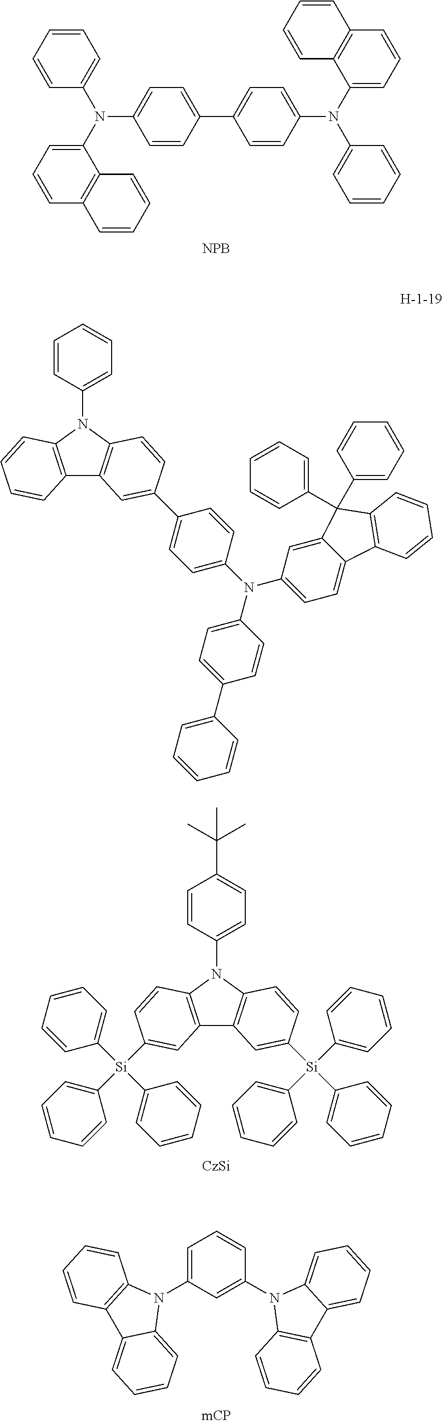

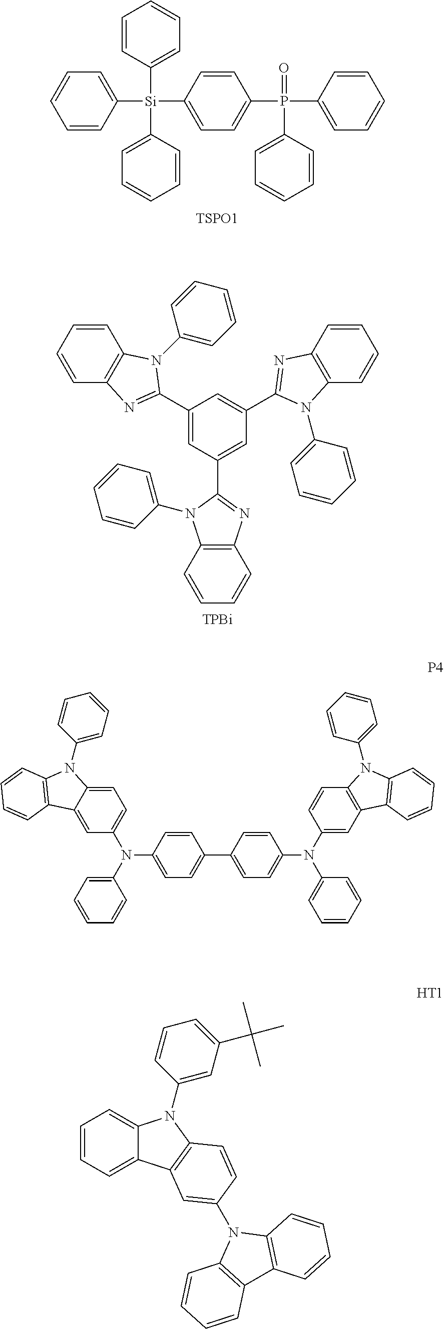

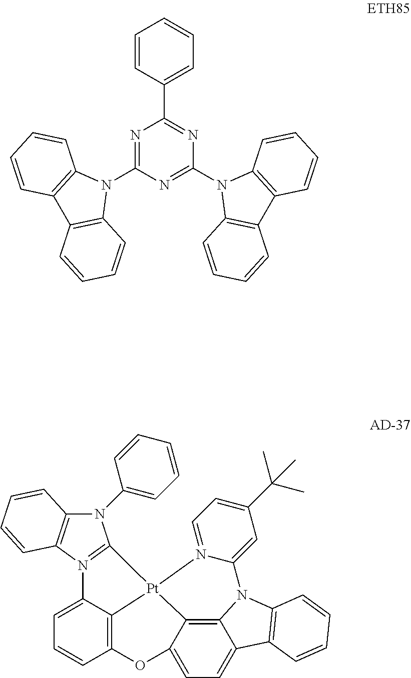

### Property Evaluation of Light Emitting Elements

### Evaluation of Physical Properties of Example Compounds and Comparative

### Example Compounds

Table 1 shows the physical properties of Example Compounds 1, 2, 5, 6, 12, 29, 43, 50, and 57 and Comparative Example Compounds C1 to C7.

In Table 1, the highest occupied molecular orbital (HOMO) energy level, lowest unoccupied molecular orbital (LUMO) energy level, lowest singlet excitation energy level (S₁ level), lowest triplet excitation energy level (T1 level), ΔE_{ST}, oscillator strength, and k_{RISC} of each of Example Compounds and Comparative Example Compounds were measured and are shown.

In Table 1, the lowest singlet excitation energy level (S₁) and the lowest triplet excitation energy level (T1) were measured using FluorEssence software on a Fluoromax+spectrometer from HORIBA equipped with a xenon light source and monochromators. The HOMO and LUMO energy levels were measured using Smart Manager software of SP2 electrochemical workstation equipment from ZIVE LAB. In Table 1, ΔEST indicates a difference between the lowest triplet excitation energy level (T1) and the lowest singlet excitation energy level (S1). In Table 1, the oscillator strength indicates an intensity of light emission at the singlet excitation energy level, and was simulated using time dependent-density functional theory (TD-DFT) methodology of Gaussian program with structure optimization at the B3LYP/6-311G(d,p) level. In Table 1, reverse intersystem crossing rate (k_{RISC}) indicates a rate constant when triplet energy is transferred from the triplet excitation energy level to the lowest singlet excitation energy level, and was also simulated and computed using TD-DFT methodology at the B3LYP/6-311G(d,p) level.

TABLE 1

| | | HOMO | LUMO | S1 | T1 | ΔE_{ST} | Oscillator | |
|---|---|---|---|---|---|---|---|---|
| | Compound | [eV] | [eV] | [eV] | [eV] | [eV] | strength | k_{RISC} [s⁻¹] |
| Example 1 | Compound 1 | −4.98 | −1.37 | 3.06 | 2.62 | 0.44 | 0.24 | 2.17E+05 |
| Example 2 | Compound 2 | −4.98 | −1.35 | 3.09 | 2.63 | 0.46 | 0.25 | 8.37E+04 |
| Example 3 | Compound 5 | −5.01 | −1.36 | 3.10 | 2.64 | 0.46 | 0.24 | 1.38E+05 |
| Example 4 | Compound 6 | −4.95 | −1.36 | 3.04 | 2.60 | 0.44 | 0.24 | 2.03E+05 |
| Example 5 | Compound 12 | −5.18 | −1.54 | 3.09 | 2.64 | 0.45 | 0.30 | 1.91E+05 |
| Example 6 | Compound 29 | −5.27 | −1.72 | 2.97 | 2.57 | 0.41 | 0.31 | 4.28E+05 |
| Example 7 | Compound 43 | −5.22 | −1.76 | 2.95 | 2.57 | 0.38 | 0.33 | 6.77E+05 |
| Example 8 | Compound 50 | −4.98 | −1.46 | 3.10 | 2.66 | 0.44 | 0.28 | 5.52E+05 |
| Example 9 | Compound 57 | −5.33 | −1.87 | 3.10 | 2.73 | 0.37 | 0.31 | 8.73E+05 |
| Comparative | Comparative | −5.00 | −1.37 | 3.10 | 2.62 | 0.48 | 0.19 | 2.26E+03 |
| Example 1 | Example | | | | | | | |
| | Compound C1 | | | | | | | |
| Comparative | Comparative | −4.99 | −1.37 | 3.07 | 2.62 | 0.45 | 0.25 | 1.26E+04 |
| Example 2 | Example | | | | | | | |
| | Compound C2 | | | | | | | |
| Comparative | Comparative | −4.97 | −1.37 | 3.06 | 2.60 | 0.46 | 0.18 | 3.44E+04 |
| Example 3 | Example | | | | | | | |
| | Compound C3 | | | | | | | |
| Comparative | Comparative | −5.01 | −1.37 | 3.09 | 2.63 | 0.46 | 0.19 | 4.89E+04 |
| Example 4 | Example | | | | | | | |
| | Compound C4 | | | | | | | |
| Comparative | Comparative | −5.28 | −1.88 | 2.85 | 2.40 | 0.45 | 0.18 | 3.87E+03 |
| Example 5 | Example | | | | | | | |
| | Compound C5 | | | | | | | |
| Comparative | Comparative | −5.00 | −1.38 | 3.07 | 2.63 | 0.44 | 0.21 | 5.11E+04 |
| Example 6 | Example | | | | | | | |
| | Compound C6 | | | | | | | |
| Comparative | Comparative | −4.99 | −1.39 | 3.06 | 2.62 | 0.44 | 0.20 | 4.61E+04 |
| Example 7 | Example | | | | | | | |
| | Compound C7 | | | | | | | |

Referring to Table 1, it is seen that Example Compounds included in Examples 1 to 9 each have greater values of oscillator strength than that of Comparative Example Compounds included in Comparative Examples 1 to 7. In addition, it is seen that Example compounds included in Examples 1 to 9 each have greater intersystem transition rate constants than that of Comparative Example Compounds included in Comparative Examples 1 to 7. Accordingly, it is expected that Example Compounds 1 to 9 each have stronger oscillator strength and faster intersystem transition rate than that of Comparative Example Compounds 1 to 7, and thus may have improved luminous efficiency and lifetime.

### Property Evaluation of Light Emitting Elements

Element efficiency and element lifetime of each of the light emitting elements prepared using Example Compounds 1, 2, 5, 6, 12, 29, 43, 50, and 57, and Comparative Example Compounds C₁ to C₇ described above were evaluated. Table 2 shows results of evaluation on light emitting elements for Examples 1 to 9 and Comparative Examples 1 to 7. In the property evaluation results for Examples and Comparative Examples shown in Table 2, driving voltage and current density were measured using V7000 OLED IVL Test System (Polaronix). To evaluate the properties of each of the light emitting elements prepared in Examples 1 to 9 and Comparative Examples 1 to 7, the driving voltage and efficiency (cd/A) were measured at a current density of 10 mA/cm², and a value comparing the time taken to reach 95% luminance deterioration from an initial value upon continuous operation at a current density of 10 mA/cm² with Comparative Example 1 was taken as a relative element life for the evaluation.

TABLE 2

| | Host (2nd | | | | | Light | |
|---|---|---|---|---|---|---|---|
| | compound:3rd | | | Driving | | emission | Lifetime |
| | compound = | 4th | 1st | voltage | Efficiency | wavelength | ratio |
| | 5:5) | compound | compound | (V) | (cd/A) | (nm) | (T95) |
| Example 1 | HT1/ETH85 | AD-37 | Compound 1 | 4.2 | 29.4 | 457 | 7.6 |
| Example 2 | HT1/ETH85 | AD-37 | Compound 2 | 4.2 | 28.5 | 457 | 7.1 |
| Example 3 | HT1/ETH85 | AD-37 | Compound 5 | 4.2 | 28.3 | 457 | 7.0 |
| Example 4 | HT1/ETH85 | AD-37 | Compound 6 | 4.3 | 28.1 | 457 | 7.1 |
| Example 5 | HT1/ETH85 | AD-37 | Compound 12 | 4.3 | 30.7 | 456 | 7.4 |
| Example 6 | HT1/ETH85 | AD-37 | Compound 29 | 4.1 | 31.3 | 458 | 7.9 |
| Example 7 | HT1/ETH85 | AD-37 | Compound 43 | 4.0 | 32.0 | 458 | 8.4 |
| Example 8 | HT1/ETH85 | AD-37 | Compound 50 | 4.3 | 29.5 | 455 | 7.2 |
| Example 9 | HT1/ETH85 | AD-37 | Compound 57 | 4.3 | 31.5 | 455 | 8.1 |
| Comparative | HT1/ETH85 | AD-37 | Comparative | 4.8 | 19.2 | 457 | 1 |
| Example 1 | | | Example | | | | |
| | | | Compound C1 | | | | |
| Comparative | HT1/ETH85 | AD-37 | Comparative | 4.7 | 20.6 | 457 | 2.3 |
| Example 2 | | | Example | | | | |
| | | | Compound C2 | | | | |
| Comparative | HT1/ETH85 | AD-37 | Comparative | 4.6 | 22.9 | 457 | 3.0 |
| Example 3 | | | Example | | | | |
| | | | Compound C3 | | | | |
| Comparative | HT1/ETH85 | AD-37 | Comparative | 4.4 | 24.3 | 457 | 4.4 |
| Example 4 | | | Example | | | | |
| | | | Compound C4 | | | | |
| Comparative | HT1/ETH85 | AD-37 | Comparative | 4.9 | 15.3 | 467 | 1.6 |
| Example 5 | | | Example | | | | |
| | | | Compound C5 | | | | |
| Comparative | HT1/ETH85 | AD-37 | Comparative | 4.4 | 19.5 | 459 | 2.1 |
| Example 6 | | | Example | | | | |
| | | | compound C6 | | | | |
| Comparative | HT1/ETH85 | AD-37 | Comparative | 4.4 | 19.4 | 461 | 1.9 |
| Example 7 | | | Example | | | | |
| | | | compound C7 | | | | |

Referring to the results of Table 2, it is seen that each of the light emitting elements of Examples using the fused polycyclic compound according to one or more embodiments of the disclosure as light emitting materials had greater light emitting efficiency and lifespan than that of the light emitting elements of Comparative Examples. Example Compounds each have a structure in which a first substituent is connected to a specific position on the fused polycyclic heterocycle, and may thus achieve high efficiency and long lifetime. Example Compounds may include the fused polycyclic heterocycle including five rings in which first to third benzene rings are connected through a first boron atom, a first nitrogen atom, and a first hetero atom, and a first substituent connected to the fused polycyclic heterocycle. The first substituent may include a first terphenyl moiety including fourth to sixth benzene rings, and a first aryl group connected to the first terphenyl moiety. For example, the first substituent may have a structure in which a fifth benzene ring and a sixth benzene ring are connected to a fourth benzene ring to be positioned ortho, and the first aryl group is substituted on the fifth benzene ring. The first substituent may be connected to the fused polycyclic heterocycle through ortho carbon of each of the fifth benzene ring and the sixth benzene ring. Any one of the fifth benzene ring and the sixth benzene ring may be connected to the first nitrogen atom of the fused polycyclic heterocycle, and the other may be connected to the first benzene ring or the second benzene ring, each of which is connected to the first nitrogen atom. The first aryl group may be connected to the fifth benzene ring included in the first terphenyl moiety. The first aryl group may be connected to the terphenyl moiety to be positioned ortho with respect to the first nitrogen atom, the first benzene ring, or the second benzene ring included in the fused polycyclic heterocycle. When the first substituent is connected to the fused polycyclic heterocycle, four benzene rings may be connected around the first nitrogen atom to form an aryl group-substituted tetrabenzo azonine derivative represented by the following structures X1 and X2.

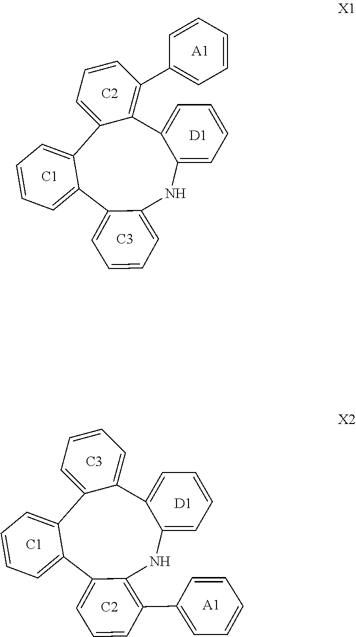

In the structures X1 and X2, a benzene ring represented by C1 may correspond to the fourth benzene ring of the first substituent, a benzene rings represented by C2 and C3 correspond to the fifth benzene ring and the sixth benzene ring, respectively, and D1 may correspond to the first benzene ring or the second benzene ring of the polycyclic heterocycle. In addition, A1 in the structures X1 and X2 may correspond to the first aryl group described above.

Example Compounds included in Examples 1 to 5 has a different steric structure from Comparative Example Compounds, in that the tetrabenzo azonine derivative formed through the introduction of the first substituent is included and the substitution position of the first aryl group is substituted in the positional relationship shown in the structures X1 or X2. For example, for Example Compounds having substitution position relationships of the structures X1 or X2, the first aryl group is substituted to carbon positioned ortho with respect to the first nitrogen atom, the first benzene ring, or the second benzene ring. Due to this specific linkage relationship, the fused polycyclic compound of one or more embodiments has a steric structure in which the first substituent covers and/or shields the boron atom in both directions (e.g., simultaneously) with respect to the plate-like structure of the fused ring core, thereby achieving the effect of effectively protecting the boron atoms. In addition, in Example Compounds, the first substituent is connected to the fused polycyclic heterocycle, and thus a tetrabenzo azonine derivative containing a 9-membered ring is formed, and accordingly, in the form in which the first substituent covers and/shields the boron atom, movement may be minimized or reduced, and a bulkiness structure may be maintained, compared to Comparative Example Compounds.

In addition, Example Compounds, with the introduction of the first substituent, may have suppressed or reduced intermolecular interactions to control excimer or exciplex formation, thereby having greater luminous efficiency. For example, in Example Compounds, a distance between adjacent molecules increases due to the structure with great steric hindrance caused by the first substituent, and accordingly, Dexter energy transfer may be suppressed or reduced to prevent or reduce lifetime deterioration resulting from an increase in triplet concentration. The light emitting element of one or more embodiments includes the fused polycyclic compound of one or more embodiments as a light emitting dopant of a thermally activated delayed fluorescence (TADF) light emitting element, and may thus achieve high element efficiency and improved lifetime in a blue light wavelength range.

Comparative Example Compound C1 included in Comparative Example 1 has a structure in which an unsubstituted phenyl group is connected to a nitrogen atom in a fused ring core containing a boron atom and a nitrogen atom, and the substituent itself, i.e., unsubstituted phenyl group, does not come along a sufficient effect of sterically protecting the fused ring core, and accordingly, Comparative Example Compound C1 may have a reduced effect in intermolecular interaction suppression, or in triplet energy concentration reduction resulting from Dexter energy transfer suppression, compared to Examples. Therefore, it is determined that when Comparative Example Compound C1 was applied to a light emitting element, luminous efficiency and lifetime were reduced compared to Examples.

Comparative Examples Compounds C2 and C3 included in Comparative Examples 2 and 3, respectively, each include no substituent corresponding to the first aryl group of the fused polycyclic compound according to one or more embodiments. Accordingly, as for each of Comparative Example Compound C2 and Comparative Example Compound C3, the steric structure effect described above may not be expected from the structures X1 and X2, and thus the effects of boron atom protection and intermolecular interaction prevention may be reduced compared to Example Compounds. Therefore, it is determined that when Comparative Example Compounds C2 and C3 were each applied to a light emitting element, luminous efficiency and lifetime were reduced compared to Examples.

Comparative Example 4 showed reduced element service life and efficiency compared to Examples. Comparative Example Compound C4 included in Comparative Example 4 includes the fused polycyclic heterocycle centered on a boron atom and a nitrogen atom, but does not include the first substituent, and thus is determined to have reduced luminous efficiency and lifetime compared to Examples, when applied to an element. In contrast, Example Compounds, with the inclusion of first substituent, has stericity in both directions (e.g., simultaneously) with respect to the plate-like structure, and has rigid characteristics due to the 9-membered ring to significantly suppress or reduce intramolecular movement, resulting in improved luminous efficiency and lifetime, compared to Comparative Example Compound C4.

Comparative Example 5 showed reduced element service life and efficiency compared to Examples. Comparative Example Compound C5 included in Comparative Example 5 is different from Example compounds in that three rings are connected around a nitrogen atom to form a hetero fused ring containing a 7-membered ring. Comparative Example Compound C5 containing a 7-membered ring has a reduced steric hindrance effect compared to Example Compounds containing a 9-membered ring, and may thus have reduced effects of boron atom protection and intermolecular interaction prevention. Therefore, it is determined that when Comparative Example Compound C5 was applied to a light emitting element, luminous efficiency and lifetime were reduced compared to Examples.

Comparing Example 1 with Comparative Examples 6 and 7, Comparative Examples 6 and 7 showed reduced element service life and efficiency compared to Example 1. Comparative Example Compounds C6 and C7 included in Comparative Examples 6 and 7, respectively, are fused polycyclic compounds containing a tetrabenzo azonine derivative, and is different from Example Compound 1 in the connection position of the phenyl group connected to the tetrabenzo azonine derivative. Comparative Example Compound C6 corresponds to a compound in which a phenyl group connected to a tetrabenzo azonine derivative is connected to be positioned meta with respect to a nitrogen atom of the fused polycyclic heterocycle, and Comparative Example Compound C7 corresponds to a compound in which a phenyl group connected to a tetrabenzo azonine derivative is connected to be positioned para with respect to a nitrogen atom of the fused polycyclic heterocycle. Comparative Compounds C6 and C7, in which a phenyl group is connected to be positioned meta or para with respect to a nitrogen atom of the fused polycyclic heterocycle, differ form Example Compounds in that the phenyl group is arranged in a direction away from the boron atom of the fused polycyclic heterocycle, and may thus have reduced effects of boron atom protection and intermolecular interaction prevention compared to Example Compounds. Therefore, it is determined that when Comparative Example Compounds C6 and C7 were each separately applied to a light emitting element, luminous efficiency and lifetime were reduced compared to Examples. In contrast, Example Compounds have a steric structure covering and/or shielding a boron atom in both directions (e.g., simultaneously) with respect to the plate-like structure of the fused ring core as a phenyl group is connected to be positioned ortho with respect to a nitrogen atom or a benzene ring of the fused polycyclic heterocycle, and may thus have an effect of effectively protecting the boron atom. Accordingly, when Example Compounds are applied to a light emitting element, high light emitting efficiency and long service life of the light emitting element is expected.

The light emitting element of one or more embodiments of the present disclosure may exhibit improved element characteristics of high efficiency and long service life.

The fused polycyclic compound of one or more embodiments of the present disclosure may be included in an emission layer of a light emitting element, and may thus contribute to high efficiency and long service life.

The display device of one or more embodiments of the present disclosure may exhibit high display quality by including the light emitting element of present disclosure.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when particles (e.g., quantum dots) are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The light-emitting element/device, the display device, the display apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Features or aspects within each embodiment should typically be considered as available for other similar features or aspects in other embodiments. Thus, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although the disclosure has been described with reference to embodiments of the disclosure, it will be understood that the present disclosure should not be limited to these embodiments but one or more suitable changes and modifications may be made by those skilled in the art without departing from the spirit and scope of the disclosure.

Accordingly, the technical scope of the present disclosure is not intended to be limited to the contents set forth in the detailed description of the present disclosure, but is intended to be defined by the appended claims and equivalents thereof.

What is claimed is:

1. A light emitting element, comprising:
a first electrode;
a second electrode on the first electrode; and
an emission layer between the first electrode and the second electrode and comprising a first compound represented by Formula 1: 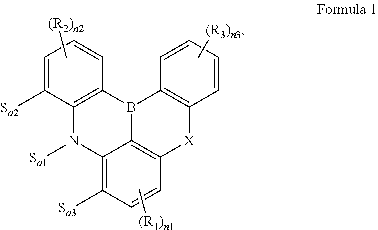
wherein, in Formula 1,
X is NR₄, O, S, or Se,
Sₐ₂, Sₐ₃, and R₁ to R₄ are each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
n1 is an integer of 0 to 2,
n2 is an integer of 0 to 3,
n3 is an integer of 0 to 4,
any one pair of Sₐ₁ and Sₐ₂ or Sₐ₁ and Sₐ₃ are positions in which a substituent represented by Formula 2 is connected, 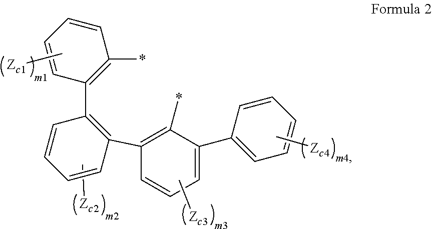
and
wherein, in Formula 2,
—* is a position connected to any one pair of Sₐ₁ and Sₐ₂ or Sₐ₁ and Sₐ₃ in Formula 1,
Z_{c1} to Z_{c4} are each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
m1 and m2 are each independently an integer of 0 to 4,
m3 is an integer of 0 to 3, and
m4 is an integer of 0 to 5.

2. The light emitting element of claim 1, wherein the first compound represented by Formula 1 is represented by any one selected from among Formulas 3-1 to 3-4: 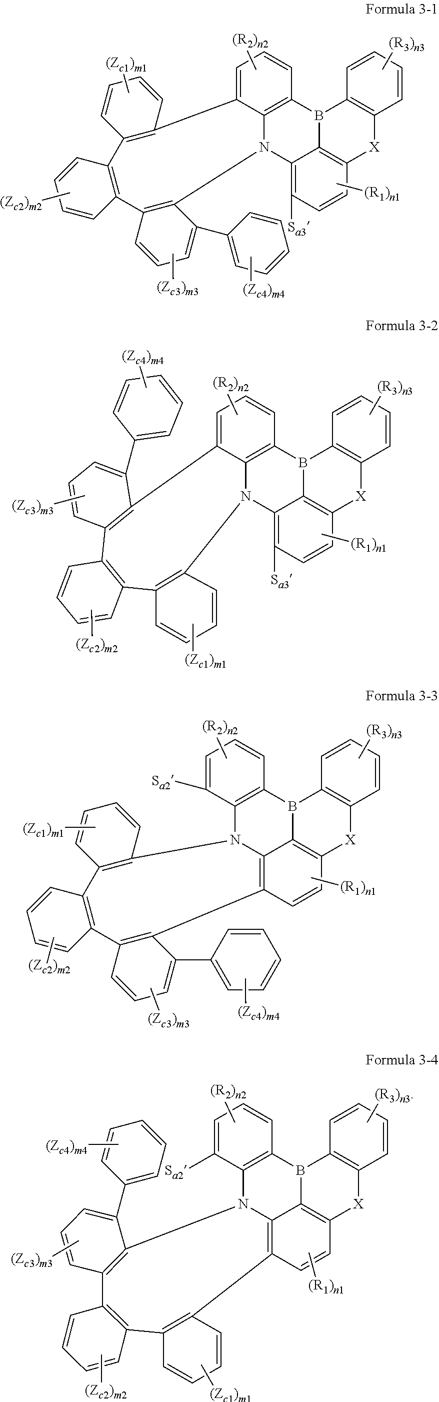
in Formulas 3-1 to 3-4,
Sₐ₂′ and Sₐ₃′ being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and
X, R₁ to R₃, n1 to n3, Z_{c1} to Z_{c4}, and m1 to m4 being each the same as defined in Formulas 1 and 2.

3. The light emitting element of claim 1, wherein the first compound represented by Formula 1 is represented by Formula 4: 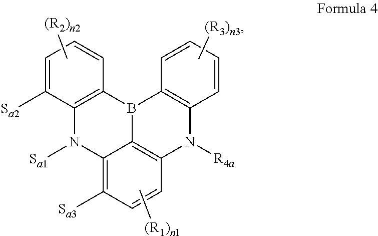
in Formula 4,
R₄ₐ being represented by any one selected from among Formulas S-1 to S-5: 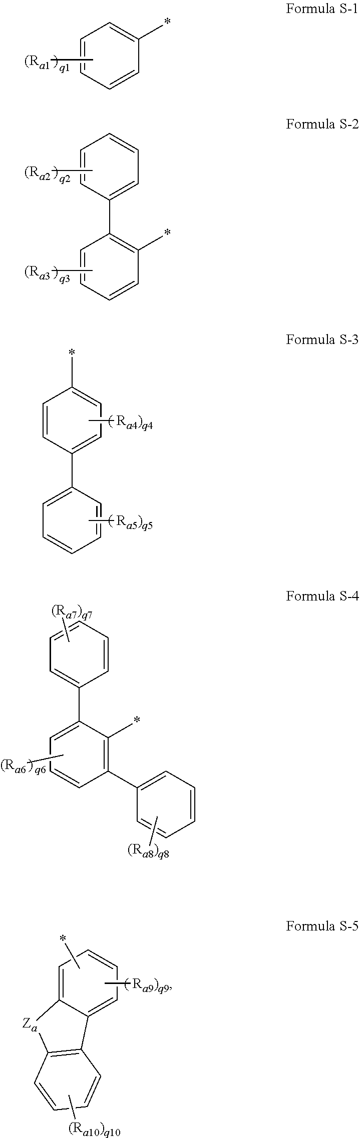
in Formulas S-1 to S-5,
Zₐ being CRₐ₁₁Rₐ₁₂, NRₐ₁₃, O, S, or Se,
Rₐ₁ to Rₐ₁₃ being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
q1, q2, q5, q7, and q8 being each independently an integer of 0 to 5,
q3, q4, and q10 being each independently an integer of 0 to 4,
q6 and q9 being each independently an integer of 0 to 3,
—* being a position connected to Formula 1, and
in Formula 4,
R₁ to R₃, n1 to n3, Sₐ₁, Sₐ₂, and Sₐ₃ being each the same as defined in Formula 1.

4. The light emitting element of claim 1, wherein the first compound represented by Formula 1 is represented by Formula 5: 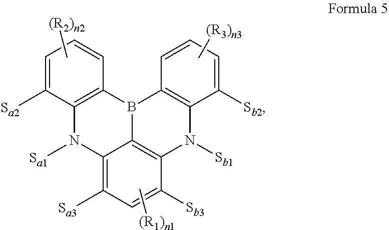
in Formula 5,
n1 being 0 or 1,
n3 being an integer of 0 to 3,
S_{b2} and S_{b3} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
any one pair of S_{b1} and S_{b2} or S_{b1} and S_{b3} being positions in which a substituent represented by Formula 6 is connected, 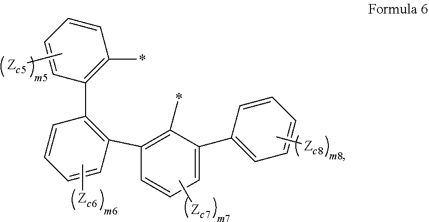
in Formula 6,
—* being a position connected to any one pair of S_{b1} and S_{b2} or S_{b1} and S_{b3} in Formula 5,
Z_{c5} to Z_{c8} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
m5 and m6 being each independently an integer of 0 to 4,
m7 being an integer of 0 to 3,
m8 being an integer of 0 to 5, and
in Formula 5,
Sₐ₁, Sₐ₂, Sₐ₃, R₁ to R₃, and n2 being each the same as defined in Formula 1.

5. The light emitting element of claim 1, wherein the first compound represented by Formula 1 is represented by any one selected from among Formulas 7-1 to 7-5: 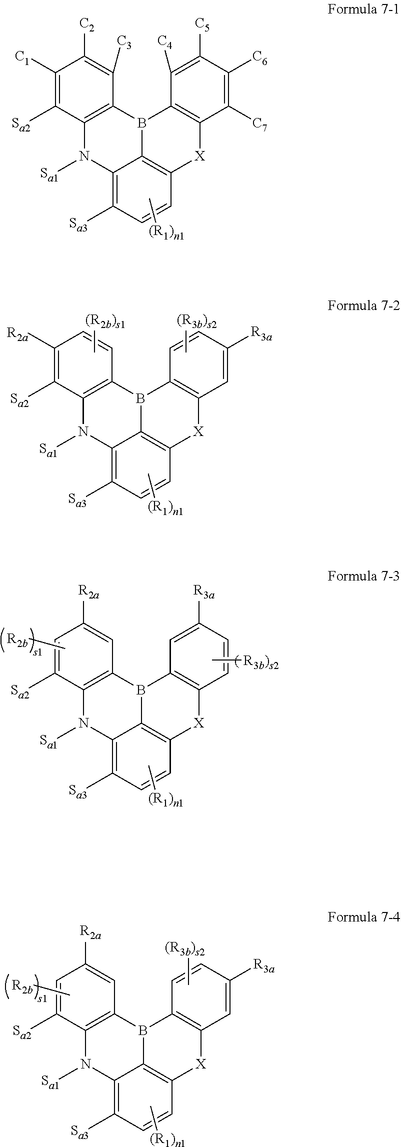 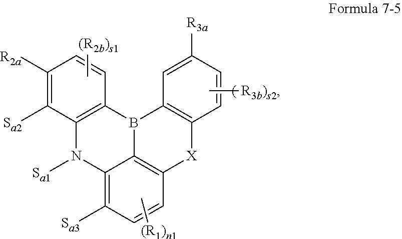
in Formulas 7-1 to 7-5,
C₁ to C₇ being each independently hydrogen or deuterium,
R₂ₐ and R₃ₐ being each independently a cyano group, or a substituted or unsubstituted alkyl group having 1 to 10 carbon atoms, or a substituent represented by any one selected from among Formulas A-1 to A-5,
R_{2b} and R_{3b} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
s1 being an integer of 0 to 2,
s2 being an integer of 0 to 3, 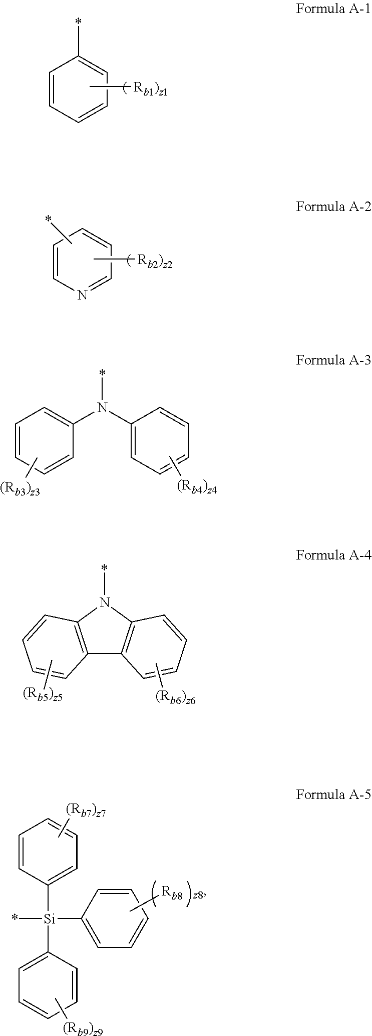
in Formulas A-1 to A-5,
R_{b1} to R_{b9} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
z1, z3, z4, and z7 to z9 being each independently an integer of 0 to 5,
z2, z5, and z6 being each independently an integer of 0 to 4,
—* being a position connected to Formulas 7-2 to 7-5, and
in Formulas 7-1 to 7-5,
X, R₁, n1, Sₐ₁, Sₐ₂, and Sₐ₃ being each the same as defined in Formula 1.

6. The light emitting element of claim 1, wherein at least one selected from among R₁ to R₃ is a cyano group, a substituted or unsubstituted isopropyl group, a substituted or unsubstituted t-butyl group, a substituted or unsubstituted phenyl group, a substituted or unsubstituted triphenylsilyl group, a substituted or unsubstituted diphenylamine group, or a substituted or unsubstituted carbazole group.

7. The light emitting element of claim 1, wherein the first compound represented by Formula 1 is represented by Formula 8-1 or Formula 8-2: 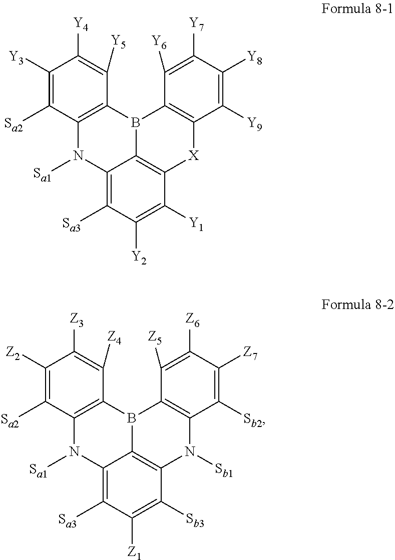
in Formulas 8-1 and 8-2,
Y₁ to Y₉ being each independently selected from among hydrogen, deuterium, and substituents of Substituent Group 1,
Z₁ to Z₇ being each independently selected from among a hydrogen atom, a deuterium atom, and the substituents of Substituent Group 1,
S_{b2} and S_{b3} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
any one pair of S_{b1} and S_{b2} or S_{b1} and S_{b3} being positions in which a substituent represented by Formula 6 is connected, 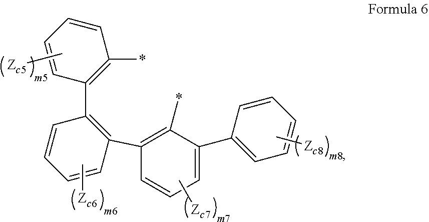
in Formula 6,
—* being a position connected to any one pair of S_{b1} and S_{b2} or S_{b1} and S_{b3} in Formula 8-2,
Z_{c5} to Z_{c8} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
m5 and m6 being each independently an integer of 0 to 4,
m7 being an integer of 0 to 3,
m8 is being integer of 0 to 5, 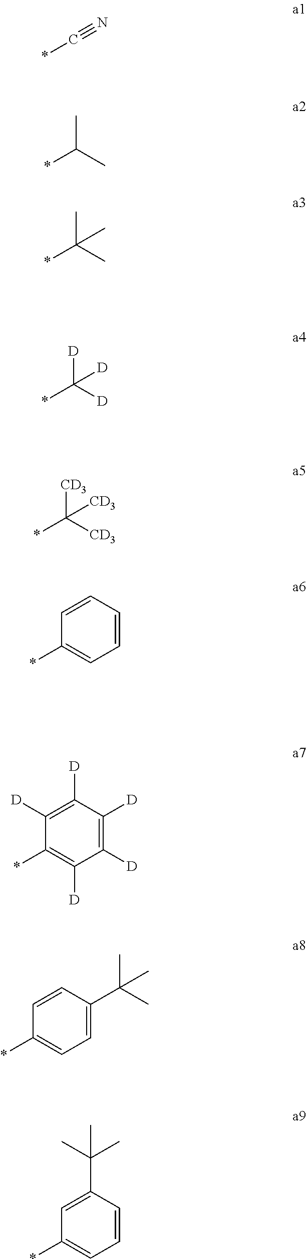 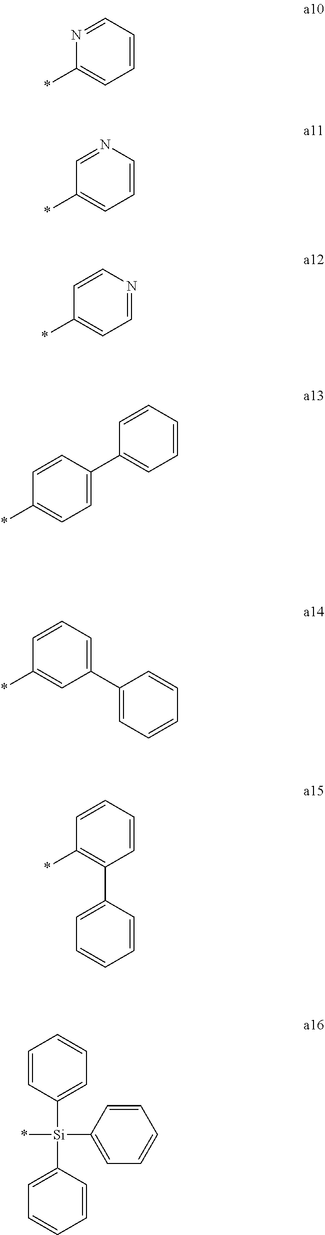 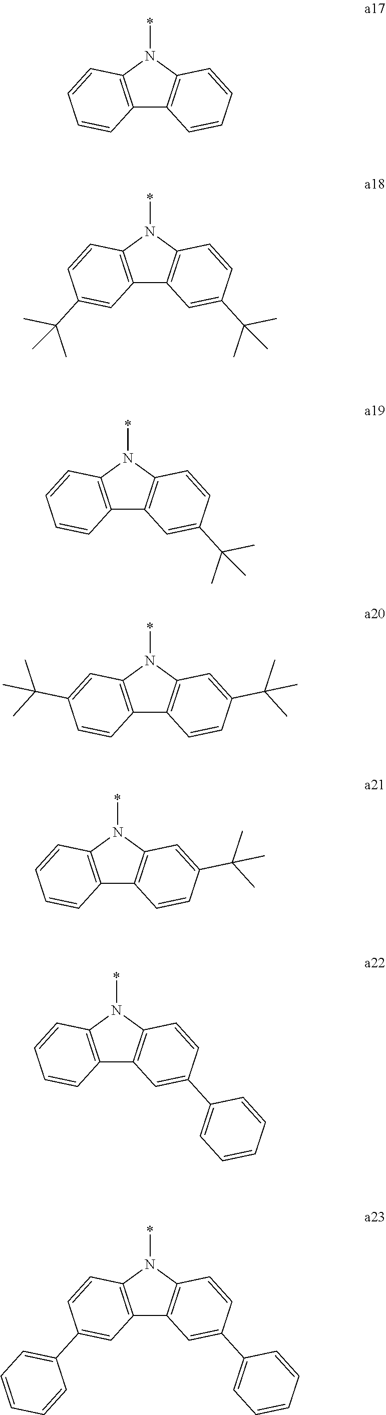 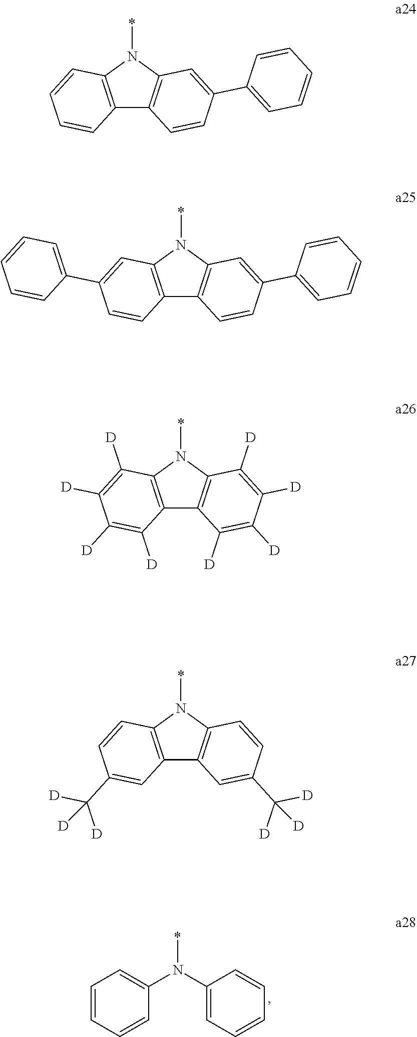 [SMILES: *n1c2ccccc2c2ccc(-c3ccccc3)cc21 ; *n1c2cc(-c3ccccc3)ccc2c2ccc(-c3ccccc3)cc21 ; *n1c2c([2H])c([2H])c([2H])c([2H])c2c2c([2H])c([2H])c([2H])c([2H])c21 ; *n1c2ccc(C([2H])([2H])[2H])cc2c2cc(C([2H])([2H])[2H])ccc21 ; *N(c1ccccc1)c1ccccc1]
and
in Formulas 8-1 and 8-2,
X, Sₐ₁, Sₐ₂, and Sₐ₃ being each the same as defined in Formula 1.

8. The light emitting element of claim 1, wherein Z_{c1} to Z_{c4} are each independently hydrogen, deuterium, a substituted or unsubstituted t-butyl group, a substituted or unsubstituted phenyl group, a substituted or unsubstituted biphenyl group, or a substituted or unsubstituted terphenyl group.

9. The light emitting element of claim 1, wherein the emission layer further comprises at least one of a second compound represented by Formula HT-1, a third compound represented by Formula ET-1, or a fourth compound represented by Formula D-1: 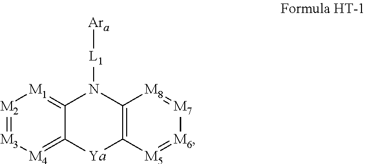
in Formula HT-1,
M1 to M₈ being each independently N or CR₅₁,
L₁ being a direct linkage, a substituted or unsubstituted arylene group having 6 to 30 ring-forming carbon atoms, or a substituted or unsubstituted heteroarylene group having 2 to 30 ring-forming carbon atoms,
Yₐ being a direct linkage, CR₅₂R₅₃, or SiR₅₄R₅₅,
Arₐ being a substituted or unsubstituted aryl group having 6 to 30 ring-forming carbon atoms or a substituted or unsubstituted heteroaryl group having 2 to 30 ring-forming carbon atoms,
R₅₁ to R₅₅ being each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, 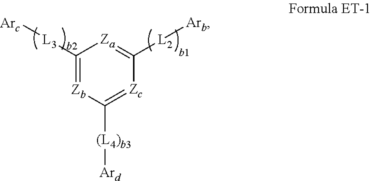
in Formula ET-1,
at least one selected from among Zₐ to Z_{c} being N and the others being CR₅₆,
R₅₆ being hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 being each independently an integer of 0 to 10,
Ar_{b} to Ar_{d} being each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₂ to L₄ being each independently a direct linkage, a substituted or unsubstituted arylene group having 6 to 30 ring-forming carbon atoms, or a substituted or unsubstituted heteroarylene group having 2 to 30 ring-forming carbon atoms, and 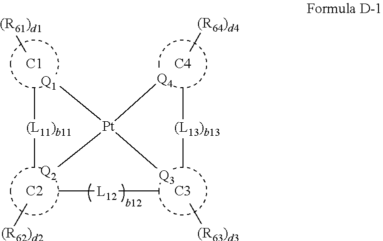
in Formula D-1,
Q₁ to Q₄ being each independently C or N,
C1 to C4 being each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ being each independently a direct linkage, *—O—*, *—S—*, 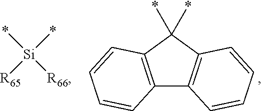
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 being each independently 0 or 1,
R₆₁ to R₆₆ being each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 being each independently an integer of 0 to 4.

10. The light emitting element of claim 1, wherein the first compound represented by Formula 1 comprises at least one selected from among compounds of Compound Group 1:

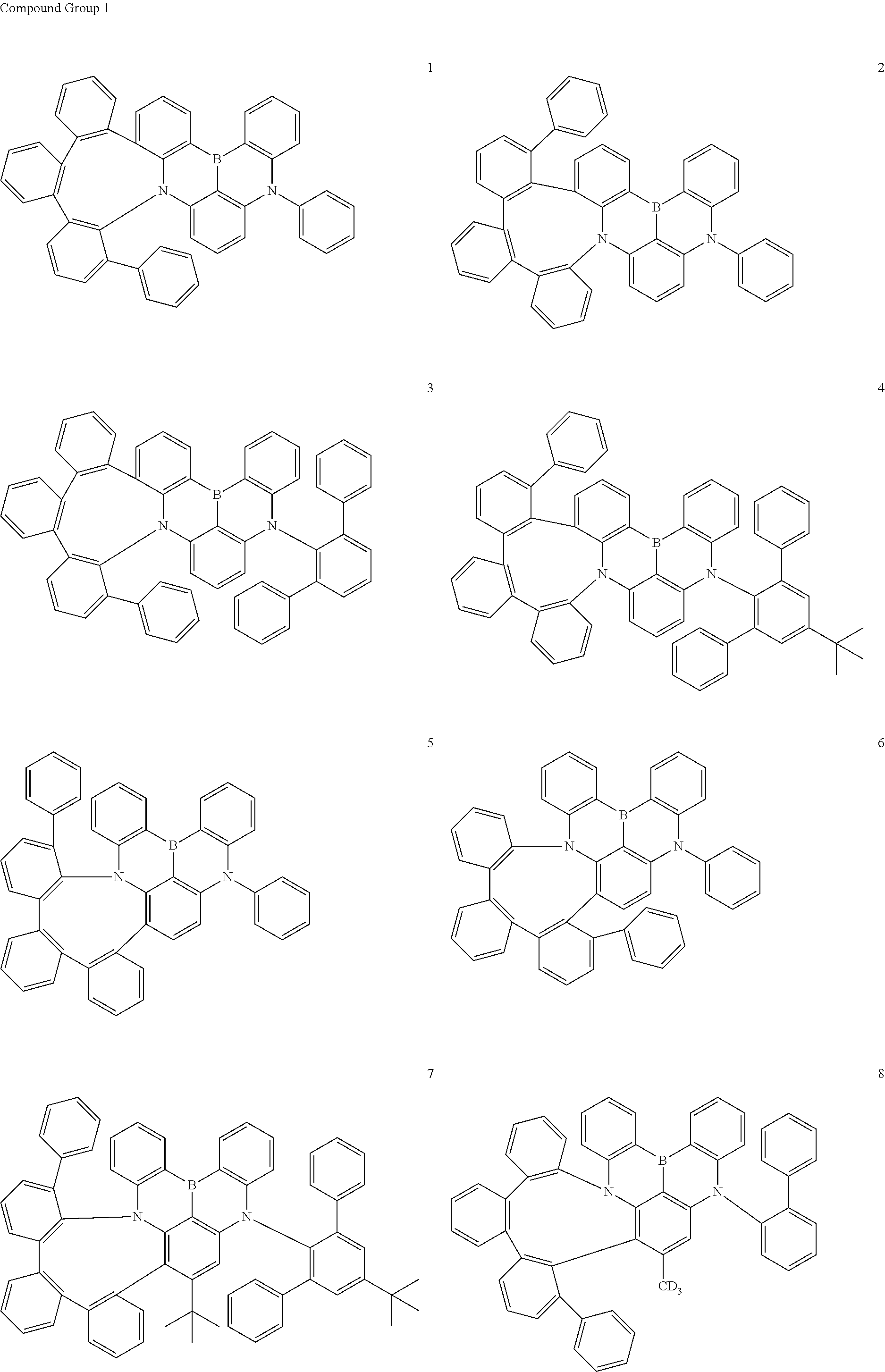

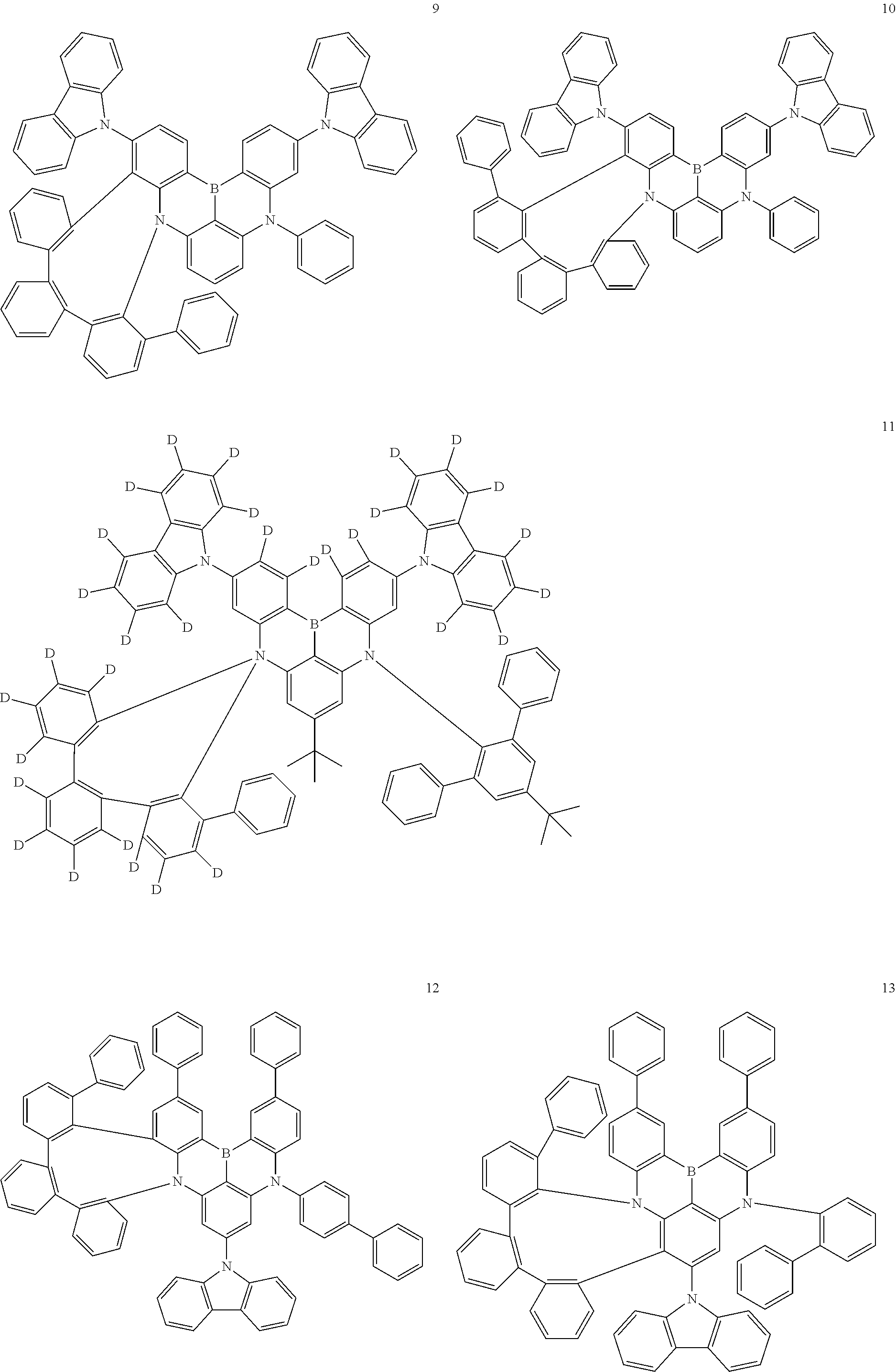

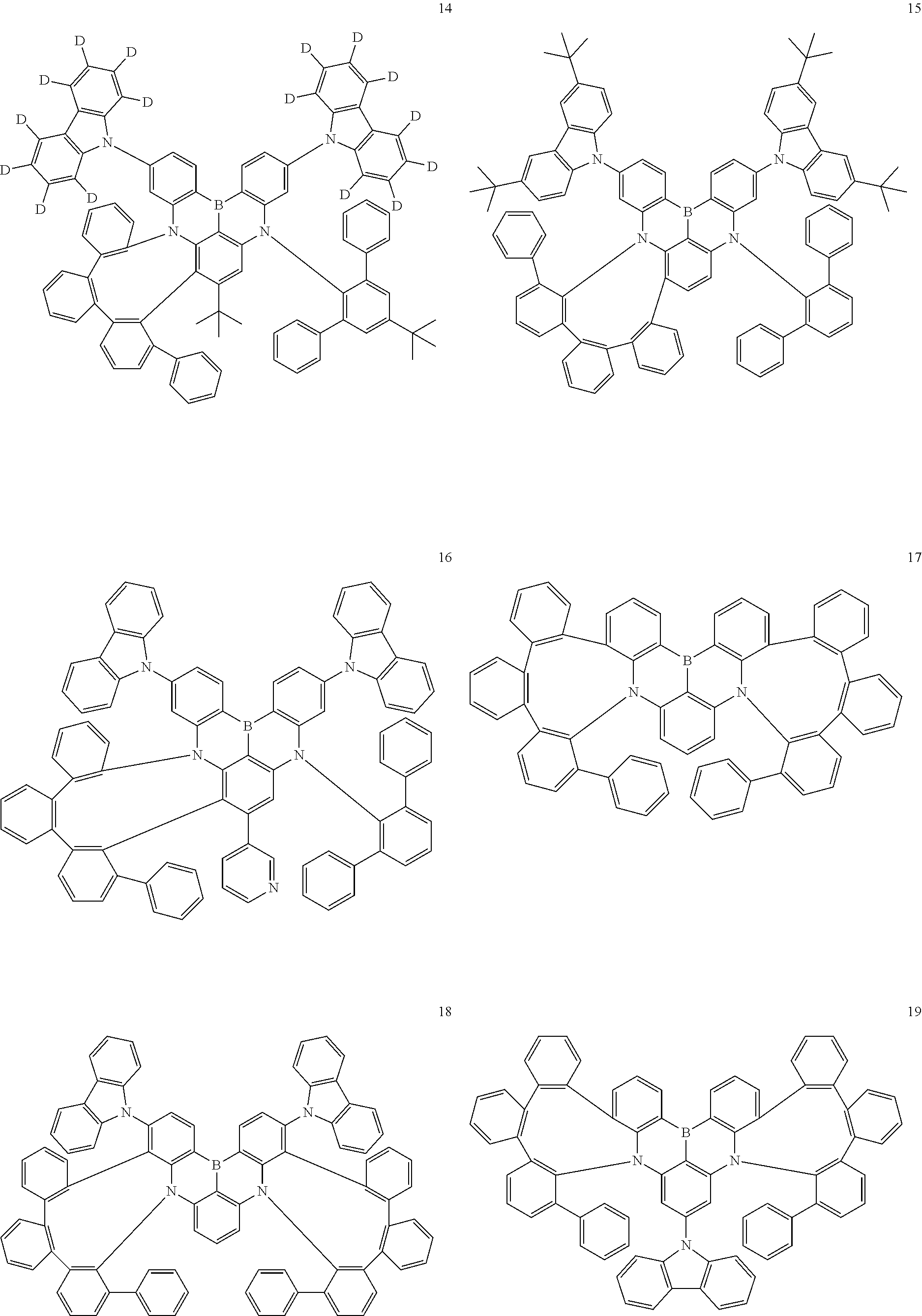

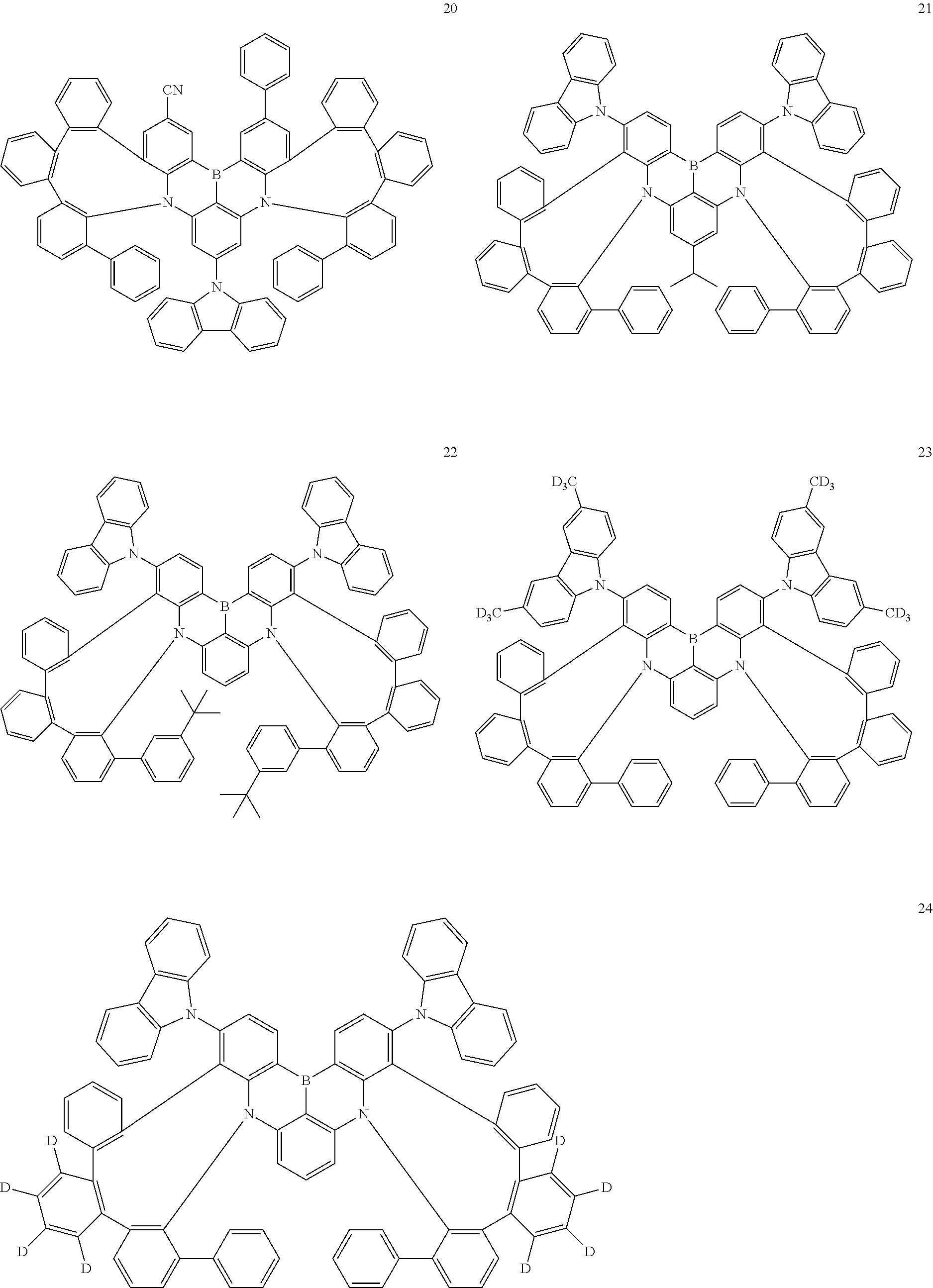

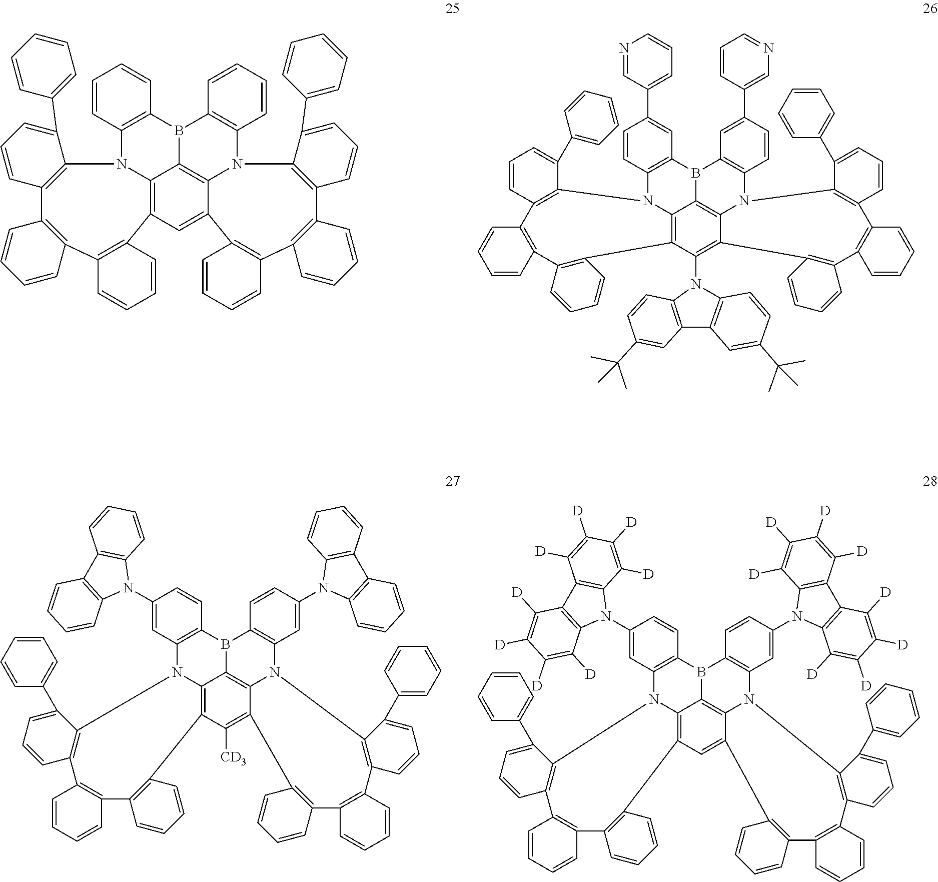

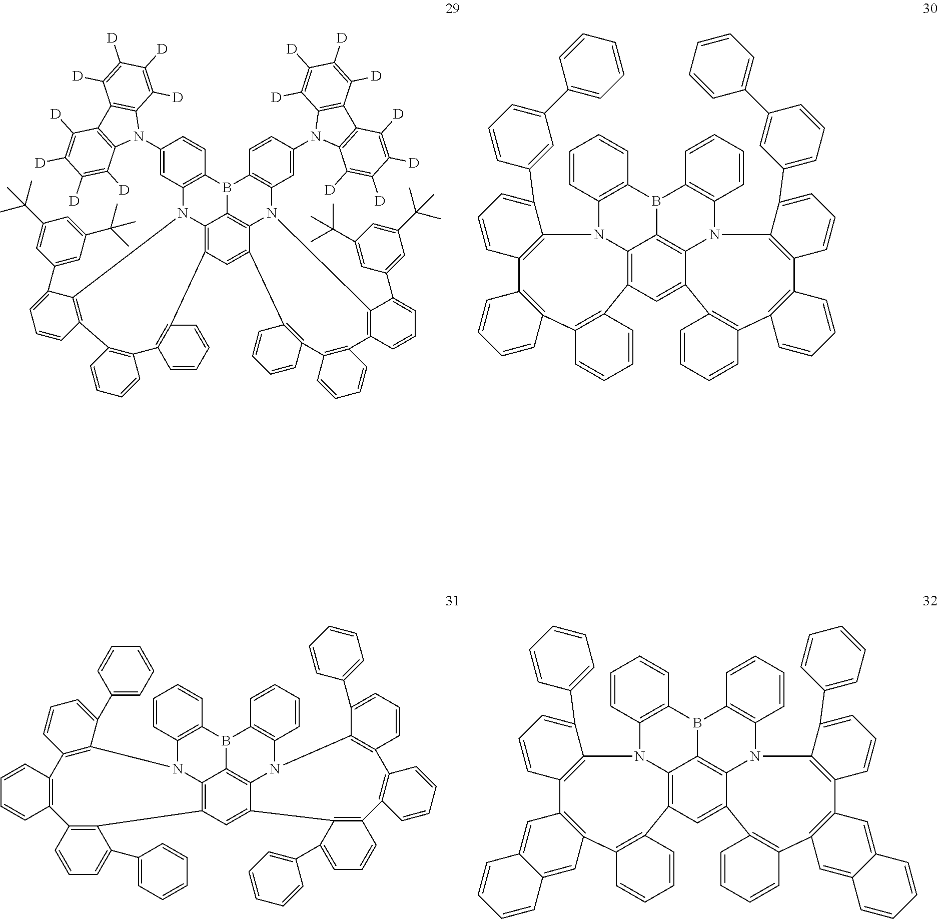

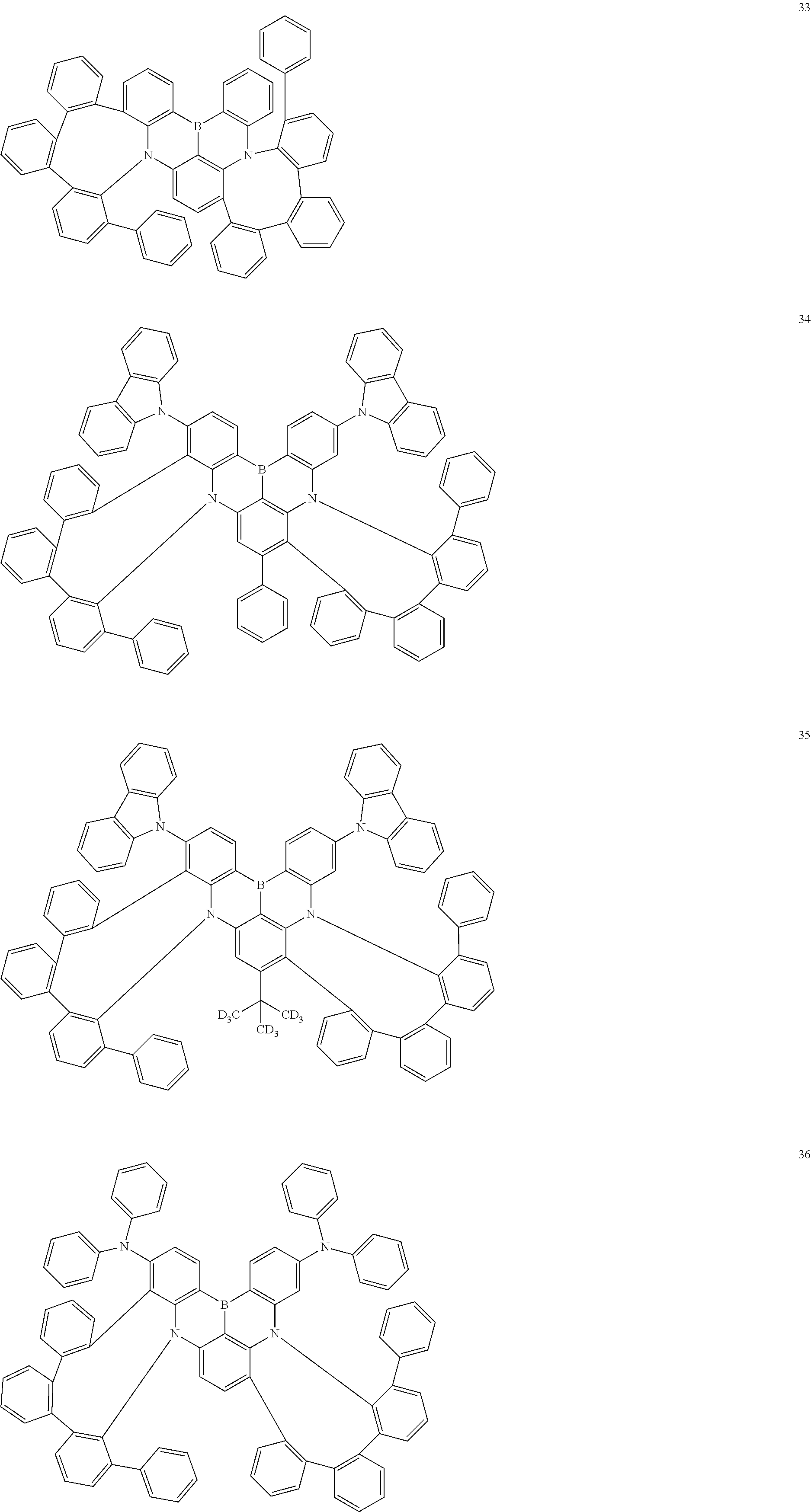

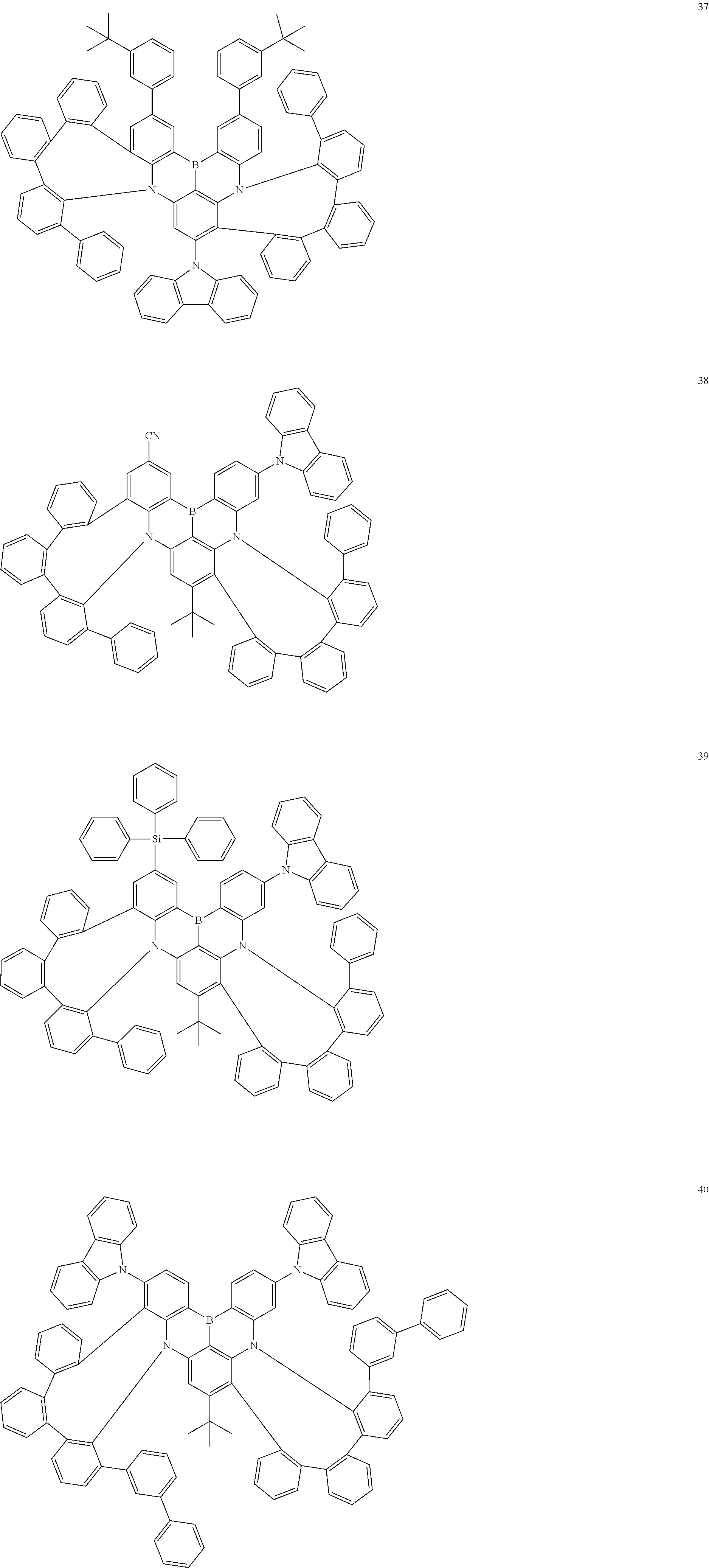

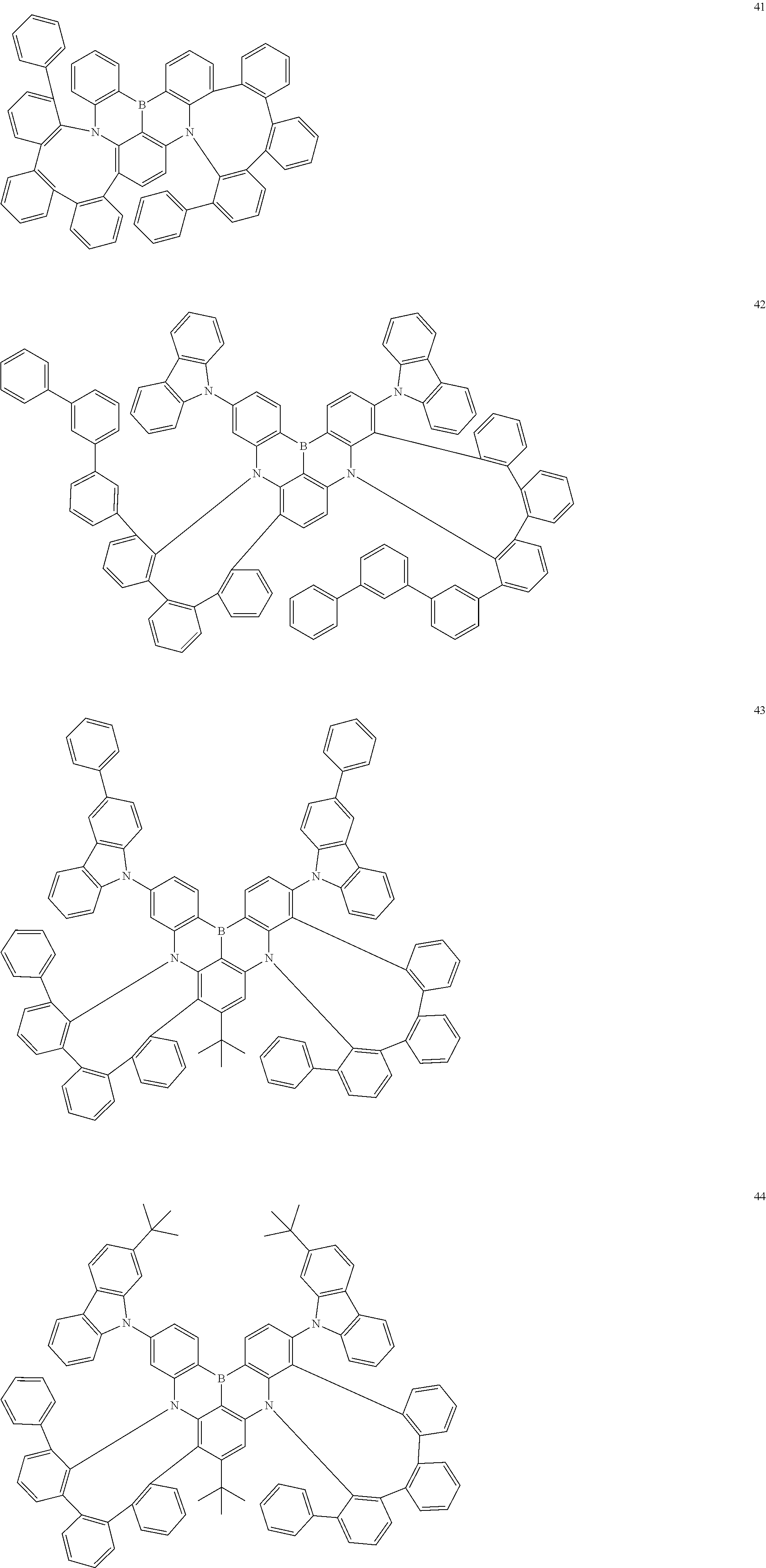

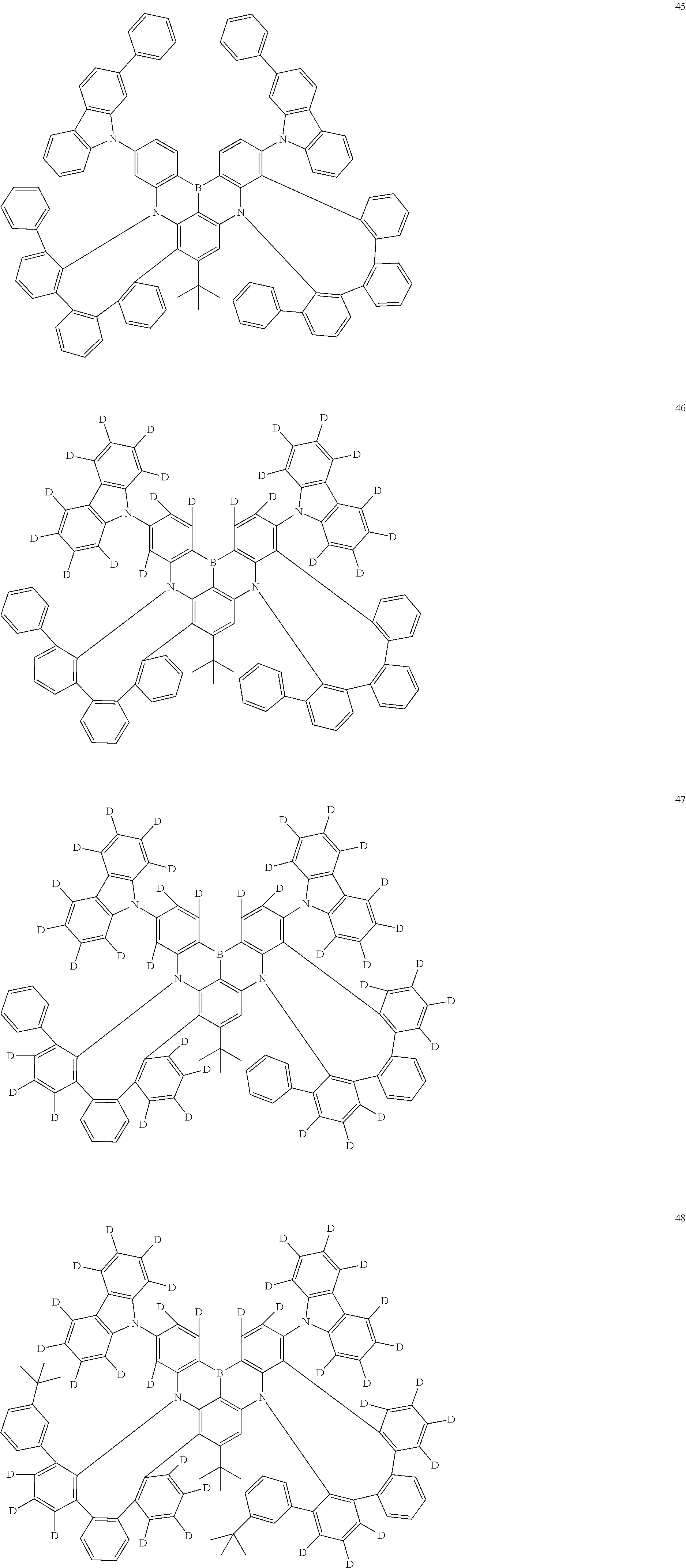

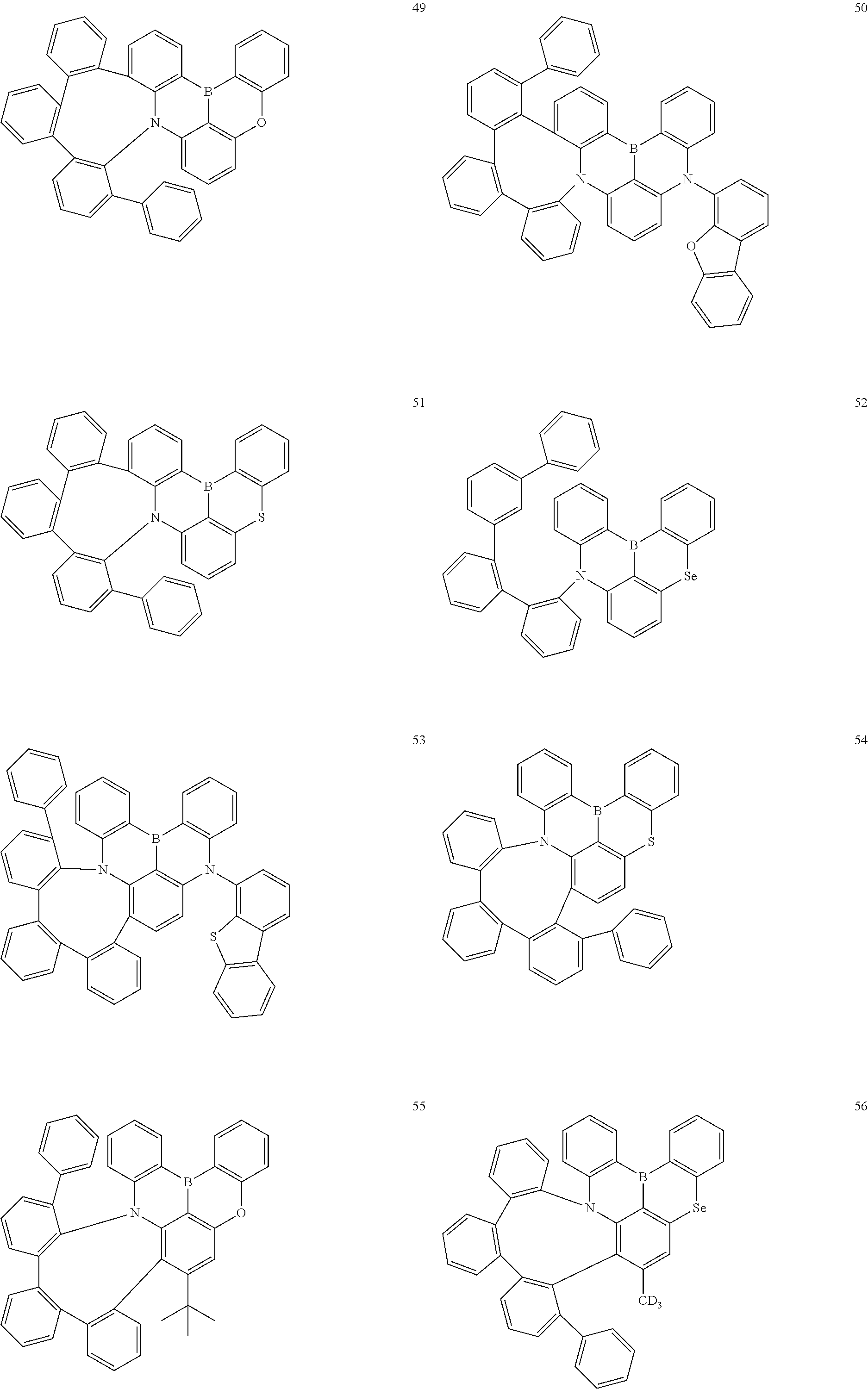

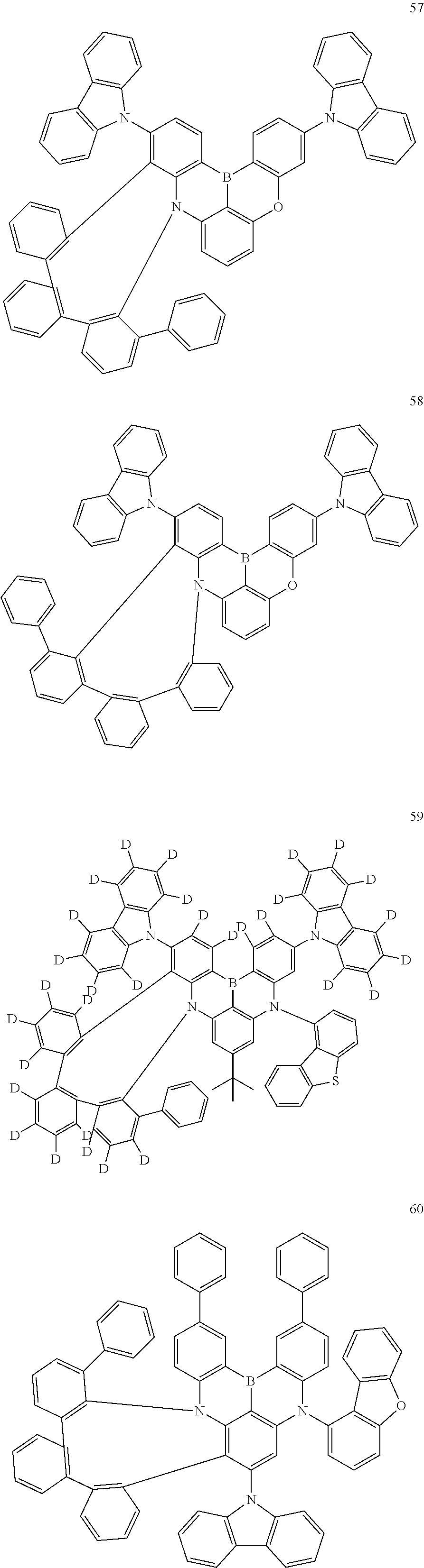

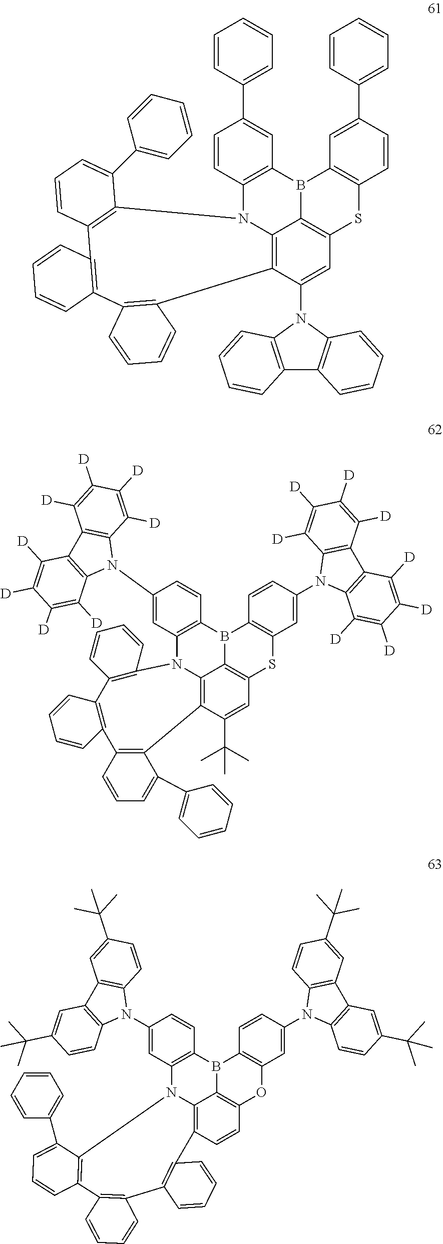 [SMILES: c1ccc(-c2ccc3c(c2)B2c4cc(-c5ccccc5)ccc4-n4c5c(-c6ccccc6)cccc5c5ccccc5c5ccccc5c5c(-n6c7ccccc7c7ccccc76)cc(c2c54)S3)cc1 ; [2H]c1c([2H])c([2H])c2c(c1[2H])c1c([2H])c([2H])c([2H])c([2H])c1n2-c1ccc2c(c1)Sc1cc(C(C)(C)C)c3c4c(-c5ccccc5)cccc4c4ccccc4c4ccccc4n4c3c1B2c1ccc(-n2c3c([2H])c([2H])c([2H])c([2H])c3c3c([2H])c([2H])c([2H])c([2H])c32)cc1-4 ; CC(C)(C)c1ccc2c(c1)c1cc(C(C)(C)C)ccc1n2-c1ccc2c(c1)Oc1ccc3c4ccccc4c4ccccc4c4cccc(-c5ccccc5)c4n4c3c1B2c1ccc(-n2c3ccc(C(C)(C)C)cc3c3cc(C(C)(C)C)ccc32)cc1-4]

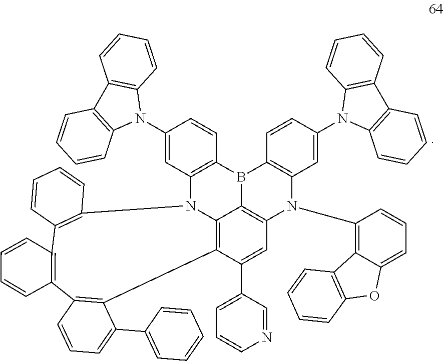 [SMILES: c1ccc(-c2cccc3c4ccccc4c4ccccc4n4c5c6c(cc(-c7cccnc7)c5c23)N(c2cccc3oc5ccccc5c23)c2cc(-n3c5ccccc5c5ccccc53)ccc2B6c2ccc(-n3c5ccccc5c5ccccc53)cc2-4)cc1]

11. A display device, comprising:
a base layer;
a circuit layer on the base layer; and
a display element layer on the circuit layer and comprising a light emitting element,
wherein the light emitting element comprises a first electrode, a second electrode on the first electrode, and an emission layer between the first electrode and the second electrode and containing a first compound represented by Formula 1: 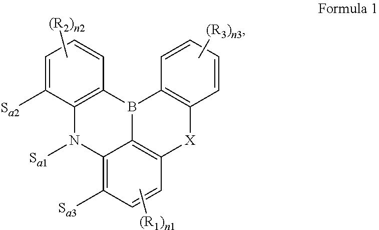
in Formula 1,
X being NR₄, O, S, or Se,
Sₐ₂, Sₐ₃, and R₁ to R₄ being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
n1 being an integer of 0 to 2,
n2 being an integer of 0 to 3,
n3 being an integer of 0 to 4,
any one pair of Sₐ₁ and Sₐ₂ or Sₐ₁ and Sₐ₃ being positions in which a substituent represented by Formula 2 is connected, 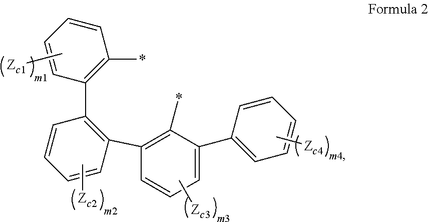
in Formula 2,
—* being a position connected to any one pair of Sₐ₁ and Sₐ₂ or Sₐ₁ and Sₐ₃ in Formula 1,
Z_{c1} to Z_{c4} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
m1 and m2 being each independently an integer of 0 to 4,
m3 being an integer of 0 to 3, and
m4 being an integer of 0 to 5.

12. The display device of claim 11, wherein the light emitting element further comprises a capping layer on the second electrode,
the capping layer having a refractive index of about 1.6 or greater in a wavelength range of about 550 nm to about 660 nm.

13. The display device of claim 11, further comprising a light control layer on the display element layer and comprising quantum dots,
wherein the light emitting element is to emit first color light, and
the light control layer comprises:
a first light control portion comprising a first quantum dot that converts the first color light into second color light having a longer wavelength than the first color light;
a second light control portion comprising a second quantum dot that converts the first color light into third color light having a longer wavelength than the first color light and the second color light; and
a third light control portion that is to transmit the first color light.

14. The display device of claim 13, further comprising a color filter layer on the light control layer,
wherein the color filter layer comprises:
a first filter that is to transmit the second color light;
a second filter that is to transmit the third color light; and
a third filter that is to transmit the first color light.

15. A fused polycyclic compound represented by Formula 1: 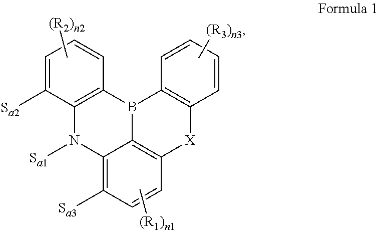
wherein, in Formula 1,
X is NR₄, O, S, or Se,
Sₐ₂, Sₐ₃, and R₁ to R₄ are each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
n1 is an integer of 0 to 2,
n2 is an integer of 0 to 3,
n3 is an integer of 0 to 4,
any one pair of Sₐ₁ and Sₐ₂ or Sₐ₁ and Sₐ₃ are positions in which a substituent represented by Formula 2 is connected, 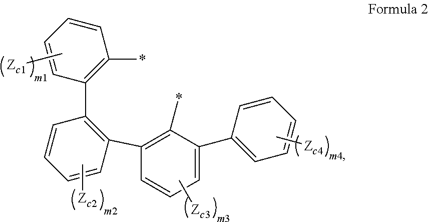
and
—* wherein, in Formula 2,
is a position connected to any one pair of Sₐ₁ and Sₐ₂ or Sₐ₁ and Sₐ₃ in Formula 1,
Z_{c1} to Z_{c4} are each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
m1 and m2 are each independently an integer of 0 to 4,
m3 is an integer of 0 to 3, and
m4 is an integer of 0 to 5.

16. The fused polycyclic compound of claim 15, wherein the fused polycyclic compound represented by Formula 1 is represented by any one selected from among Formulas 3-1 to 3-4: 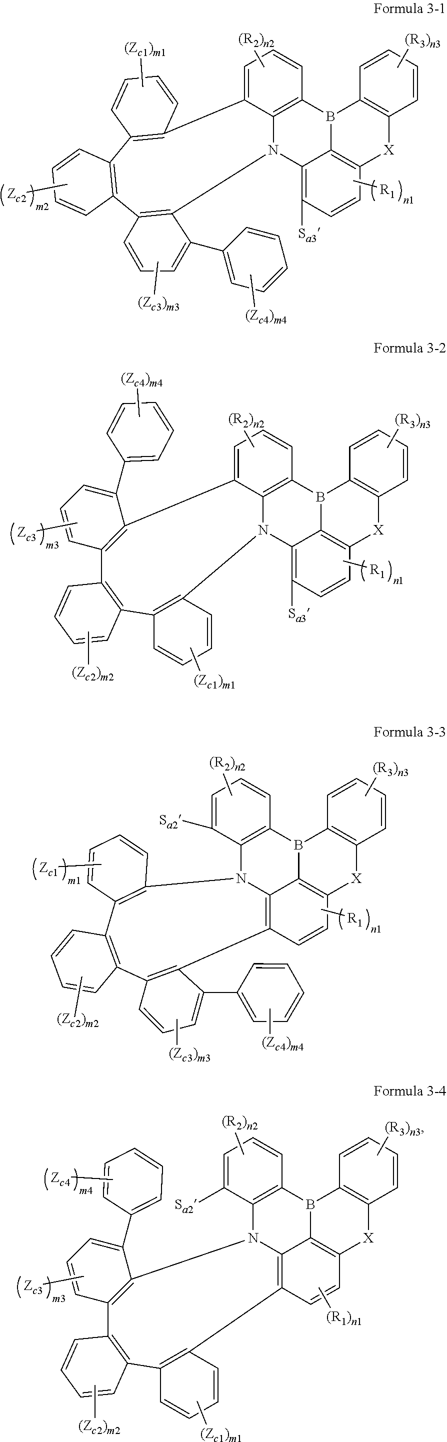
in Formulas 3-1 to 3-4,
Sₐ₂′ and Sₐ₃′ being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and
X, R₁ to R₃, n1 to n3, Z_{c1} to Z_{c4}, and m1 to m4 being each the same as defined in Formulas 1 and 2.

17. The fused polycyclic compound of claim 15, wherein the fused polycyclic compound represented by Formula 1 is represented by Formula 4: 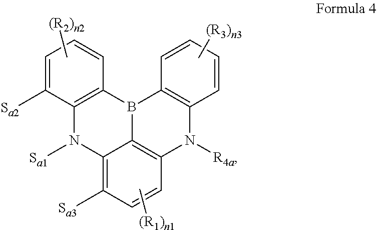
in Formula 4,
R₄ₐ being represented by any one selected from among Formulas S-1 to S-5: 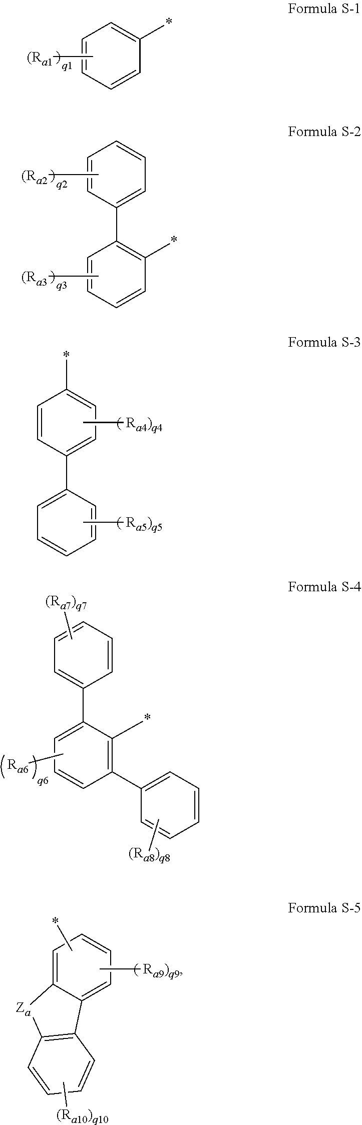
in Formulas S-1 to S-5,
Zₐ being CRₐ₁₁Rₐ₁₂, NRₐ₁₃, O, S, or Se,
Rₐ₁ to Rₐ₁₃ being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
q1, q2, q5, q7, and q8 being each independently an integer of 0 to 5,
q3, q4, and q10 being each independently an integer of 0 to 4,
q6 and q9 being each independently an integer of 0 to 3,
—* being a position connected to Formula 1, and
in Formula 4,
R₁ to R₃, n1 to n3, Sₐ₁, Sₐ₂, and Sₐ₃ being each the same as defined in Formula 1.

18. The fused polycyclic compound of claim 15, wherein the fused polycyclic compound represented by Formula 1 is represented by Formula 5: 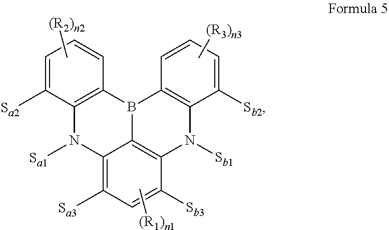
in Formula 5,
n1 being 0 or 1,
n2 being an integer of 0 to 3
S_{b2} and S_{b3} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
any one pair of S_{b1} and S_{b2} or S_{b1} and S_{b3} being positions in which a substituent represented by Formula 6 is connected, 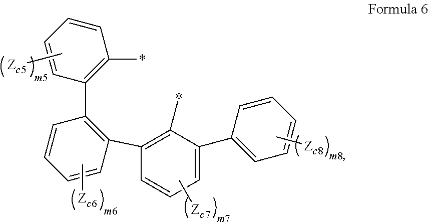
in Formula 6,
—* being a position connected to any one pair of S_{b1} and S_{b2} or S_{b1} and S_{b3} in Formula 5,
Z_{c5} to Z_{c8} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
m5 and m6 being each independently an integer of 0 to 4,
m7 being an integer of 0 to 3,
m8 is being integer of 0 to 5, and
in Formula 5,
Sₐ₁, Sₐ₂, Sₐ₃, R₁ to R₃, and n2 being each the same as defined in Formula 1.

19. The fused polycyclic compound of claim 15, wherein the fused polycyclic compound represented by Formula 1 is represented by any one selected from among Formulas 7-1 to 7-5: 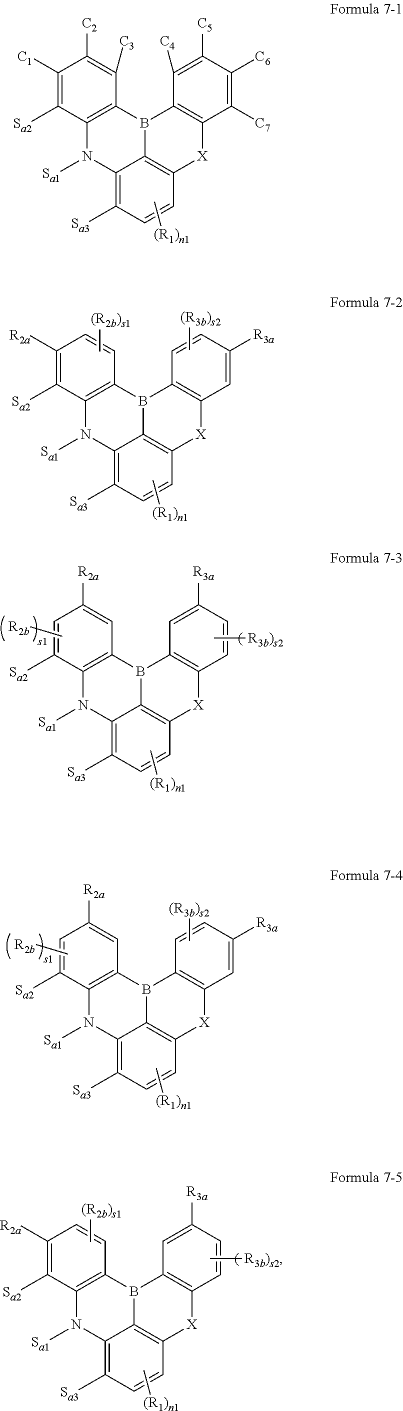
in Formulas 7-1 to 7-5,
C1 to C₇ being each independently hydrogen or deuterium,
R₂ₐ and R₃ₐ being each independently a cyano group, or a substituted or unsubstituted alkyl group having 1 to 10 carbon atoms, or a substituent represented by any one selected from among Formulas A-1 to A-5,
R_{2b} and R_{3b} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
s1 being an integer of 0 to 2,
s2 being an integer of 0 to 3, 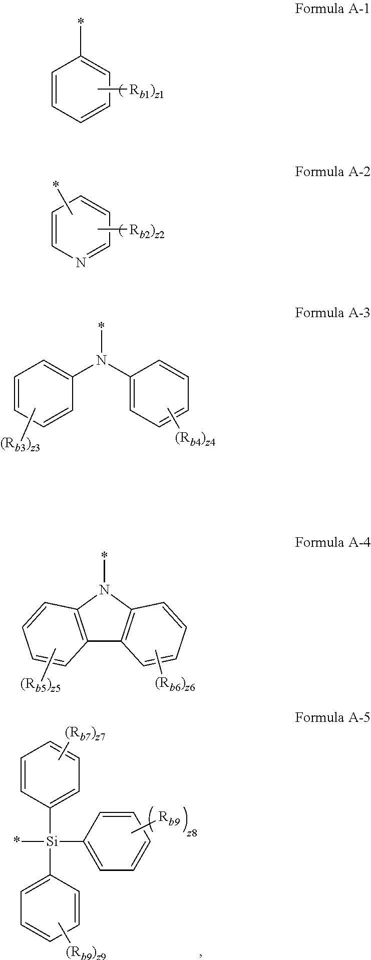
in Formulas A-1 to A-5,
R_{b1} to R_{b9} being each independently hydrogen, deuterium, a halogen, a cyano group, a nitro group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms,
z1, z3, z4, and z7 to z9 being each independently an integer of 0 to 5,
z2, z5, and z6 being each independently an integer of 0 to 4,
—* being a position connected to Formulas 7-2 to 7-4, and
in Formulas 7-1 to 7-5,
X, R₁, n1, Sₐ₁, Sₐ₂, and Sₐ₃ being each the same as defined in Formula 1.

20. The fused polycyclic compound of claim 15, wherein the fused polycyclic compound represented by Formula 1 is any one selected from among compounds of Compound Group 1: 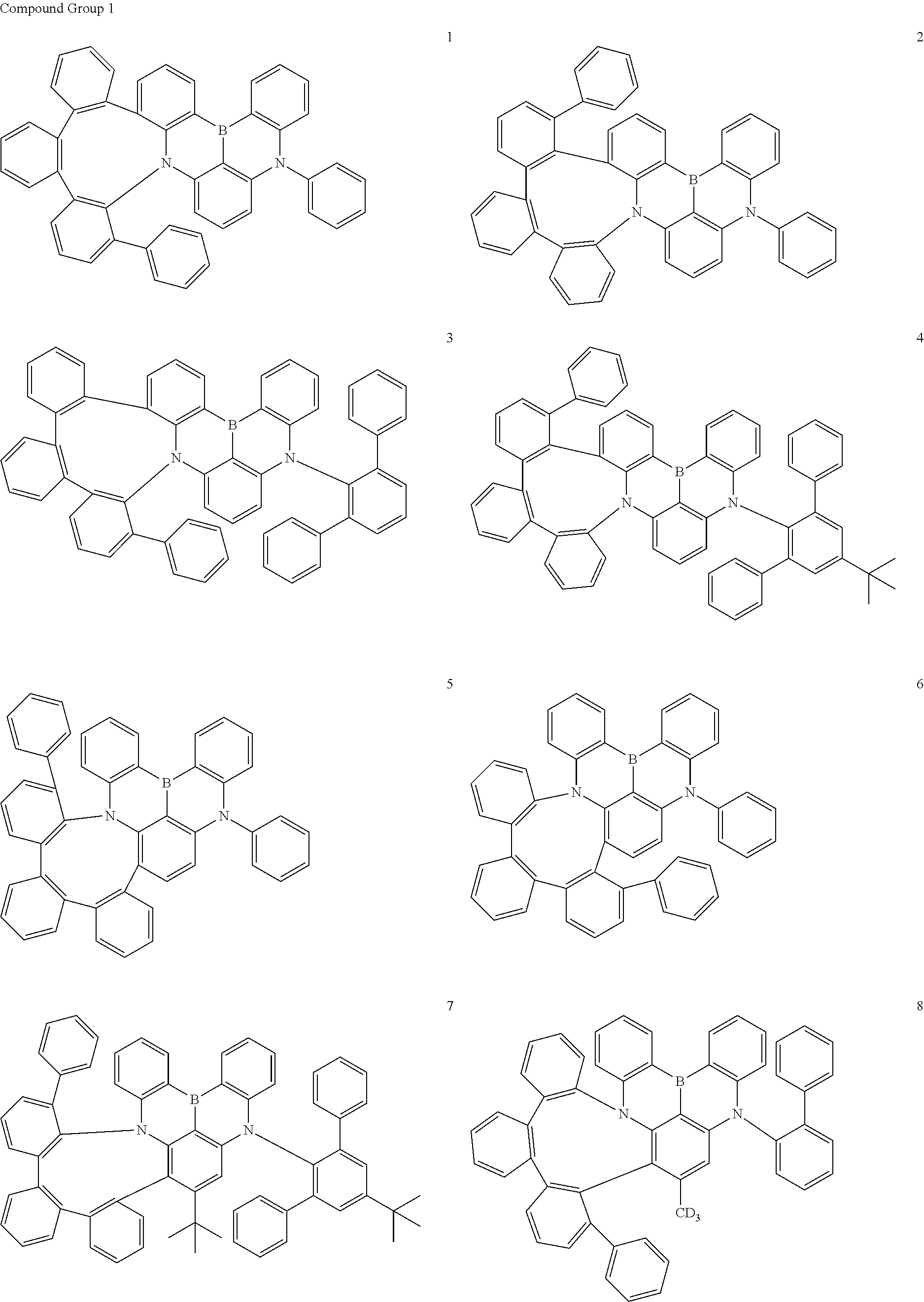 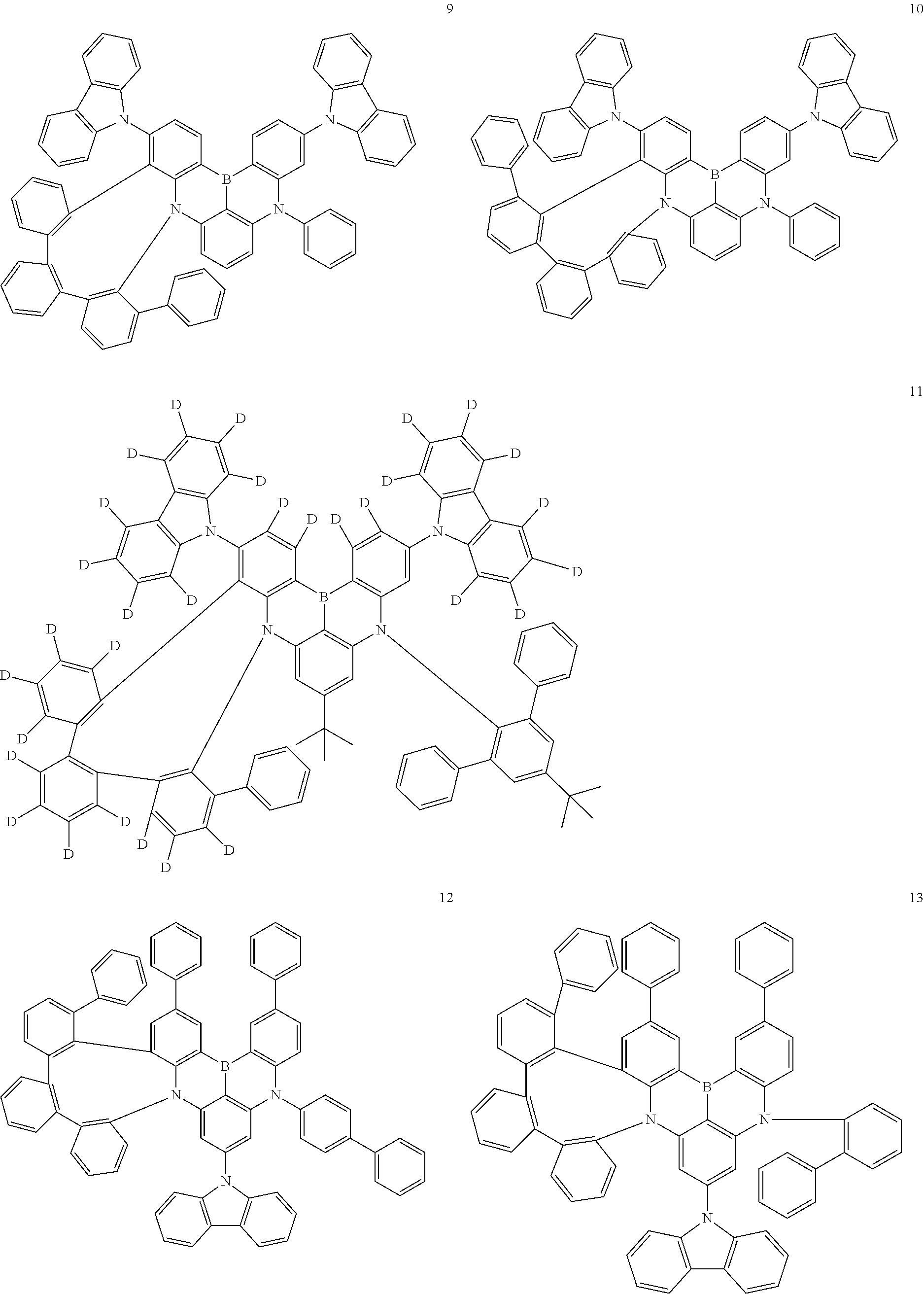 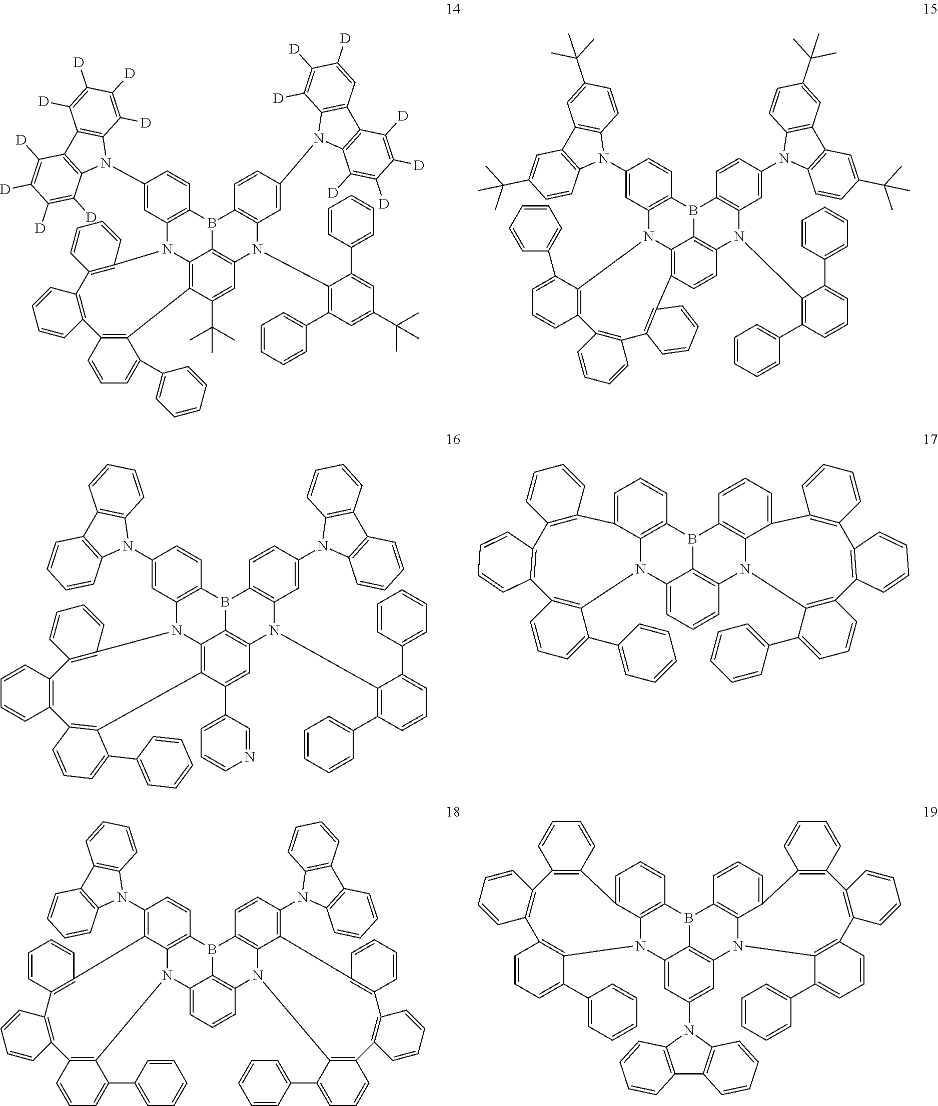 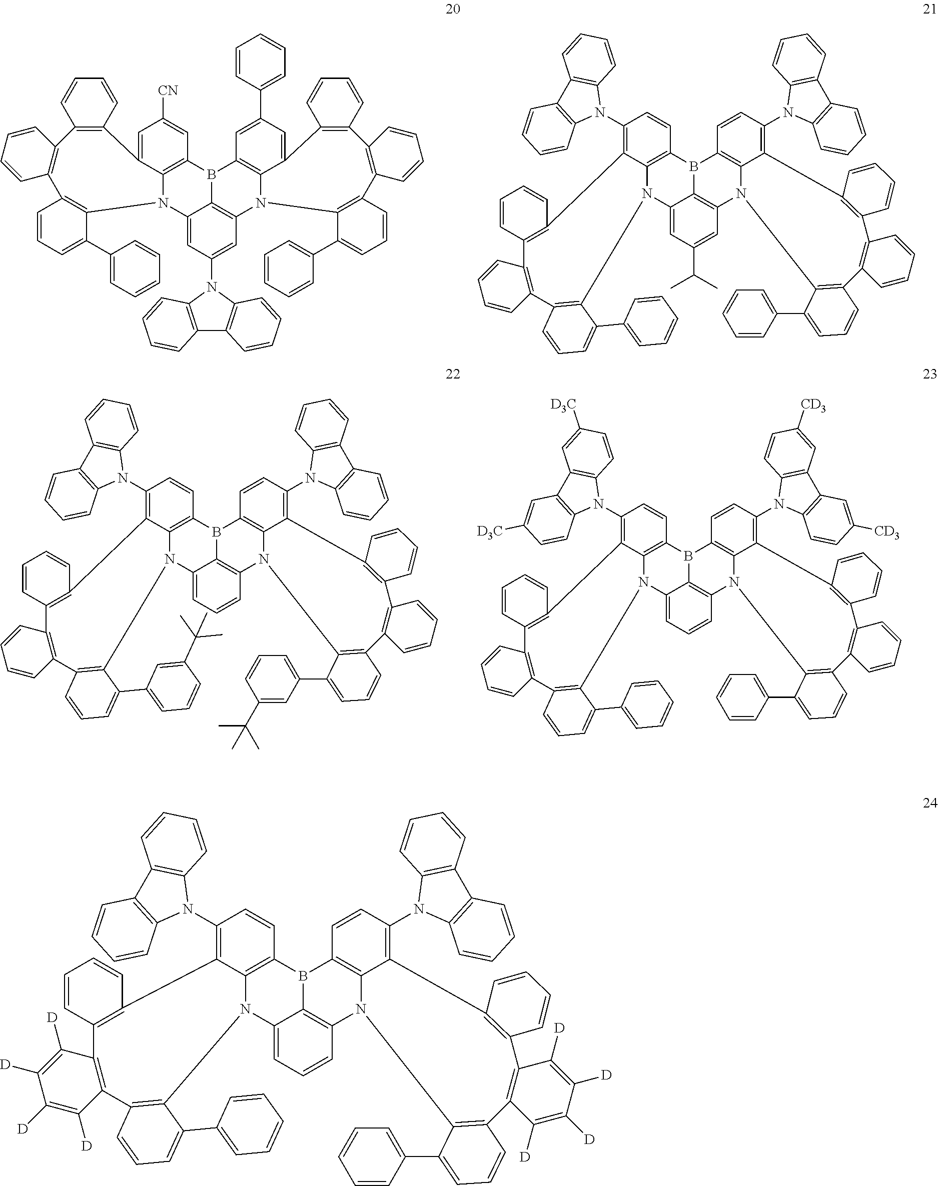 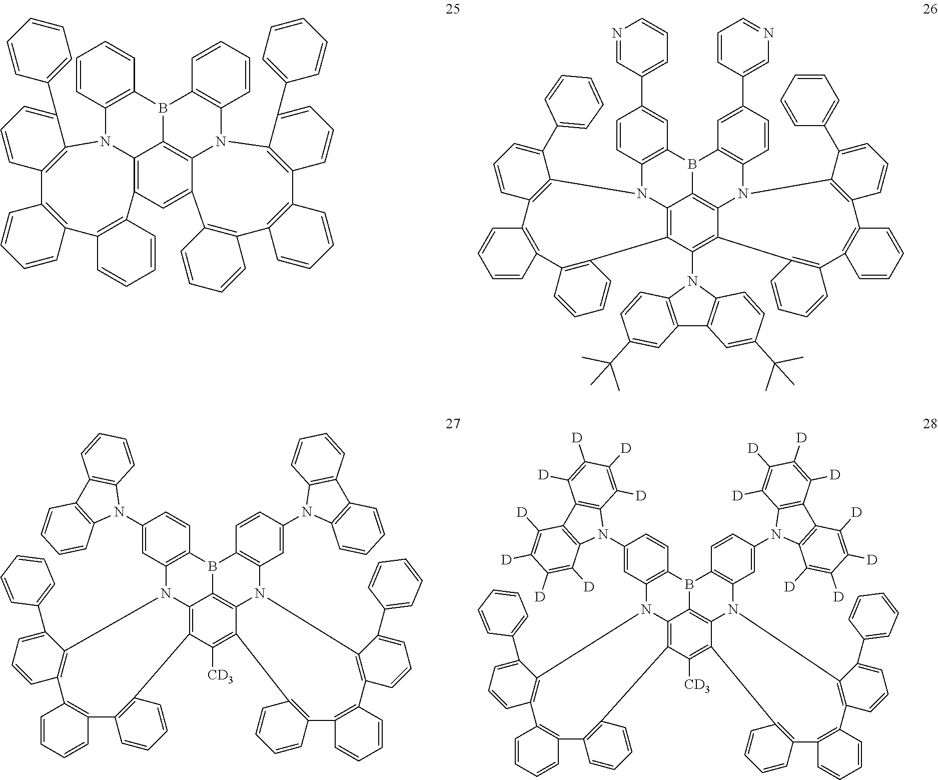 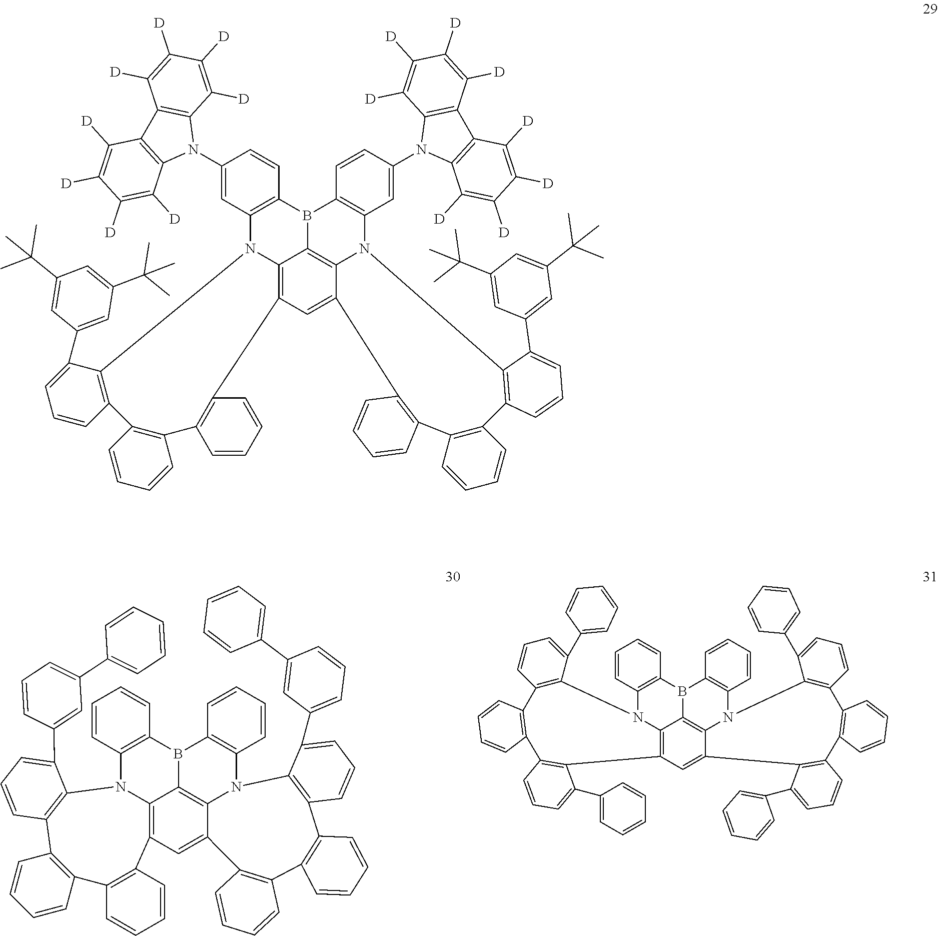 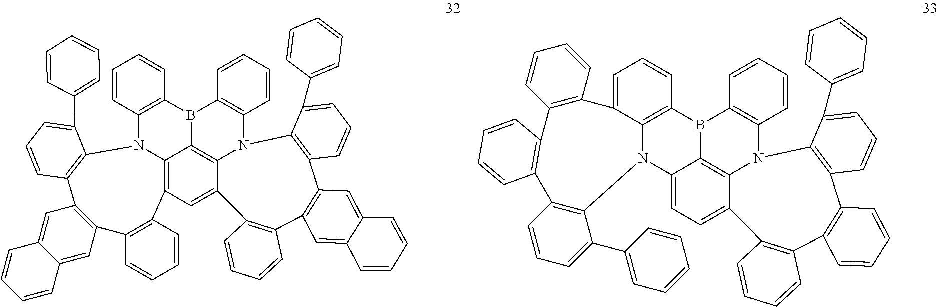 [SMILES: c1ccc(-c2cccc3c4cc5ccccc5cc4c4ccccc4c4cc5c6ccccc6c6cc7ccccc7cc6c6cccc(-c7ccccc7)c6n6c5c5c4n(c23)-c2ccccc2B5c2ccccc2-6)cc1 ; c1ccc(-c2cccc3c4ccccc4c4ccccc4c4cccc5c4n(c23)-c2ccc3c4ccccc4c4ccccc4c4cccc(-c6ccccc6)c4n4c3c2B5c2ccccc2-4)cc1] 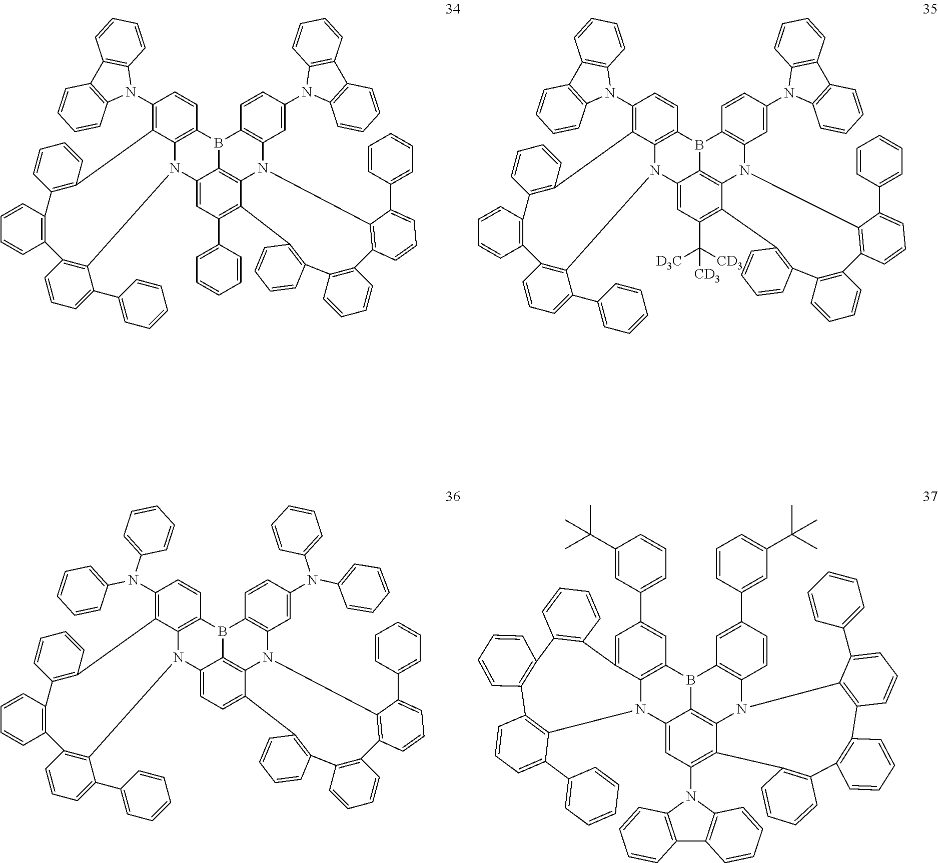 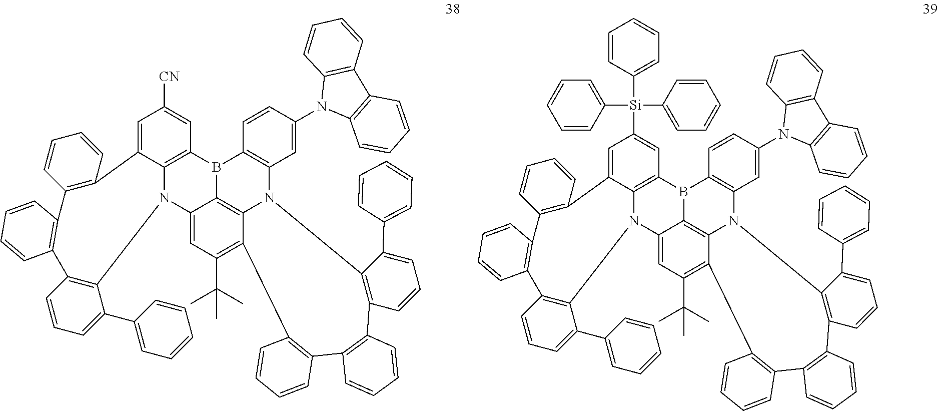 [SMILES: CC(C)(C)c1cc2c3c4c1c1ccccc1c1ccccc1c1cccc(-c5ccccc5)c1n4-c1cc(-n4c5ccccc5c5ccccc54)ccc1B3c1cc(C#N)cc3c4ccccc4c4ccccc4c4cccc(-c5ccccc5)c4n-2c13 ; CC(C)(C)c1cc2c3c4c1c1ccccc1c1ccccc1c1cccc(-c5ccccc5)c1n4-c1cc(-n4c5ccccc5c5ccccc54)ccc1B3c1cc([Si](c3ccccc3)(c3ccccc3)c3ccccc3)cc3c4ccccc4c4ccccc4c4cccc(-c5ccccc5)c4n-2c13] 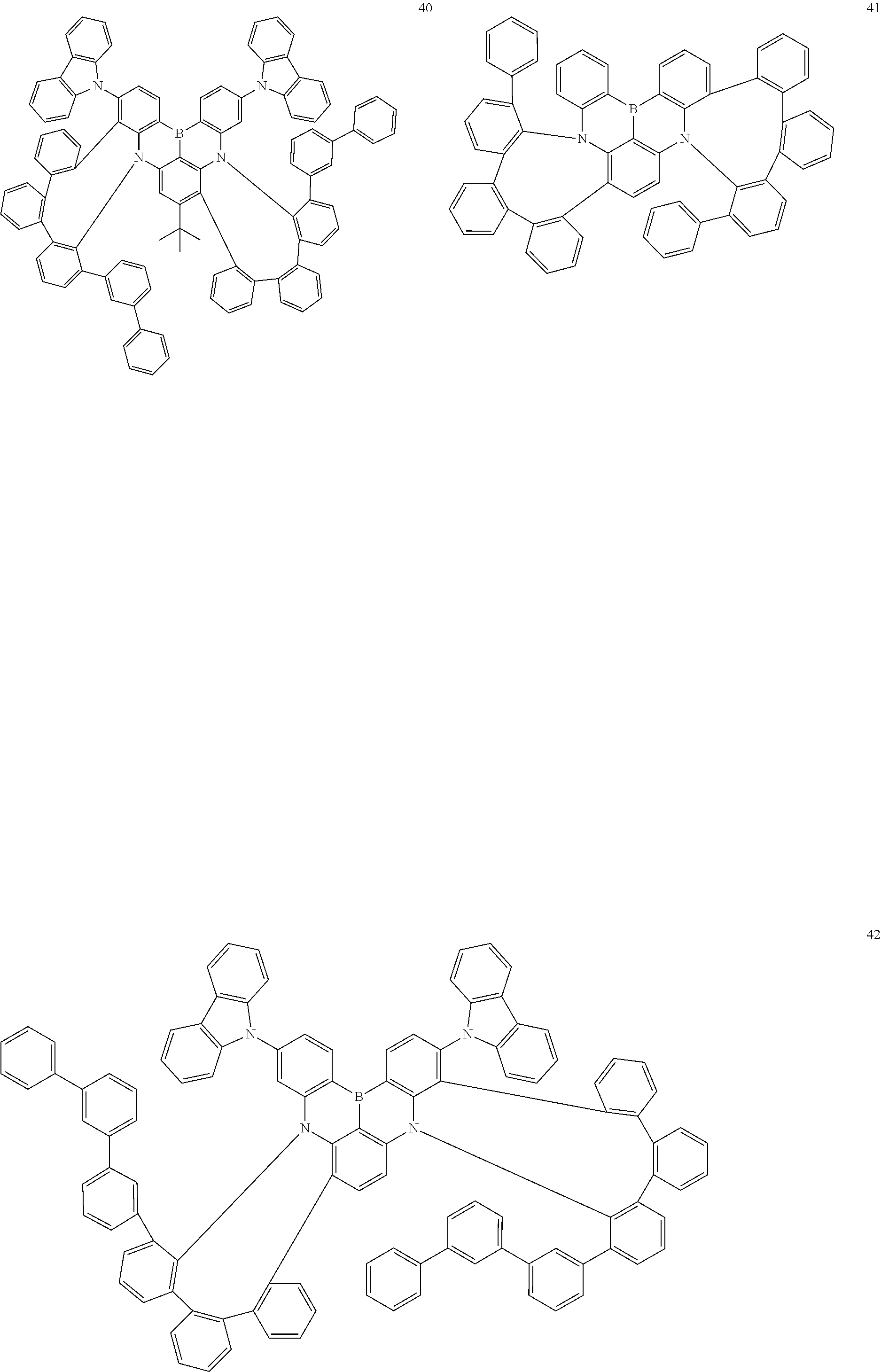 [SMILES: CC(C)(C)c1cc2c3c4c1c1ccccc1c1ccccc1c1cccc(-c5cccc(-c6ccccc6)c5)c1n4-c1cc(-n4c5ccccc5c5ccccc54)ccc1B3c1ccc(-n3c4ccccc4c4ccccc43)c3c4ccccc4c4ccccc4c4cccc(-c5cccc(-c6ccccc6)c5)c4n-2c13 ; c1ccc(-c2cccc3c4ccccc4c4ccccc4c4cccc5c4n(c23)-c2ccc3c4ccccc4c4ccccc4c4cccc(-c6ccccc6)c4n4c3c2B5c2ccccc2-4)cc1 ; c1ccc(-c2cccc(-c3cccc(-c4cccc5c6ccccc6c6ccccc6c6ccc7c8c6n(c45)-c4cc(-n5c6ccccc6c6ccccc65)ccc4B8c4ccc(-n5c6ccccc6c6ccccc65)c5c6ccccc6c6ccccc6c6cccc(-c8cccc(-c9cccc(-c%10ccccc%10)c9)c8)c6n-7c45)c3)c2)cc1] 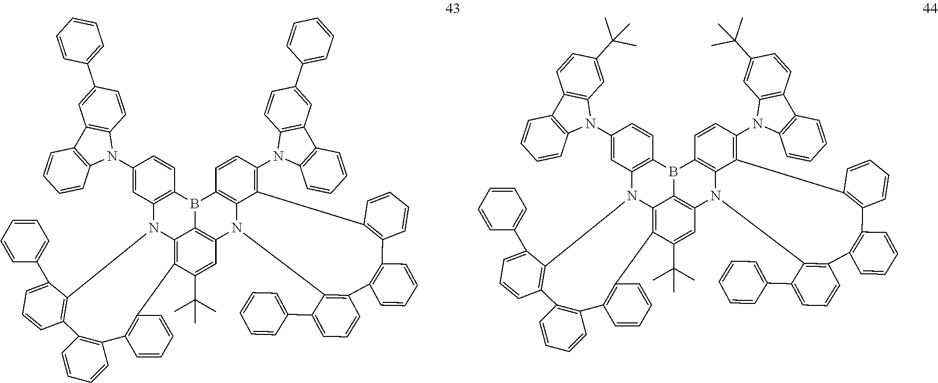 [SMILES: CC(C)(C)c1cc2c3c4c1c1ccccc1c1ccccc1c1cccc(-c5ccccc5)c1n4-c1cc(-n4c5ccccc5c5cc(-c6ccccc6)ccc54)ccc1B3c1ccc(-n3c4ccccc4c4cc(-c5ccccc5)ccc43)c3c4ccccc4c4ccccc4c4cccc(-c5ccccc5)c4n-2c13 ; CC(C)(C)c1ccc2c3ccccc3n(-c3ccc4c(c3)-n3c5c(-c6ccccc6)cccc5c5ccccc5c5ccccc5c5c(C(C)(C)C)cc6c(c53)B4c3ccc(-n4c5ccccc5c5ccc(C(C)(C)C)cc54)c4c5ccccc5c5ccccc5c5cccc(-c7ccccc7)c5n-6c34)c2c1] 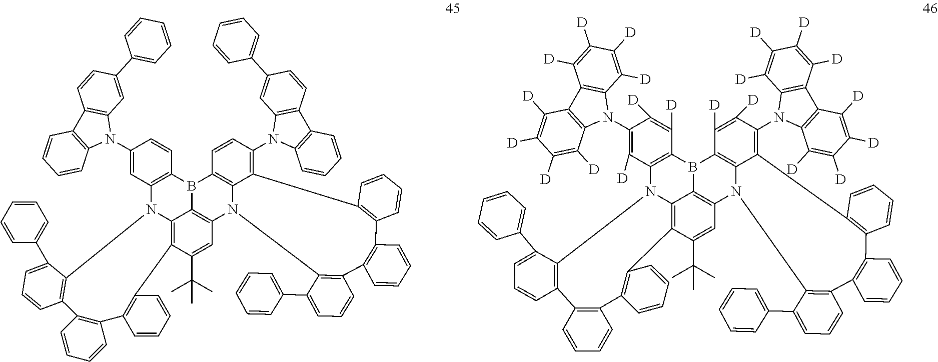 [SMILES: CC(C)(C)c1cc2c3c4c1c1ccccc1c1ccccc1c1cccc(-c5ccccc5)c1n4-c1cc(-n4c5ccccc5c5ccc(-c6ccccc6)cc54)ccc1B3c1ccc(-n3c4ccccc4c4ccc(-c5ccccc5)cc43)c3c4ccccc4c4ccccc4c4cccc(-c5ccccc5)c4n-2c13 ; [2H]c1c([2H])c(-n2c3c([2H])c([2H])c([2H])c([2H])c3c3c([2H])c([2H])c([2H])c([2H])c32)c([2H])c2c1B1c3c([2H])c([2H])c(-n4c5c([2H])c([2H])c([2H])c([2H])c5c5c([2H])c([2H])c([2H])c([2H])c54)c4c5ccccc5c5ccccc5c5cccc(-c6ccccc6)c5n(c34)-c3cc(C(C)(C)C)c4c5ccccc5c5ccccc5c5cccc(-c6ccccc6)c5n-2c4c31] 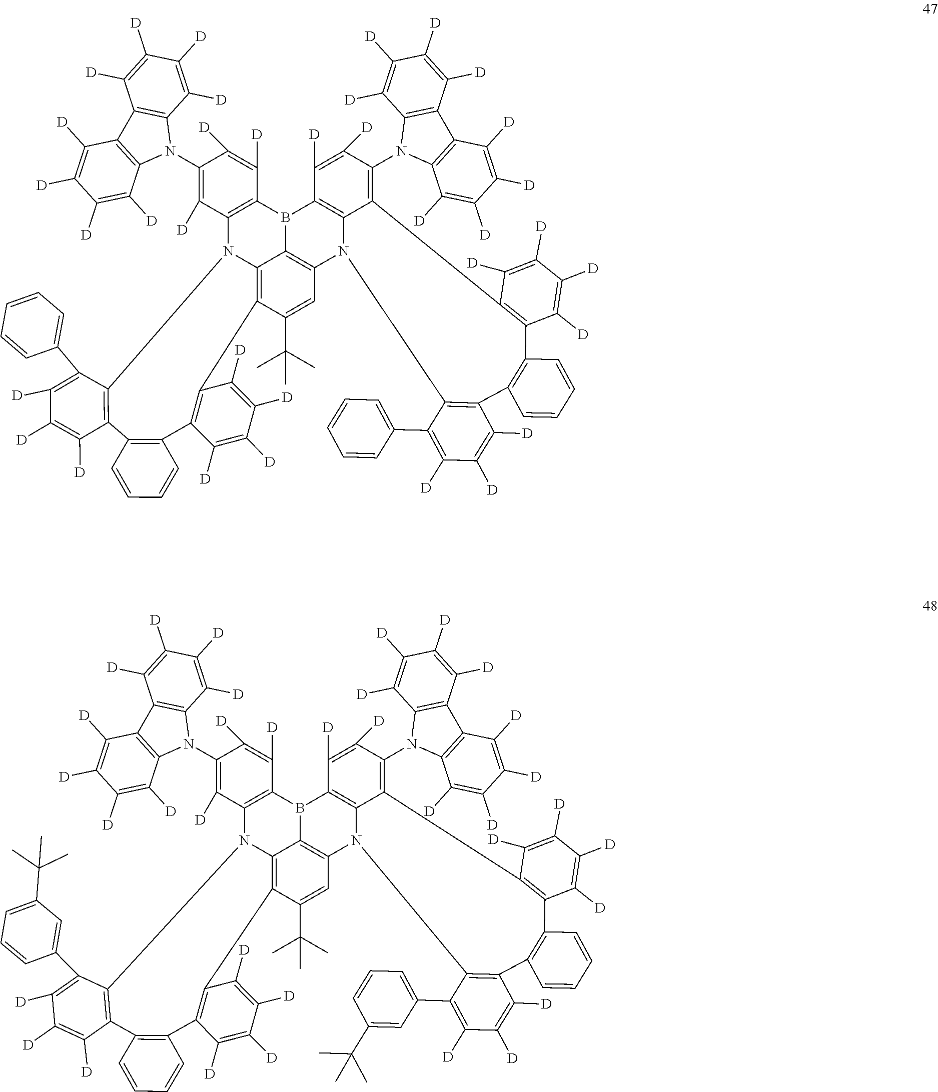 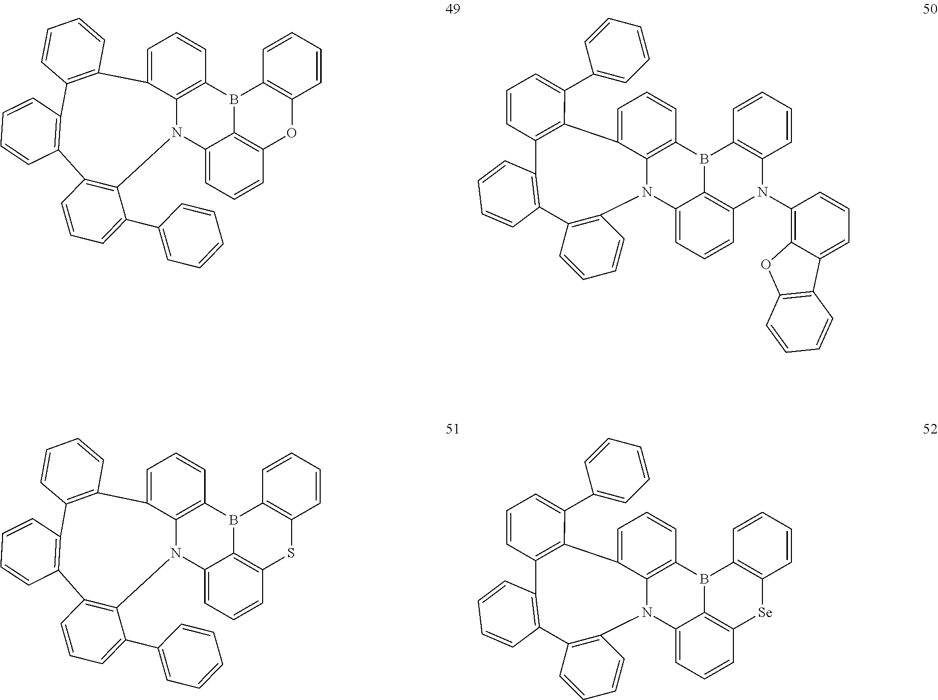 [SMILES: c1ccc(-c2cccc3c4ccccc4c4ccccc4c4cccc5c4n(c23)-c2cccc3c2B5c2ccccc2O3)cc1 ; c1ccc(-c2cccc3c4ccccc4c4ccccc4n4c5c(cccc5c23)B2c3ccccc3N(c3cccc5c3oc3ccccc35)c3cccc-4c32)cc1 ; c1ccc(-c2cccc3c4ccccc4c4ccccc4c4cccc5c4n(c23)-c2cccc3c2B5c2ccccc2S3)cc1 ; c1ccc(-c2cccc3c4ccccc4c4ccccc4n4c5c(cccc5c23)B2c3ccccc3[Se]c3cccc-4c32)cc1] 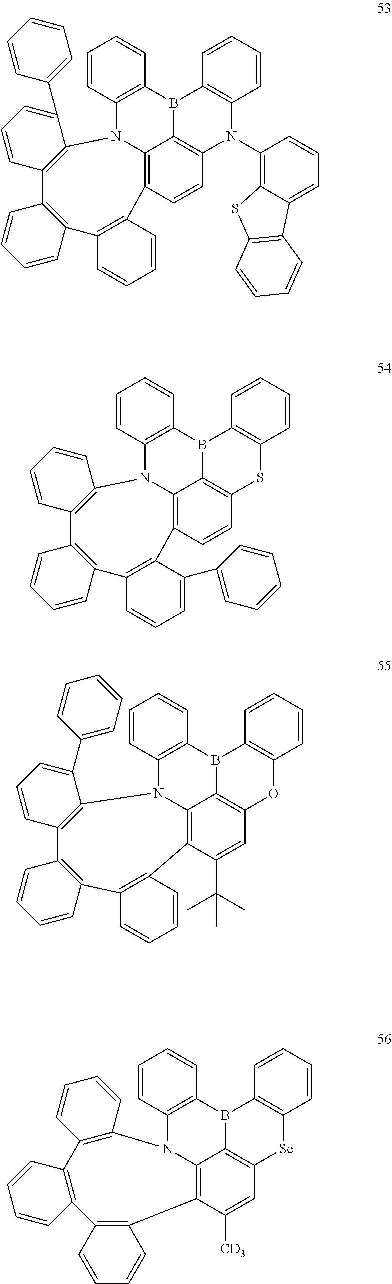 [SMILES: c1ccc(-c2cccc3c4ccccc4c4ccccc4c4ccc5c6c4n(c23)-c2ccccc2B6c2ccccc2N5c2cccc3c2sc2ccccc23)cc1 ; c1ccc(-c2cccc3c4ccccc4c4ccccc4n4c5c6c(ccc5c23)Sc2ccccc2B6c2ccccc2-4)cc1 ; CC(C)(C)c1cc2c3c4c1c1ccccc1c1ccccc1c1cccc(-c5ccccc5)c1n4-c1ccccc1B3c1ccccc1O2 ; [2H]C([2H])([2H])c1cc2c3c4c1c1ccccc1c1ccccc1c1ccccc1n4-c1ccccc1B3c1ccccc1[Se]2] 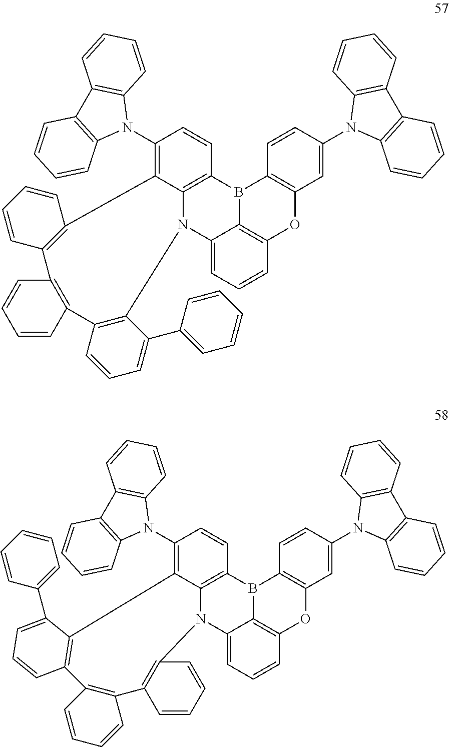 [SMILES: c1ccc(-c2cccc3c4ccccc4c4ccccc4c4c(-n5c6ccccc6c6ccccc65)ccc5c4n(c23)-c2cccc3c2B5c2ccc(-n4c5ccccc5c5ccccc54)cc2O3)cc1 ; c1ccc(-c2cccc3c4ccccc4c4ccccc4n4c5c(ccc(-n6c7ccccc7c7ccccc76)c5c23)B2c3ccc(-n5c6ccccc6c6ccccc65)cc3Oc3cccc-4c32)cc1] 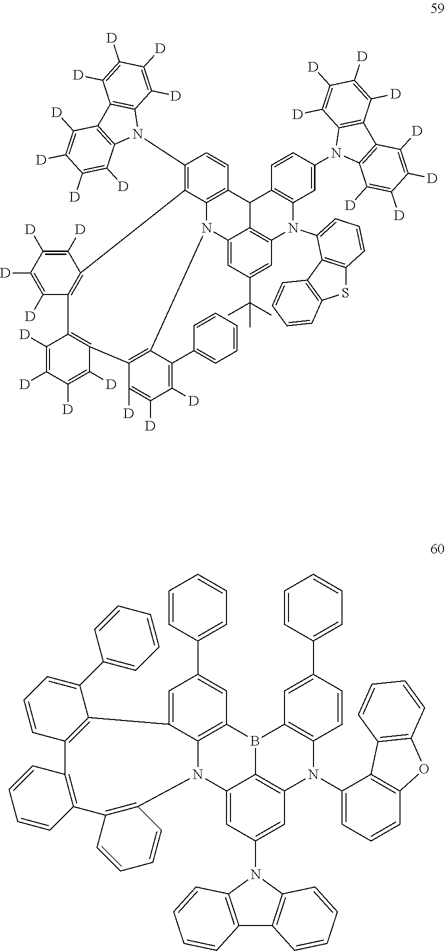 [SMILES: [2H]c1c([2H])c([2H])c2c(c1[2H])c1c([2H])c([2H])c([2H])c([2H])c1c1c([2H])c([2H])c([2H])c(-c3ccccc3)c1n1c3c(ccc(-n4c5c([2H])c([2H])c([2H])c([2H])c5c5c([2H])c([2H])c([2H])c([2H])c54)c23)C2c3ccc(-n4c5c([2H])c([2H])c([2H])c([2H])c5c5c([2H])c([2H])c([2H])c([2H])c54)cc3N(c3cccc4sc5ccccc5c34)c3cc(C(C)(C)C)cc-1c32 ; c1ccc(-c2ccc3c(c2)B2c4c(cc(-n5c6ccccc6c6ccccc65)cc4-n4c5ccccc5c5ccccc5c5cccc(-c6ccccc6)c5c5cc(-c6ccccc6)cc2c54)N3c2cccc3oc4ccccc4c23)cc1] 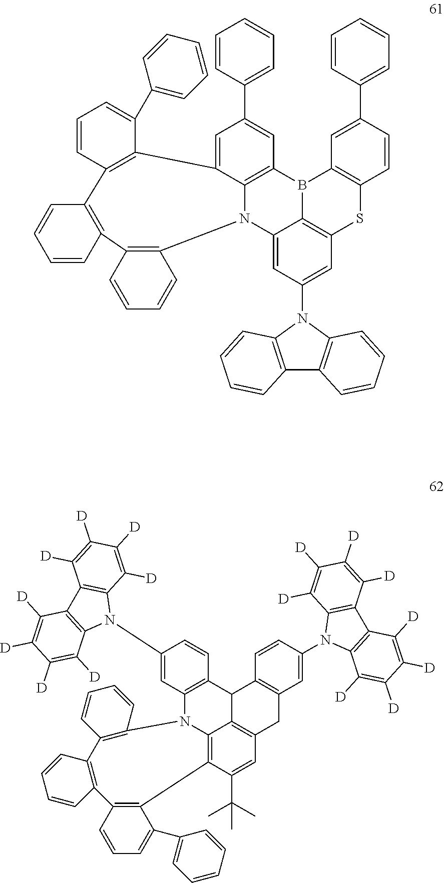 [SMILES: c1ccc(-c2ccc3c(c2)B2c4c(cc(-n5c6ccccc6c6ccccc65)cc4-n4c5ccccc5c5ccccc5c5cccc(-c6ccccc6)c5c5cc(-c6ccccc6)cc2c54)S3)cc1 ; [2H]c1c([2H])c([2H])c2c(c1[2H])c1c([2H])c([2H])c([2H])c([2H])c1n2-c1ccc2c(c1)Cc1cc(C(C)(C)C)c3c4c(-c5ccccc5)cccc4c4ccccc4c4ccccc4n4c3c1C2c1ccc(-n2c3c([2H])c([2H])c([2H])c([2H])c3c3c([2H])c([2H])c([2H])c([2H])c32)cc1-4] 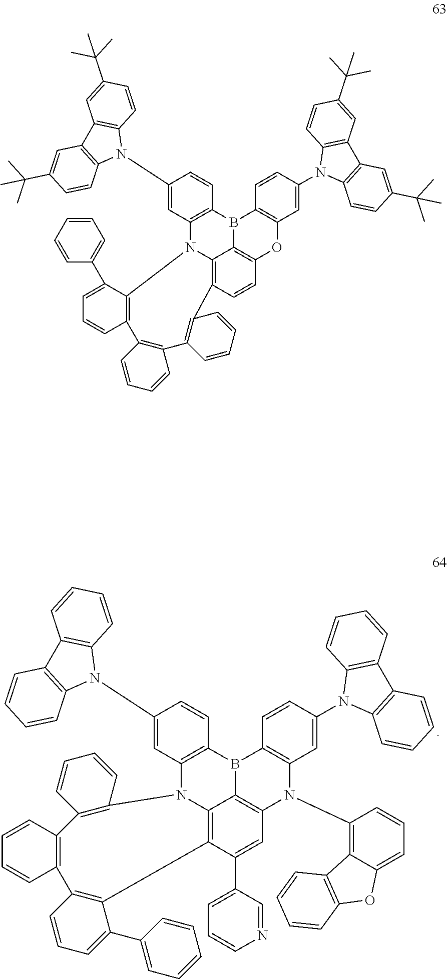 [SMILES: CC(C)(C)c1ccc2c(c1)c1cc(C(C)(C)C)ccc1n2-c1ccc2c(c1)Oc1ccc3c4ccccc4c4ccccc4c4cccc(-c5ccccc5)c4n4c3c1B2c1ccc(-n2c3ccc(C(C)(C)C)cc3c3cc(C(C)(C)C)ccc32)cc1-4 ; c1ccc(-c2cccc3c4ccccc4c4ccccc4n4c5c6c(cc(-c7cccnc7)c5c23)N(c2cccc3oc5ccccc5c23)c2cc(-n3c5ccccc5c5ccccc53)ccc2B6c2ccc(-n3c5ccccc5c5ccccc53)cc2-4)cc1]
